(19) United States
(12) Patent Application Publication
(10) Pub. No.: US 2025/0017032 A1
(43) Pub. Date: Jan. 9, 2025

(54) LIGHT EMITTING ELEMENT AND POLYCYCLIC COMPOUND FOR THE LIGHT EMITTING ELEMENT

(71) Applicant: Samsung Display Co., Ltd., Yongin-si (KR)

(72) Inventors: JANG YEOL BAEK, Yongin-si (KR); TAEIL KIM, Yongin-si (KR); SUN YOUNG PAK, Yongin-si (KR); JUNHA PARK, Yongin-si (KR); Kyoung SUNWOO, Yongin-si (KR); MUN-KI SIM, Yongin-si (KR); CHANSEOK OH, Yongin-si (KR); MINJUNG JUNG, Yongin-si (KR)

(73) Assignee: Samsung Display Co., Ltd., Yongin-si (KR)

(21) Appl. No.: 18/751,557

(22) Filed: Jun. 24, 2024

(30) Foreign Application Priority Data
Jun. 26, 2023 (KR) 10-2023-0082104

(51) Int. Cl. H10K 50/11; H10K 85/30; H10K 85/40; H10K 85/60; H10K 101/10

(52) U.S. Cl. CPC H10K 50/11; H10K 85/342; H10K 85/346; H10K 85/40; H10K 85/622; H10K 85/633; H10K 85/636; H10K 85/654; H10K 85/6572; H10K 85/6574; H10K 85/6576; H10K 85/658; H10K 2101/10

(57) ABSTRACT

Embodiments provide a polycyclic compound and a light emitting element that includes the polycyclic compound. The light emitting element includes a first electrode, a second electrode disposed on the first electrode, and an emission layer disposed between the first electrode and the second electrode and including the polycyclic compound. The polycyclic compound is represented by Formula 1, which is explained in the specification.

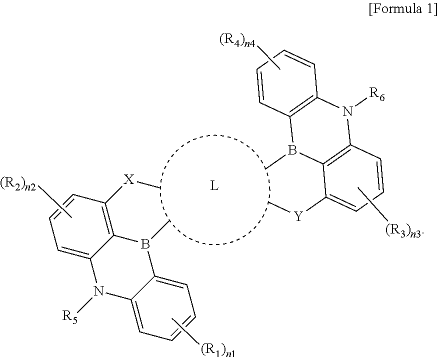

### CROSS-REFERENCE TO RELATED APPLICATION(S)

This application claims priority to and benefits of Korean Patent Application No. 10-2023-0082104 under 35 U.S.C. § 119, filed on Jun. 26, 2023 in the Korean Intellectual Property Office, the entire contents of which are incorporated herein by reference.

### BACKGROUND

### 1. Technical Field

The disclosure relates to a light emitting element and a polycyclic compound used in the light emitting element.

### 2. Description of the Related Art

Active development continues for an organic electroluminescence display device as an image display device. An organic electroluminescence display device is different from a liquid crystal display device and is a so-called self-luminescent display device in which holes and electrons respectively injected from a first electrode and a second electrode recombine in an emission layer, so that a light-emitting material including an organic compound in the emission layer emits light to achieve display.

In the application of a light emitting element to a display device, there is a demand for the improvement of driving voltage, emission efficiency and lifetime, and continuous development is required on materials for a light emitting element that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element which may have low driving voltage characteristics and long-life characteristics.

The disclosure provides a polycyclic compound which may reduce the driving voltage and improve the lifetime of a light emitting element.

An embodiment provides a light emitting element which may include a first electrode, a second electrode disposed on the first electrode, and an emission layer disposed between the first electrode and the second electrode. The emission layer may include a first compound represented by Formula 1.

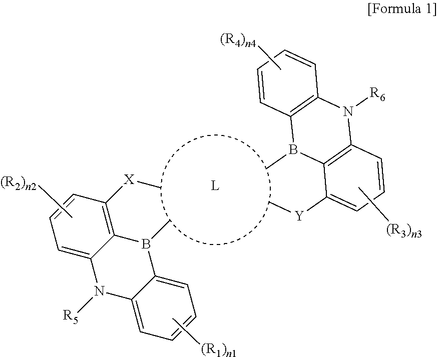

In Formula 1, L may be a substituted or unsubstituted polycyclic aromatic hydrocarbon group of 12 to 25 ring-forming carbon atoms; and X and Y may each independently be N(R₇), O, S, or Se. In Formula 1, R₁ to R₄ may each independently be a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted alkoxy group of 1 to 60 carbon atoms, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms. In Formula 1, R₅ to R₇ may each independently be a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. In Formula 1, n1 and n4 may each independently be an integer from 0 to 4; and n2 and n3 may each independently be an integer from 0 to 3.

In an embodiment, the first compound may be represented by any one of Formula 2-1 to Formula 2-5.

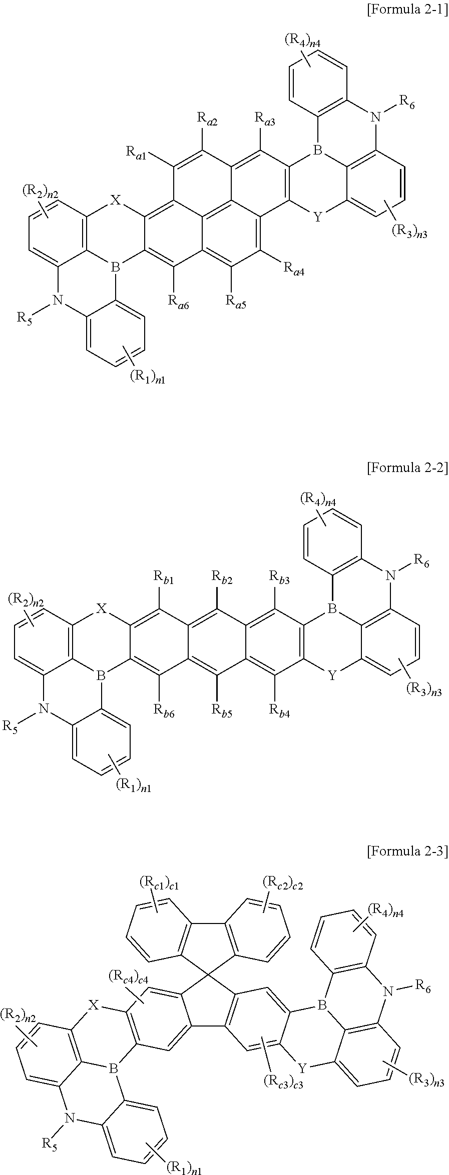

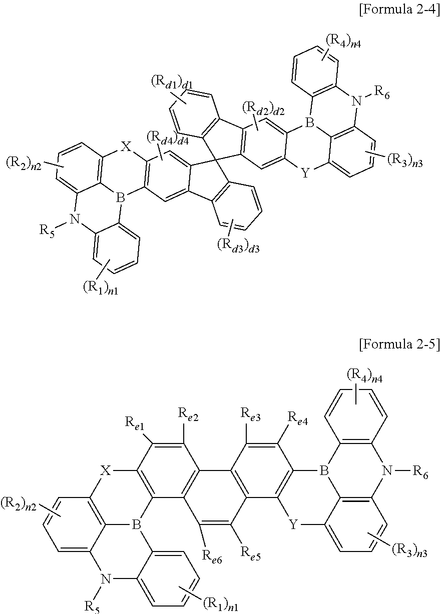

In Formula 2-1 to Formula 2-5, Rₐ₁ to Rₐ₆, R_{b1} to R_{b6}, R_{c1} to R_{c4}, R_{d1} to R_{d4}, and Rₑ₁ to Rₑ₆ may each independently be a hydrogen atom, a deuterium atom, or a substituted or unsubstituted aryl group of 6 to 15 ring-forming carbon atoms. In Formula 2-1 to Formula 2-5, c1, c2, d1, and d3 may each independently be an integer from 0 to 4; c3, c4, d2, and d4 may each independently be an integer from 0 to 2; and X, Y, R₁ to R₆, and n1 to n4 may be the same as defined in Formula 1.

In an embodiment, the first compound may be represented by Formula 2-1A.

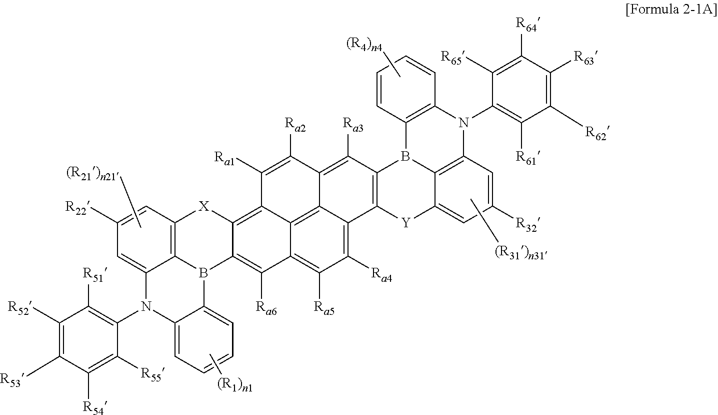

In Formula 2-1A, R₂₁′ and R₃₁′ may each independently be a hydrogen atom or a deuterium atom; and R₂₂′ and R₃₂′ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. In Formula 2-1A, R₅₁′ to R₅₅′ and R₆₁′ to R₆₅′ may each independently be a hydrogen atom, a deuterium atom, a substituted or unsubstituted alkyl group of 1 to 10 carbon atoms, or a substituted or unsubstituted aryl group of 6 to 10 ring-forming carbon atoms. In Formula 2-1A, n21′ and n31′ may each independently be an integer from 0 to 2; and R₁, R₄, Rₐ₁ to Rₐ₆, n1, n4, X, and Y may be the same as defined in Formula 1 and Formula 2-1.

In an embodiment, the first compound may be represented by Formula 2-2A.

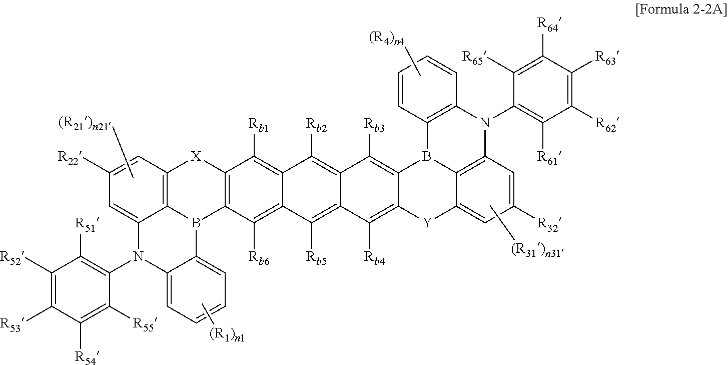

In Formula 2-2A, R₂₁′ and R₃₁′ may each independently be a hydrogen atom or a deuterium atom; and R₂₂′ and R₃₂′ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. In Formula 2-2A, R₅₁′ to R₅₅′ and R₆₁′ to R₆₅′ may each independently be a hydrogen atom, a deuterium atom, a substituted or unsubstituted alkyl group of 1 to 10 carbon atoms, or a substituted or unsubstituted aryl group of 6 to 10 ring-forming carbon atoms. In Formula 2-2A, n21′ and n31′ may each independently be an integer from 0 to 2; and R₁, R₄, R_{b1} to R_{b6}, n1, n4, X, and Y may be the same as defined in Formula 1 and Formula 2-2.

In an embodiment, in Formula 1, L may have a lowest triplet energy level (T1) in a range of about 1.5 eV to about 2.4 eV.

In an embodiment, the first compound may be represented by Formula 3.

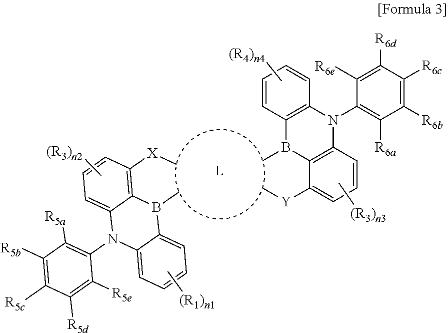

In Formula 3, R₅ₐ to R₅ₑ and R₆ₐ to R₆ₑ may each independently be a hydrogen atom, a deuterium atom, a substituted or unsubstituted alkyl group of 1 to 10 carbon atoms, or a substituted or unsubstituted aryl group of 6 to 10 ring-forming carbon atoms; and R₁ to R₄, n1 to n4, L, X and Y may be the same as defined in Formula 1.

In an embodiment, the first compound may be represented by Formula 4.

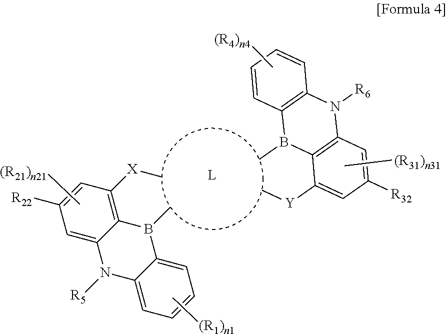

In Formula 4, R₂₁ and R₃₁ may each independently be a hydrogen atom or a deuterium atom; and R₂₂ and R₃₂ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. In Formula 4, n21 and n31 may each independently be an integer from 0 to 2; and R₁, R₄ to R₆, n1, n4, L, X and Y may be the same as defined in Formula 1.

In an embodiment, the first compound may be represented by any one of Formula 5-1 to Formula 5-4.

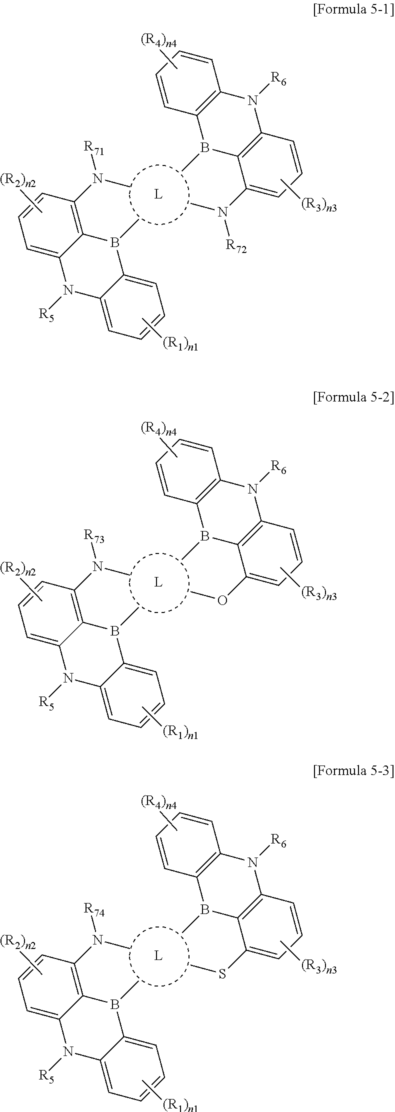

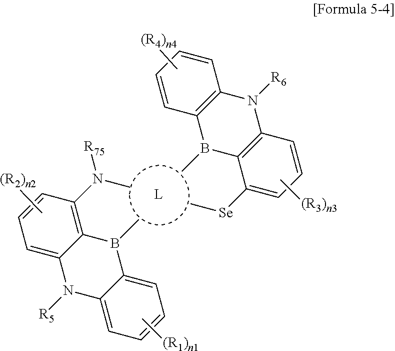

In Formula 5-1 to Formula 5-4, R₇₁ to R₇₅ may each independently be a substituted or unsubstituted aryl group of 6 to 20 ring-forming carbon atoms or a substituted or unsubstituted heteroaryl group of 2 to 20 ring-forming carbon atoms. In Formula 5-1 to Formula 5-4, R₁ to R₆, n1 to n4, and L may be the same as defined in Formula 1.

In an embodiment, in Formula 1, at least one of L and R₁ to R₇ may each independently be a deuterium atom, or a substituent including a deuterium atom.

In an embodiment, the emission layer may further include at least one of a second compound represented by Formula HT-1, a third compound represented by Formula ET-1, and a fourth compound represented by Formula S-1, wherein Formulas HT-1, ET-1, and S-1 are explained below.

In an embodiment, the emission layer may include the first compound, the second compound, and the third compound.

In an embodiment, the emission layer may include the first compound, the second compound, the third compound, and the fourth compound.

In an embodiment, the first compound may include at least one compound selected from Compound Group 1, which is explained below.

An embodiment provides a polycyclic compound which may be represented by Formula 1, which is explained herein.

In an embodiment, L may be a substituted or unsubstituted pyrenyl group, a substituted or unsubstituted anthracenyl group, a substituted or unsubstituted phenanthryl group, or a substituted or unsubstituted fluorenyl group.

In an embodiment, the polycyclic compound represented by Formula 1 may be represented by one of Formula 2-1 to Formula 2-5, which are explained herein.

In an embodiment, the polycyclic compound represented by Formula 2-1 may be represented by Formula 2-1A, which is explained herein.

In an embodiment, the polycyclic compound represented by Formula 2-2 may be represented by Formula 2-2A, which is explained herein.

In an embodiment, the polycyclic compound represented by Formula 1 may be represented by Formula 3, which is explained herein.

In an embodiment, the polycyclic compound represented by Formula 1 may be represented by Formula 4, which is explained herein.

In an embodiment, the polycyclic compound represented by Formula 1 may be represented by one of Formula 5-1 to Formula 5-4, which are explained herein.

In an embodiment, at least one of X and Y may each independently be N(R₇).

In an embodiment, the polycyclic compound represented by Formula 1 may be selected from Compound Group 1, which is explained below.

In an embodiment, wherein in the polycyclic compound represented by Formula 1, a difference between a lowest singlet energy level and a second lowest triplet energy level may be greater than a difference between the second lowest triplet energy level and a lowest triplet energy level.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment

FIG. 5 is a schematic cross-sectional view of a light emitting element according to an embodiment;

FIG. 6 is a schematic cross-sectional view of a light emitting element according to an embodiment;

FIGS. 7A to 7C are schematic diagrams of the energy levels of polycyclic compounds, respectively;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment;

FIG. 11 is a schematic cross-sectional view of a display device according to an embodiment; and

FIG. 12 is a schematic perspective view of an interior of a vehicle including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear or branched. The number of carbon atoms in an alkyl group may be 1 to 60, 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 60, 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group including at least one carbon-carbon double bond in the middle or at a terminus of an alkyl group having 2 or more carbon atoms. An alkenyl group may be linear or branched. The number of carbon atoms in an alkenyl group is not particularly limited, but may be 2 to 60, 2 to 30, 2 to 20, or 2 to 10. Examples of an alkenyl group may include a vinyl group, a 1-butenyl group, a 1-pentenyl group, a 1,3-butadienyl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not particularly limited, but may be 2 to 60, 2 to 30, 2 to 20, or 2 to 10. Examples of an alkynyl group may include an ethynyl group, a propynyl group, etc., but embodiments are not limited thereto.

In the specification, the hydrocarbon ring group may be any functional group or substituent derived from an aliphatic hydrocarbon ring. For example, a hydrocarbon ring group may be a saturated hydrocarbon ring group having 5 to 30 or 5 to 20 ring-forming carbon atoms.

In the specification, an aryl group may be any functional group or substituent derived from an aromatic hydrocarbon ring. An aryl group may be a monocyclic or polycyclic. The number of ring-forming carbon atoms in an aryl group may be 6 to 60, 6 to 30, 6 to 20, 6 to 15, or 6 to 10. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

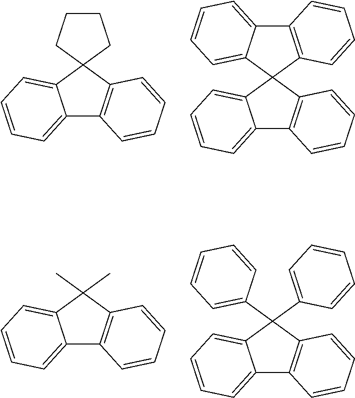

In the specification, a heterocyclic group may be any functional group or substituent derived from a ring including at least one of B, O, N, P, Si, S, and Se as a heteroatom. A heterocyclic group may be an aliphatic heterocyclic group or an aromatic heterocyclic group. An aromatic heterocyclic group may be a heteroaryl group. An aliphatic heterocycle and an aromatic heterocycle may each independently be monocyclic or polycyclic.

In the specification, a heterocyclic group may include at least one of B, O, N, P, Si, S, and Se as a heteroatom. If a heterocyclic group include two or more heteroatoms, the two or more heteroatoms may be the same as or different from each other. A heterocyclic group may be monocyclic heterocyclic or polycyclic heterocyclic. A heterocyclic group may be a heteroaryl group. The number of ring-forming carbon atoms in a heterocyclic group may be 2 to 60, 2 to 30, 2 to 20, or 2 to 10.

In the specification, an aliphatic heterocyclic group may include at least one of B, O, N, P, Si, S, and Se as a heteroatom. The number of ring-forming carbon atoms in an aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, and Se as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. The description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, but may be 1 to 40, 1 to 30, or 1 to 20. For example, a carbonyl group may have one of the following structures, but embodiments are not limited thereto.

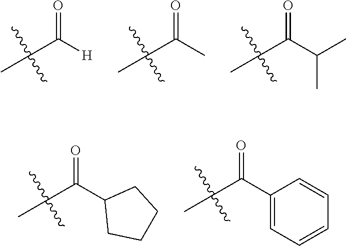

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. The alkyl group in the alkylthio group may be linear, branched, or cyclic. The number of carbon atoms in the alkylthio is not particularly limited, and may be, for example, 1 to 20 or 1 to 10. The number of carbon atoms in the arylthio group is not particularly limited, and may be, for example, 6 to 30, 6 to 20, or 6 to 15. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, or a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group herein may be a boron atom that is bonded to an alkyl group or an aryl group as defined above. A boron group may be an alkyl boron group or an aryl boron group. The alkyl group in the alkyl boron group may be linear, branched, or cyclic. The number of carbon atoms in the alkyl boron group is not particularly limited, and may be, for example, 1 to 20 or 1 to 10. The number of carbon atoms in the aryl boron group is not particularly limited, and may be, for example, 6 to 30, 6 to 20, or 6 to 15. Examples of a boron group may include a dimethylboron group, a t-butyldimethylboron group, a diphenylboron group, a phenylboron group, etc., but embodiments are not limited thereto.

In the specification, the number of carbon atoms in an amine group is not particularly limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

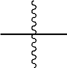

and [symbol] each represent a bond to a neighboring atom in a corresponding formula or moiety.

Hereinafter, embodiments will be described with reference to the accompanying drawings.

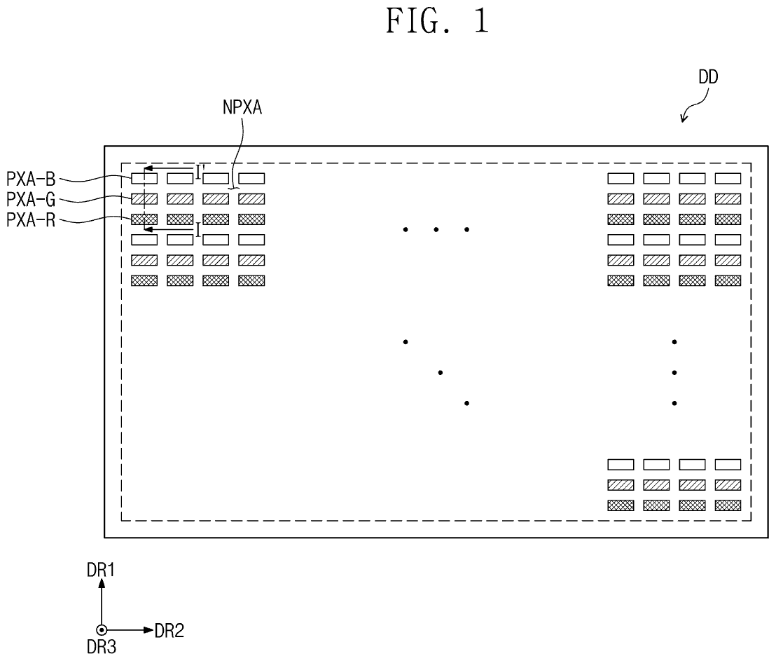

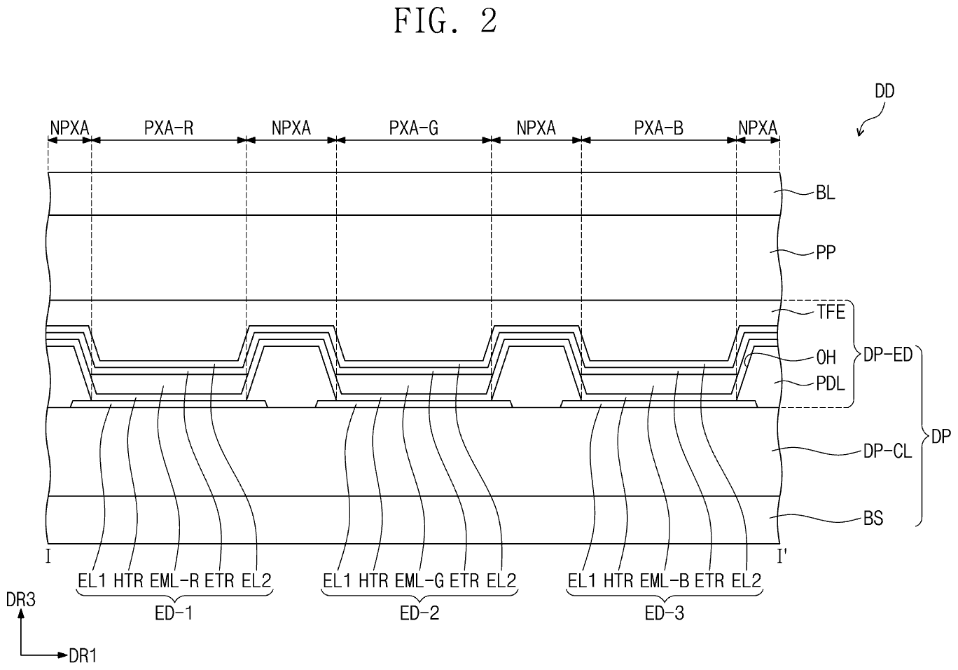

FIG. 1 is a schematic plan view of a display device DD according to an embodiment. FIG. 2 is a schematic cross-sectional view of a display device DD according to an embodiment. FIG. 2 is a cross-sectional view of a part taken along line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

In an embodiment, a base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

In an embodiment, the display panel DP may include a base layer BS, a circuit layer DP-CL provided on the base layer BS, and the display device layer DP-ED. The display device layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

In an embodiment, the base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display device layer DP-ED.

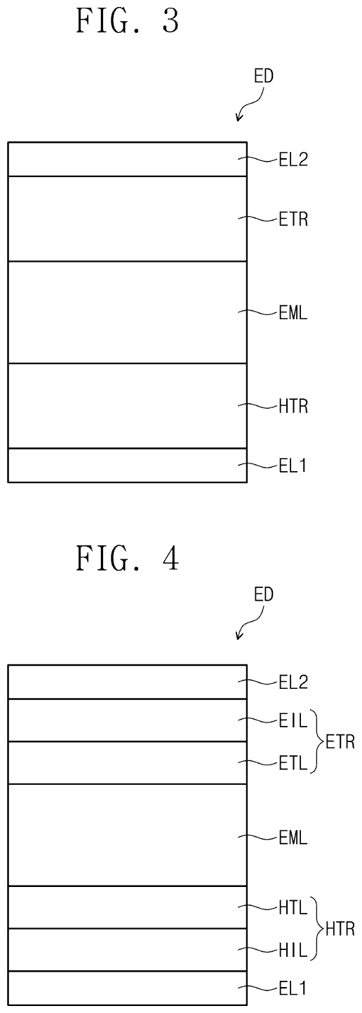

The light emitting elements ED-1, ED-2, and ED-3 may each have a structure of a light emitting element ED according to an embodiment according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for all of the light emitting elements ED-1, ED-2, and ED-3. However, the embodiments are not limited thereto. Although not shown in FIG. 2, in an embodiment, the hole transport region HTR and the electron transport region ETR may each be provided by being patterned in the openings OH defined in the pixel defining film PDL. In an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or multiple layers. The encapsulation layer TFE may include at least one insulation layer. The encapsulation layer TFE may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not particularly limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between the adjacent light emitting regions PXA-R, PXA-G, and PXA-B, and which correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined by the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from one another.

In the display device DD according to an embodiment, the light emitting elements ED-1, ED-2 and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit a light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2. A third directional axis DR3 may be perpendicular to a plane defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as PENTILE®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

FIG. 3 to FIG. 6 are each a schematic cross-sectional view of a light emitting elements according to an embodiment. The light emitting element ED according to an embodiment may include a first electrode EL1, a second electrode EL2 oppositely disposed to the first electrode EL1, and at least one functional layer disposed between the first electrode EL1 and the second electrode EL2. The light emitting element ED according to an embodiment may include the polycyclic compound according to an embodiment, which will be explained later, in the at least one functional layer.

The light emitting element ED may include a hole transport region HTR, an emission layer EML, an electron transport region ETR, or the like, stacked in order as the at least one functional layer. The light emitting element ED according to an embodiment may include a first electrode EL1, a hole transport region HTR, an emission layer EML, an electron transport region ETR, and a second electrode EL2, stacked in order.

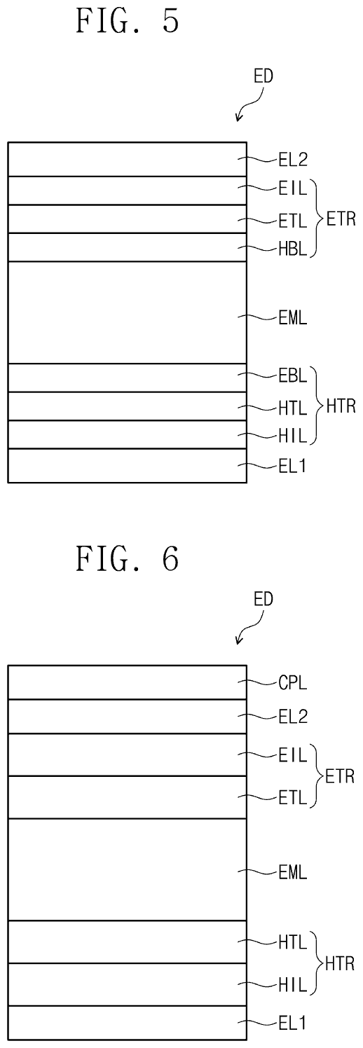

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 is a schematic embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another example, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be in a range of from about 50 Å to about 15,000 Å.

The hole transport region HTR may be a layer consisting of a single material, a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

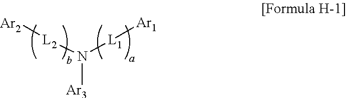

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is an integer equal to or greater than 2, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

In an embodiment, a compound represented by Formula H-1 may be a monoamine compound. In an embodiment, a compound represented by Formula H-1 may be a diamine compound in which at least one of Ar₁ to Ar₃ includes an amine group as a substituent. In another embodiment, a compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

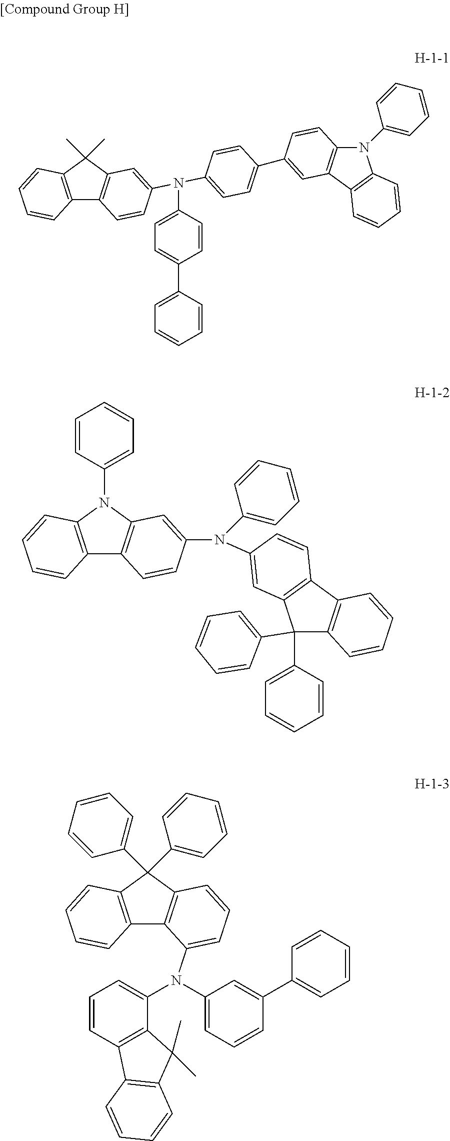 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

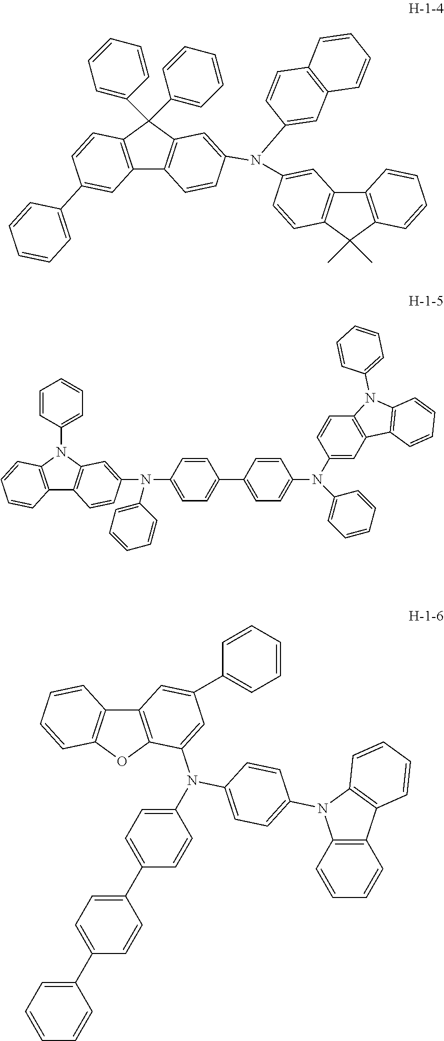 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

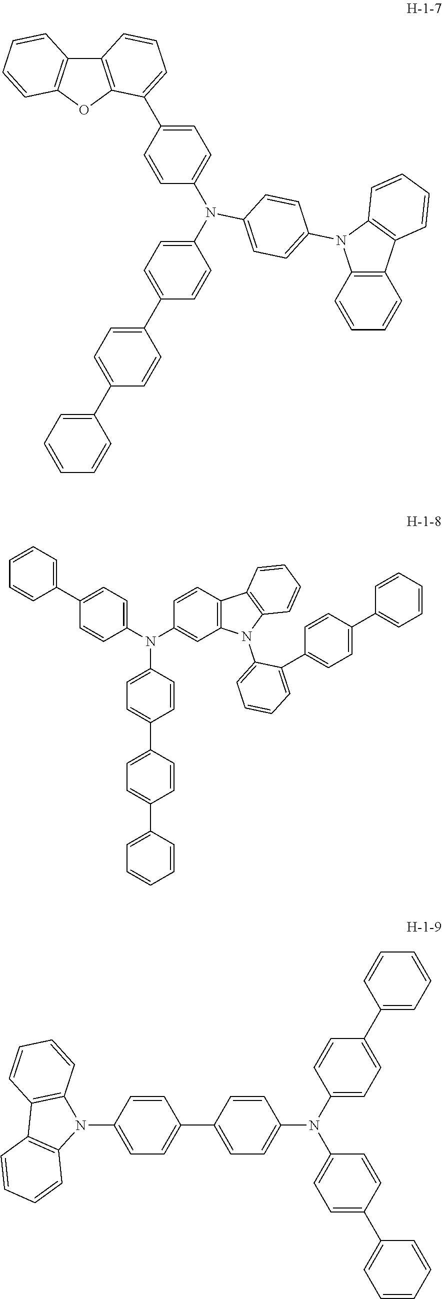 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

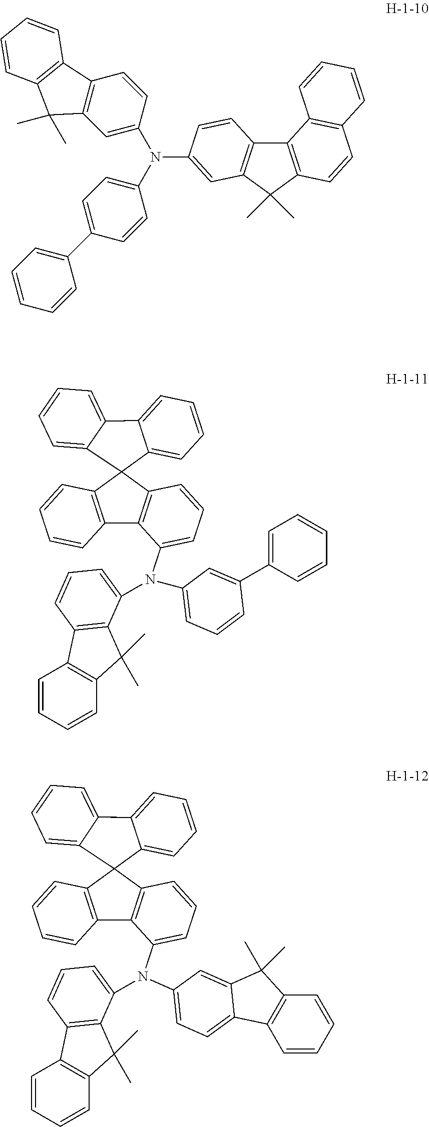 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

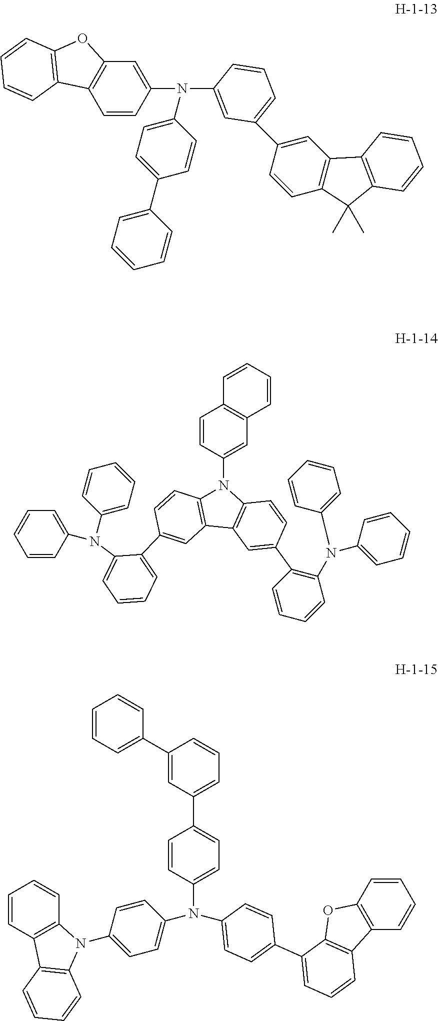 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

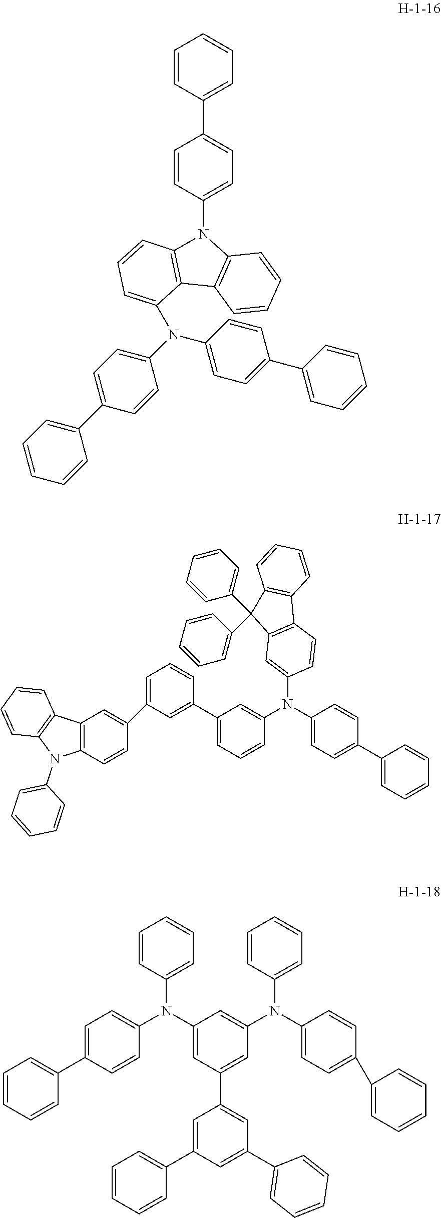 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

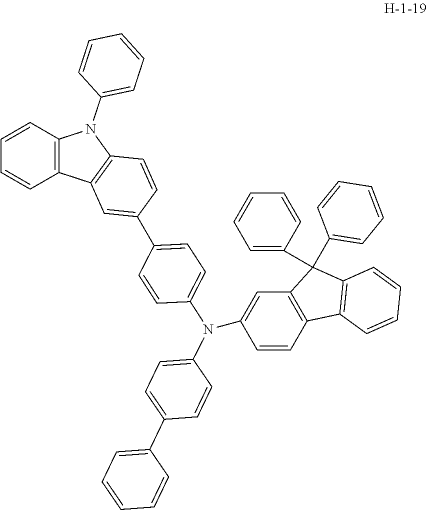 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. For example, when the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto.

For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HAT-CN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL in addition to the hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown). The electron blocking layer EBL may prevent the injection of electrons from an electron transport region ETR to the hole transport region HTR.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

The light emitting element ED may include a polycyclic compound represented by Formula 1 in at least one functional layer disposed between the first electrode EL1 and the second electrode EL2. In the light emitting element ED, the emission layer EML may include the polycyclic compound according to an embodiment. The emission layer EML may include the polycyclic compound as a dopant. The polycyclic compound according to an embodiment may be a dopant material in the emission layer EML. In the description, the polycyclic compound according to an embodiment may be referred to as the first compound.

The polycyclic compound may include the core part of polycyclic aromatic hydrocarbons (PAHs). The polycyclic aromatic hydrocarbon rings may mean a fused structure of multiple aromatic rings. The polycyclic compound according to an embodiment may include the fused structure of fused rings including one boron atom and two heteroatoms as ring-forming atoms in the core part. For example, the polycyclic compound may include a fused structure of two fused rings formed by fusing multiple aromatic rings via one boron atom and two heteroatoms in the core part.

In an embodiment, the polycyclic compound may include a fused structure of multiple aromatic rings via a first boron atom, a second boron atom, a first nitrogen atom, a second nitrogen atom, a first heteroatom and a second heteroatom. For example, the polycyclic compound may include a connected structure of a first fused ring including a first boron atom, a first nitrogen atom, and a first heteroatom, and a second fused ring including a second boron atom, a second nitrogen atom, and a second heteroatom, while sharing polycyclic aromatic hydrocarbon rings. For example, the polycyclic compound may include a fused structure of the first fused ring and the second fused ring in the core part. The core part may be connected to the first boron atom and the first heteroatom of the first fused ring, and the second boron atom and the second heteroatom of the second fused ring.

In an embodiment, a lowest triplet energy level (T1) of the core part may substantially determine a lowest triplet energy level (T1) of the polycyclic compound. Accordingly, if the lowest triplet energy level (T1) of the core part is low, the lowest triplet energy level (T1) of the polycyclic compound may be low. The polycyclic compound according to an embodiment includes an organic compound having a low value of a lowest triplet energy level (T1) in the core part, and a lowest triplet energy level (T1) of the whole polycyclic compound may be low. For example, the polycyclic compound may include polycyclic aromatic hydrocarbon rings having the lowest triplet energy level (T1) of about equal to or less than 2.4 eV in the core part. In an embodiment, the lowest triplet energy level (T1) of the polycyclic aromatic hydrocarbon rings included in the core part may be about 1.5 eV to about 2.4 eV. In an embodiment, the polycyclic aromatic hydrocarbon rings having the lowest triplet energy level (T1) in a range of about 1.5 eV to about 2.4 eV may be pyrene, anthracene, phenanthrene, or fluorene, but embodiments are not limited thereto. The pyrene, anthracene, phenanthrene, and fluorene may each independently be substituted or unsubstituted. In the specification, the lowest triplet energy level (T1) may be referred to as the lowest triplet state energy level (T1) or the lowest triplet excitation energy level (T1).

The polycyclic compound according to an embodiment may be represented by Formula 1. In Formula 1, L may correspond to the above-described core part. A fused ring which includes substituent X and N—R₅ as ring-forming atoms and which includes fused benzene rings which are substituted with substituents represented by R₁ and R₂, may correspond to the first fused ring. A fused ring which includes substituent Y and N—R₆ as ring-forming atoms and which includes fused benzene rings which are substituted with substituents represented by R₃ and R₄, may correspond to the second fused ring.

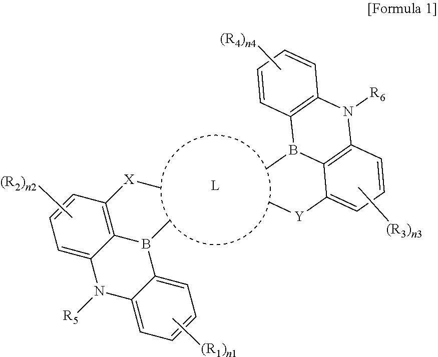

In Formula 1, L may be a substituted or unsubstituted polycyclic aromatic hydrocarbon group having a low value of a lowest triplet energy level (T1). In an embodiment, in Formula 1, L may be a substituted or unsubstituted polycyclic aromatic hydrocarbon group having a lowest triplet energy level (T1) in a range of about 1.5 eV to about 2.4 eV. In an embodiment, in Formula 1, L may be a substituted or unsubstituted polycyclic aromatic hydrocarbon group of 12 to 25 ring-forming carbon atoms. In an embodiment, L may be a substituted or unsubstituted pyrenyl group, a substituted or unsubstituted anthracenyl group, a substituted or unsubstituted phenanthryl group, or a substituted or unsubstituted fluorenyl group. If L is a substituted group, the substituent may be a deuterium atom, or a substituted or unsubstituted aryl group of 6 to 15 ring-forming carbon atoms, without limitation.

In Formula 1, X and Y may each independently be N(R₇), O, S, or Se. X may correspond to the above-explained first heteroatom, and Y may correspond to the above-explained second heteroatom. In an embodiment, X and Y may be the same or different. In an embodiment, at least one of X and Y may each independently be N(R₇). For example, X and Y may each independently be N(R₇). As another example, any one of X and Y may be N(R₇), and the other one may be O, S, or Se.

In Formula 1, R₁ to R₄ may each independently be a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted alkoxy group of 1 to 60 carbon atoms, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms. For example, R₁ to R₄ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. In an embodiment, R₁ to R₄ may each independently be a hydrogen atom, a deuterium atom, a substituted or unsubstituted diphenylamine group, a substituted or unsubstituted t-butyl group, a substituted or unsubstituted phenyl group, or a substituted or unsubstituted carbazole group, but embodiments are not limited thereto.

In Formula 1, R₅ to R₇ may each independently be a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. For example, R₅ to R₇ may each independently be a substituted or unsubstituted phenyl group, a substituted or unsubstituted biphenyl group, a substituted or unsubstituted terphenyl group, or a substituted or unsubstituted dibenzofuran group.

In Formula 1, n1 and n4 may each independently be an integer from 0 to 4. In Formula 1, if n1 and n4 are 0, the polycyclic compound according to an embodiment may be unsubstituted with R₁ and R₄, respectively. Cases where n1 and n4 are 4, and R₁ and R₄ are all hydrogen atoms, may be the same as cases where n1 and n4 are 0, respectively. If n1 and n4 are integers of 2 or more, each of multiple R₁ and R₄ may be the same, or at least one of each of multiple R₁ and R₄ may be different.

In Formula 1, n2 and n3 may each independently be an integer from 0 to 3. In Formula 1, if n2 and n3 are 0, the polycyclic compound may be unsubstituted with R₂ and R₃, respectively. In Formula 1, cases where n2 and n3 are 3, and R₂ and R₃ are all hydrogen atoms, may be the same as cases where n2 and n3 are 0, respectively. If n2 and n3 are integers of 2 or more, each of multiple R₂ and R₃ may be the same, or at least one of each of multiple R₂ and R₃ may be different.

The polycyclic compound represented by Formula 1 includes an organic compound (polycyclic aromatic hydrocarbons, PAHs) having a low value of a lowest triplet energy level (T1) in the core part, and may thus exhibit low values of a lowest triplet energy level (T1) of the polycyclic compound itself, and may also exhibit low values of a second lowest triplet energy level (T2, or second lowest triplet excitation energy level). Accordingly, the polycyclic compound may have a difference (Δ_{S1-T2}) between a lowest singlet energy level (S1, or the lowest singlet excitation energy level) and a second lowest triplet energy level (T2) is greater than a difference (Δ_{T2-T1}) between a second lowest triplet energy level (T2) and a lowest triplet energy level (T1).

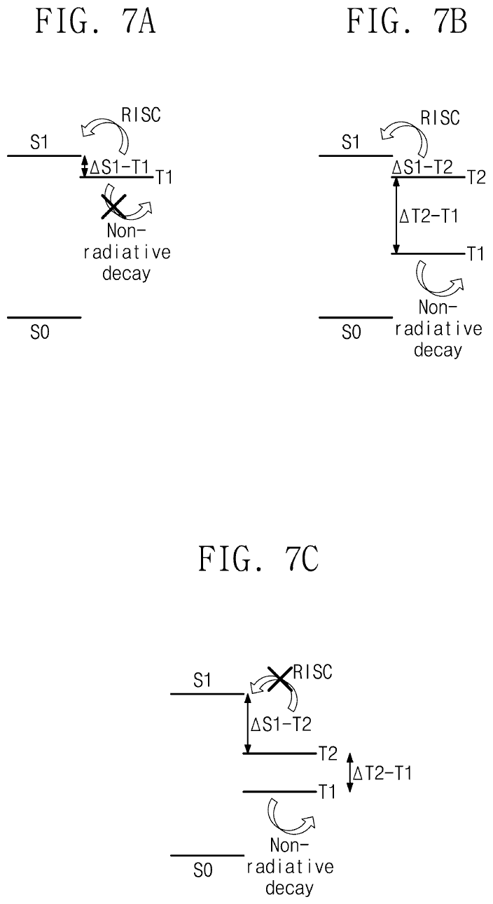

FIG. 7A to FIG. 7C are schematic diagrams of the energy levels of polycyclic compounds, respectively. FIG. 7A is a schematic diagram of the energy level of Compound X1, and FIG. 7B is a schematic diagram of the energy level of Compound X2. FIG. 7C is a schematic diagram of the energy level of Compound X3. Compound X1 and Compound X2 are Comparative Compounds, and Compound X3 is a polycyclic compound according to an embodiment.

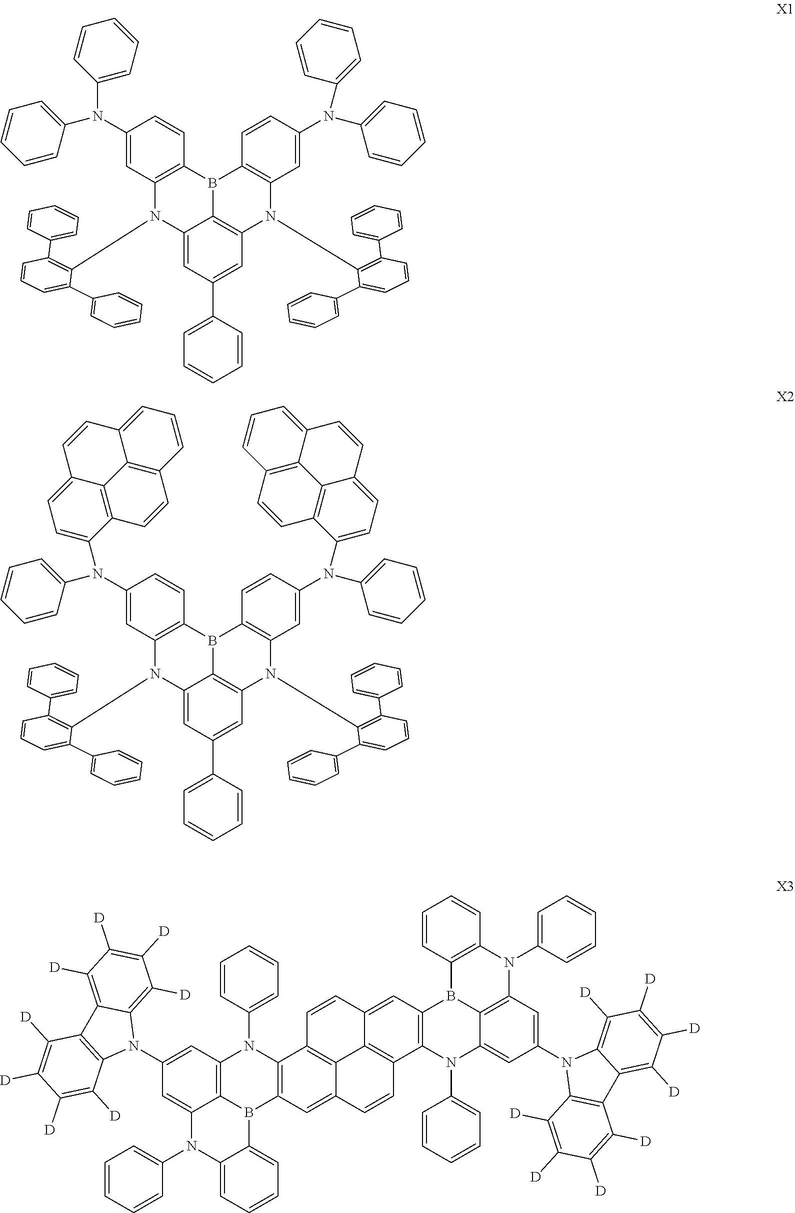

Referring to FIG. 7A, since Compound X1 not introducing an organic compound (polycyclic aromatic hydrocarbons, PAHs) having a low value of the lowest triplet energy level (T1) has a very narrow energy gap (ΔE_{ST}≤0.2 eV) between the lowest singlet energy level (S1) and the lowest triplet energy level (T1), transition phenomenon of triplet excitons formed in a triplet state to a singlet state by reverse inter system crossing (RISC) may arise. The transition from the triplet state to the singlet state is a prohibition rule by a selection rule, the transition rate between the states is very slow (μs-ms). Since triplet excitons having high energy stay in the triplet state during the spin-flip time of electrons in Compound X1, the deterioration of an organic material may be accelerated.

Compound X2 introduces pyrene having a low value of the lowest triplet energy level (T1) not as a core part but as a substituent. Referring to FIG. 7B, in Compound X2, competitive pathways are present from a second lowest triplet energy level (T2) to a lowest singlet energy level (S1) and from a second lowest triplet energy level (T2) to a low state of a lowest triplet state (T1), and both lifetime and efficiency are deteriorated.

Referring to FIG. 7C, Compound X3 corresponding to the polycyclic compound according to an embodiment introduces polycyclic aromatic hydrocarbons (PAHs) having a low value of the lowest triplet energy level (T1) at the core part, and may reduce the second lowest triplet energy level (T2). The polycyclic compound according to an embodiment introduces polycyclic aromatic hydrocarbons having the lowest triplet energy level (T1) equal to or less than about 2.4 eV at the core part. The polycyclic compound according to an embodiment introduces polycyclic aromatic hydrocarbons having a lowest triplet energy level (T1) equal to or less than about 2.0 eV at the core part. In an embodiment, an energy difference from the lowest singlet energy level (S1) to a second lowest triplet energy level (T2) is greater than an energy difference from a second lowest triplet energy level (T2) to the lowest triplet energy level (T1). Accordingly, in the polycyclic compound, the RISC of the triplet excitons formed in a second lowest triplet state may be maximally suppressed, most of the triplet excitons formed in the triplet state may become extinct through nonradiative decay after transition to the lowest triplet state, and the lifetime of the light emitting element ED may increase.

The polycyclic compound according to an embodiment, represented by Formula 1 may have a plate-type strong bonding structure through the fusion of the first fused ring and the second fused ring in the core part, and the chemical stability of a whole molecule may be improved. Accordingly, if the polycyclic compound is applied to the emission layer EML of a light emitting element ED, element lifetime as well as the emission efficiency may be improved.

The polycyclic compound may include a deuterium atom as a substituent. In an embodiment, in the polycyclic compound represented by Formula 1, at least one of L and R₁ to R₇ may each independently include a deuterium atom, or a substituent including a deuterium atom. However, this is only an example, and embodiments are not limited thereto.

In an embodiment, the polycyclic compound represented by Formula 1 may be represented by any one of Formula 2-1 to Formula 2-5.

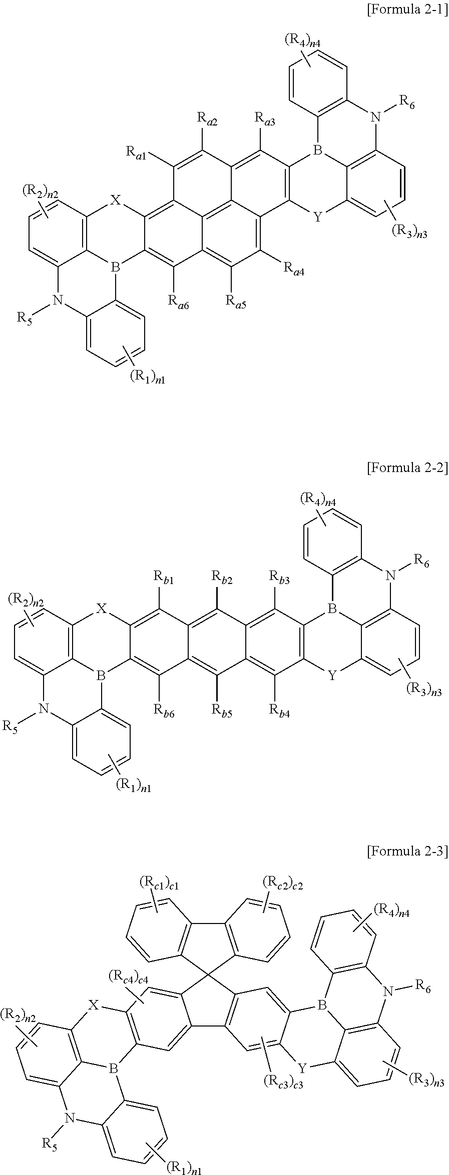

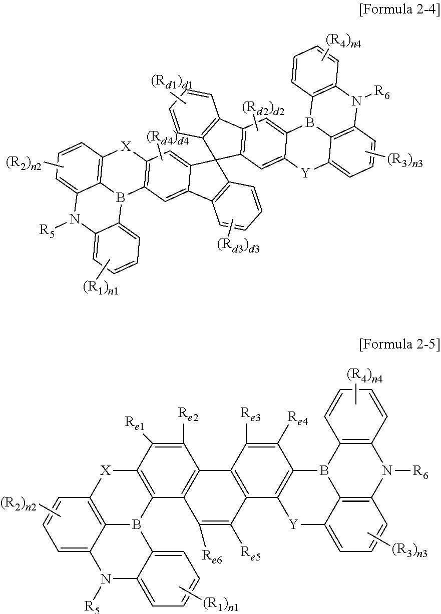

In Formula 2-1 to Formula 2-5, Rₐ₁ to Rₐ₆, R_{b1} to R_{b6}, R_{c1} to R_{c4}, R_{d1} to R_{d4}, and Rₑ₁ to Rₑ₆ may each independently be a hydrogen atom, a deuterium atom, or a substituted or unsubstituted aryl group of 6 to 15 ring-forming carbon atoms. For example, Rₐ₁ to Rₐ₆, R_{b1} to R_{b6}, R_{c1} to R_{c4}, R_{d1} to R_{d4}, and Rₑ₁ to Rₑ₆ may each independently be a hydrogen atom, a deuterium atom, or a substituted or unsubstituted phenyl group. In an embodiment, Rₐ₁ to Rₐ₆, R_{c1} to R_{c4}, R_{d1} to R_{d4}, and Rₑ₁ to Rₑ₆ may each independently be a hydrogen atom or a deuterium atom. In an embodiment, R_{b1}, R_{b3}, R_{b4} and R_{b6} may each independently be a hydrogen atom or a deuterium atom, and R_{b2} and Rb₅ may each be an unsubstituted phenyl group.

In Formula 2-3 and Formula 2-4, c1, c2, d1, and d3 may each independently be an integer from 0 to 4; and c3, c4, d2, and d4 may each independently be an integer from 0 to 2. If c1 to c4 and d1 to d4 are 0, the polycyclic compound may be unsubstituted with R_{b1} to R_{c4} and R_{d1} to R_{d4}, respectively. Cases where c1, c2, d1, and d3 are 0 may be the same as cases where c1, c2, d1, and d3 are 4, and four of each of R_{c1}, R_{c2}, R_{d1} and R_{d3} are all hydrogen atoms. Cases where c3, c4, d2, and d4 are 0 may be the same as cases where c3, c4, d2, and d4 are 2, and two of each of R_{c3}, R_{c4}, R_{d2} and R_{d4} are all hydrogen atoms. If c1 to c4, and d1 to d4 are integers of 2 or more, each of multiple R_{c1} to R_{c4}, and R_{d1} to R_{d4} may be all the same, or at least one of multiple R_{c1} to R_{c4}, and R_{d1} to R_{d4} may be different.

In Formula 2-1 to Formula 2-5, X, Y, R₁ to R₆, and n1 to n4 may be the same as defined in Formula 1.

In an embodiment, the polycyclic compound represented by Formula 2-1 may be represented by Formula 2-1A.

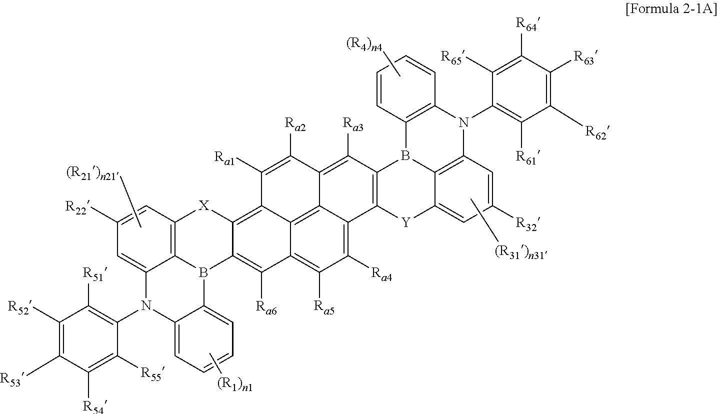

In Formula 2-1A, R₂₁′ and R₃₁′ may each independently be a hydrogen atom or a deuterium atom. In Formula 2-1A, n21′ and n31′ may each independently be an integer from 0 to 2. If n21′ and n31′ are 0, the polycyclic compound may be unsubstituted with R₂₁′ and R₃₁′, respectively. In Formula 2-1A, cases where R₂₁′ and R₃₁′ are 2, and two of each of R₂₁′ and R₃₁′ are all hydrogen atoms, may be the same as cases where n21′ and n31′ are 0, respectively. If n21′ is 2, two R₂₁′ may be the same, or two R₂₁′ may be different from each other. If n31′ is 2, two R₃₁′ may be the same, or two R₃₁′ may be different from each other.

In Formula 2-1A, R₂₂′ and R₃₂′ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. For example, R₂₂′ and R₃₂′ may each independently be a hydrogen atom, a deuterium atom, a substituted or unsubstituted diphenylamine group, a substituted or unsubstituted t-butyl group, a substituted or unsubstituted phenyl group or a substituted or unsubstituted carbazole group. In an embodiment, each of R₂₂′ and R₃₂′ may be substituted with a deuterium atom, but embodiments are not limited thereto.

In Formula 2-1A, R₅₁′ to R₅₅′ and R₆₁′ to R₆₅′ may each independently be a hydrogen atom, a deuterium atom, a substituted or unsubstituted alkyl group of 1 to 10 carbon atoms, or a substituted or unsubstituted aryl group of 6 to 10 ring-forming carbon atoms. For example, R₅₁′ to R₅₅′ and R₆₁′ to R₆₅′ may each independently be a hydrogen atom, a deuterium atom, a substituted or unsubstituted t-butyl group, or a substituted or unsubstituted phenyl group.

In Formula 2-1A, R₁, R₄, Rₐ₁ to Rₐ₆, n1, n4, X, and Y may be the same as defined in Formula 1 and Formula 2-1.

In an embodiment, the polycyclic compound represented by Formula 2-2 may be represented by Formula 2-2A.

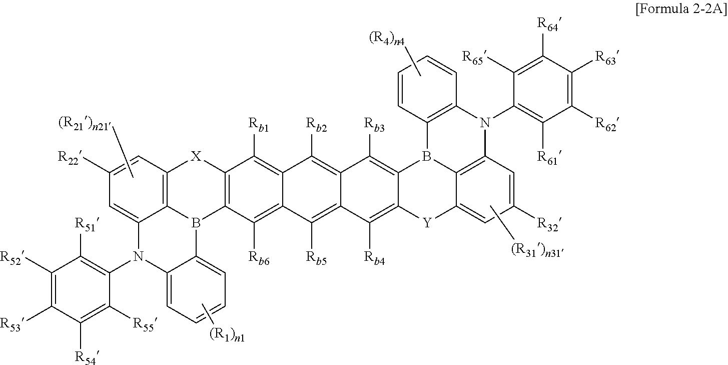

In Formula 2-2A, R₂₁′ and R₃₁′ may each independently be a hydrogen atom or a deuterium atom. In Formula 2-2A, n21′ and n31′ may each independently be an integer from 0 to 2. If n21′ and n31′ are 0, the polycyclic compound may be unsubstituted with R₂₁′ and R₃₁′, respectively. In Formula 2-2A, cases where R₂₁′ and R₃₁′ are 2, and two of each of R₂₁′ and R₃₁′ are all hydrogen atoms, may be the same as cases where n21′ and n31′ are 0, respectively, in Formula 2-2A. If n21′ is 2, two R₂₁′ may be the same, or two R₂₁′ may be different. If n31′ is 2, two R₃₁′ may be the same, or two R₃₁′ may be different.

In Formula 2-2A, R₂₂′ and R₃₂′ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. For example, R₂₂′ and R₃₂′ may each independently be a hydrogen atom, a deuterium atom, a substituted or unsubstituted diphenylamine group, a substituted or unsubstituted t-butyl group, a substituted or unsubstituted phenyl group, or a substituted or unsubstituted carbazole group. In an embodiment, if substituted, R₂₂′ and R₃₂′ may be substituted with deuterium atoms, but embodiments are not limited thereto.

In Formula 2-2A, R₅₁′ to R₅₅′ and R₆₁′ to R₆₅′ may each independently be a hydrogen atom, a deuterium atom, a substituted or unsubstituted alkyl group of 1 to 10 carbon atoms, or a substituted or unsubstituted aryl group of 6 to 10 ring-forming carbon atoms. For example, R₅₁′ to R₅₅′ and R₆₁′ to R₆₅′ may each independently be a hydrogen atom, a deuterium atom, a substituted or unsubstituted t-butyl group, or a substituted unsubstituted phenyl group.

In Formula 2-2A, R₁, R₄, R_{b1} to R_{b6}, n1, n4, X, and Y may be the same as defined in Formula 1 and Formula 2-2.

In an embodiment, the polycyclic compound represented by Formula 1 may be represented by Formula 3.

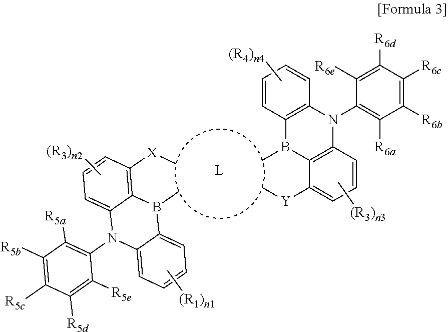

In Formula 3, R₅ₐ to R₅ₑ and R₆ₐ to R₆ₑ may each independently be a hydrogen atom, a deuterium atom, a substituted or unsubstituted alkyl group of 1 to 10 carbon atoms, or a substituted or unsubstituted aryl group of 6 to 10 ring-forming carbon atoms. For example, R₅ₐ to R₅ₑ, and R₆ₐ to R₆ₑ may each independently be a hydrogen atom, a deuterium atom, a substituted or unsubstituted t-butyl group, or a substituted or unsubstituted phenyl group.

In Formula 3, R₁ to R₄, n1 to n4, L, X, and Y may be the same as defined in Formula 1.

In an embodiment, the polycyclic compound represented by Formula 1 may be represented by Formula 4.

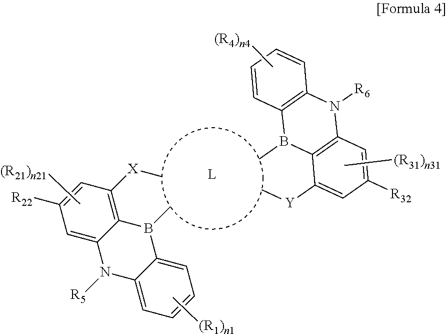

In Formula 4, R₂₁ and R₃₁ may each independently be a hydrogen atom or a deuterium atom. In Formula 4, n21 and n31 may each independently be an integer from 0 to 2. If n21 and n31 are 0, the polycyclic compound may be unsubstituted with R₂₁ and R₃₁, respectively. In Formula 4, cases where n21 and n31 are 2, and two of each of R₂₁ and R₃₁ are all hydrogen atoms, may be the same as cases where n21 and n31 are 0 in Formula 4. If n21 is 2, two R₂₁ may be the same, or two R₂₁ may be different. If n31 is 2, two R₃₁ may be the same, or two R₃₁ may be different.

In Formula 4, R₂₂ and R₃₂ may each independently be a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms. For example, R₂₂ and R₃₂ may each independently be a hydrogen atom, a deuterium atom, a substituted or unsubstituted diphenylamine group, a substituted or unsubstituted t-butyl group, a substituted or unsubstituted phenyl group, or a substituted or unsubstituted carbazole group. In an embodiment, if substituted, R₂₂ and R₃₂ may be substituted with deuterium atoms, but embodiments are not limited thereto.

In Formula 4, R₁, R₄ to R₆, n1, n4, L, X, and Y may be the same as defined in Formula 1.

In an embodiment, the polycyclic compound represented by Formula 1 may be represented by any one of Formula 5-1 to Formula 5-4.

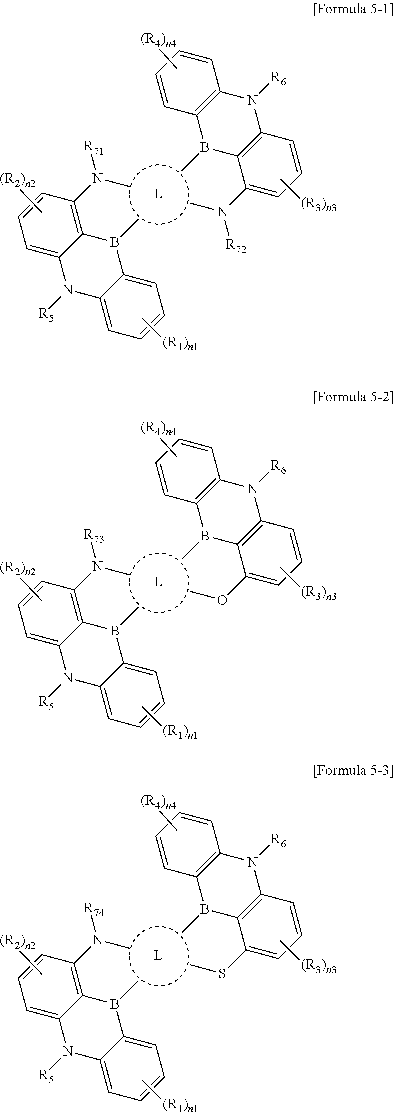

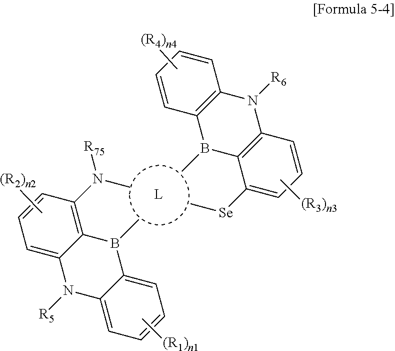

In Formula 5-1 to Formula 5-4, R₇₁ to R₇₅ may each independently be a substituted or unsubstituted aryl group of 6 to 20 ring-forming carbon atoms or a substituted or unsubstituted heteroaryl group of 2 to 20 ring-forming carbon atoms. For example, R₇₁ to R₇₅ may each independently be a substituted or unsubstituted phenyl group, or a substituted or unsubstituted dibenzofuran group.

In Formula 5-1 to Formula 5-4, R₁ to R₆, n1 to n4, and L may be the same as defined in Formula 1.

In an embodiment, the polycyclic compound may be any compound selected from Compound Group 1. In an embodiment, in the light emitting element ED, the at least one functional layer (for example, an emission layer EML) may include at least one polycyclic compound selected from Compound Group 1. In Compound Group 1, D represents a deuterium atom.

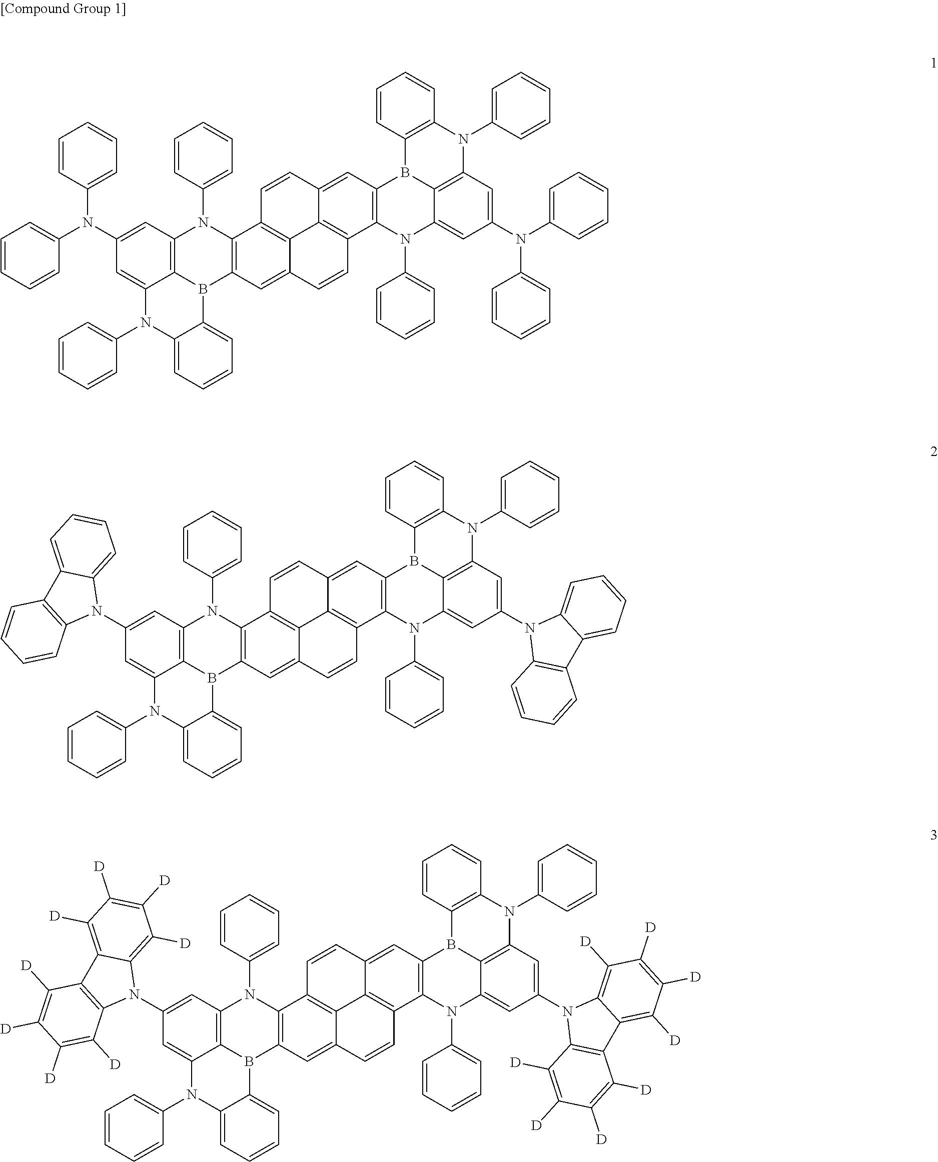

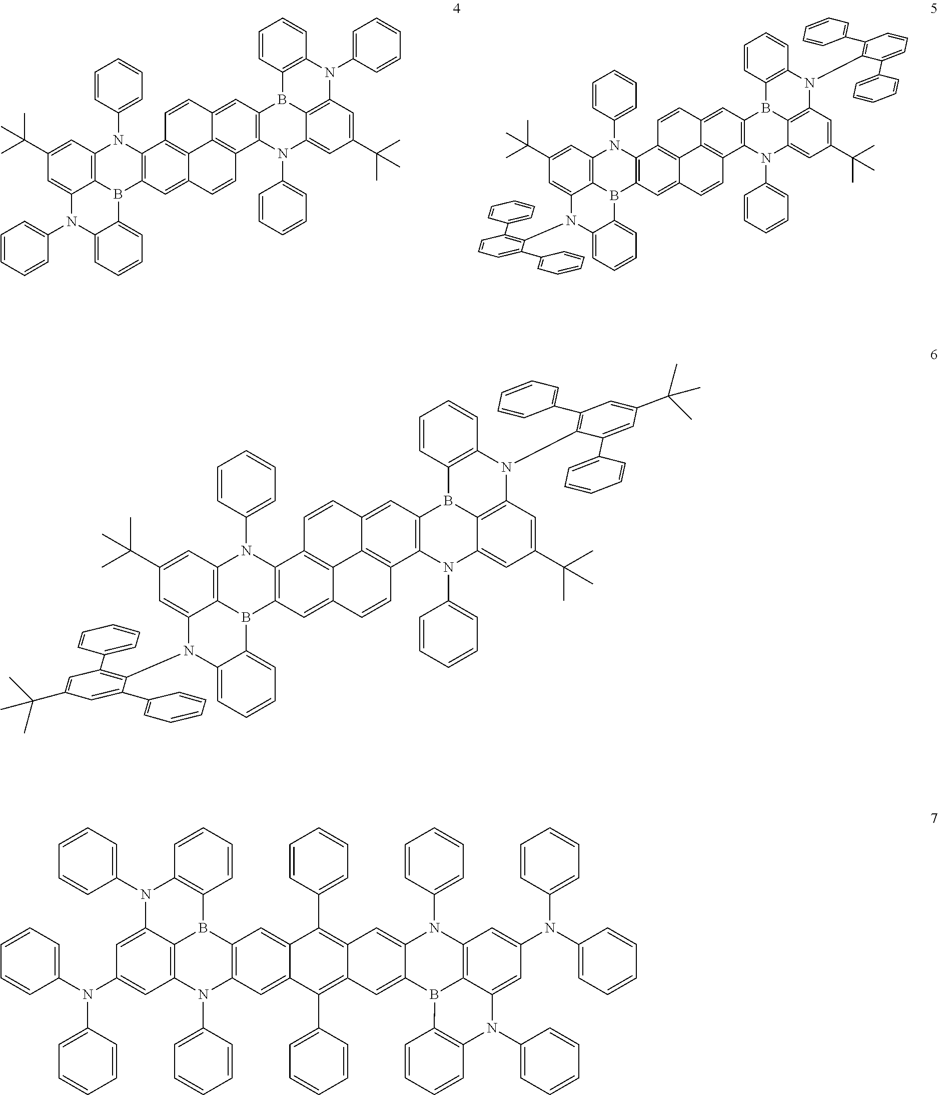

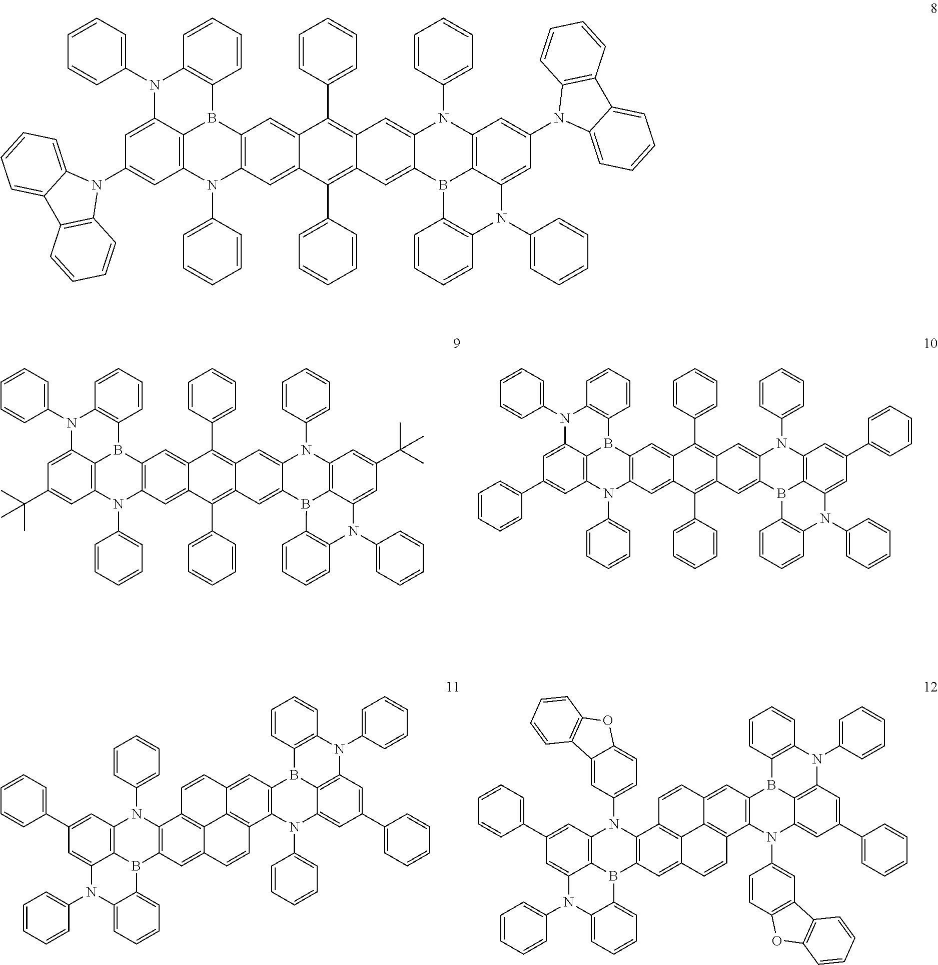

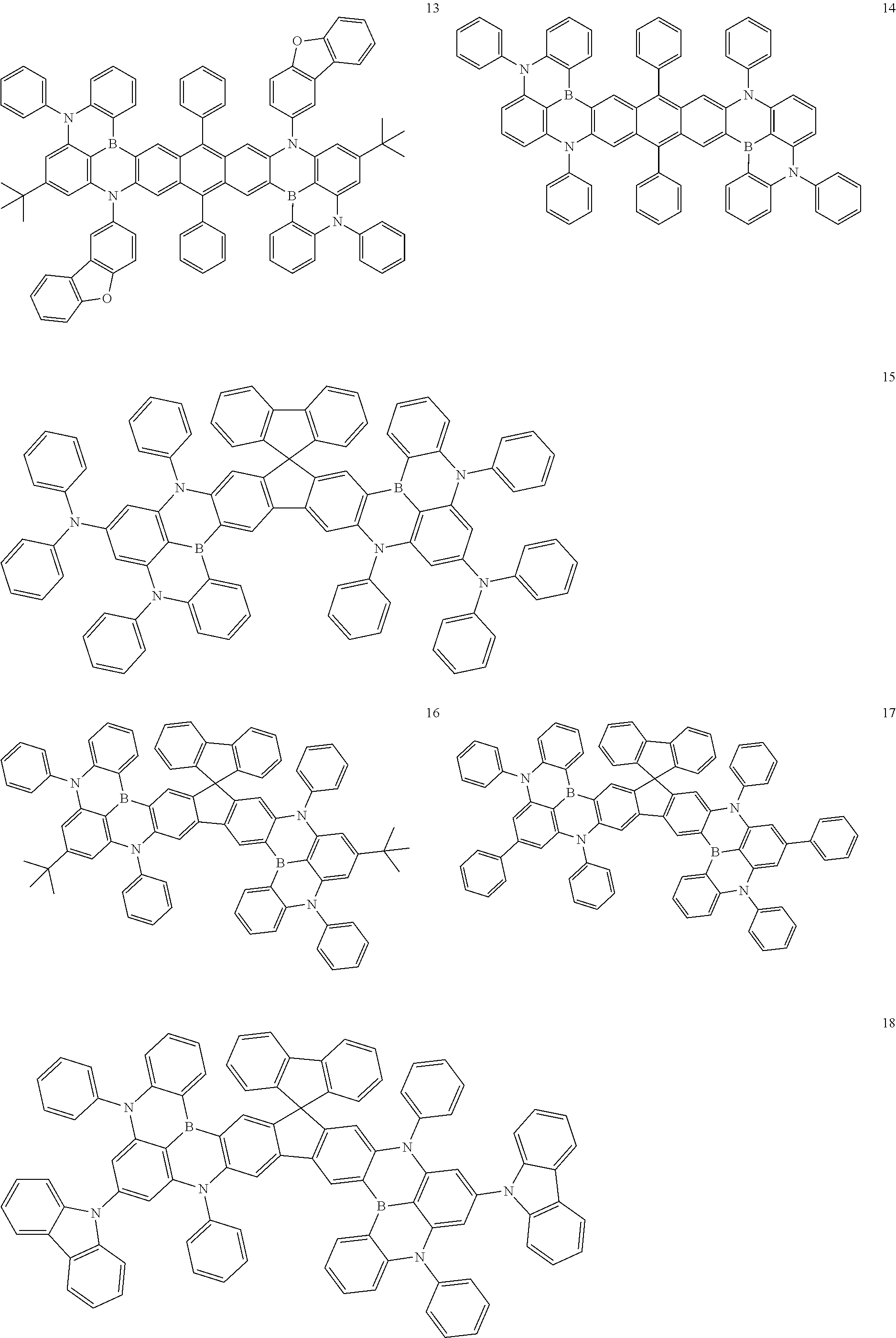

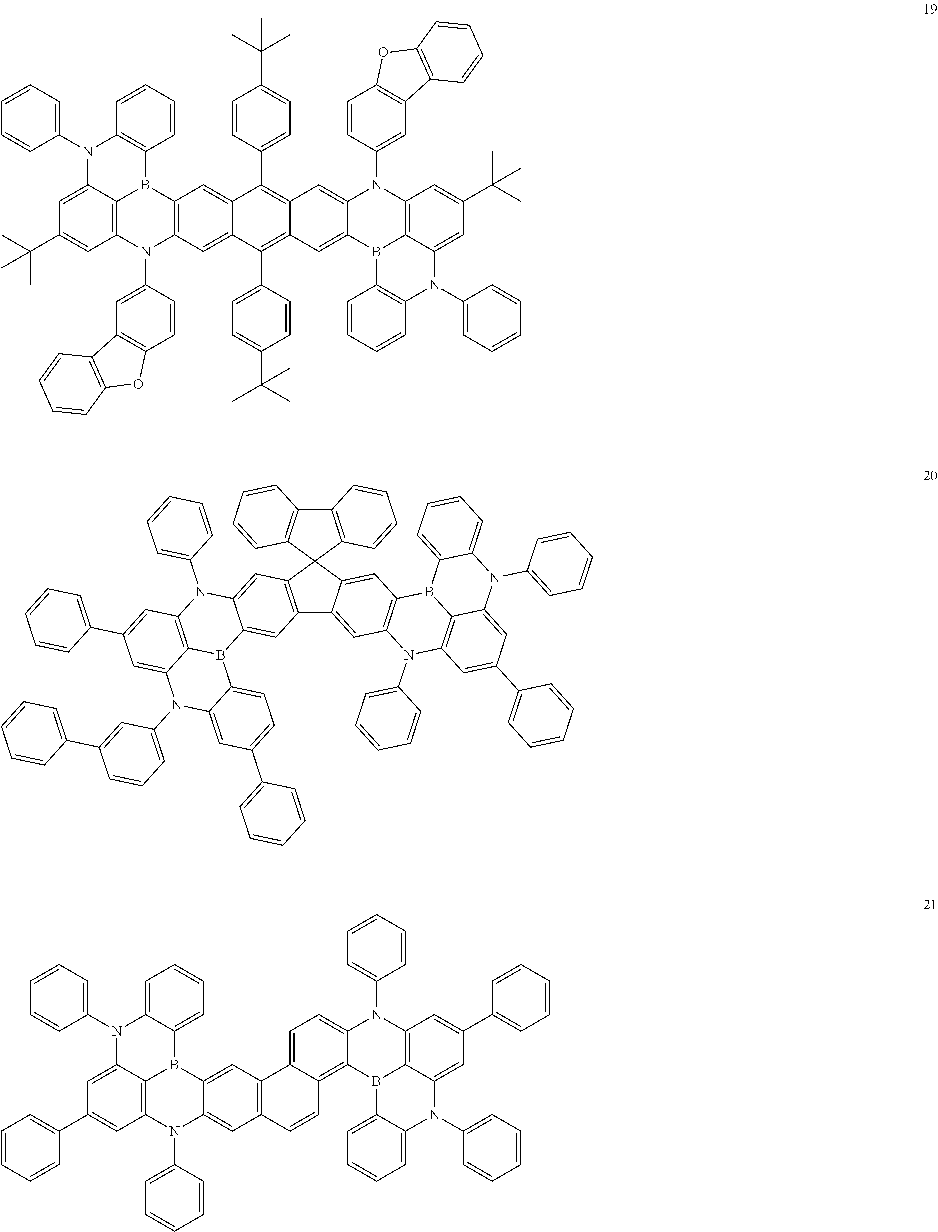 [SMILES: CC(C)(C)c1ccc(-c2c3cc4c(cc3c(-c3ccc(C(C)(C)C)cc3)c3cc5c(cc23)N(c2ccc3oc6ccccc6c3c2)c2cc(C(C)(C)C)cc3c2B5c2ccccc2N3c2ccccc2)N(c2ccc3oc5ccccc5c3c2)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5N(c5ccccc5)c5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1 ; c1ccc(-c2cc3c4c(c2)N(c2ccccc2)c2cc5ccc6c7c(ccc6c5cc2B4c2ccccc2N3c2ccccc2)N(c2ccccc2)c2cc(-c3ccccc3)cc3c2B7c2ccccc2N3c2ccccc2)cc1]

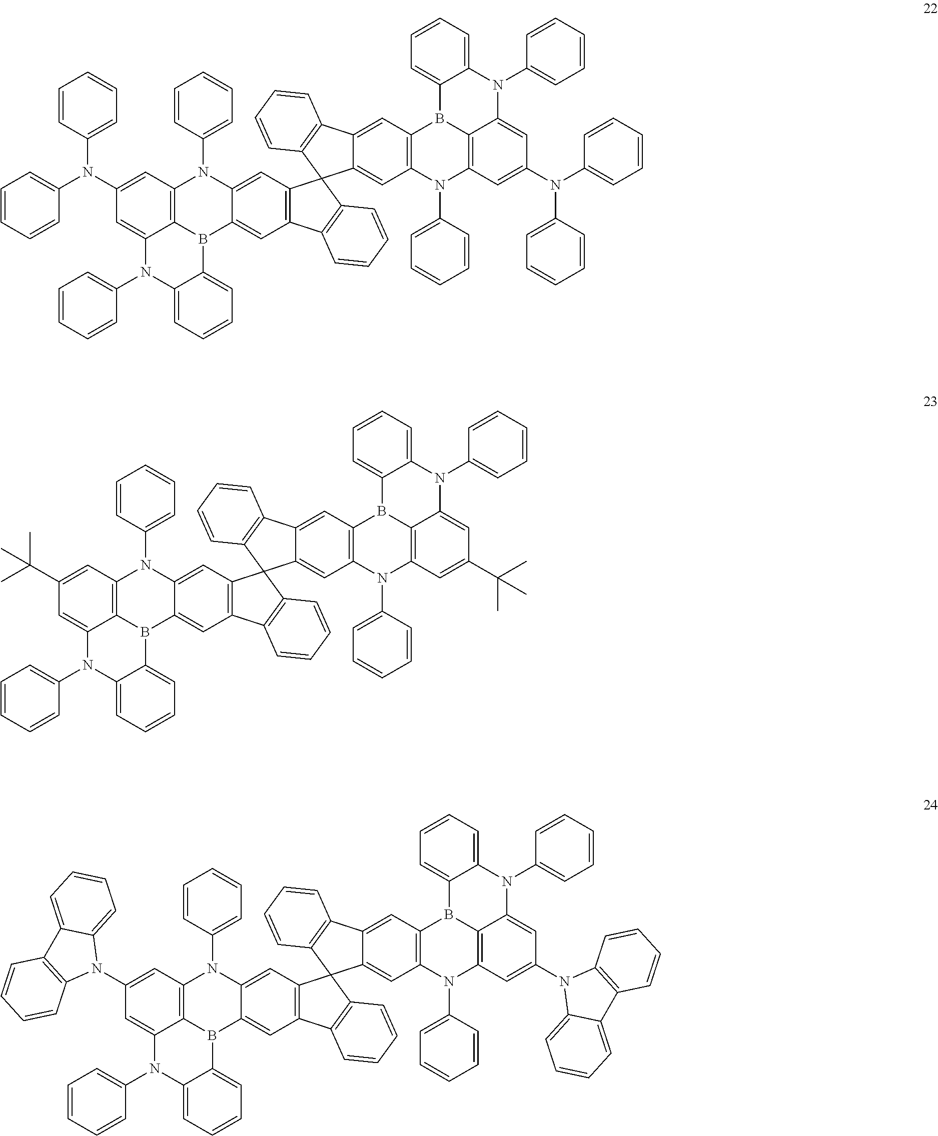 [SMILES: c1ccc(N(c2ccccc2)c2cc3c4c(c2)N(c2ccccc2)c2cc5c(cc2B4c2ccccc2N3c2ccccc2)-c2ccccc2C52c3ccccc3-c3cc4c(cc32)N(c2ccccc2)c2cc(N(c3ccccc3)c3ccccc3)cc3c2B4c2ccccc2N3c2ccccc2)cc1 ; CC(C)(C)c1cc2c3c(c1)N(c1ccccc1)c1cc4c(cc1B3c1ccccc1N2c1ccccc1)-c1ccccc1C41c2ccccc2-c2cc3c(cc21)N(c1ccccc1)c1cc(C(C)(C)C)cc2c1B3c1ccccc1N2c1ccccc1 ; c1ccc(N2c3ccccc3B3c4cc5c(cc4N(c4ccccc4)c4cc(-n6c7ccccc7c7ccccc76)cc2c43)C2(c3ccccc3-5)c3ccccc3-c3cc4c(cc32)N(c2ccccc2)c2cc(-n3c5ccccc5c5ccccc53)cc3c2B4c2ccccc2N3c2ccccc2)cc1]

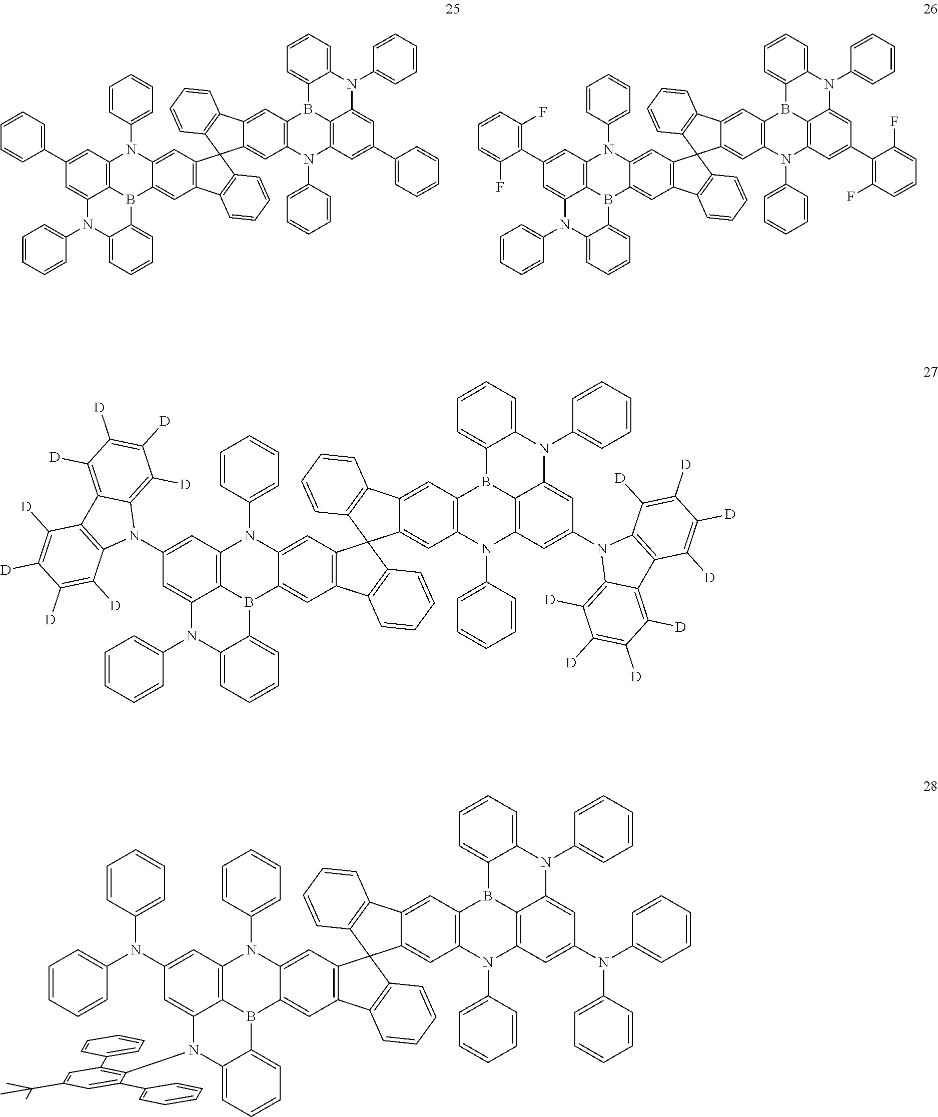

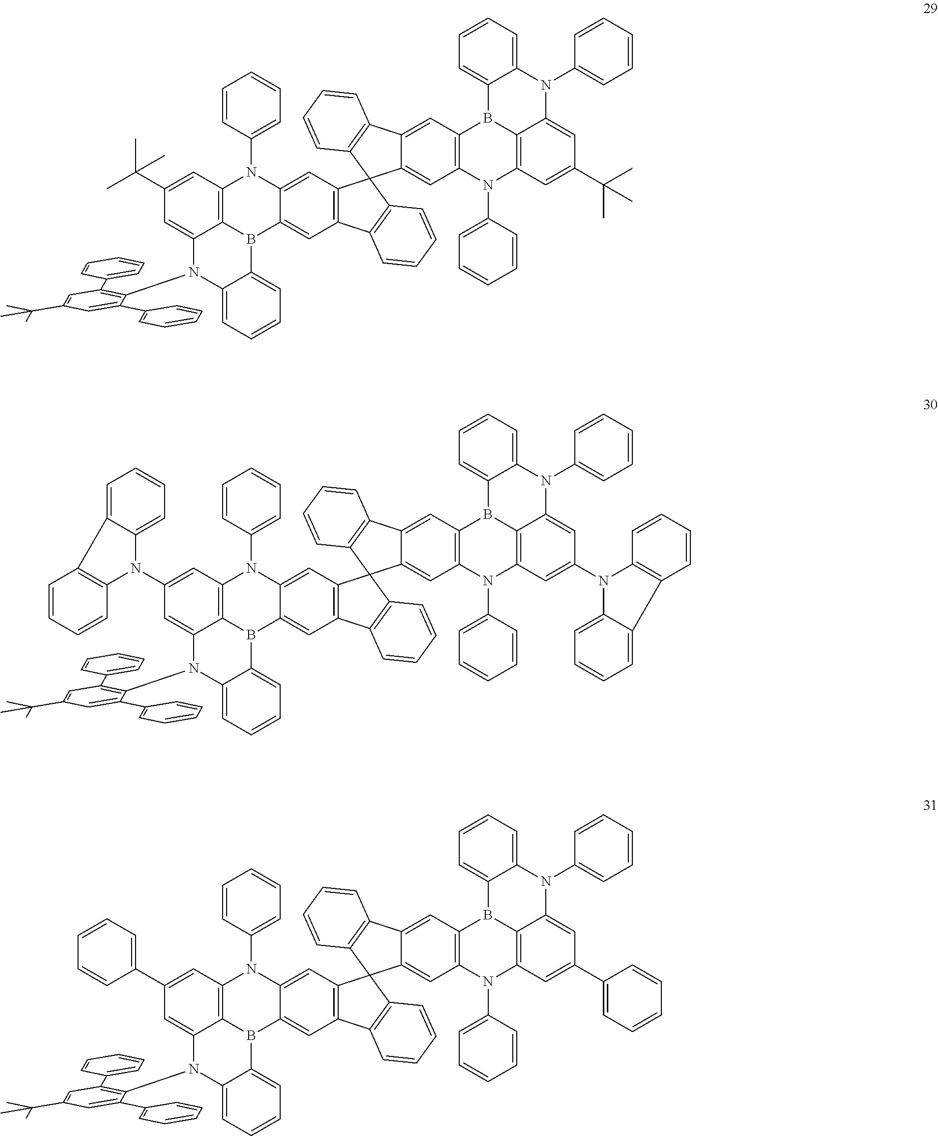

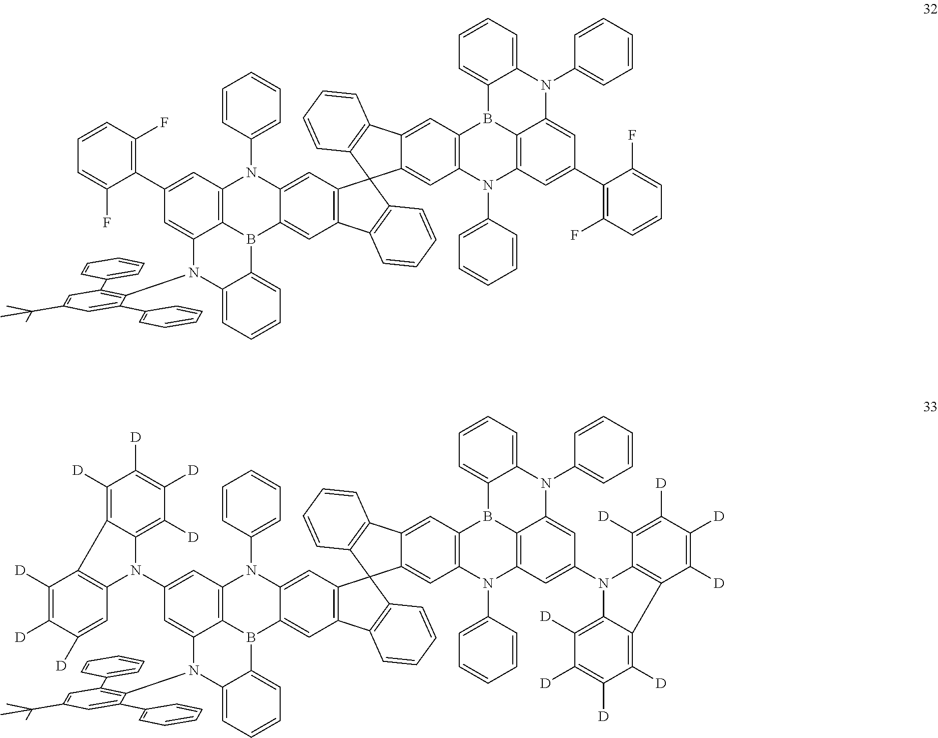 [SMILES: CC(C)(C)c1cc(-c2ccccc2)c(N2c3ccccc3B3c4cc5c(cc4N(c4ccccc4)c4cc(-c6c(F)cccc6F)cc2c43)C2(c3ccccc3-c3cc4c(cc32)N(c2ccccc2)c2cc(-c3c(F)cccc3F)cc3c2B4c2ccccc2N3c2ccccc2)c2ccccc2-5)c(-c2ccccc2)c1 ; [2H]c1cc2c(c([2H])c1[2H])c1c([2H])c([2H])c([2H])c([2H])c1n2-c1cc2c3c(c1)N(c1c(-c4ccccc4)cc(C(C)(C)C)cc1-c1ccccc1)c1ccccc1B3c1cc3c(cc1N2c1ccccc1)C1(c2ccccc2-c2cc4c(cc21)N(c1ccccc1)c1cc(-n2c5c([2H])c([2H])c([2H])c([2H])c5c5c([2H])c([2H])c([2H])c([2H])c52)cc2c1B4c1ccccc1N2c1ccccc1)c1ccccc1-3]

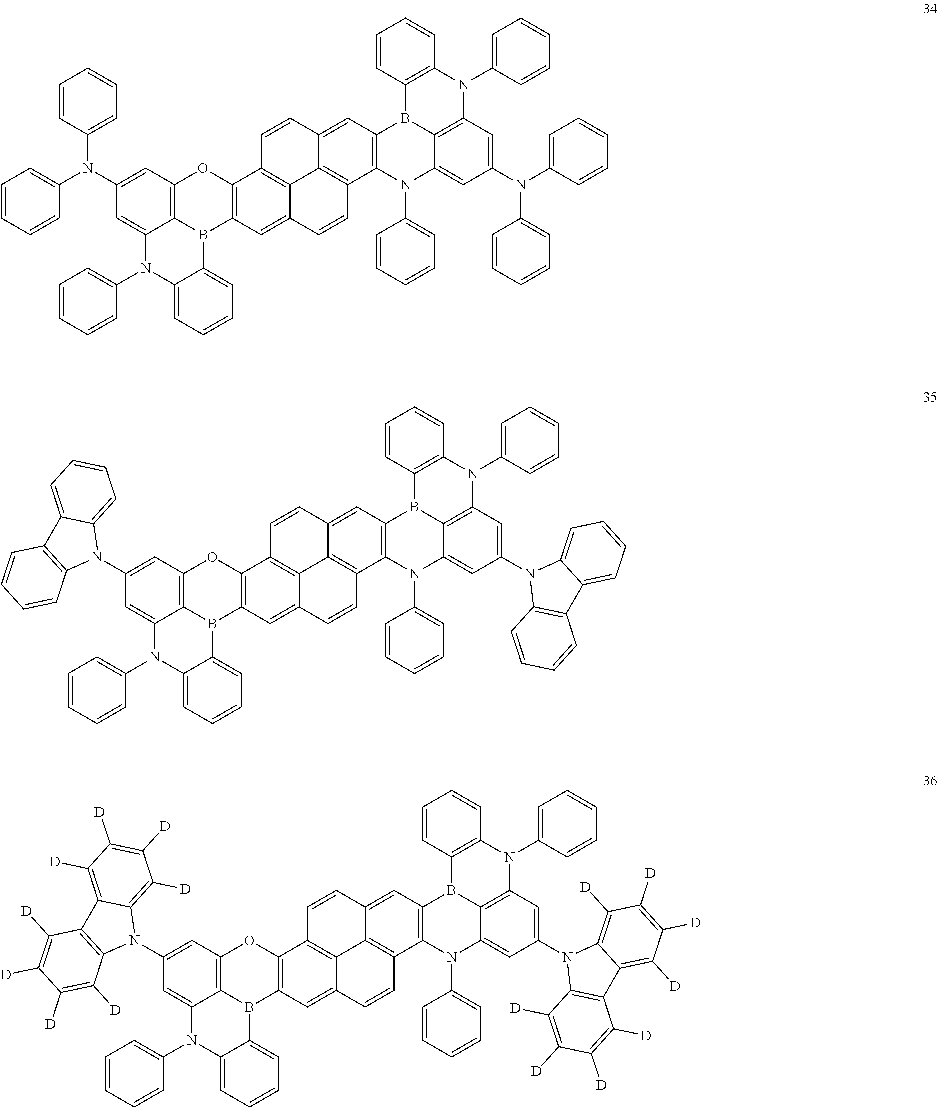

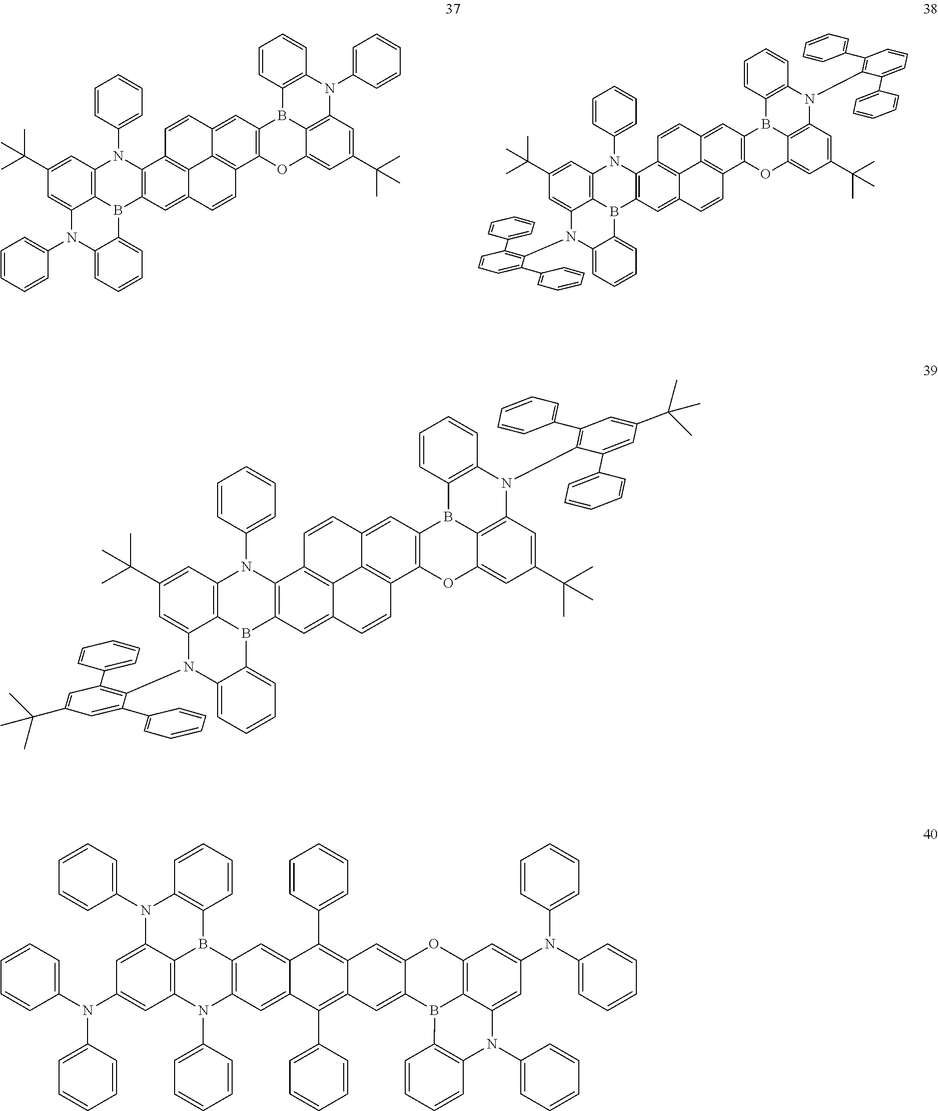

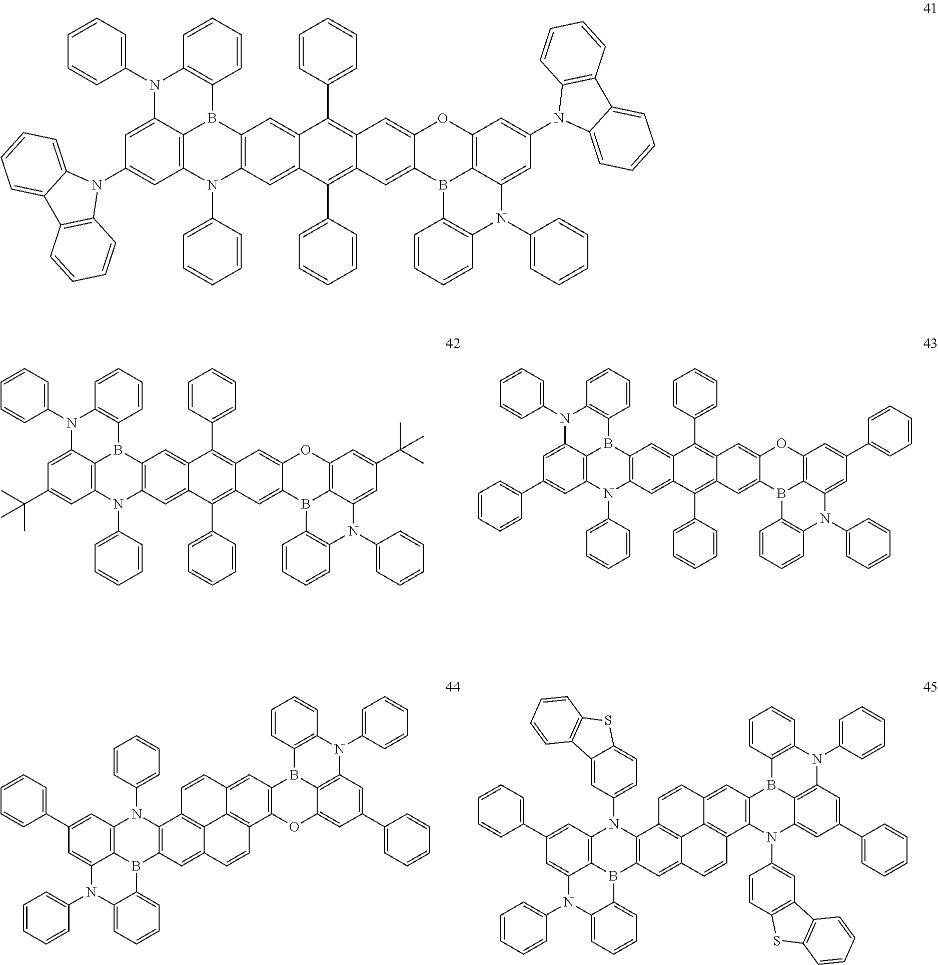

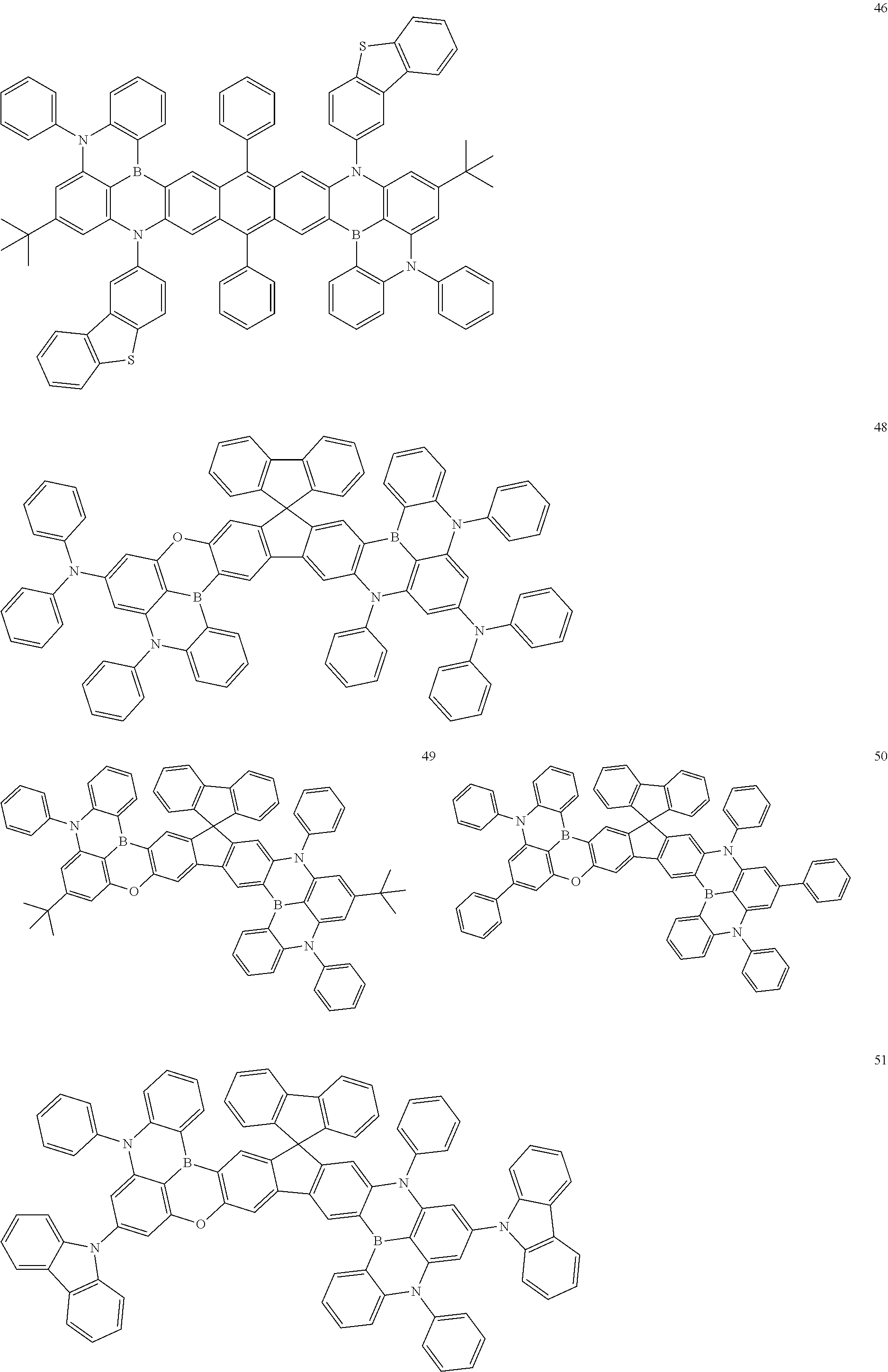

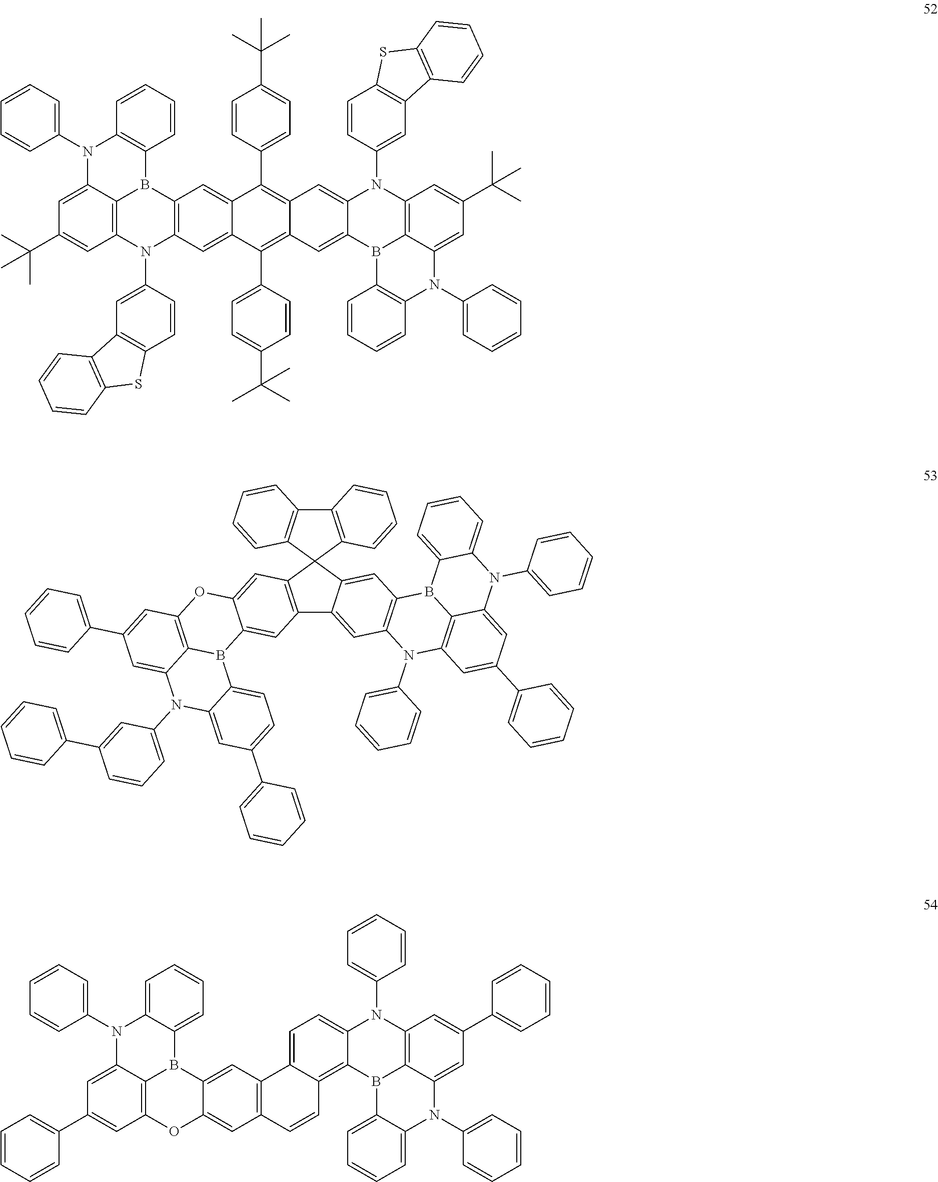 [SMILES: CC(C)(C)c1ccc(-c2c3cc4c(cc3c(-c3ccc(C(C)(C)C)cc3)c3cc5c(cc23)N(c2ccc3sc6ccccc6c3c2)c2cc(C(C)(C)C)cc3c2B5c2ccccc2N3c2ccccc2)N(c2ccc3sc5ccccc5c3c2)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5Oc5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1 ; c1ccc(-c2cc3c4c(c2)N(c2ccccc2)c2ccccc2B4c2cc4c(ccc5c6c(ccc54)N(c4ccccc4)c4cc(-c5ccccc5)cc5c4B6c4ccccc4N5c4ccccc4)cc2O3)cc1]

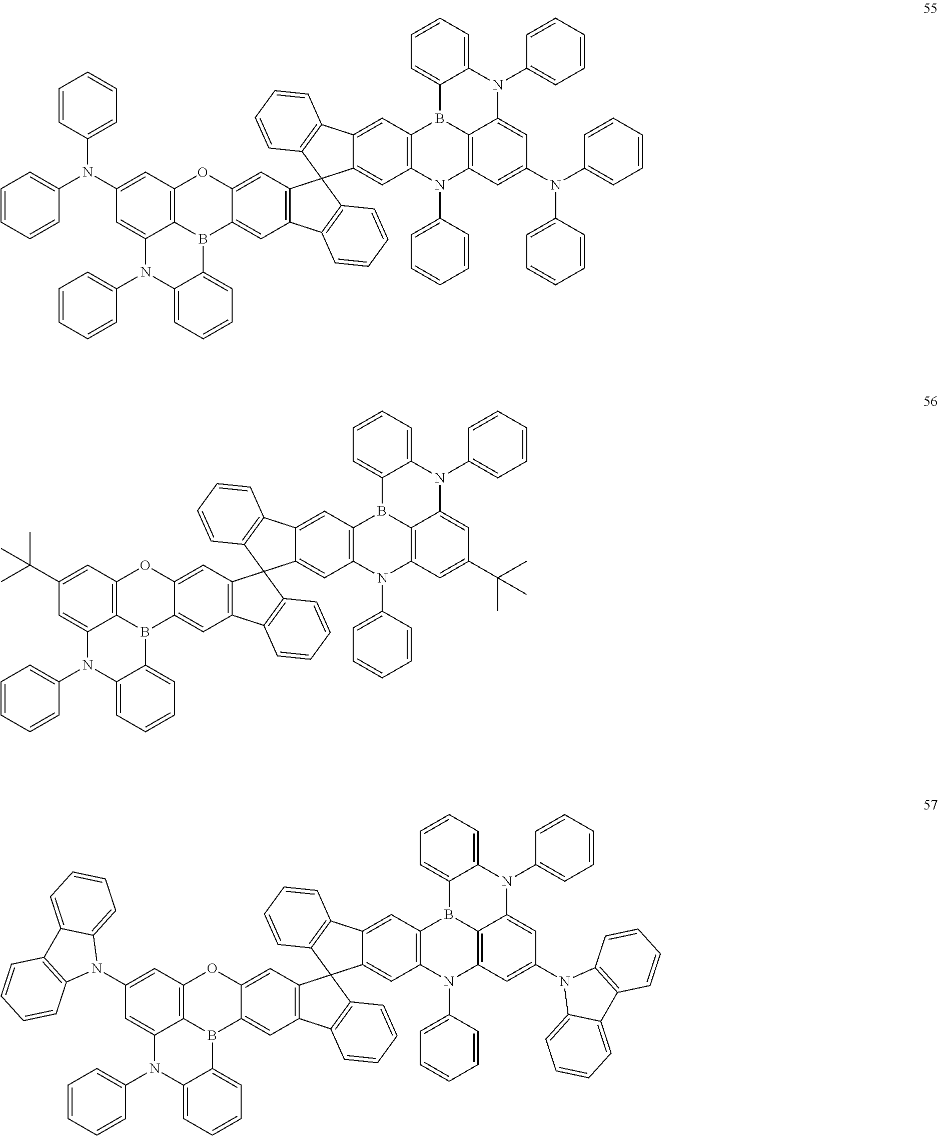 [SMILES: c1ccc(N(c2ccccc2)c2cc3c4c(c2)N(c2ccccc2)c2ccccc2B4c2cc4c(cc2O3)C2(c3ccccc3-4)c3ccccc3-c3cc4c(cc32)N(c2ccccc2)c2cc(N(c3ccccc3)c3ccccc3)cc3c2B4c2ccccc2N3c2ccccc2)cc1 ; CC(C)(C)c1cc2c3c(c1)N(c1ccccc1)c1ccccc1B3c1cc3c(cc1O2)C1(c2ccccc2-3)c2ccccc2-c2cc3c(cc21)N(c1ccccc1)c1cc(C(C)(C)C)cc2c1B3c1ccccc1N2c1ccccc1 ; c1ccc(N2c3ccccc3B3c4cc5c(cc4Oc4cc(-n6c7ccccc7c7ccccc76)cc2c43)C2(c3ccccc3-5)c3ccccc3-c3cc4c(cc32)N(c2ccccc2)c2cc(-n3c5ccccc5c5ccccc53)cc3c2B4c2ccccc2N3c2ccccc2)cc1]

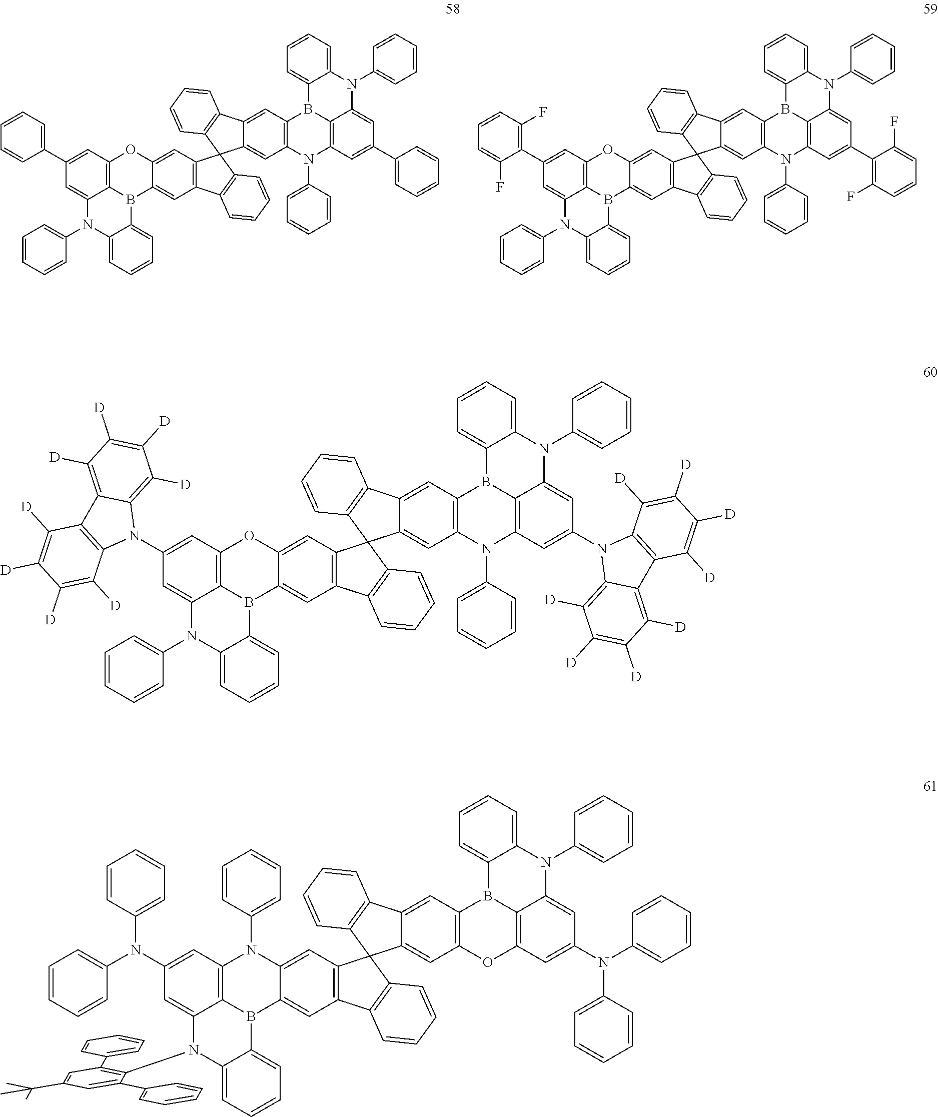

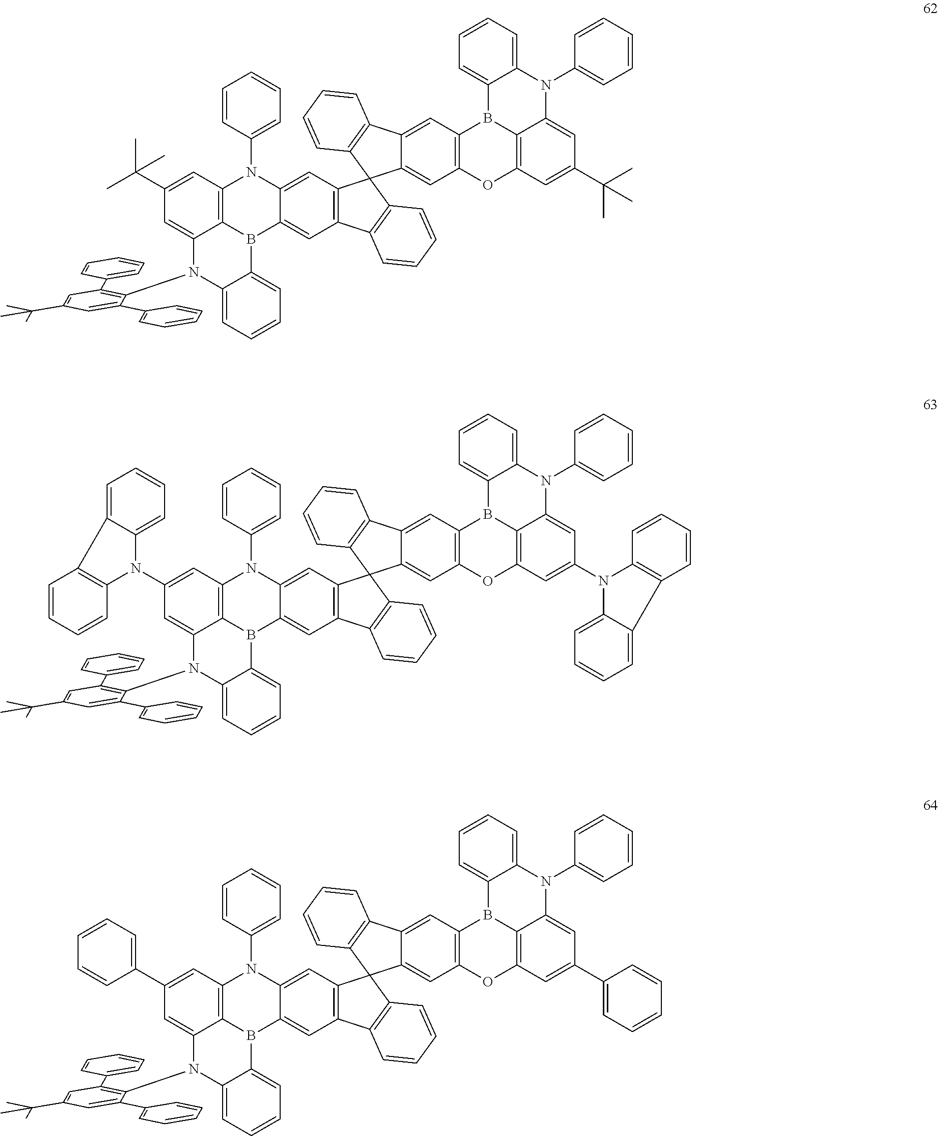

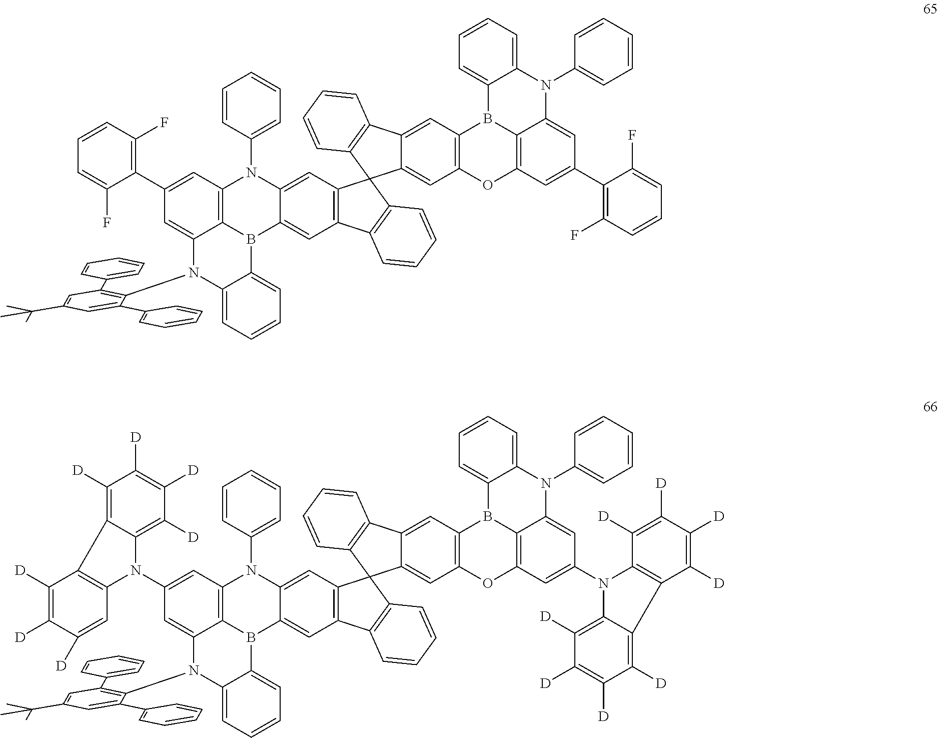 [SMILES: CC(C)(C)c1cc(-c2ccccc2)c(N2c3ccccc3B3c4cc5c(cc4N(c4ccccc4)c4cc(-c6c(F)cccc6F)cc2c43)C2(c3ccccc3-c3cc4c(cc32)Oc2cc(-c3c(F)cccc3F)cc3c2B4c2ccccc2N3c2ccccc2)c2ccccc2-5)c(-c2ccccc2)c1 ; [2H]c1cc2c(c([2H])c1[2H])c1c([2H])c([2H])c([2H])c([2H])c1n2-c1cc2c3c(c1)N(c1c(-c4ccccc4)cc(C(C)(C)C)cc1-c1ccccc1)c1ccccc1B3c1cc3c(cc1N2c1ccccc1)C1(c2ccccc2-c2cc4c(cc21)Oc1cc(-n2c5c([2H])c([2H])c([2H])c([2H])c5c5c([2H])c([2H])c([2H])c([2H])c52)cc2c1B4c1ccccc1N2c1ccccc1)c1ccccc1-3]

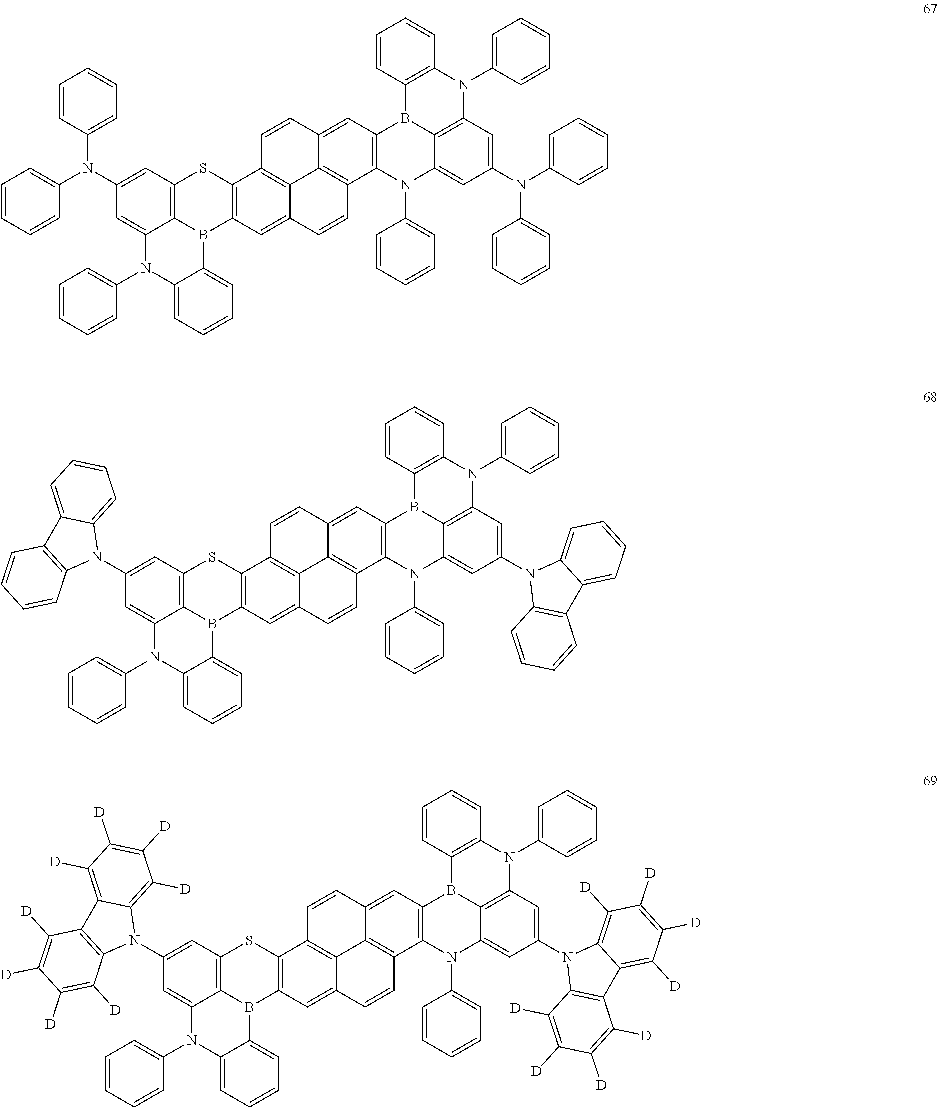

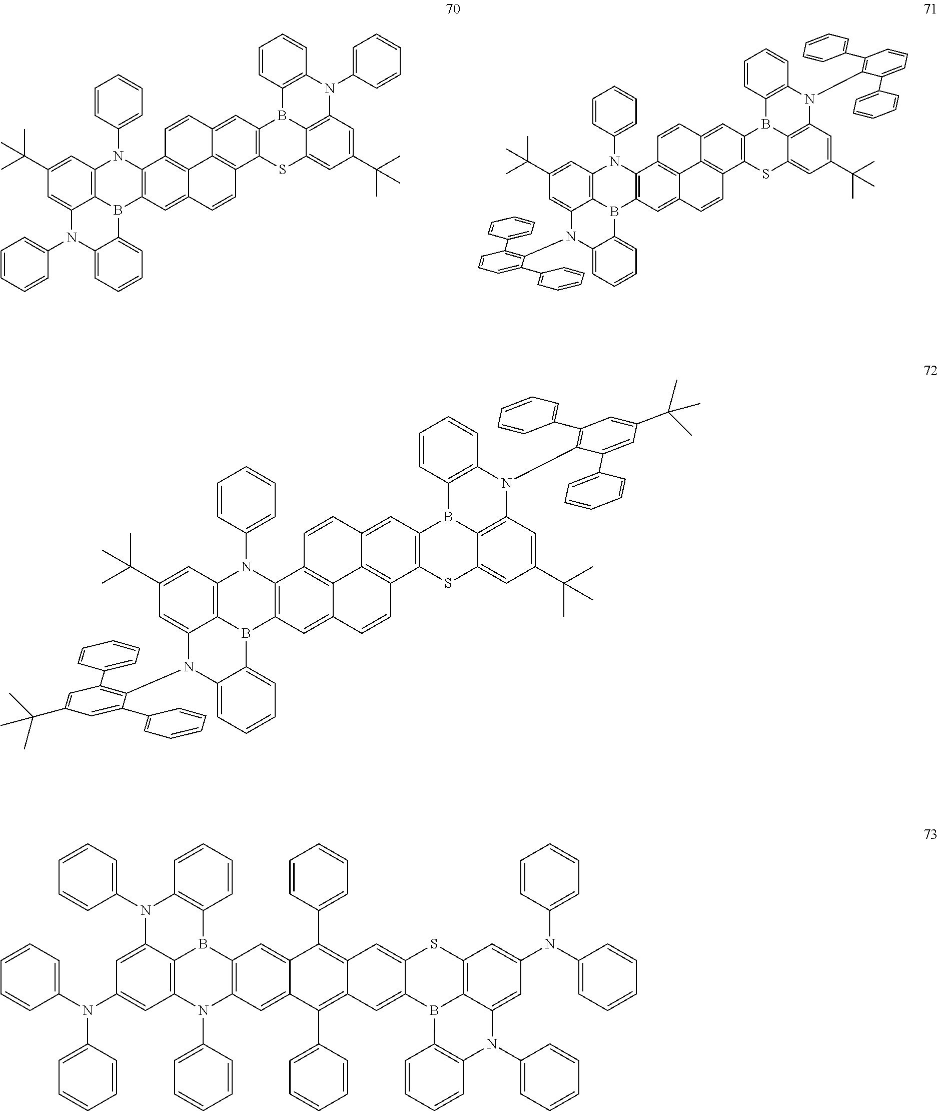

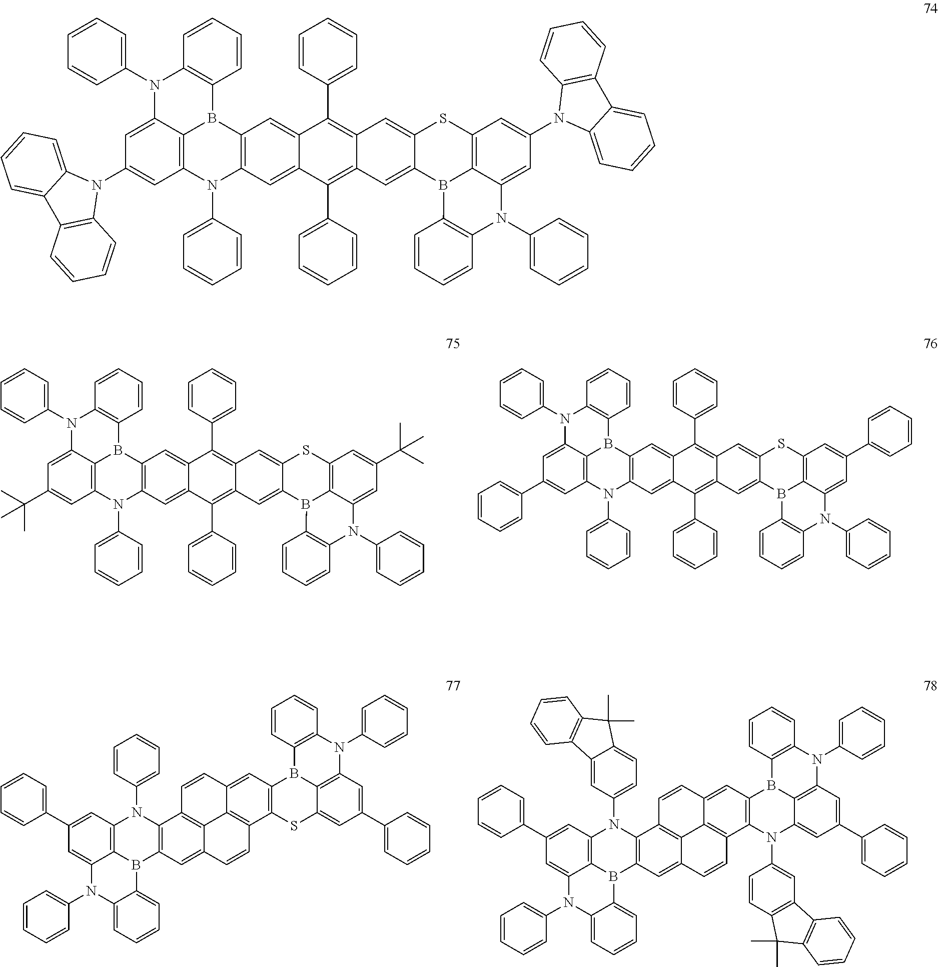

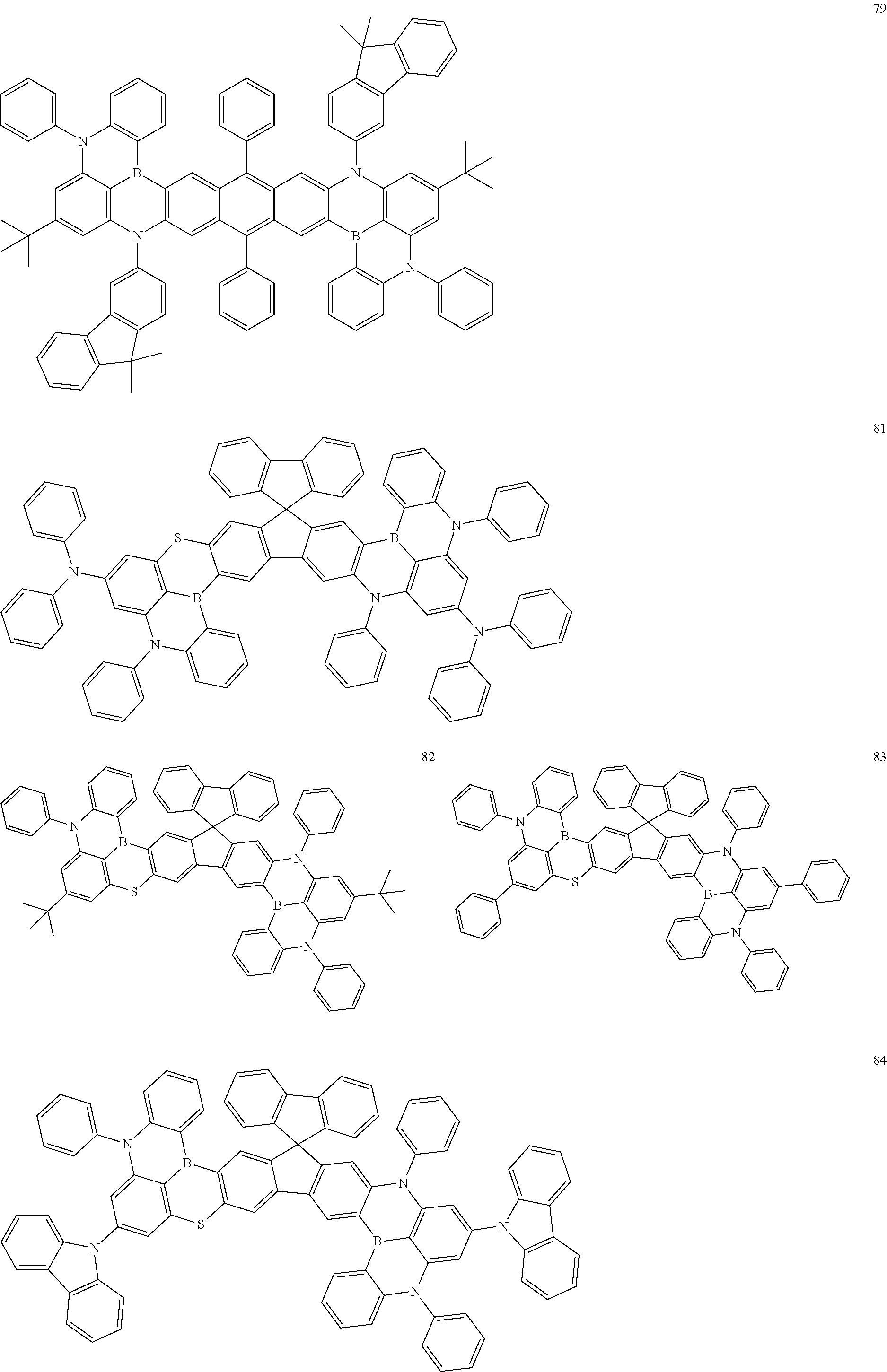

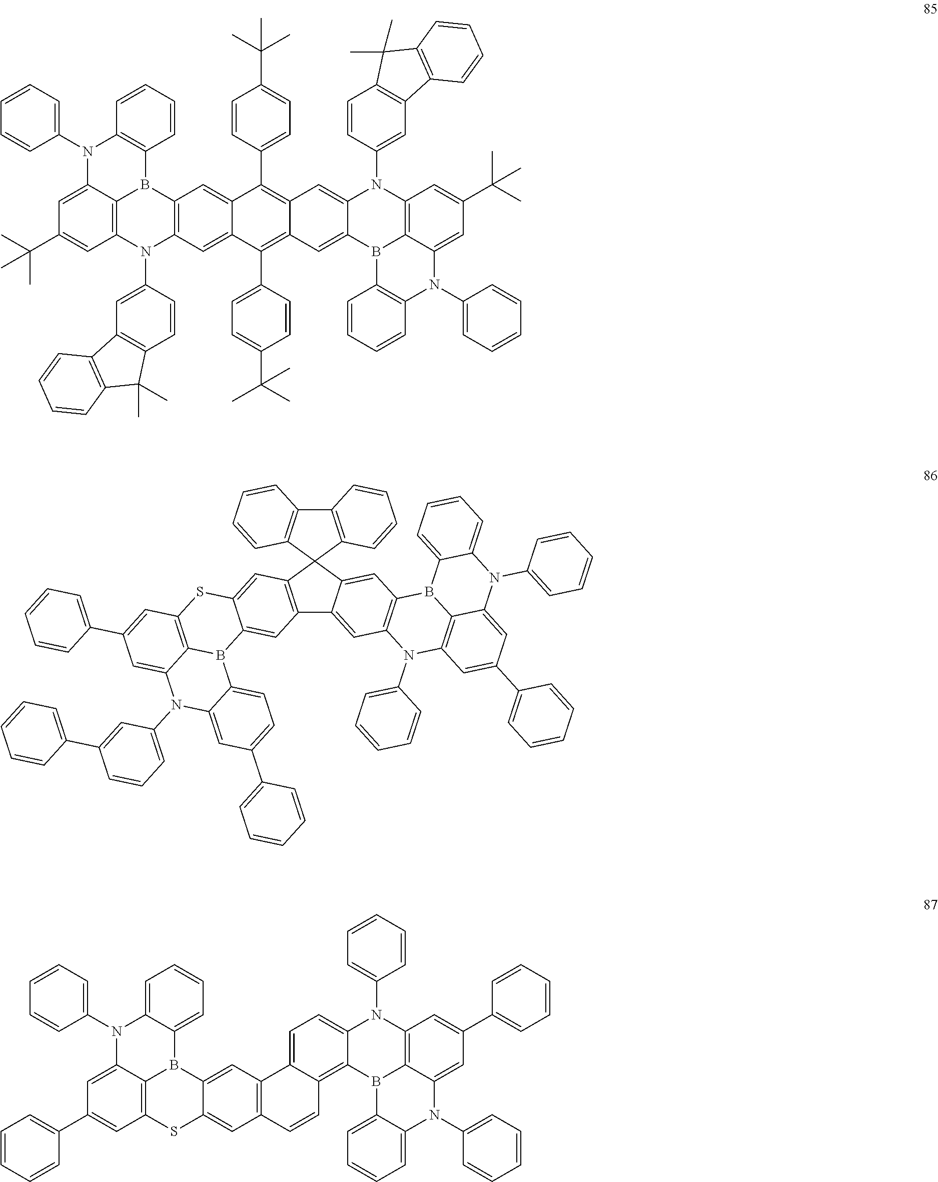 [SMILES: CC(C)(C)c1ccc(-c2c3cc4c(cc3c(-c3ccc(C(C)(C)C)cc3)c3cc5c(cc23)N(c2ccc3c(c2)-c2ccccc2C3(C)C)c2cc(C(C)(C)C)cc3c2B5c2ccccc2N3c2ccccc2)N(c2ccc3c(c2)-c2ccccc2C3(C)C)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5Sc5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1 ; c1ccc(-c2cc3c4c(c2)N(c2ccccc2)c2ccccc2B4c2cc4c(ccc5c6c(ccc54)N(c4ccccc4)c4cc(-c5ccccc5)cc5c4B6c4ccccc4N5c4ccccc4)cc2S3)cc1]

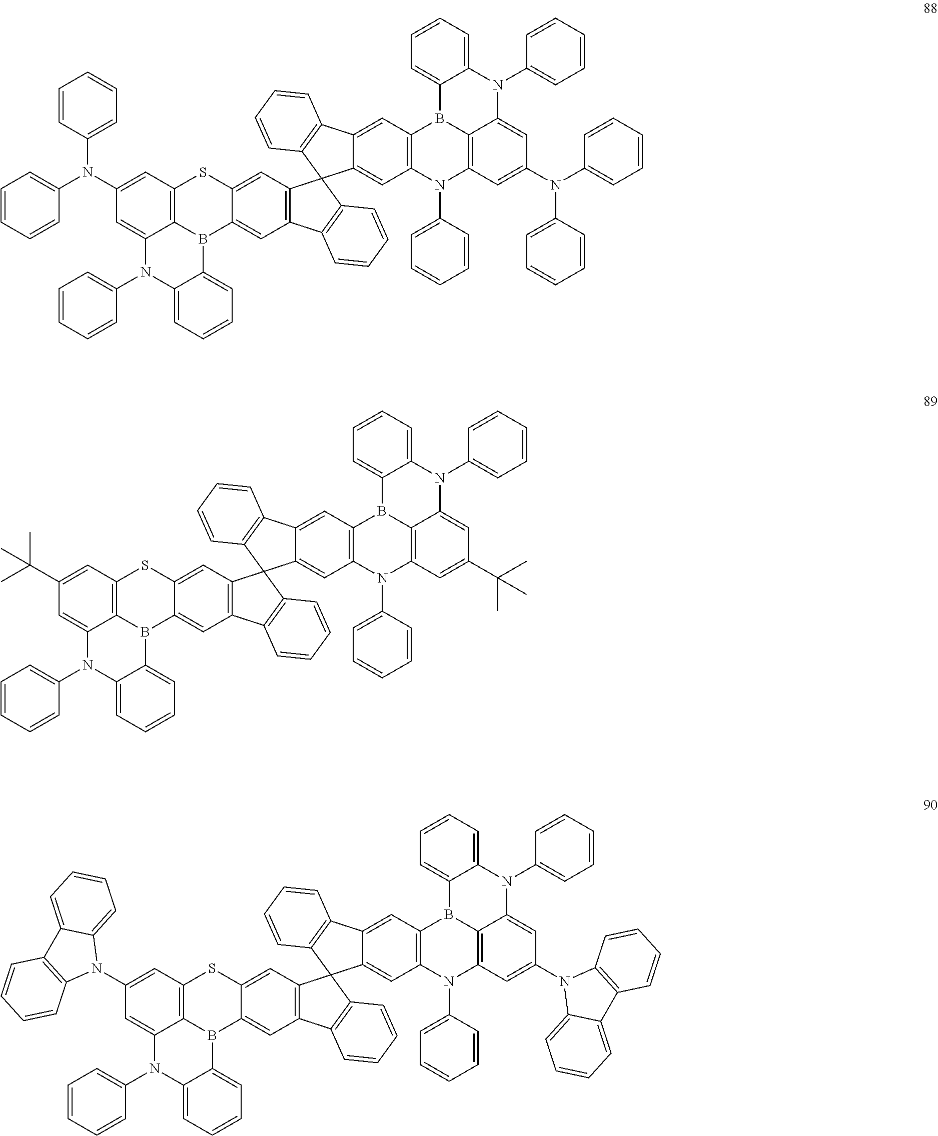 [SMILES: c1ccc(N(c2ccccc2)c2cc3c4c(c2)N(c2ccccc2)c2ccccc2B4c2cc4c(cc2S3)C2(c3ccccc3-4)c3ccccc3-c3cc4c(cc32)N(c2ccccc2)c2cc(N(c3ccccc3)c3ccccc3)cc3c2B4c2ccccc2N3c2ccccc2)cc1 ; CC(C)(C)c1cc2c3c(c1)N(c1ccccc1)c1ccccc1B3c1cc3c(cc1S2)C1(c2ccccc2-3)c2ccccc2-c2cc3c(cc21)N(c1ccccc1)c1cc(C(C)(C)C)cc2c1B3c1ccccc1N2c1ccccc1 ; c1ccc(N2c3ccccc3B3c4cc5c(cc4Sc4cc(-n6c7ccccc7c7ccccc76)cc2c43)C2(c3ccccc3-5)c3ccccc3-c3cc4c(cc32)N(c2ccccc2)c2cc(-n3c5ccccc5c5ccccc53)cc3c2B4c2ccccc2N3c2ccccc2)cc1]

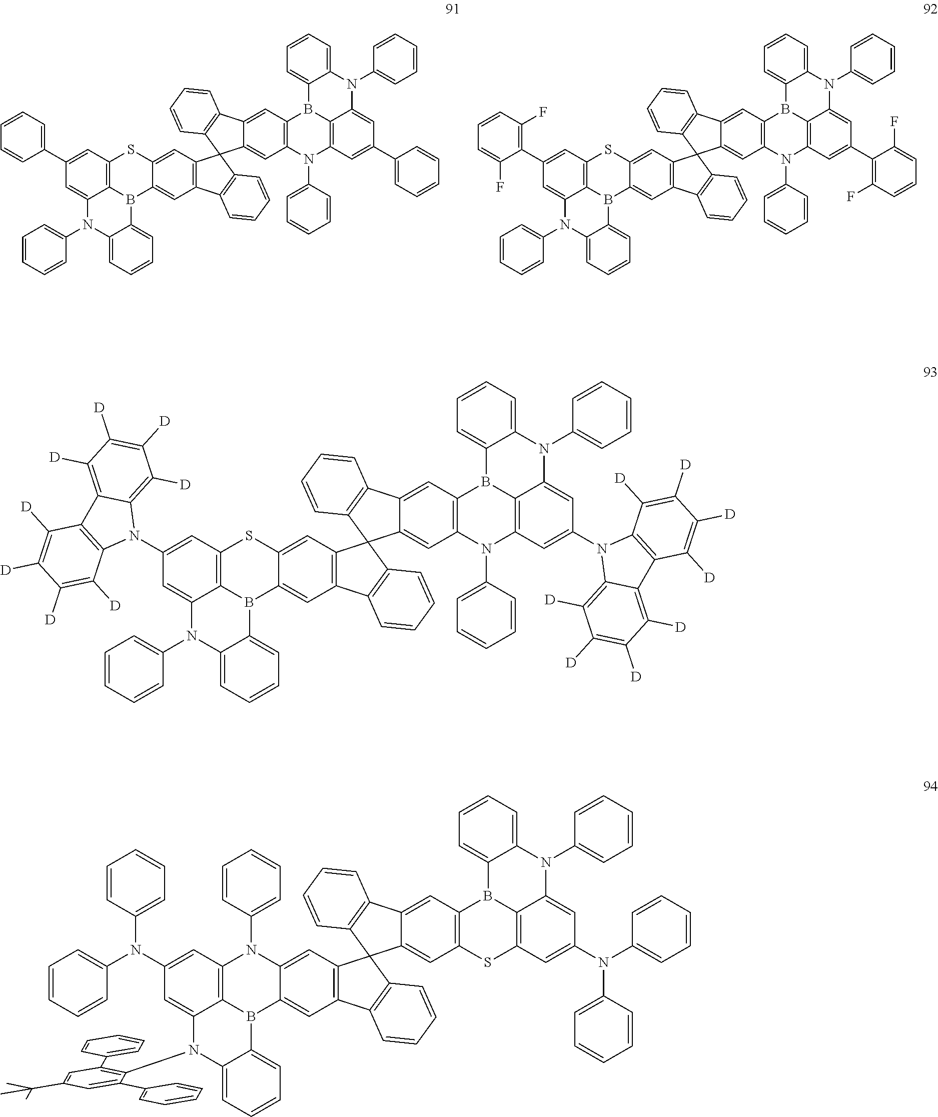

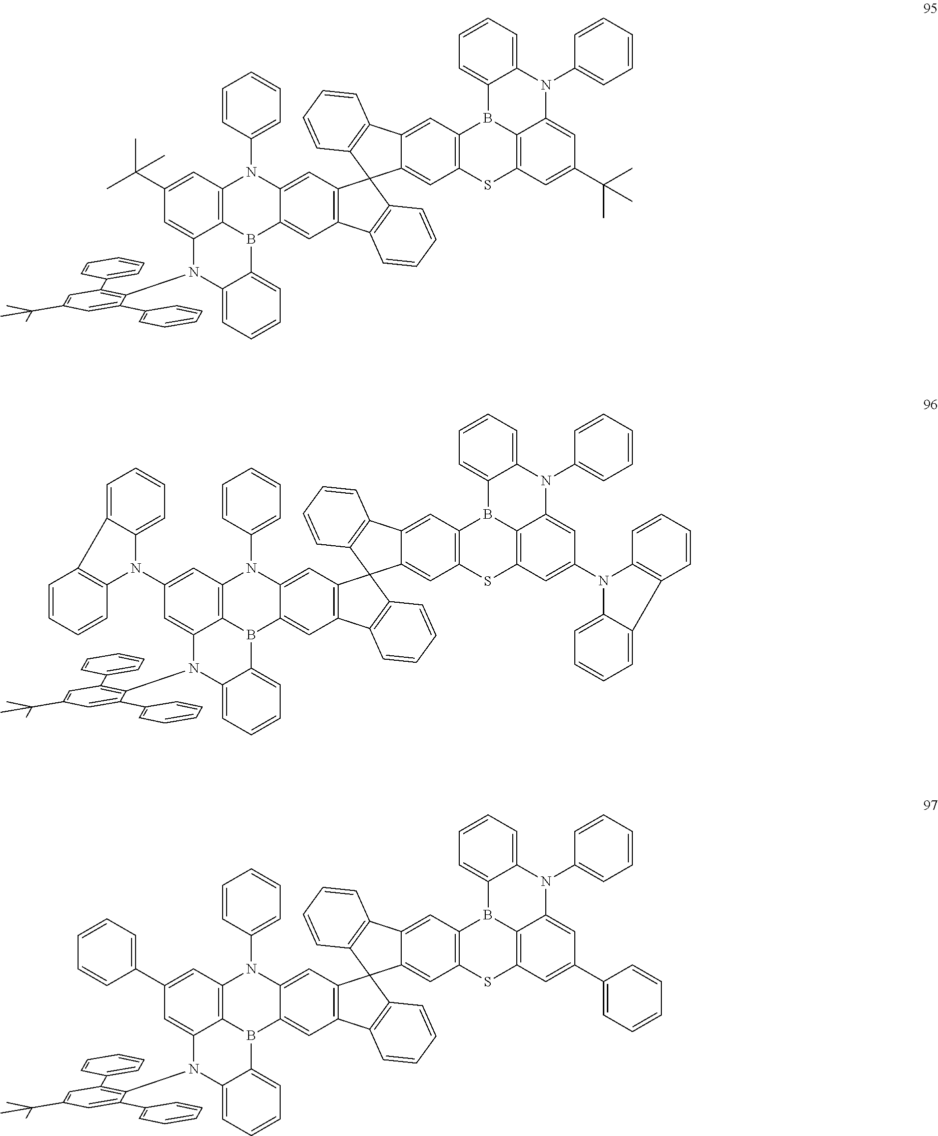

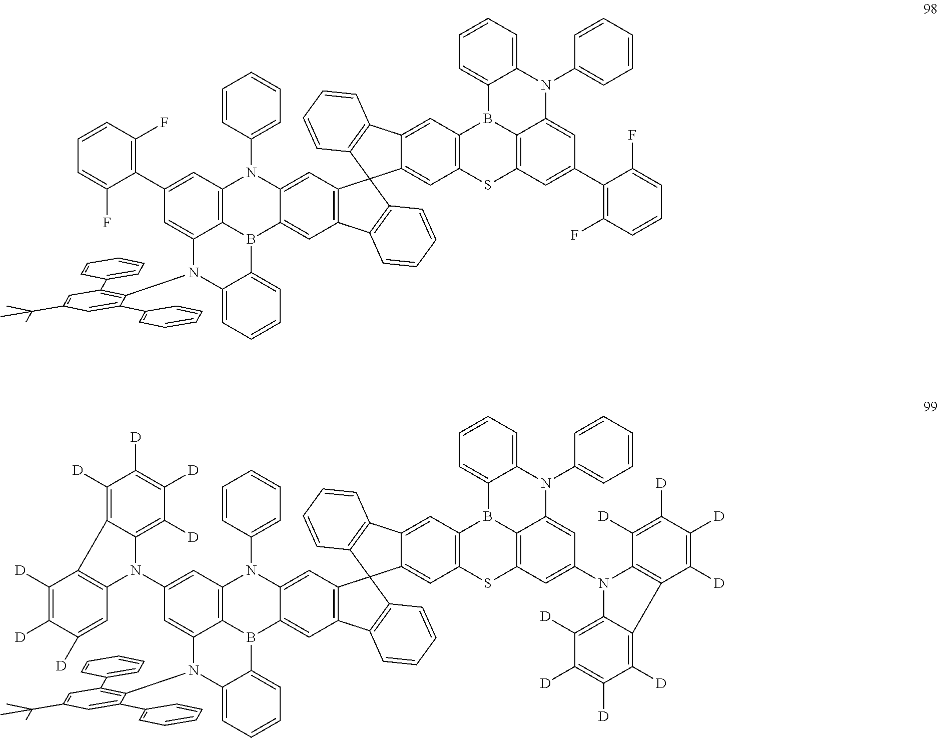 [SMILES: CC(C)(C)c1cc(-c2ccccc2)c(N2c3ccccc3B3c4cc5c(cc4N(c4ccccc4)c4cc(-c6c(F)cccc6F)cc2c43)C2(c3ccccc3-c3cc4c(cc32)Sc2cc(-c3c(F)cccc3F)cc3c2B4c2ccccc2N3c2ccccc2)c2ccccc2-5)c(-c2ccccc2)c1 ; [2H]c1cc2c(c([2H])c1[2H])c1c([2H])c([2H])c([2H])c([2H])c1n2-c1cc2c3c(c1)N(c1c(-c4ccccc4)cc(C(C)(C)C)cc1-c1ccccc1)c1ccccc1B3c1cc3c(cc1N2c1ccccc1)C1(c2ccccc2-c2cc4c(cc21)Sc1cc(-n2c5c([2H])c([2H])c([2H])c([2H])c5c5c([2H])c([2H])c([2H])c([2H])c52)cc2c1B4c1ccccc1N2c1ccccc1)c1ccccc1-3]

In the polycyclic compound represented by Formula 1, an emission spectrum may have a full width at half maximum (FWHM) in a range of about 10 to 50 min. For example, the emission spectrum may have a full width at half maximum (FWHM) in a range of about 20 to 40 nm. The emission spectrum of the polycyclic compound represented by Formula 1 may have the above-described range of the full width at half maximum, and if applied to an element as a dopant, emission efficiency may be improved. If the polycyclic compound is used as a blue light emitting element material for a light emitting element, the lifetime of the element may be improved.

The polycyclic compound represented by Formula 1 may be a material for emitting thermally activated delayed fluorescence. The polycyclic compound represented by Formula 1 may be a thermally activated delayed fluorescence dopant having a difference (ΔE_{ST1}) between the lowest triplet excitation energy level (T1) and the lowest singlet excitation energy level (S1) equal to or less than about 1.2 eV.

The polycyclic compound according to an embodiment may be included in an emission layer EML. The polycyclic compound may be included in the emission layer EML as a dopant material. The polycyclic compound may be a thermally activated delayed fluorescence emitting material. The polycyclic compound may be used as a thermally activated delayed fluorescence (TADF) dopant. For example, in the light emitting element ED, the emission layer EML may include at least one of the polycyclic compounds represented in Compound Group 1 as the thermally activated delayed fluorescence dopant. However, the use of the polycyclic compound is not limited thereto.

The polycyclic compound represented by Formula 1 may be a light-emitting material having an emission center wavelength in a wavelength region in a range of about 430 nm to about 490 nm. The polycyclic compound may emit blue light. For example, the polycyclic compound represented by Formula 1 may be a blue thermally activated delayed fluorescence (TADF) dopant. However, embodiments are not limited thereto.

In the light emitting element ED, the emission layer EML may emit delayed fluorescence. For example, the emission layer EML may emit thermally activated delayed fluorescence (TADF).

The emission layer EML of the light emitting element ED may emit blue light. For example, the emission layer EML of the light emitting element ED may emit blue light in a wavelength range equal to or less than about 490 nm. However, embodiments are not limited thereto, and the emission layer EML may emit green light or red light.

In an embodiment, the emission layer EML may include multiple compounds. In an embodiment, the emission layer EML may include the polycyclic compound represented by Formula 1 as the first compound, and may further include at least one of a second compound represented by Formula HT-1, a third compound represented by Formula ET-1, and a fourth compound represented by Formula S-1. For example, the emission layer EML may include the first compound, the second compound, and the third compound.

In the emission layer EML, the second compound and the third compound may form an exciplex, and energy may be transferred from the exciplex to the first compound to emit light. In an embodiment, the emission layer EML may include the first compound, the second compound, the third compound, and the fourth compound. In the emission layer EML, the second compound and the third compound may form as exciplex, and energy may be transferred from the exciplex to the fourth compound and the first compound to emit light. The fourth compound may be referred to as a sensitizer. The fourth compound may emit phosphorescence, or may transfer energy to the first compound as an auxiliary dopant. However, these are only examples, and embodiments are not limited thereto.

The light emitting element ED may include the first compound, the second compound, the third compound, and the fourth compound, and the emission layer EML may include two host materials and two dopant materials in combination. In the light emitting element ED, the emission layer EML may include the first compound which emits delayed fluorescence, the second compound and the third compound, which are different two hosts, and the fourth compound including an organometallic complex, and thus the light emitting element ED may exhibit excellent emission efficiency properties.

In an embodiment, the emission layer EML may further include a second compound represented by Formula HT-1. In an embodiment, the second compound may be used as a hole transporting host material in the emission layer EML.

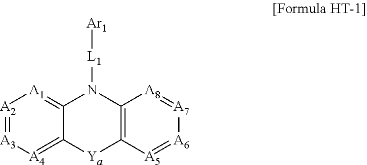

In Formula HT-1, A₁ to A₈ may each independently be N or C(Rₓ₁). For example, A₁ to A₈ may each independently be C(Rₓ₁). In another example, one of A₁ to A₈ may be N, and the remainder of A₁ to A₈ may each independently be C(Rₓ₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(Rₓ₂)(Rₓ₃), or Si(Rₓ₄)(Rₓ₅). For example, the two benzene rings that are bonded to the nitrogen atom in Formula HT-1 may be bonded to each other via a direct linkage,

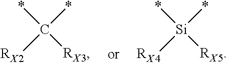

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, An may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, Rₓ₁ to Rₓ₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, Rₓ₁ to Rₓ₅ may each independently be a hydrogen atom or a deuterium atom. For example, Rₓ₁ to Rₓ₅ may each independently be an unsubstituted methyl group or an unsubstituted phenyl group.

In an embodiment, the second compound represented by Formula HT-1 may be selected from Compound Group 2. In an embodiment, in the light emitting element ED, the second compound may include at least one compound selected from Compound Group 2.

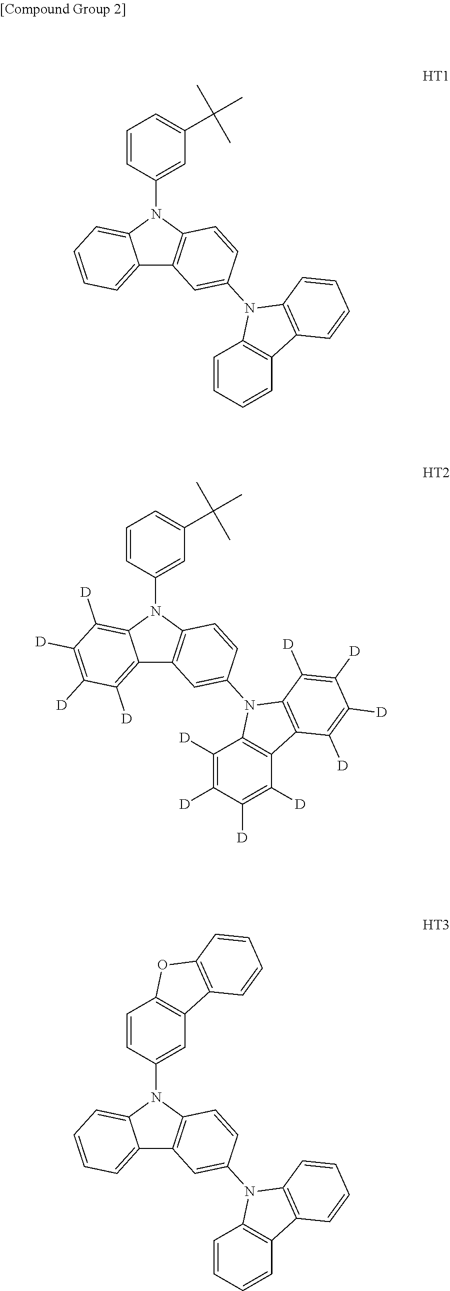 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

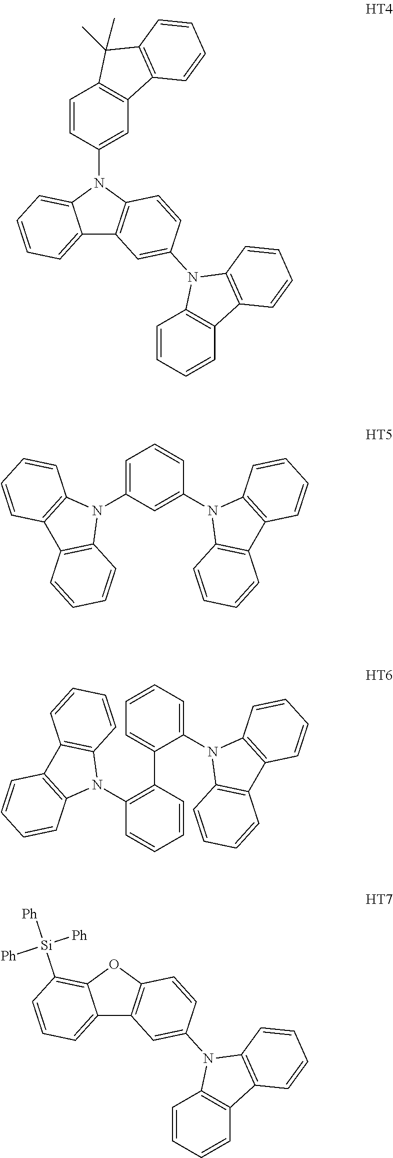 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

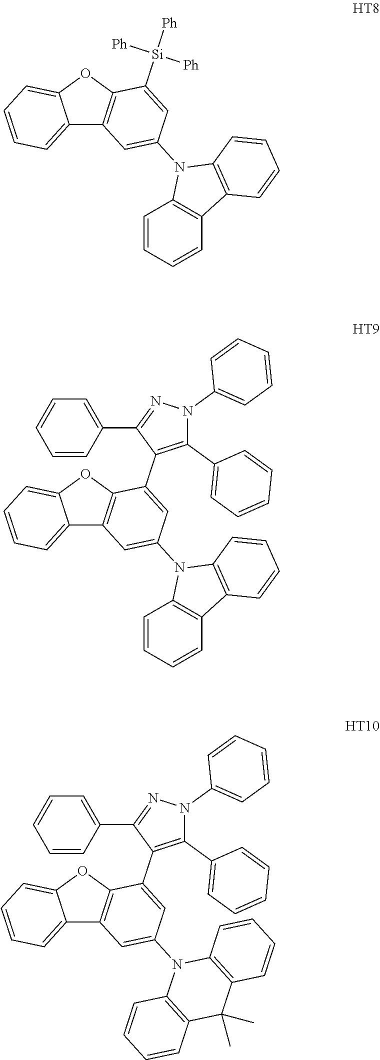 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21]

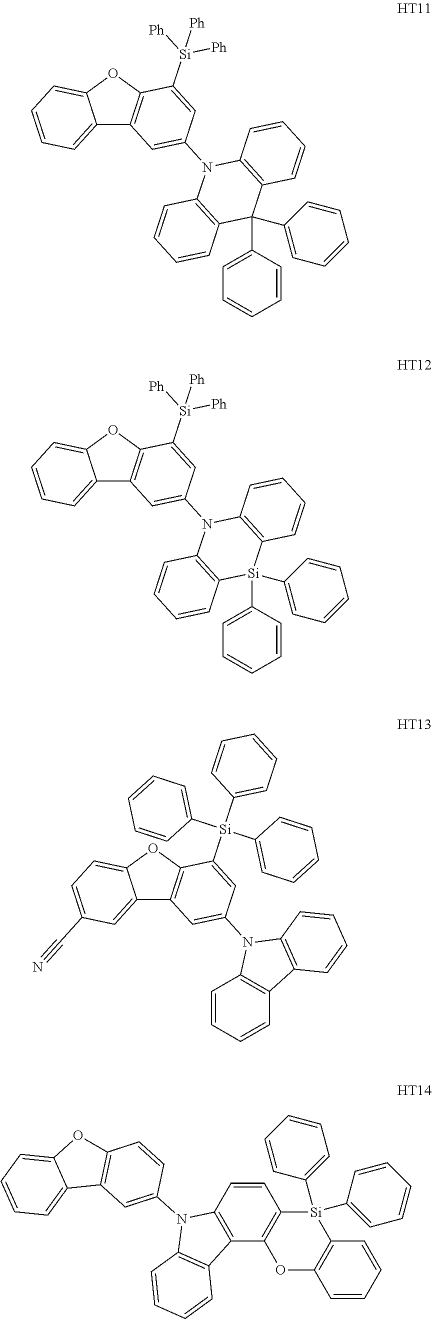 [SMILES: c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

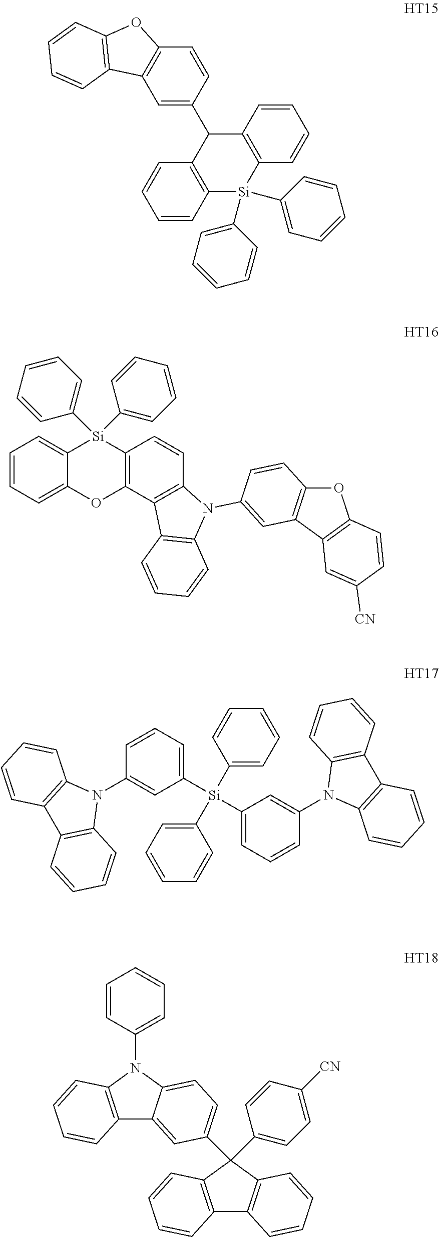 [SMILES: c1ccc([Si]2(c3ccccc3)c3ccccc3C(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

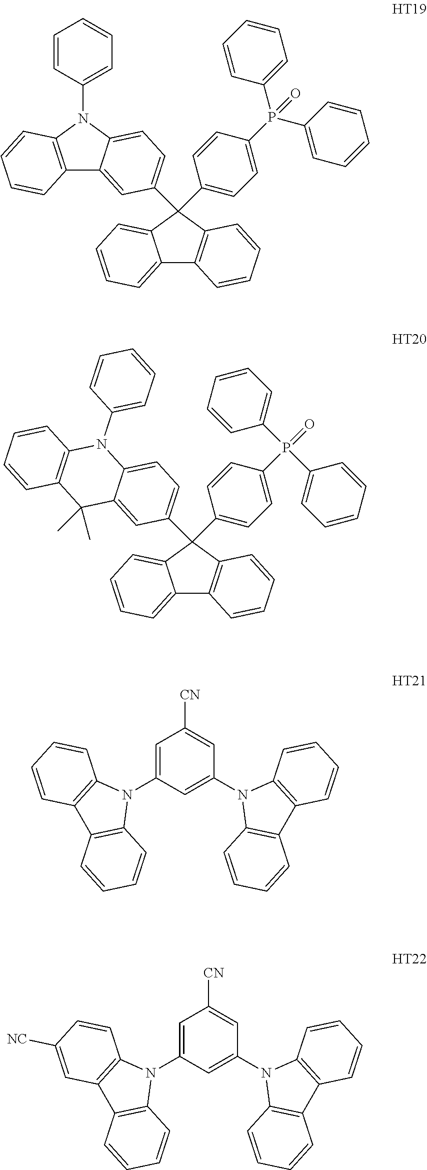 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

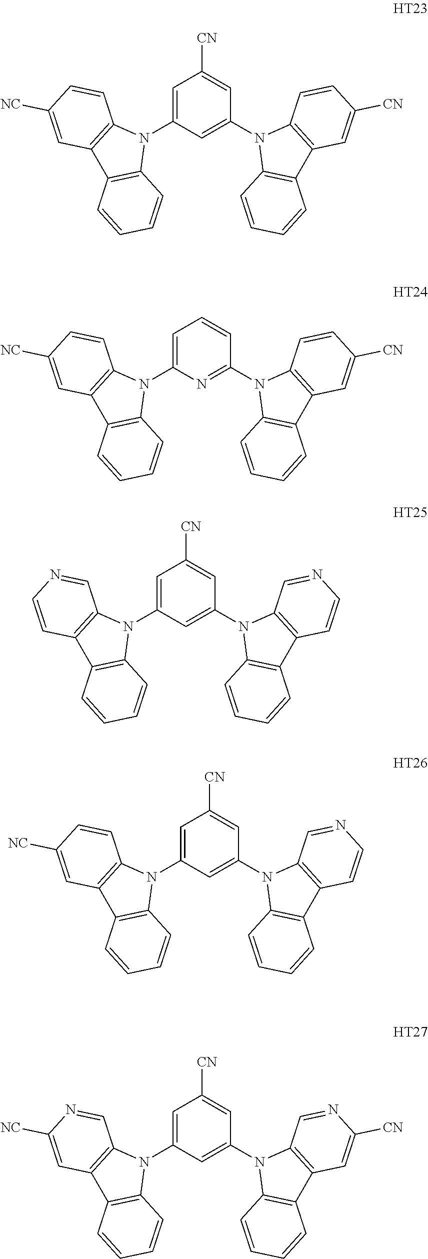 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

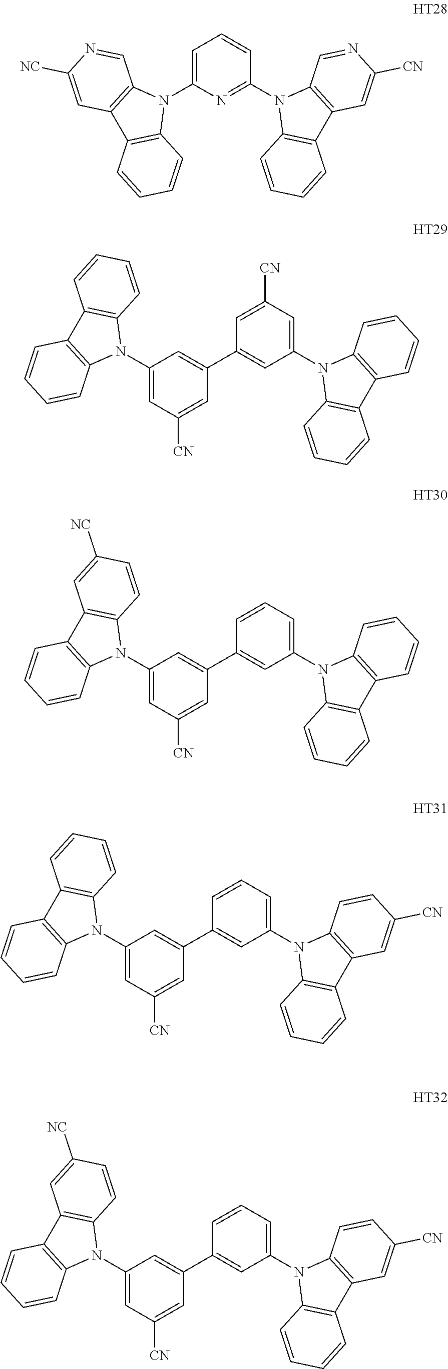 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

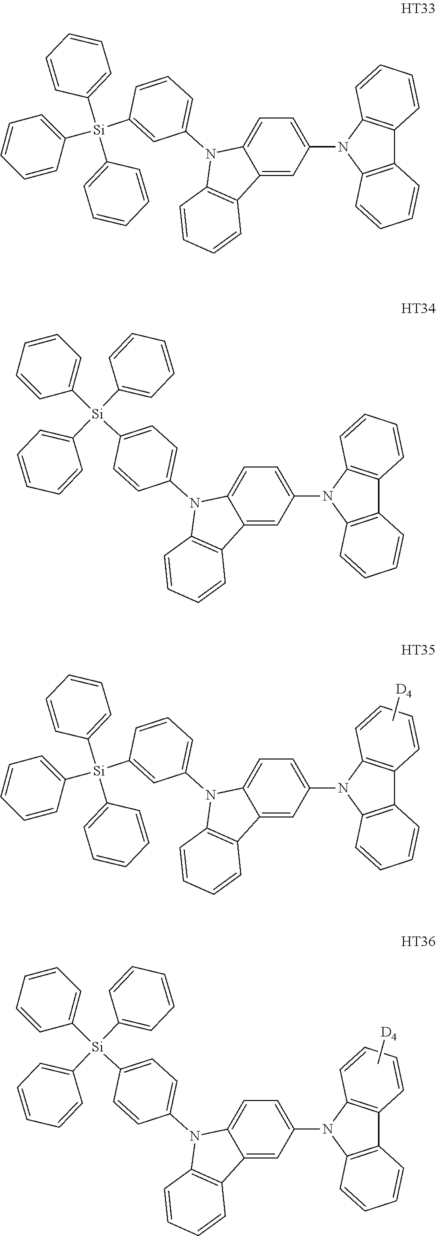

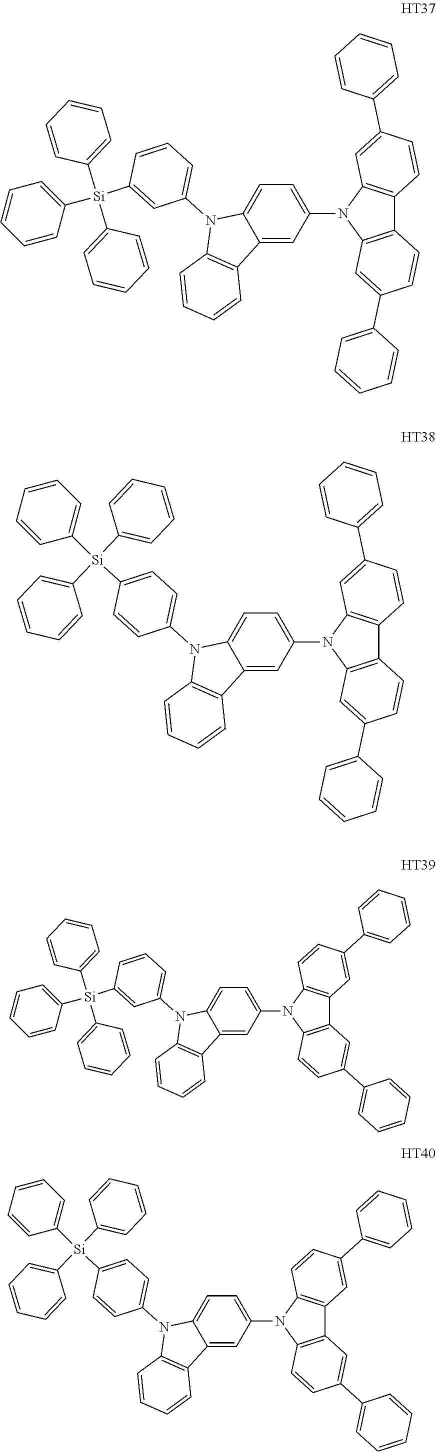 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

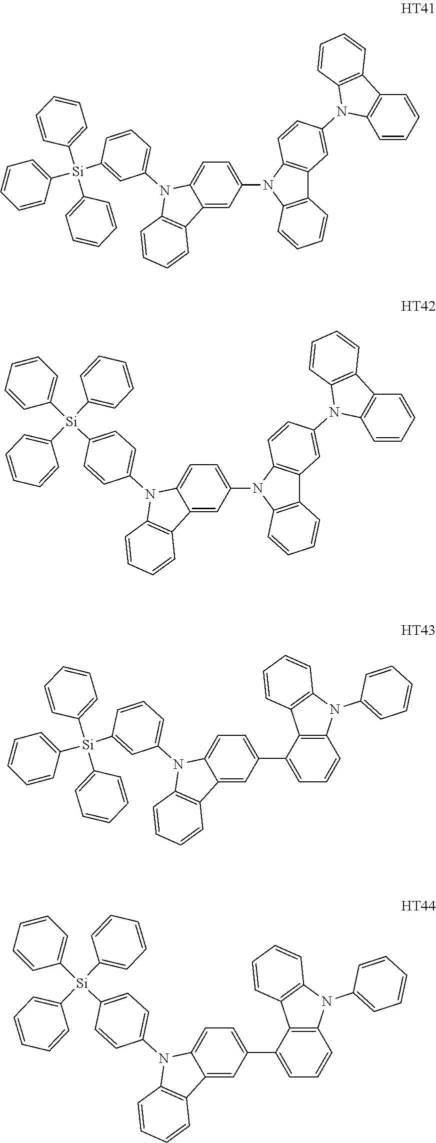 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

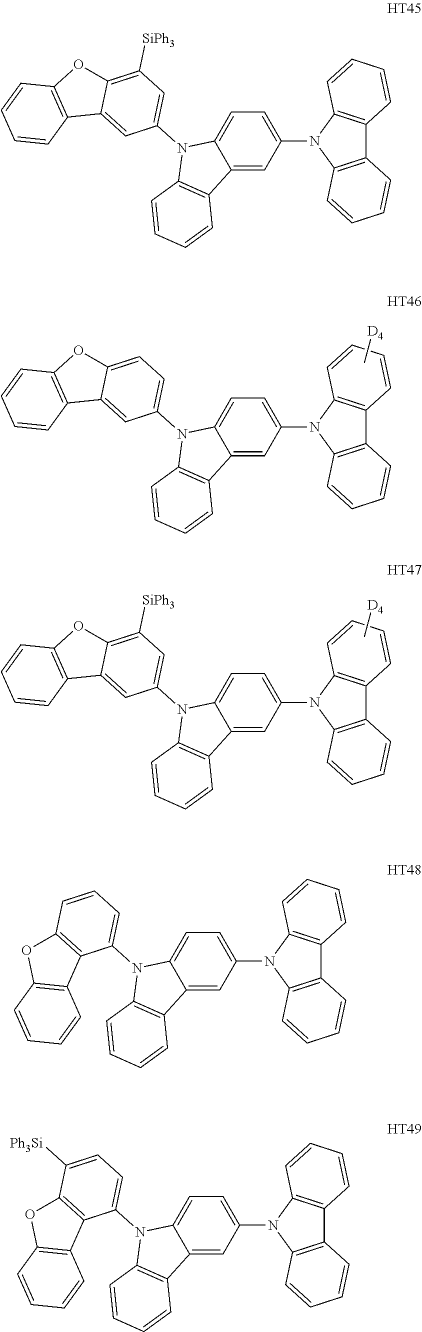

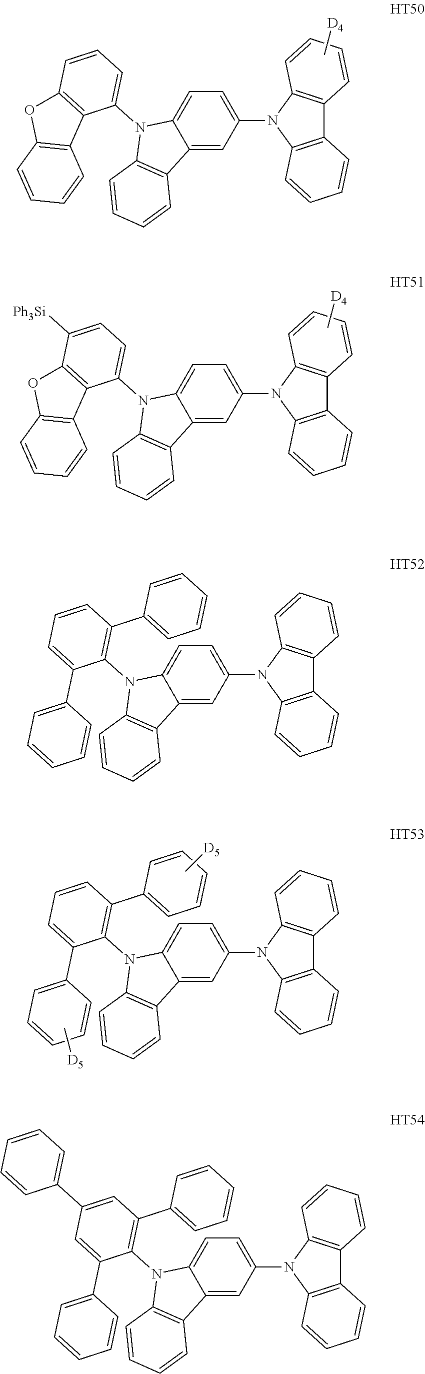

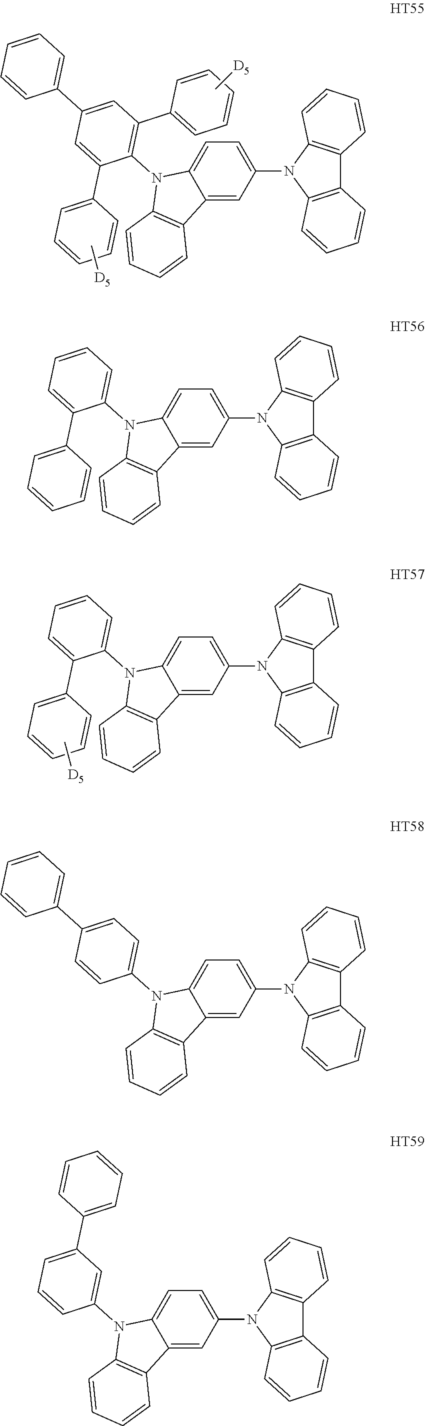

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

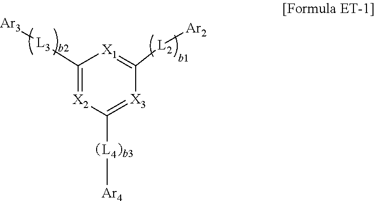

In Formula ET-1, at least one of X₁ to X₃ may each be N, and the remainder of X₁ to X₃ may each independently be C(Rₓ₆). For example, one of X₁ to X₃ may be N, and the remainder of X₁ to X₃ may each independently be C(Rₓ₆). Thus, the third compound represented by Formula ET-1 may include a pyridine moiety. As another example, two of X₁ to X₃ may each be N, and the remainder of X₁ to X₃ may be C(Rₓ₆). Thus, the third compound represented by Formula ET-1 may include a pyrimidine moiety. As yet another example, X₁ to X₃ may each be N. Thus, the third compound represented by Formula ET-1 may include a triazine moiety.

In Formula ET-1, Rₓ₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are integers equal to or greater than 2, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3.

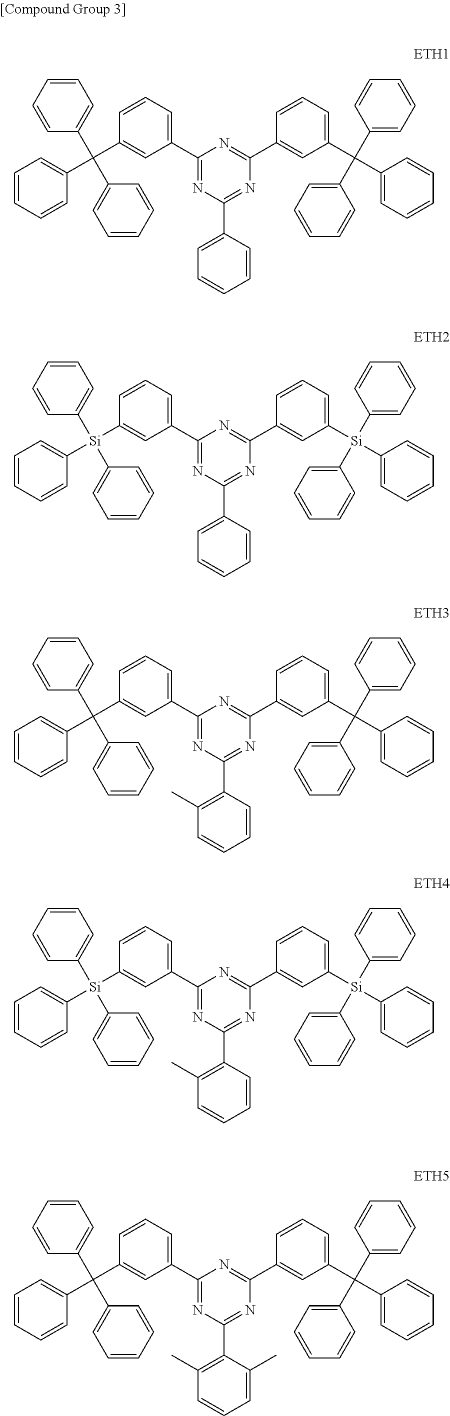

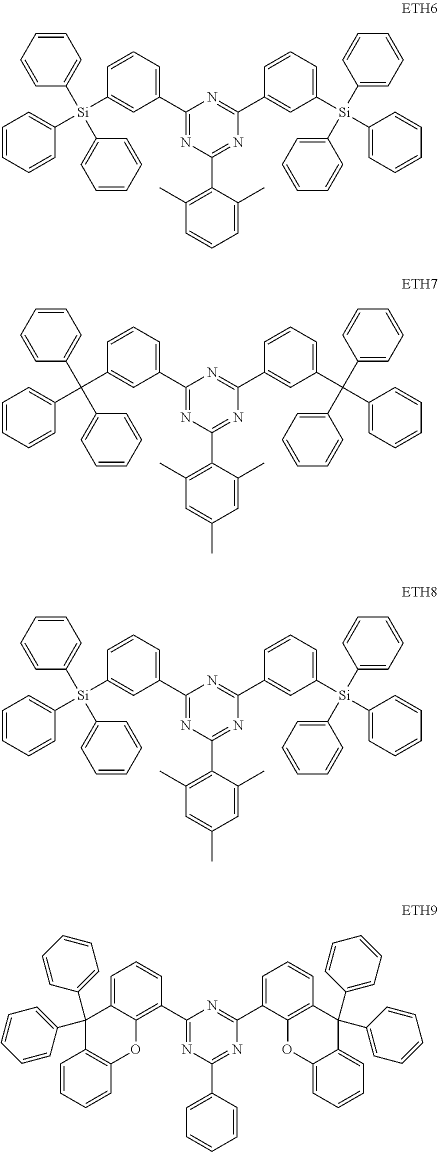 [SMILES: Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1]

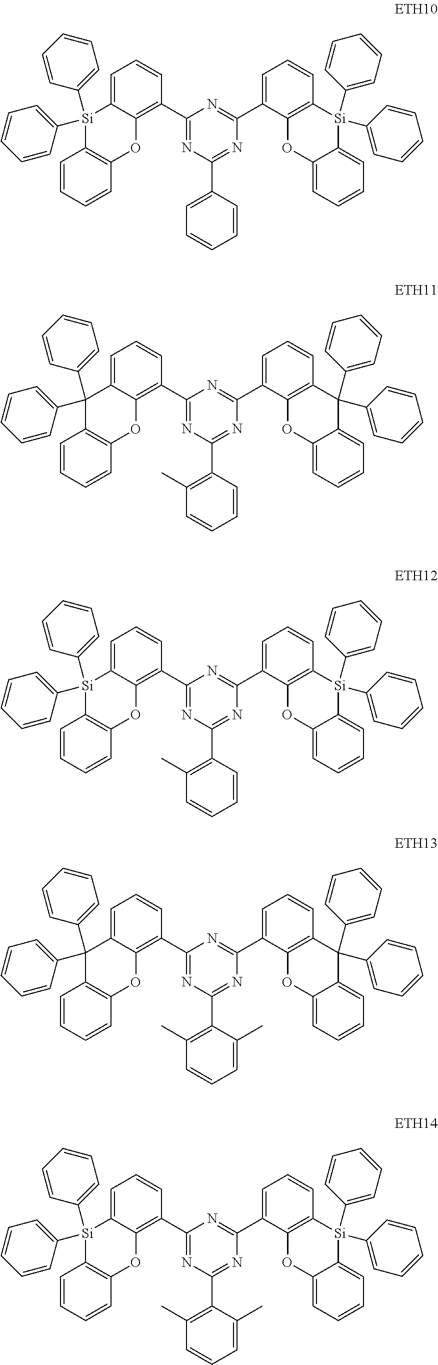

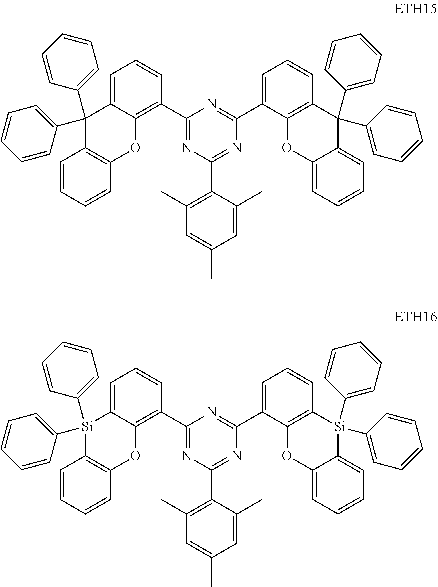 [SMILES: Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

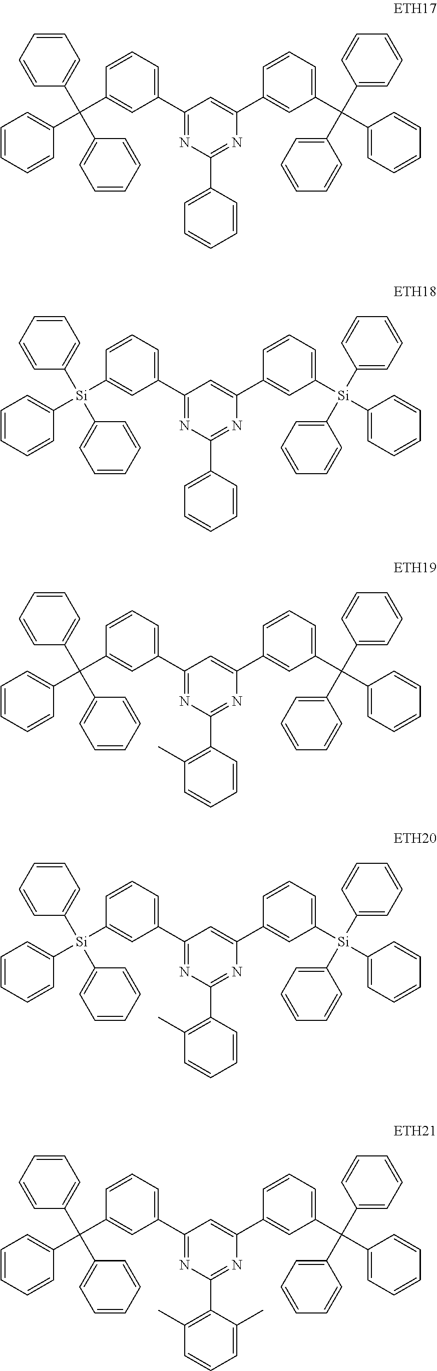

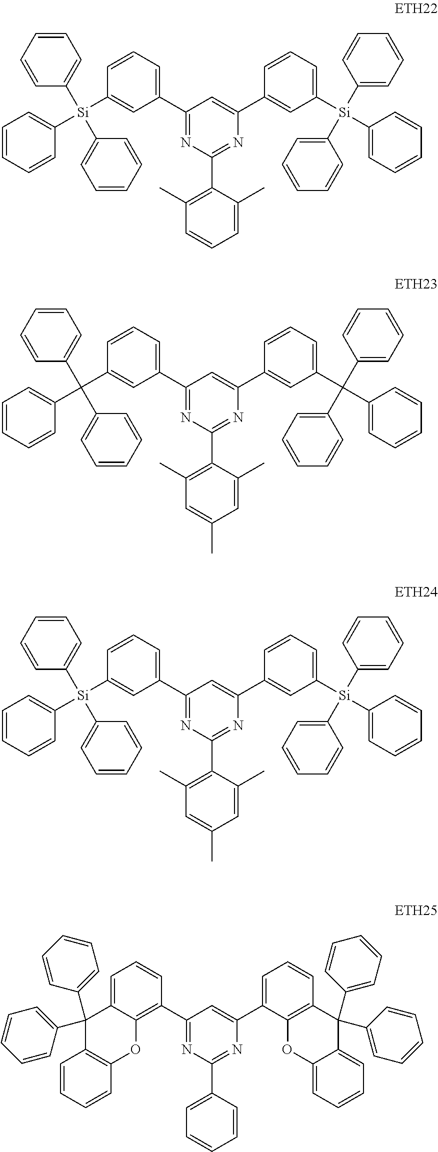 [SMILES: Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1]

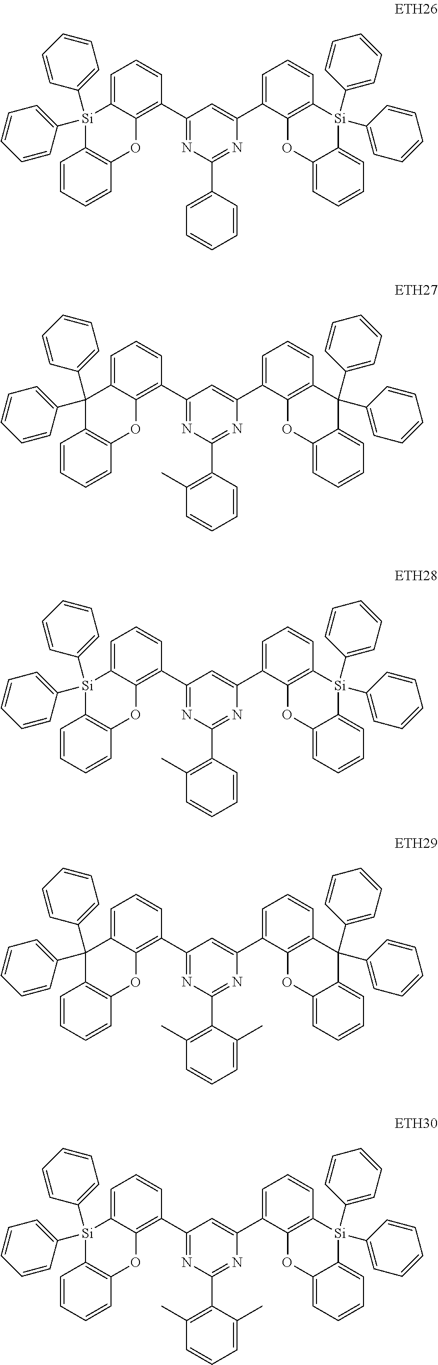

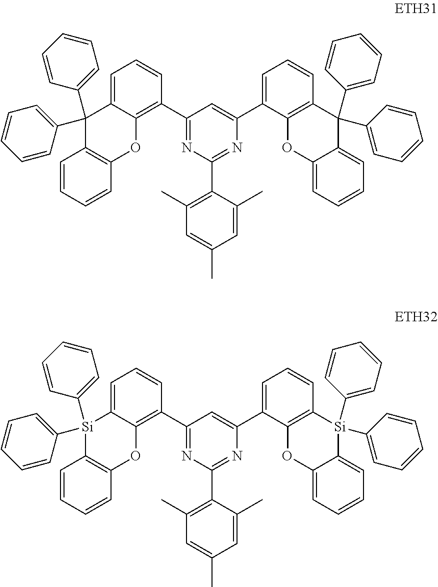 [SMILES: Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

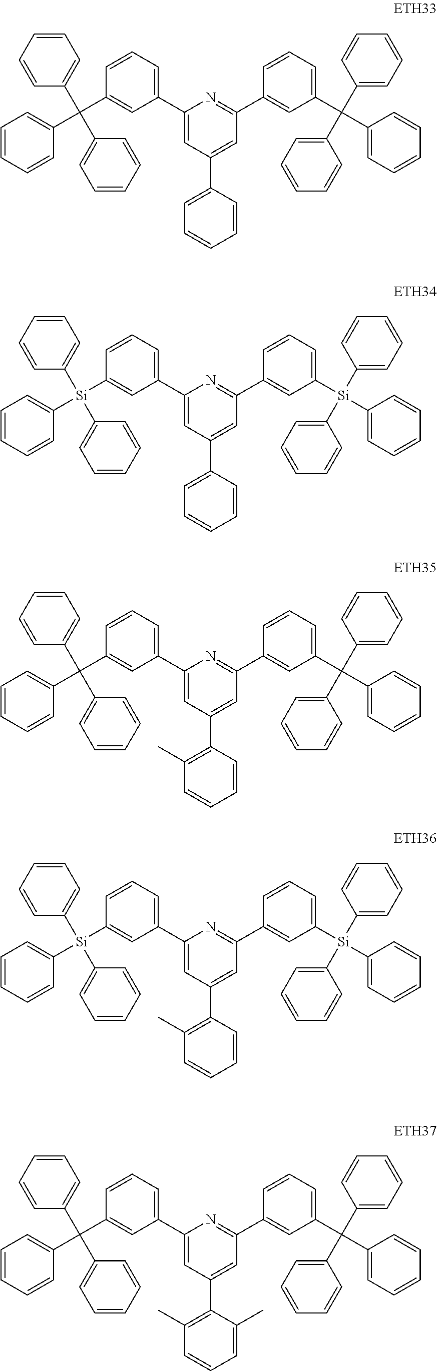

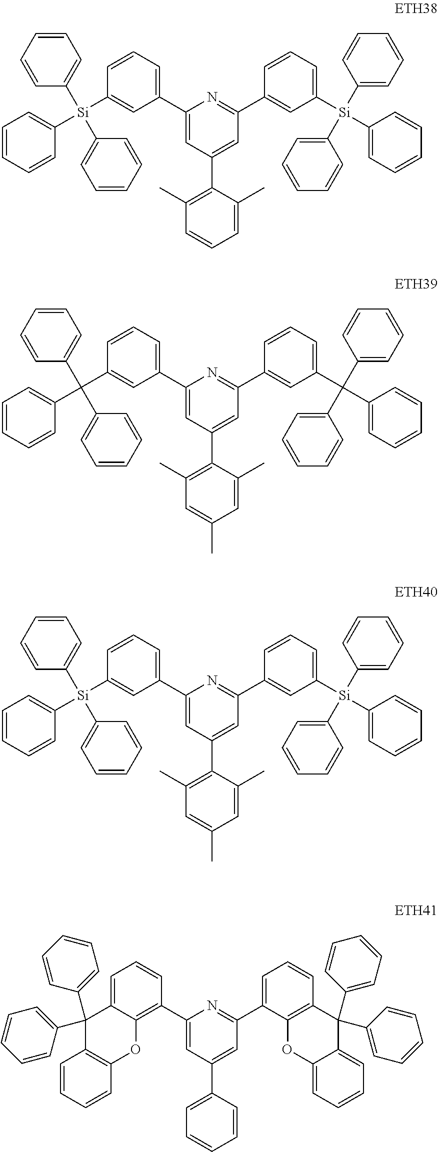 [SMILES: Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1]

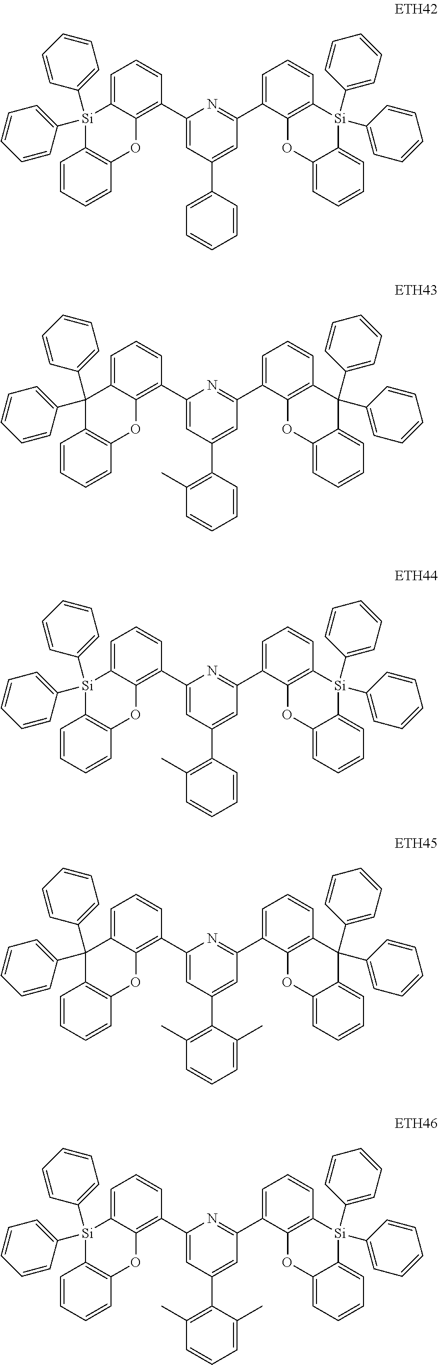

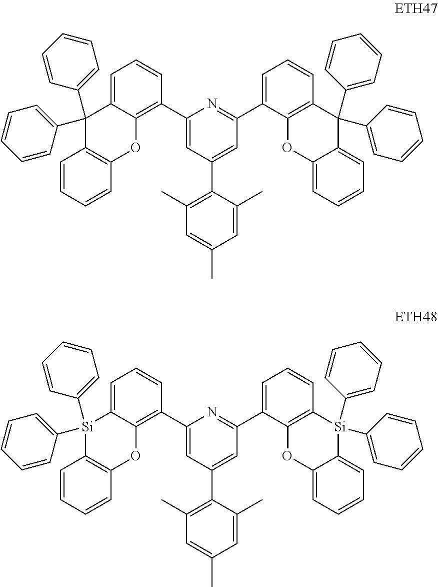 [SMILES: Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

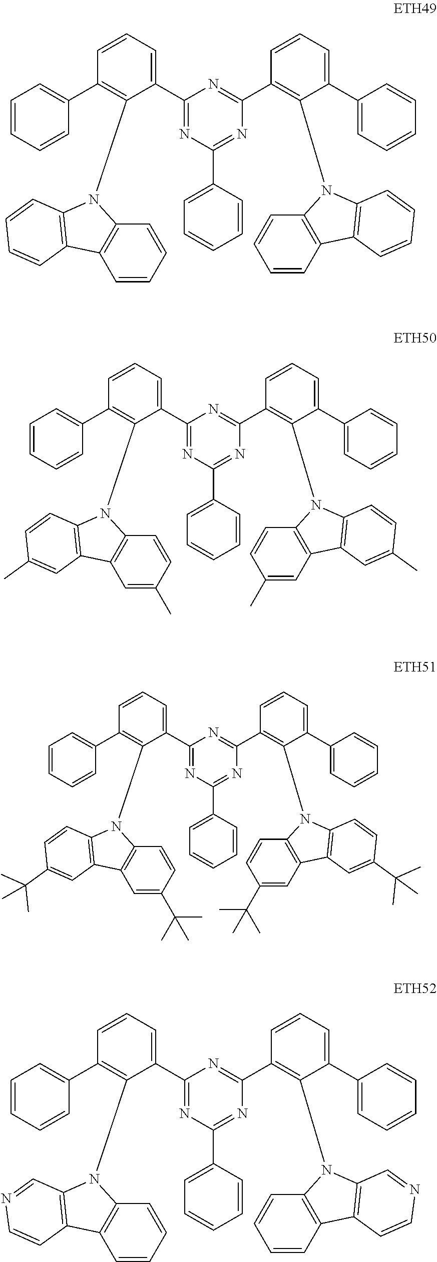

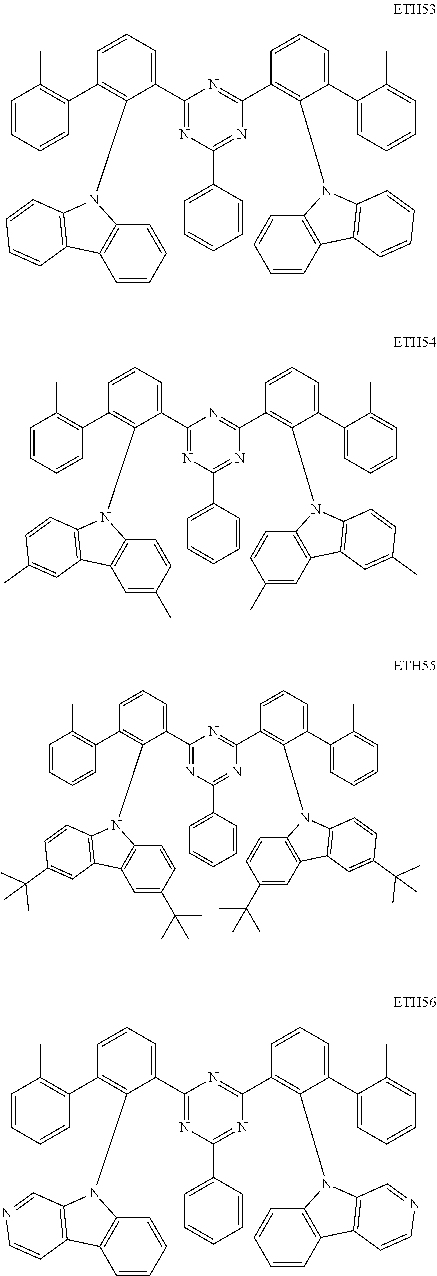

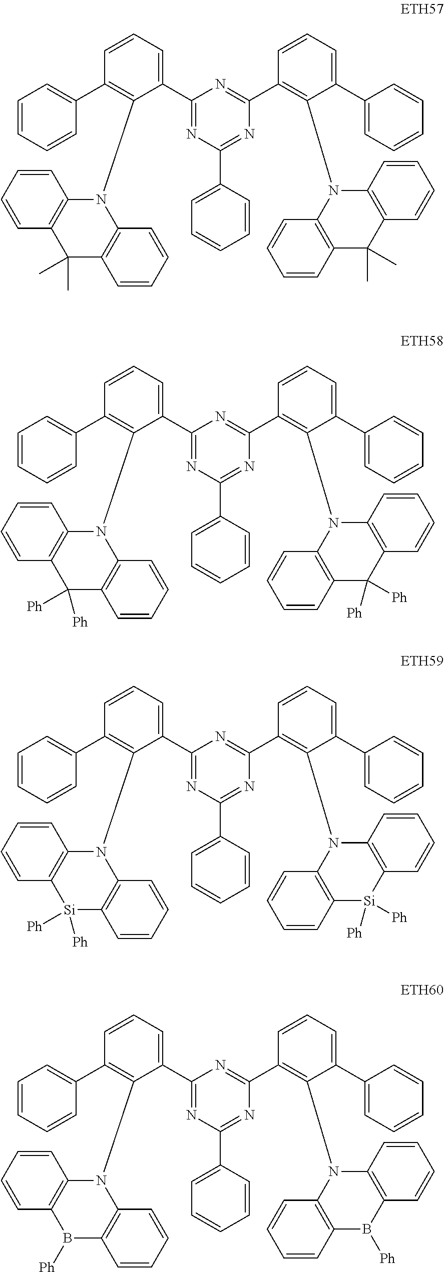

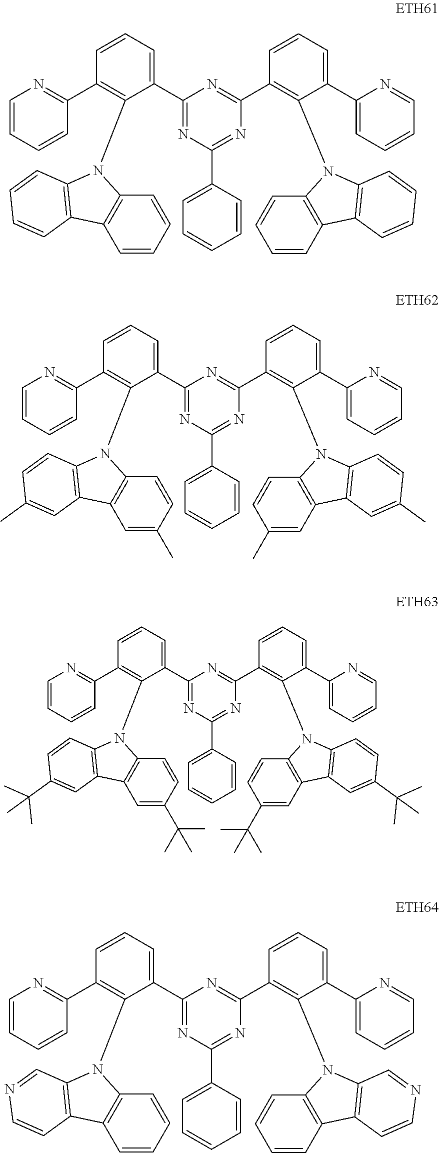

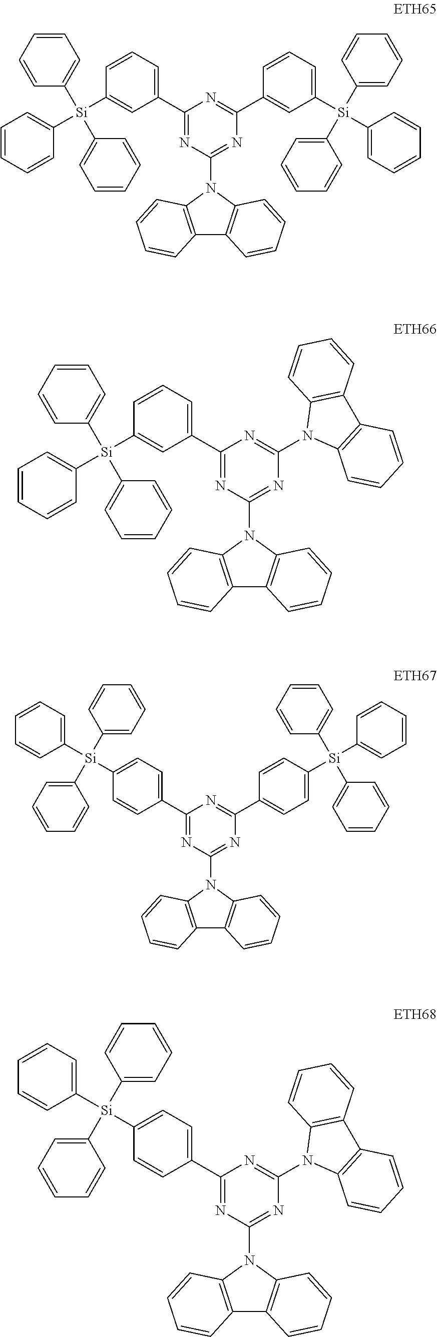 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

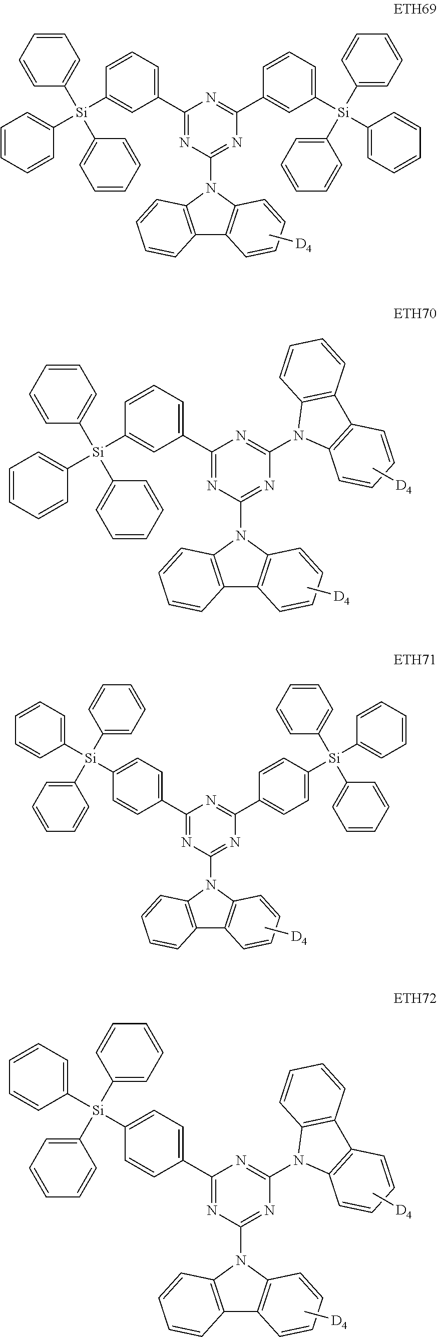

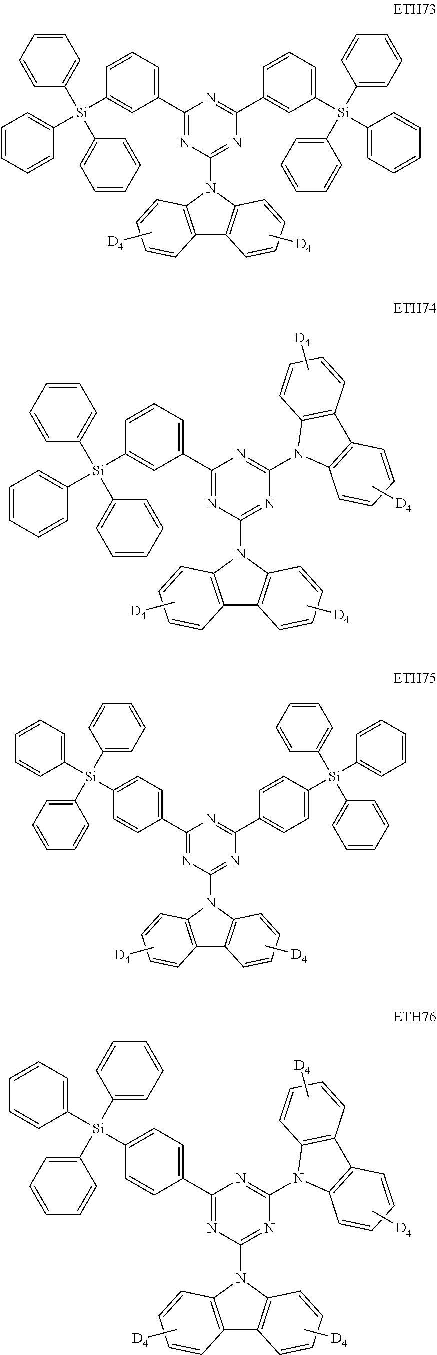

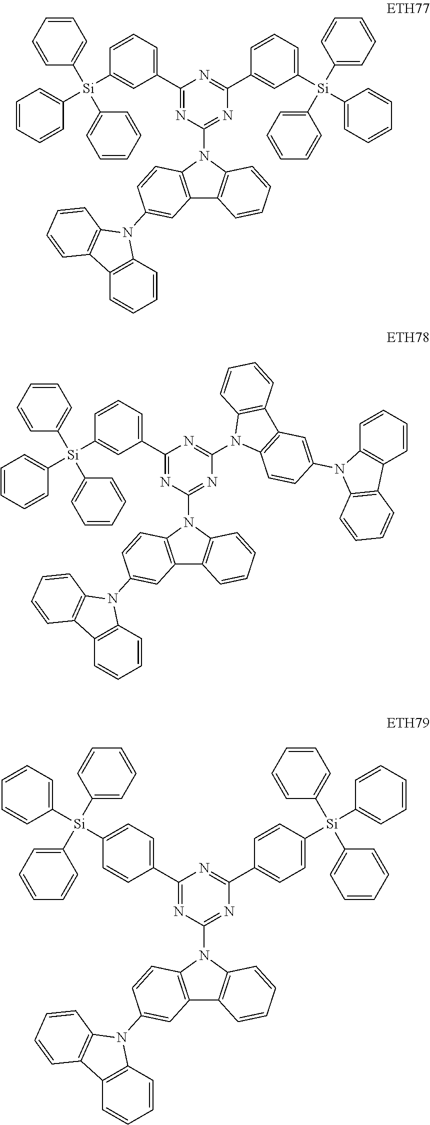 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

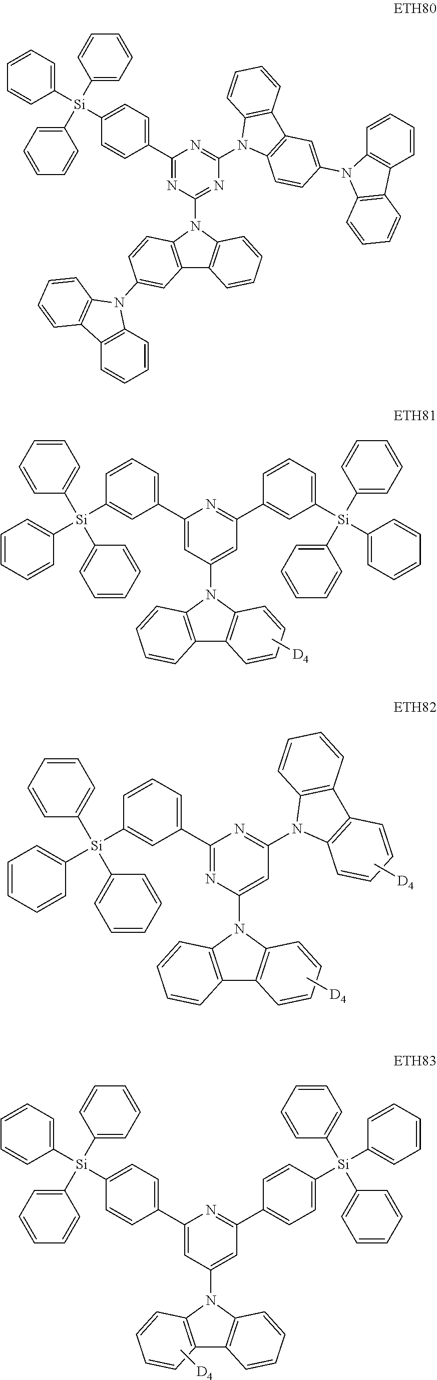

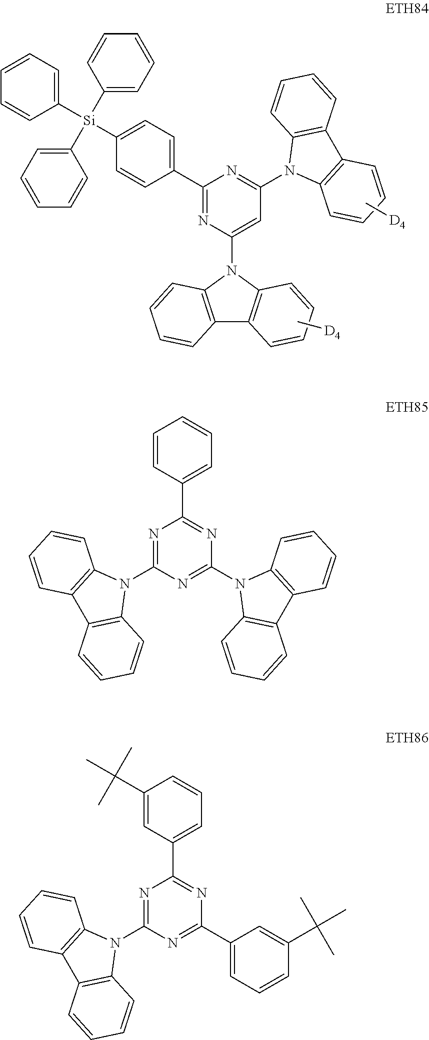

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy level of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may have a value that is smaller than an energy gap of each host material. The exciplex may have a triplet energy level less than or equal to about 3.0 eV, which is an energy gap between the hole transporting host and the electron transporting host.

In an embodiment, the emission layer EML may include a fourth compound in addition to the first compound, the second compound, and the third compound as described above. The fourth compound may be used as a phosphorescent sensitizer in the emission layer EML. Energy may be transferred from the fourth compound to the first compound, thereby emitting light.

In an embodiment, the emission layer EML may include, as a fourth compound, an organometallic complex that includes platinum (Pt) as a central metal atom and ligands connected to the central metal atom. In an embodiment, the emission layer EML may further include a fourth compound represented by Formula S-1:

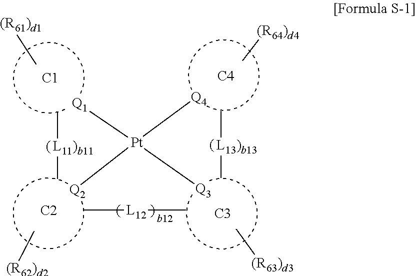

In Formula S-1, Q₁ to Q₄ may each independently be C or N.

In Formula S-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula S-1, L₁₁ to L₁₃ may each independently be a direct linkage,

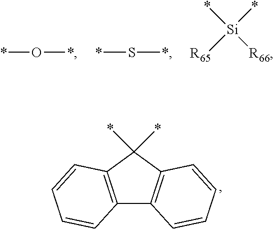

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bond to one of C1 to C4.

In Formula S-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula S-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula S-1, d1 to d4 may each independently be an integer from 0 to 4. In Formula S-1, if d1 to d4 are each 0, the fourth compound may not be substituted with any of R₆₁ to R₆₄. A case where d1 to d4 are each 4 and groups of each of R₆₁ to R₆₄ are hydrogen atoms may be the same as a case where d1 to d4 are each 0. When d1 to d4 is each 2 or more, multiple groups of each of R₆₁ to R₆₄ may be the same as each other, or at least one group thereof may be different from the remainder.

In an embodiment, in Formula S-1, C1 to C4 may each independently be a substituted or unsubstituted hydrocarbon ring or a substituted or unsubstituted heterocycle that is represented by one of Formula C-1 to Formula C-4:

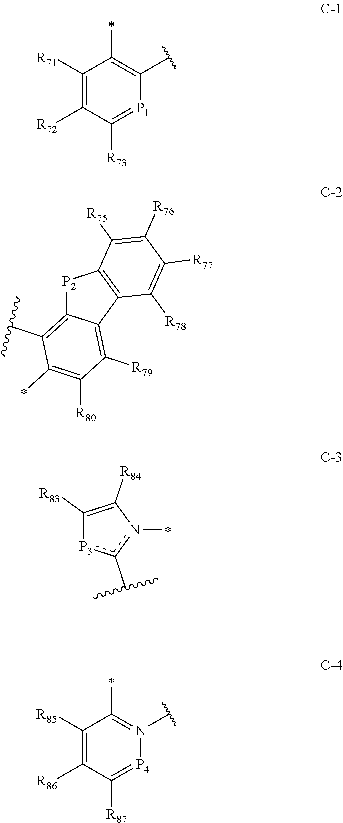

In Formula C-1 to Formula C-4, P₁ may be C [symbol] or C(R₇₄), P₂ may be N [symbol] or N(R₈₁), P₃ may be N [symbol] or N(R₈₂), and P₄ may be C [symbol] or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4,

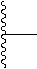

represents a bond to Pt, which is a central metal atom, and [symbol] represents a bond to a neighboring cyclic group (C1 to C4) or to a linker (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer. The fourth compound included in the emission layer EML of the light emitting element ED may serve as a sensitizer to transfer energy from the host to the first compound, which is a light emitting dopant. For example, the fourth compound, which serves as an auxiliary dopant, accelerates energy transfer to the first compound, which serve as a light emitting dopant, thereby increasing an emission ratio of the first compound. Therefore, the emission layer EML may have improved luminous efficiency. When energy transfer to the first compound is increased, excitons formed in the emission layer EML may not accumulate inside the emission layer EML and may emit light rapidly, so that deterioration of the device may be reduced. Therefore, the service life of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound which emits delayed fluorescence, and the fourth compound which includes an organometallic complex, and thus the light emitting element ED may exhibit excellent luminous efficiency characteristics.

In an embodiment, the fourth compound represented by Formula S-1 may be selected from Compound Group 4. In an embodiment, in the light emitting element ED, the fourth compound may include at least one compound selected from Compound Group 4.

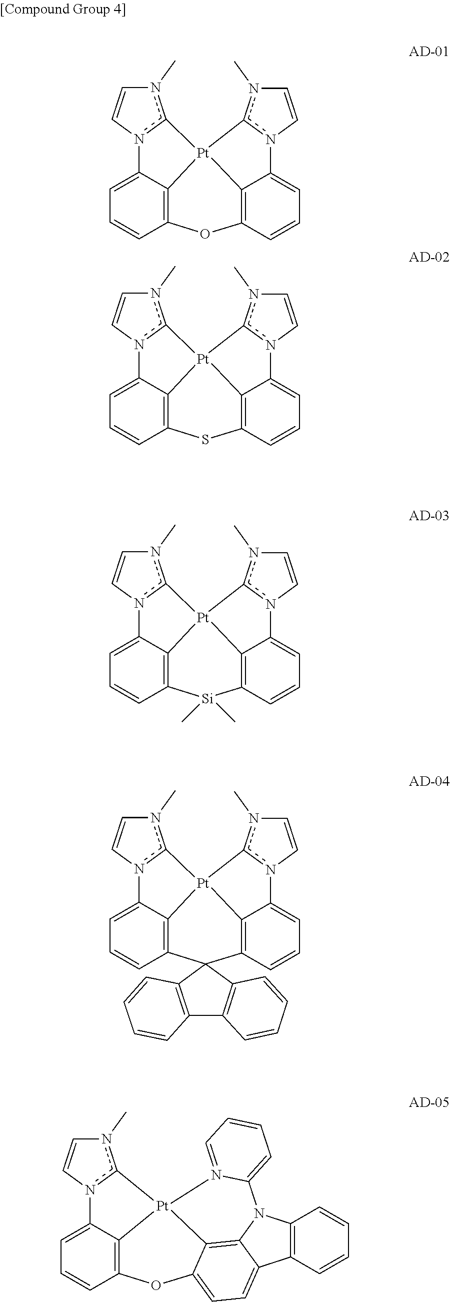

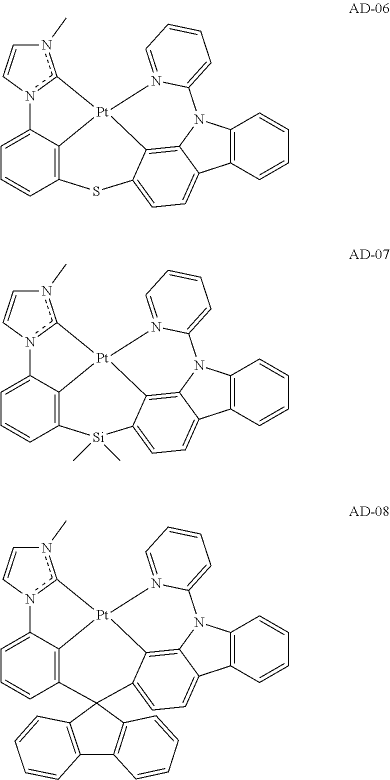

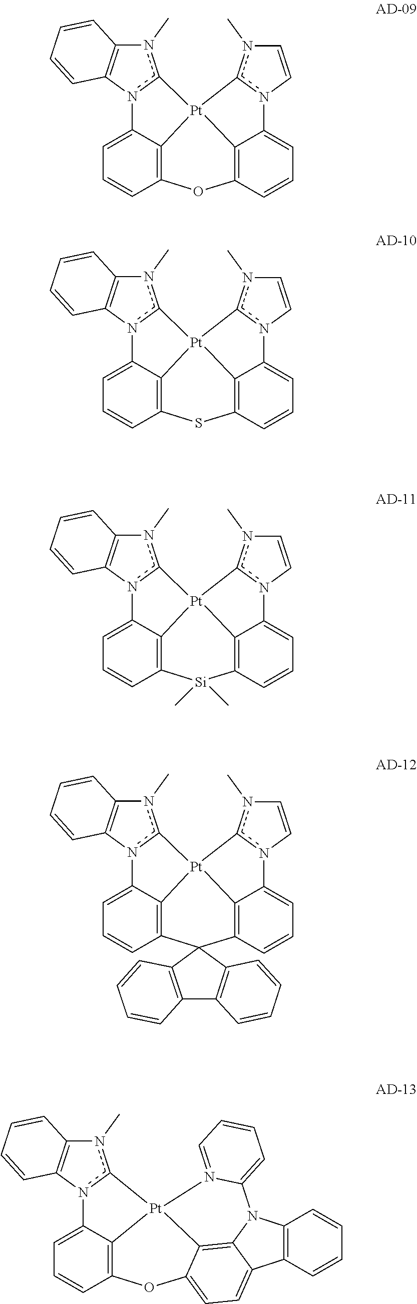

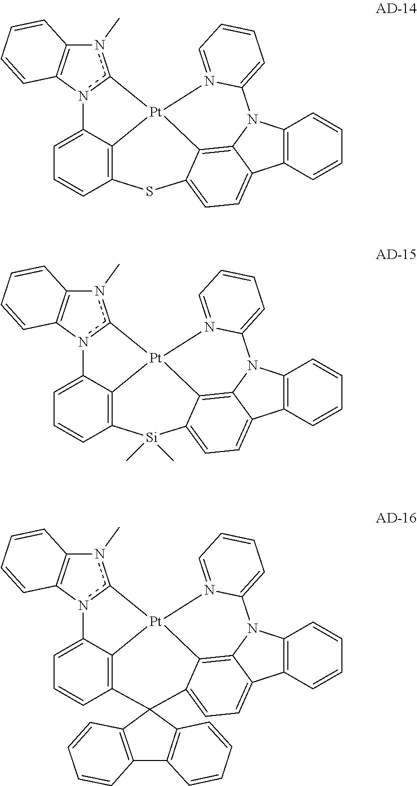

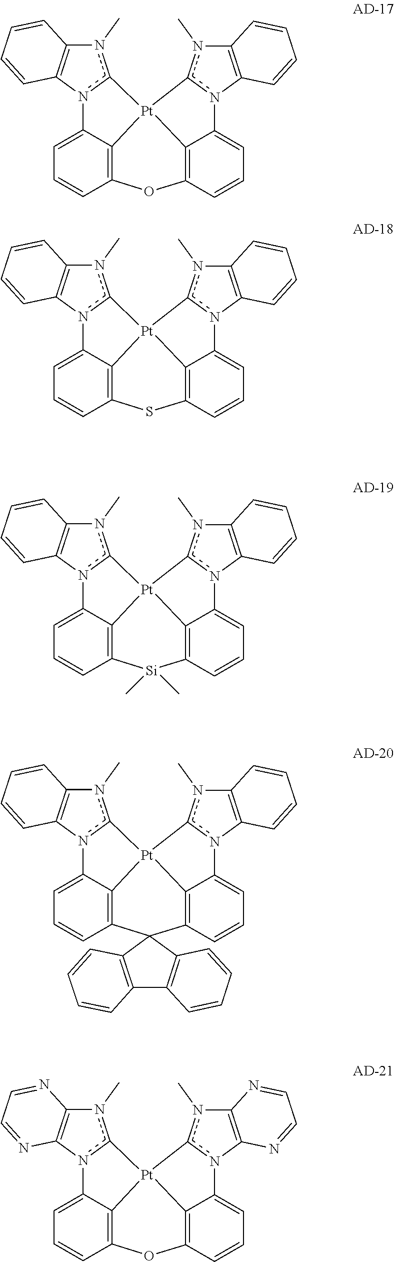

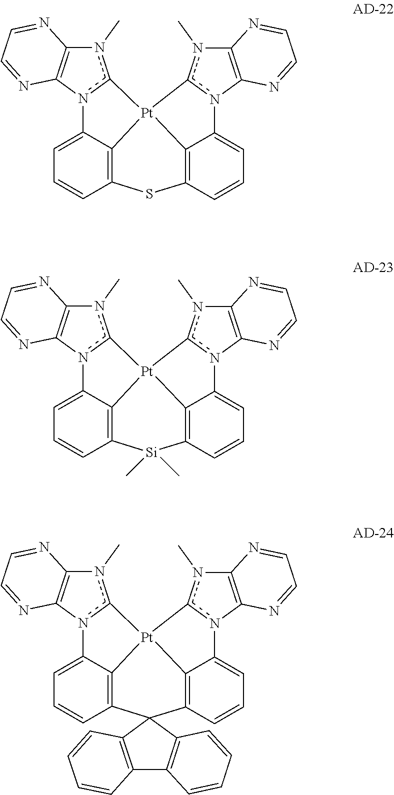

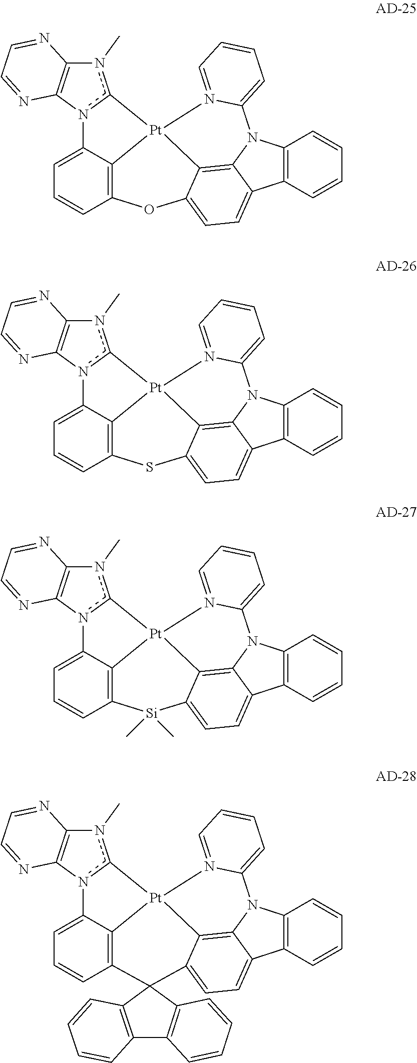

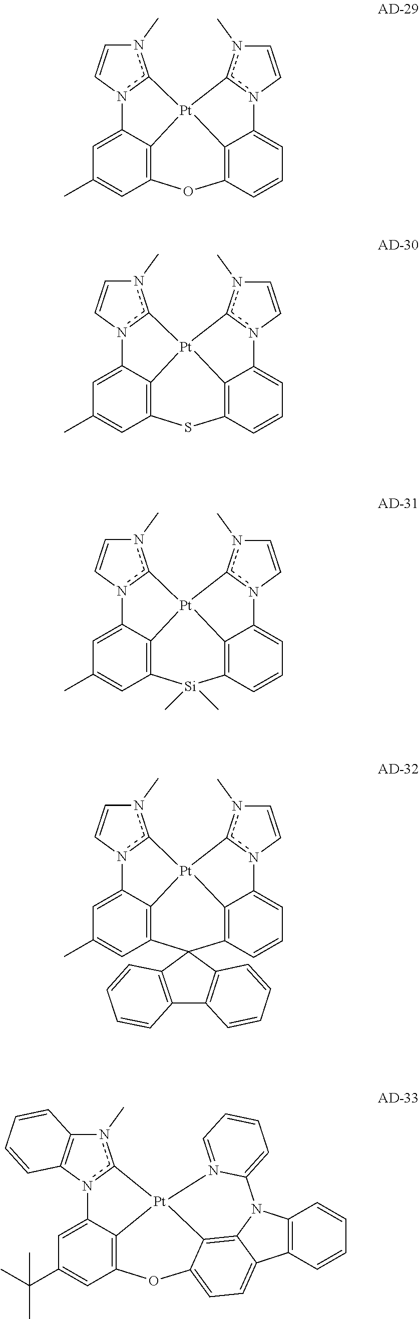

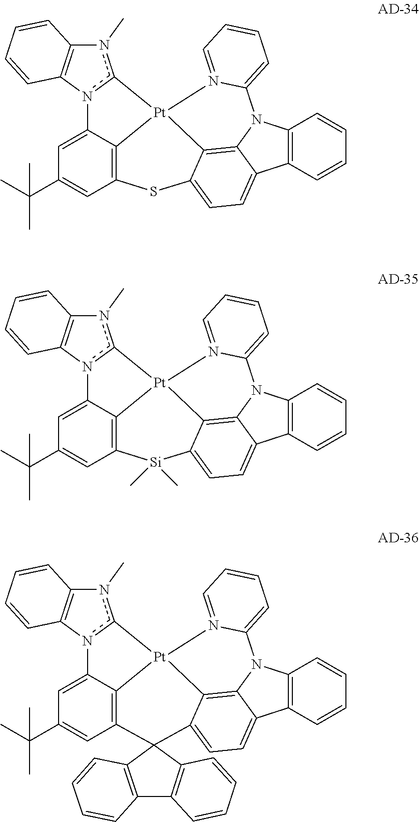

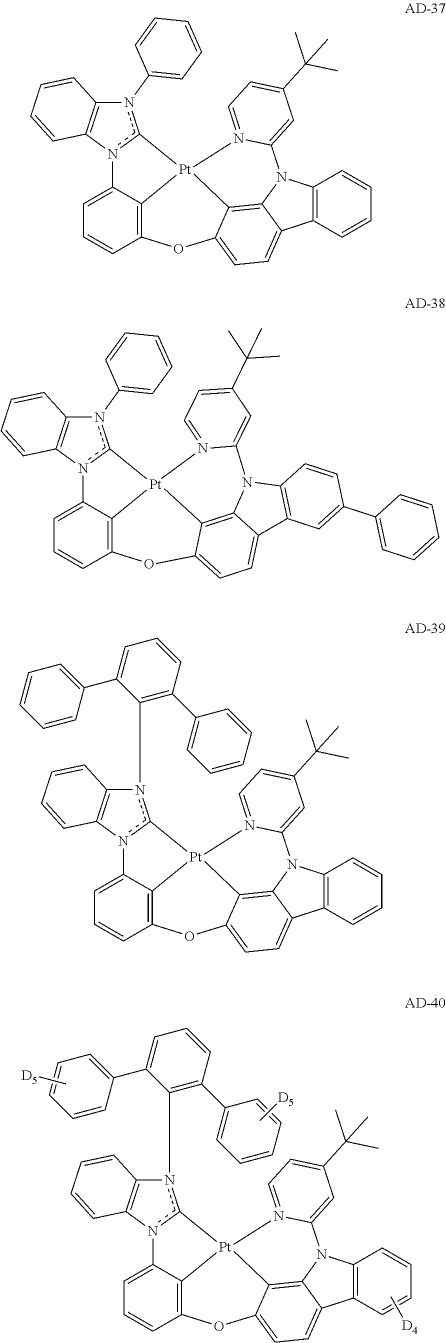

In Compound Group 4, D represents a deuterium atom.

In an embodiment, the light emitting element ED may include multiple emission layers. The multiple emission layers may be provided as a stack of emission layer, so that the light emitting element ED including the multiple emission layers may emit white light. The light emitting element ED including the multiple emission layers may be a light emitting element of a tandem structure. If the light emitting element ED includes multiple emission layers, at least one emission layer EML may include the first compound represented by Formula 1. In an embodiment, if the light emitting element ED includes multiple emission layers, at least one emission layer EML may include the first compound, the second compound, the third compound and the fourth compound as described above.

When the emission layer EML in the light emitting element ED includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the above-described range, the energy transfer from the second compound and the third compound to the first compound may increase, and thus the luminous efficiency and device service life may increase.

The combined amounts of the second compound and the third compound in the emission layer EML may be the remainder of the total weight of the first compound, the second compound, and the third compound, excluding the amount of the first compound. For example, a total amount of the second compound and the third compound in the emission layer EML may be in a range of about 65 wt % to about 95 wt % with respect to a total weight of the first compound, the second compound, and the third compound.

Within the total amount of the second compound and the third compound in the emission layer EML, a weight ratio of the second compound to the third compound may be in a range of about 3:7 to about 7:3.

When the amounts of the second compound and the third compound satisfy the above-described ranges and ratios, a charge balance characteristic in the emission layer EML may be improved, and thus the luminous efficiency and device service life may increase. When the amounts of the second compound and the third compound deviate from the above-described arranges and ratios, charge balance in the emission layer EML may not be achieved, and thus the luminous efficiency may be reduced and the device may readily deteriorate.

When the emission layer EML includes the fourth compound, an amount of the fourth compound in the emission layer EML may be in a range of about 4 wt % to about 30 wt % with respect to a total weight of the first compound, the second compound, the third compound, and the fourth compound. However, embodiments are not limited thereto. When an amount of the fourth compound satisfies the above-described ranges, energy transfer from the host to the first compound, which is a light emitting dopant, may increase, so that a luminous ratio may be improved, and thus, luminous efficiency of the emission layer EML may be improved. When the amounts of first compound, the second compound, the third compound, and the fourth compound included in the emission layer EML satisfy the above-described ranges and ratios, excellent luminous efficiency and long service life may be achieved.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in each of FIGS. 3 to 6, the emission layer EML may further include a host and a dopant of the related art, in addition to the above-described host and dopant.

In an embodiment, the emission layer EML may include a compound represented by Formula E-1. The compound represented by Formula E-1 may be used as a fluorescent host material.

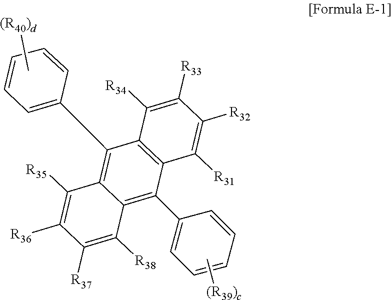

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

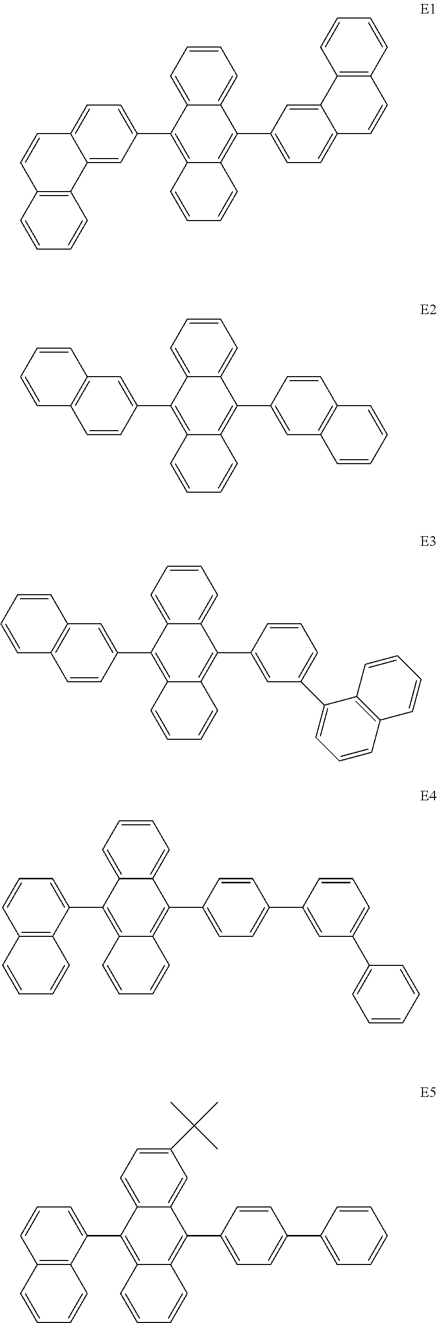

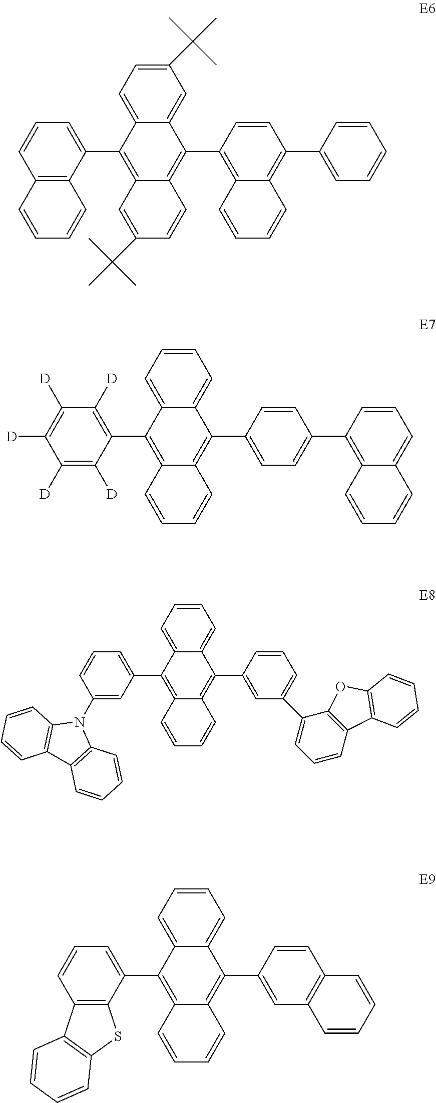

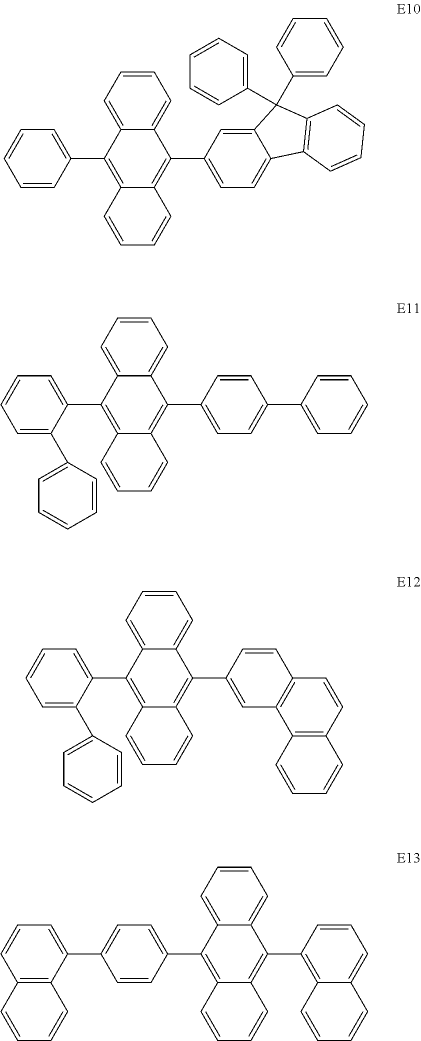

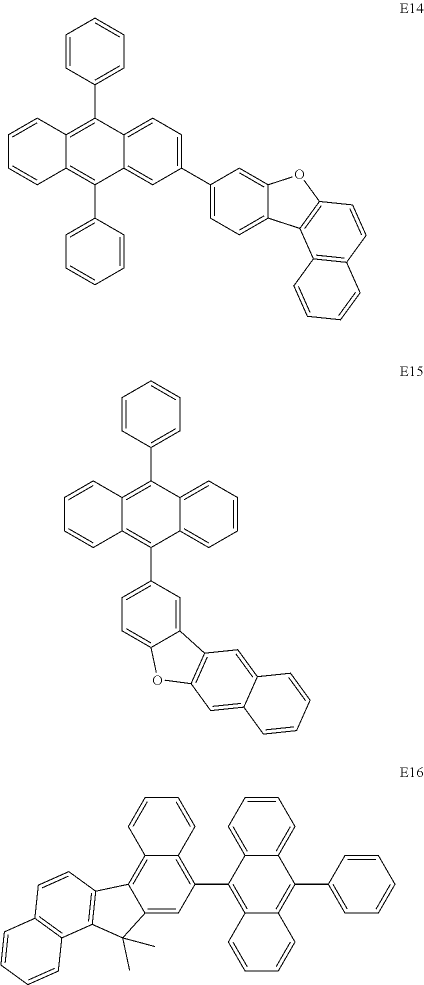

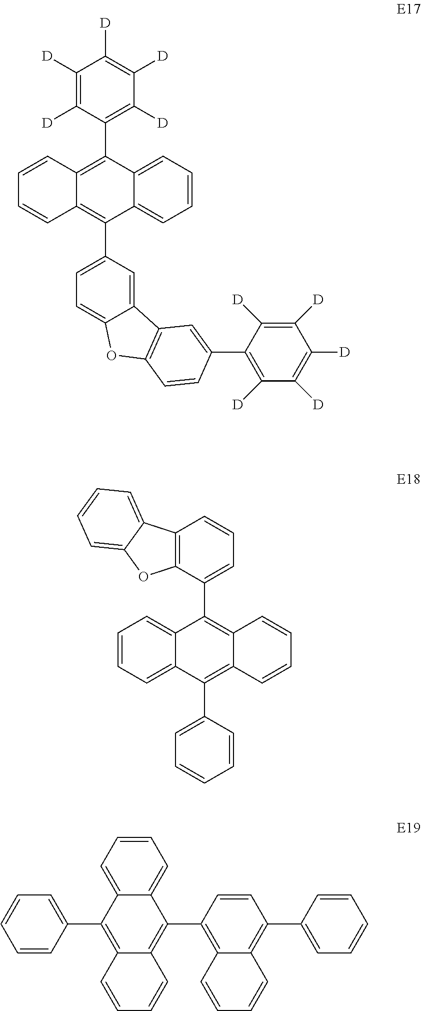

In an embodiment, the emission layer EML may include a compound represented by Formula E-2a or Formula E-2b. The compound represented by Formula E-2a or Formula E-2b may be used as a phosphorescent host material.

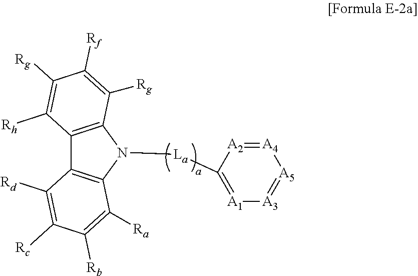

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is equal to or greater than 2, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle including N, O, S, etc., as a ring-forming atom.

In Formula E-2a, two or three of A₁ to A₅ may each be N, and the remainder of A₁ to A₅ may each independently be C(Rᵢ).

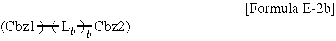

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In formula E-2b, b may be an integer from 0 to 10; and when b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

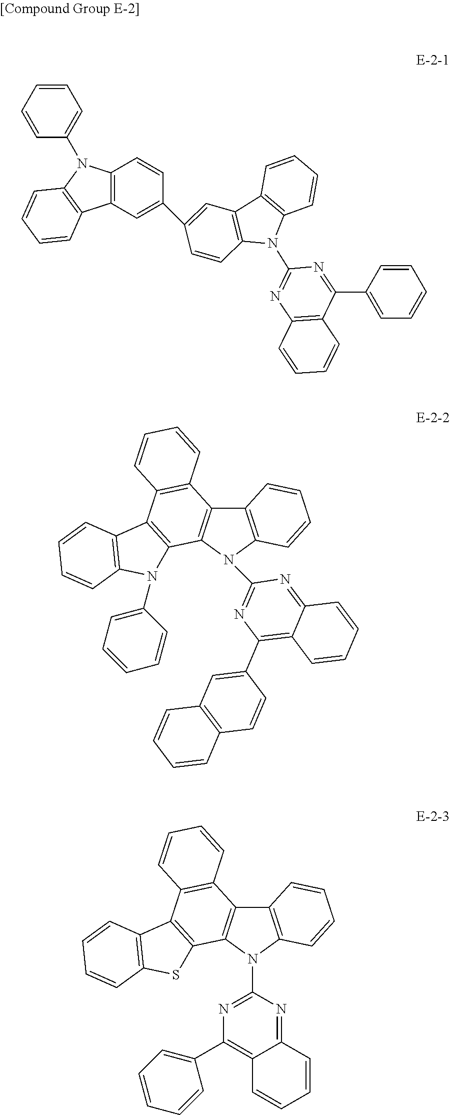 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

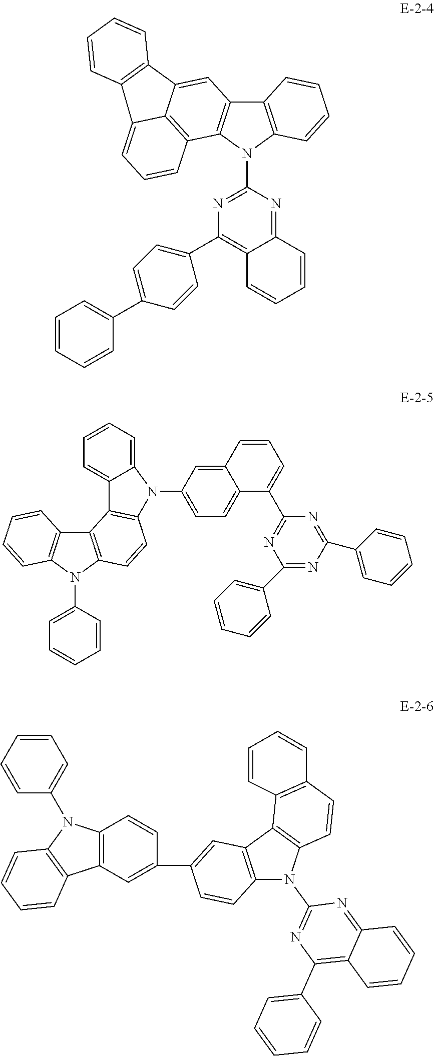 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

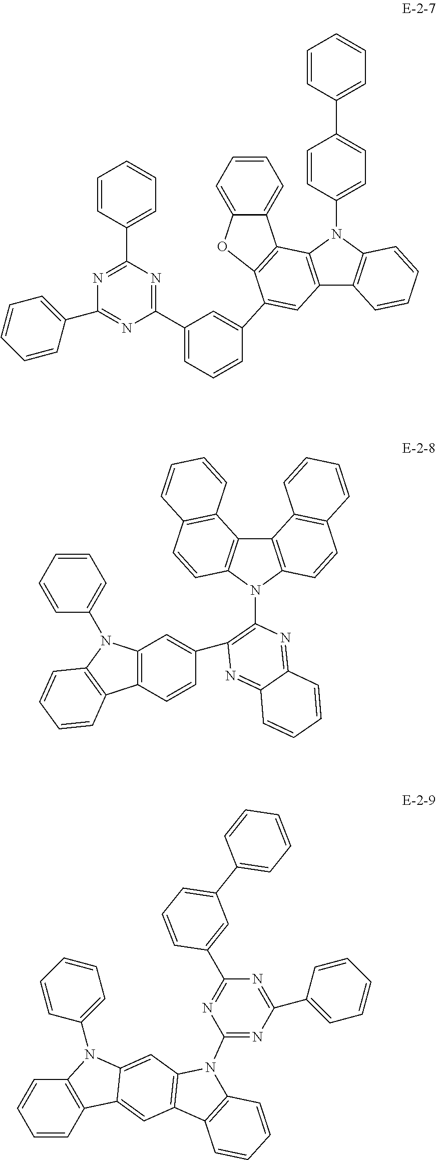 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

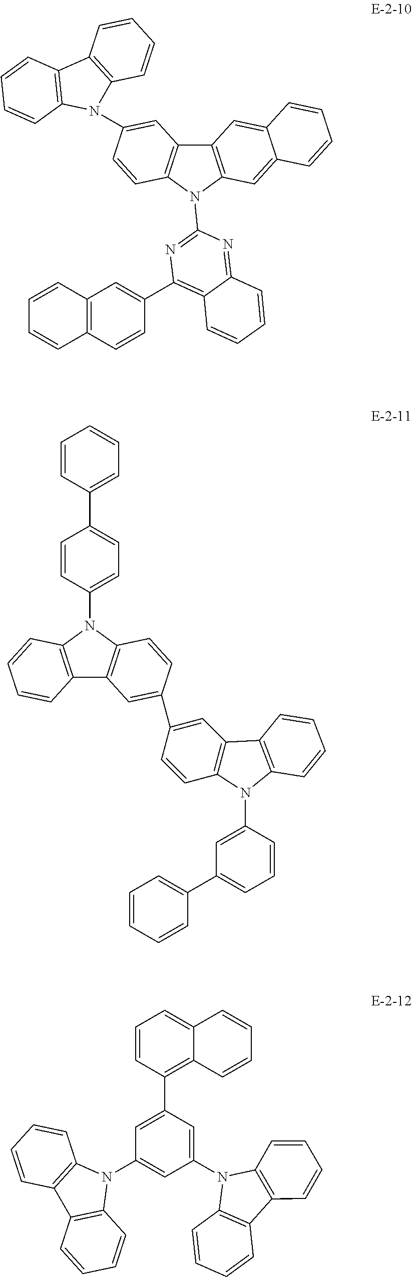 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

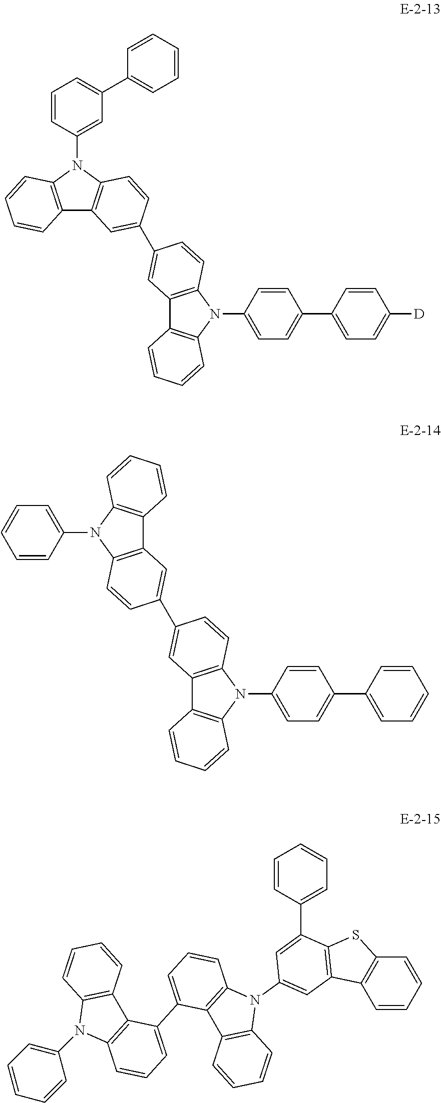 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

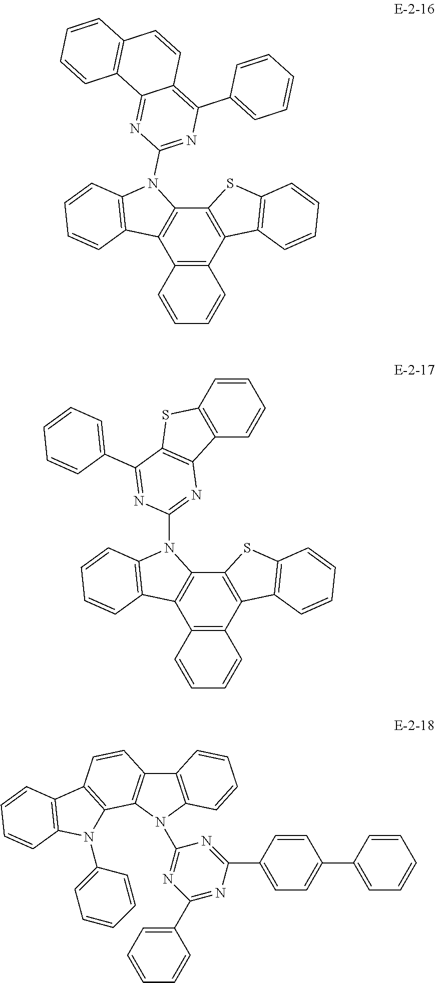 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

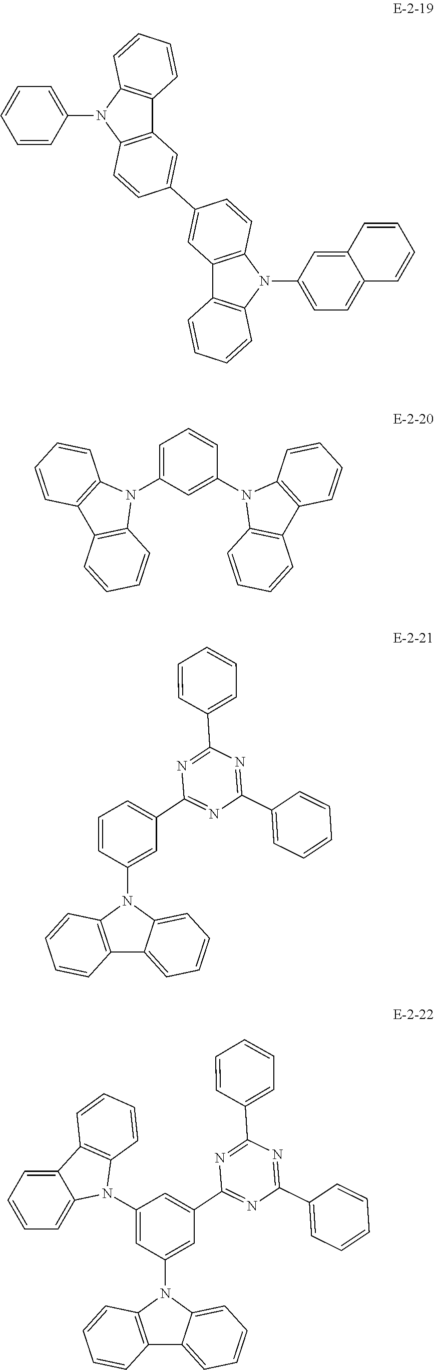 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

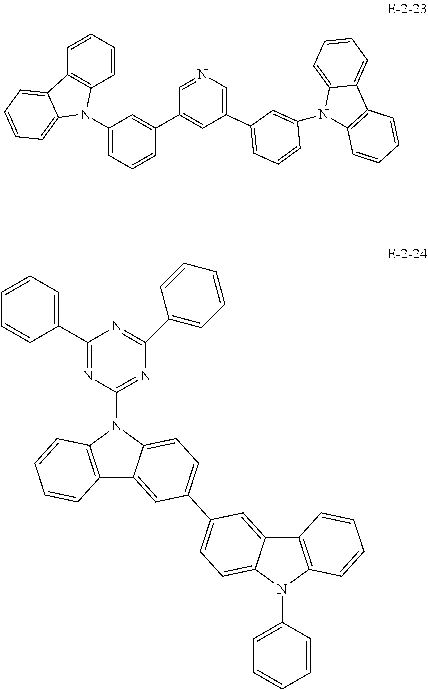 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a may be used as a phosphorescent dopant material.

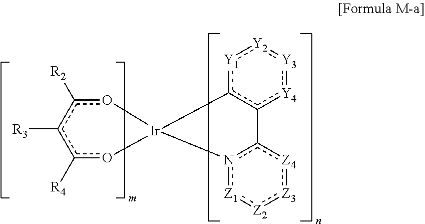

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

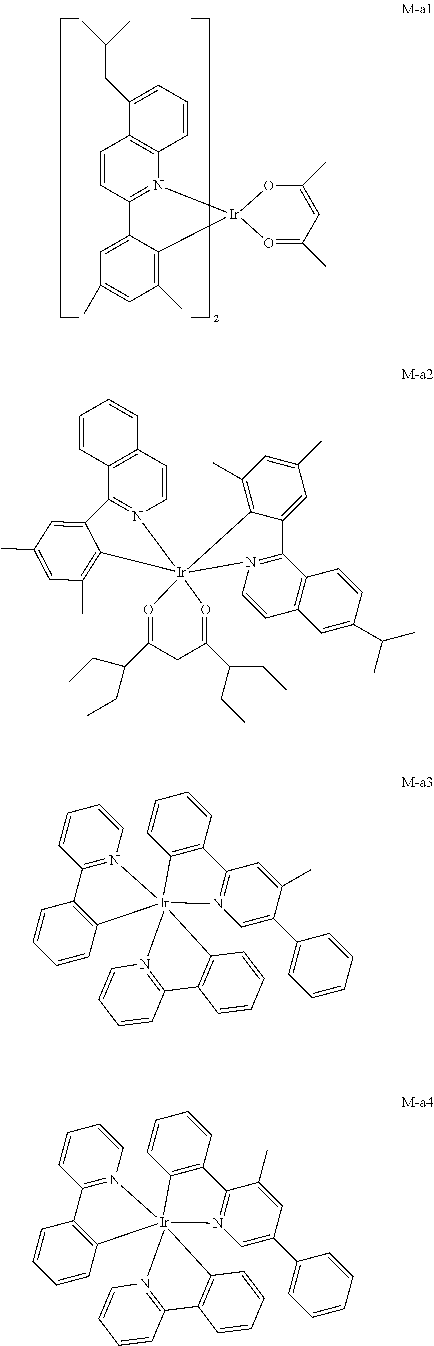

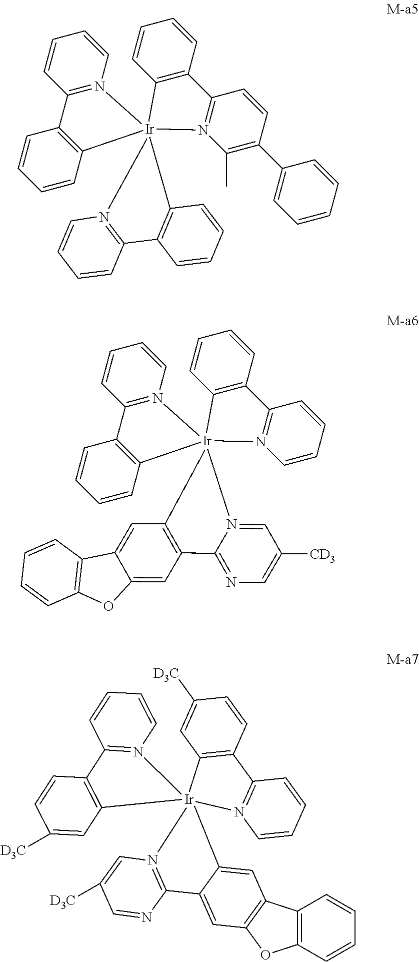

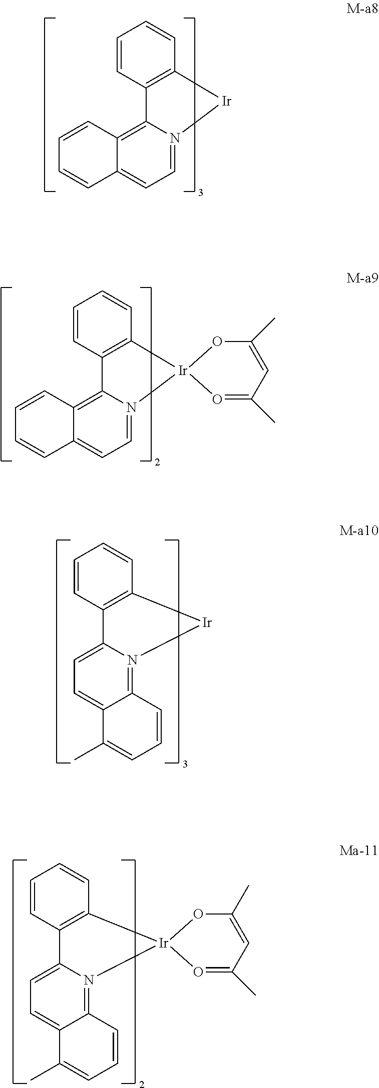

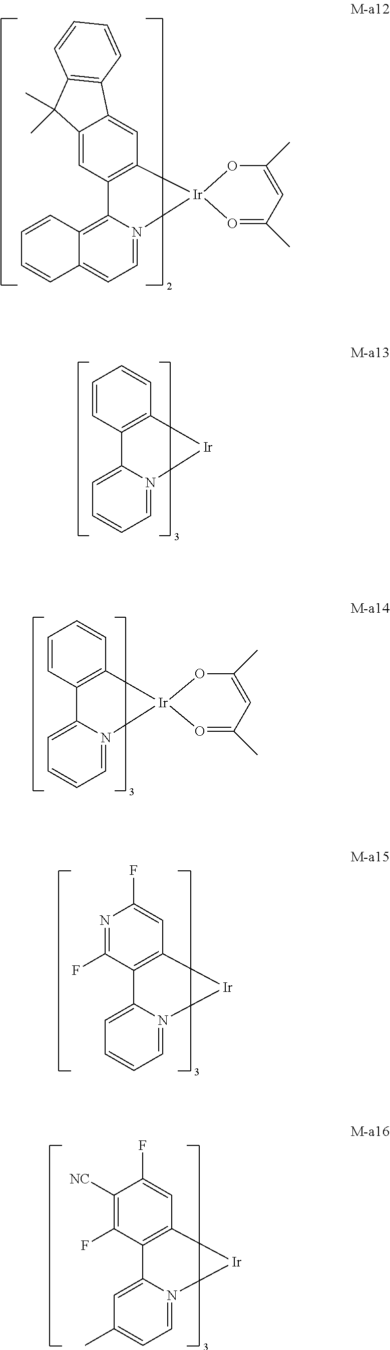

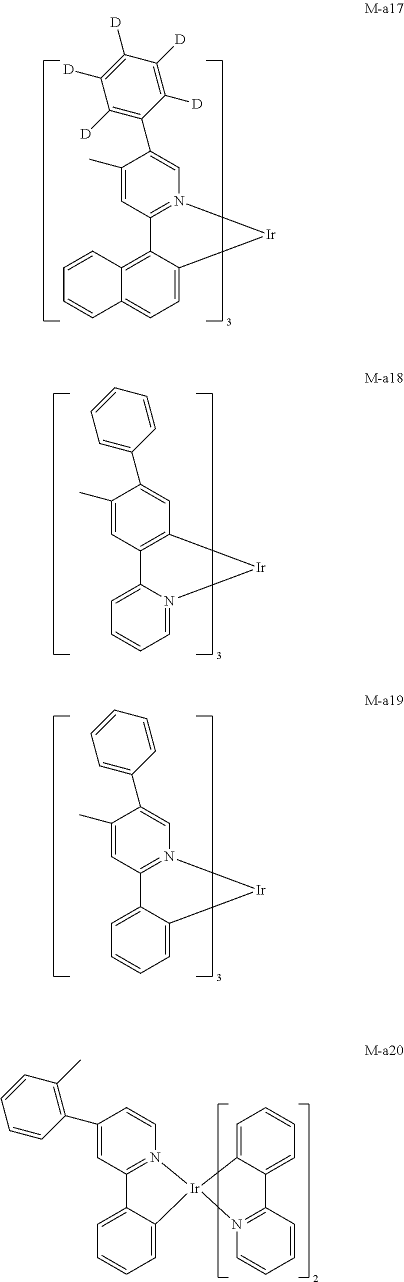

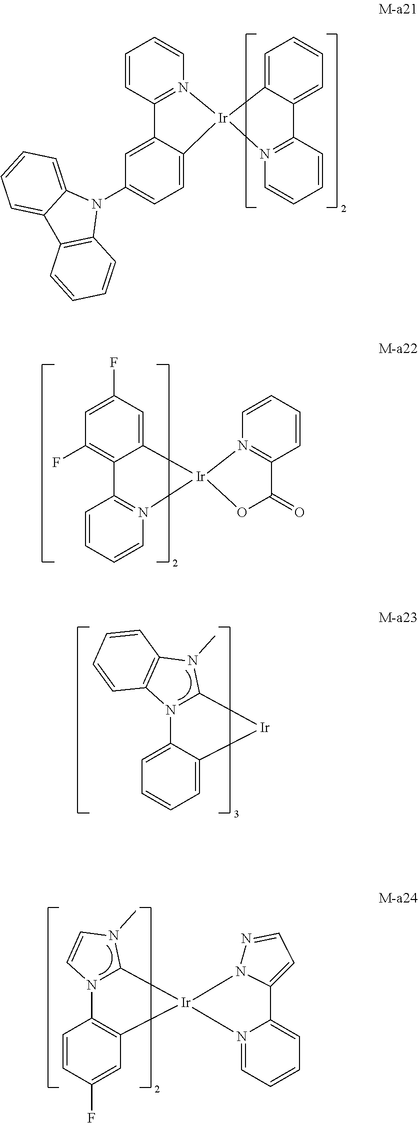

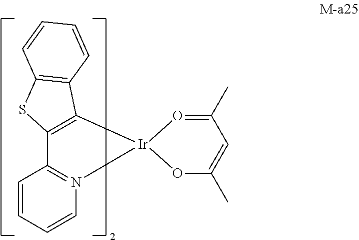

In an embodiment, the emission layer EML may include a compound represented by one of Formula F-a to Formula F-c. The compound represented by one of Formula F-a to Formula F-c may be used as a fluorescence dopant material.

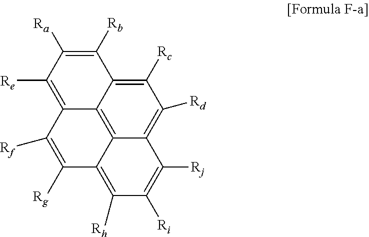

In Formula F-a, two of Rₐ to Rⱼ may each independently be substituted with a group represented by *-NAr₁Ar₂. The remainder of Rₐ to Rⱼ which are not substituted with the group represented by *-NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *-NAr₁Ar₂, Ar and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may be a heteroaryl group including O or S as a ring-forming atom.

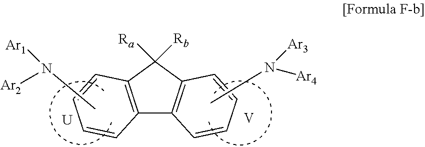

In Formula F-b, Rₐ and Rb may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may be a heteroaryl group including O or S as a ring-forming atom.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion indicated by U or V, and when the number of U or V is 0, a fused ring may be present at the portion indicated by U or V. When the number of U is 0 and the number of V is 1, or when the number of U is 1 and the number of V is 0, the fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

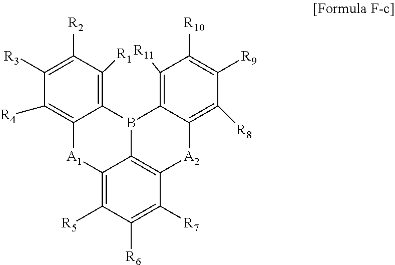

In Formula F-c, A₁ and A₂ may each independently be O, S, Se, or N(Rₘ), and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may further include, as a known dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex including iridium (Ir), platinum (Pt), osmium (Os), gold (Au), titanium (T1), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (FIr6), or platinum octaethyl porphyrin (PtOEP) may be used as a phosphorescent dopant. However, embodiments are not limited thereto.

In an embodiment, the emission layer EML may include a quantum dot. The quantum dot may be a crystal of a semiconductor compound. The quantum dot may emit light of various emission wavelengths, according to a size of the crystal. The quantum dot may emit light of various emission wavelengths by adjusting an elemental ratio in a quantum dot compound.

A diameter of the quantum dot may be in a range of about 1 nm to about 10 nm.

The quantum dot may be synthesized by a chemical bath deposition, a metal organic chemical vapor deposition, a molecular beam epitaxy, or a similar process therewith. The chemical bath deposition is a method of mixing an organic solvent and a precursor material and growing quantum dot particle crystals. While growing the crystals, the organic solvent may serve as a dispersant that is coordinated onto a surface of a quantum dot crystal, and the organic solvent may control the growth of the crystals. Accordingly, chemical bath deposition may be more advantageous when compared to a metal organic chemical vapor deposition (MOCVD) process or a molecular beam epitaxy (MBE) process, and the growth of quantum dot particles may be controlled through a low-cost process.

In an embodiment, the emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS; a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a mixture thereof; or any combination thereof.

Examples of a Group II-VI semiconductor compound may further include metals in Group I and/or elements in Group IV. Examples of a Group I-II-VI compound may include CuSnS or CuZnS. Examples of a Group II-IV-VI compound may include ZnSnS or the like. Examples of a Group I-II-IV-VI compound may include quaternary compounds selected from the group consisting of Cu₂ZnSnS₂, Cu₂ZnSnS₄, Cu₂ZnSnSe₄, Ag₂ZnSnS₂ and mixtures thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; or a quaternary compound such as AgInGaS₂ or CuInGaS₂; or any combination thereof

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; or any combination thereof. In an embodiment, a Group III-V compound may further include a Group II metal. For example, InZnP, etc., may be selected as a Group III—II-V compound.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; a quaternary compound selected from the group consisting of SnPbSSe, SnPbSeTe, SnPbSTe, and a mixture thereof; or any combination thereof. Examples of a Group IV element may include Si, Ge, and a mixture thereof. Examples of a Group IV compound may include a binary compound selected from the group consisting of SiC, SiGe, and a mixture thereof.

Each element included in a polynary compound such as a binary compound, a ternary compound, or a quaternary compound may be present in a particle at a uniform or a non-uniform concentration distribution. For example, a formula may indicate the elements included in a compound, and an elemental ratio in the compound may vary. For example, AgInGaS₂ may mean AgInₓGa₁₋ₓS₂ (wherein 0<x<1).

In an embodiment, a quantum dot may have a single structure, in which the concentration of each element included in the quantum dot is uniform, or a quantum dot may have a core-shell structure in which a quantum dot surrounds another quantum dot. For example, a material included in the core may be different from a material included in the shell.

The shell of the quantum dot may serve as a protection layer to prevent the chemical deformation of the core to maintain semiconductor properties, and/or may serve as a charging layer to impart electrophoresis properties to the quantum dot. The shell may be a single layer or multiple layers. An interface between the core and the shell may have a concentration gradient in which the concentration of an element that is present in the shell decreases towards the core.

In embodiments, the quantum dot may have the above-described core/shell structure including a core including nanocrystals and a shell surrounding the core. Examples of a shell of a quantum dot may include a metal oxide, non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplate particles, etc.

As a size of the quantum dot is adjusted or an elemental ratio of a quantum dot compound is adjusted, it is possible to control the energy band gap, and thus light in various wavelength ranges may be obtained from a quantum dot emission layer. Therefore, a quantum dot as described above (using different sizes of quantum dots or different elemental ratios in a quantum dot compound) may be implemented, so that a light emitting element may emit light in various wavelengths. A size of a quantum dot or an elemental ratio of a quantum dot compound may each independently be adjusted to emit red light, green light, and/or blue light. For example, the quantum dots may be configured to emit white light by combining various colors of light.

In the light emitting elements ED according to an embodiment as shown in each of FIGS. 3 to 6, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

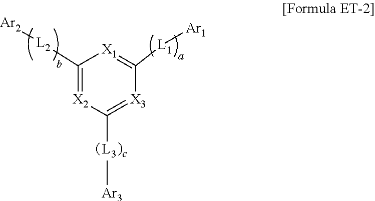

In Formula ET-2, at least one of X₁ to X₃ may each be N, and the remainder of X1 to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

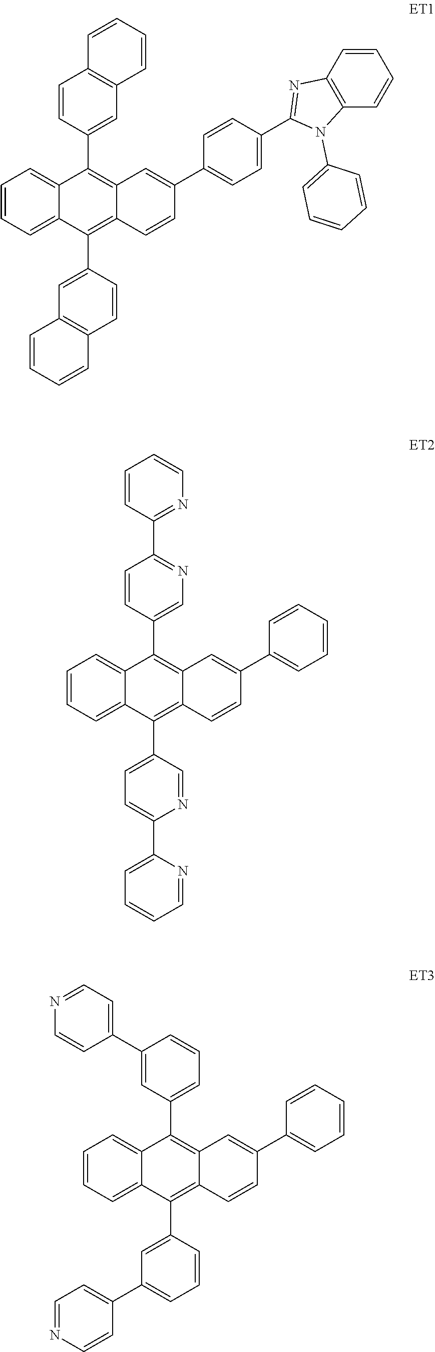 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

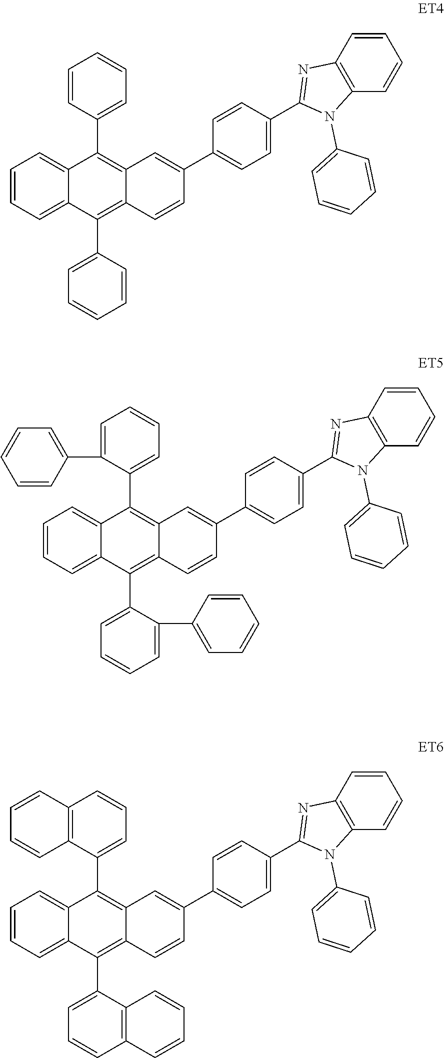 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

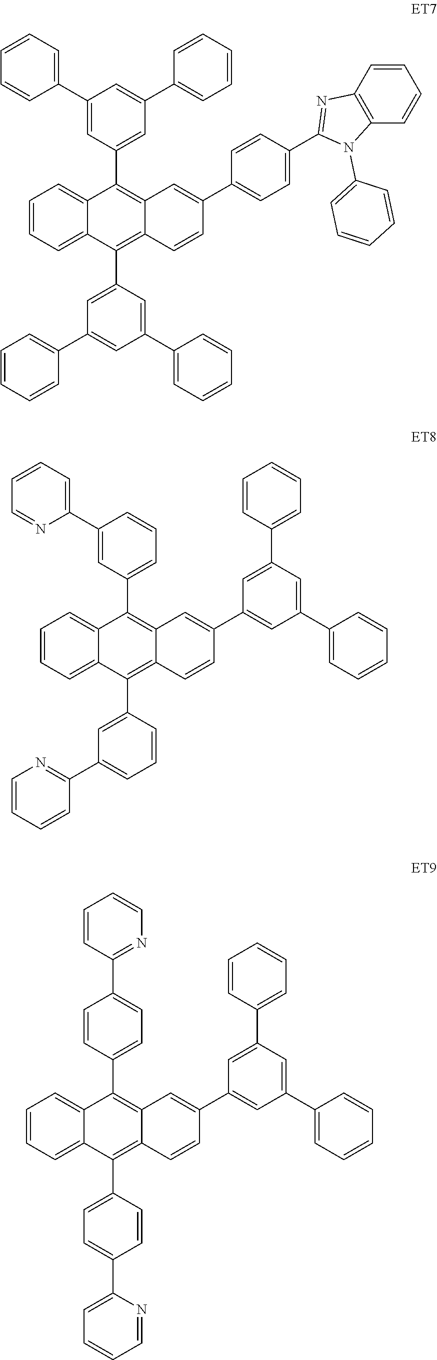 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

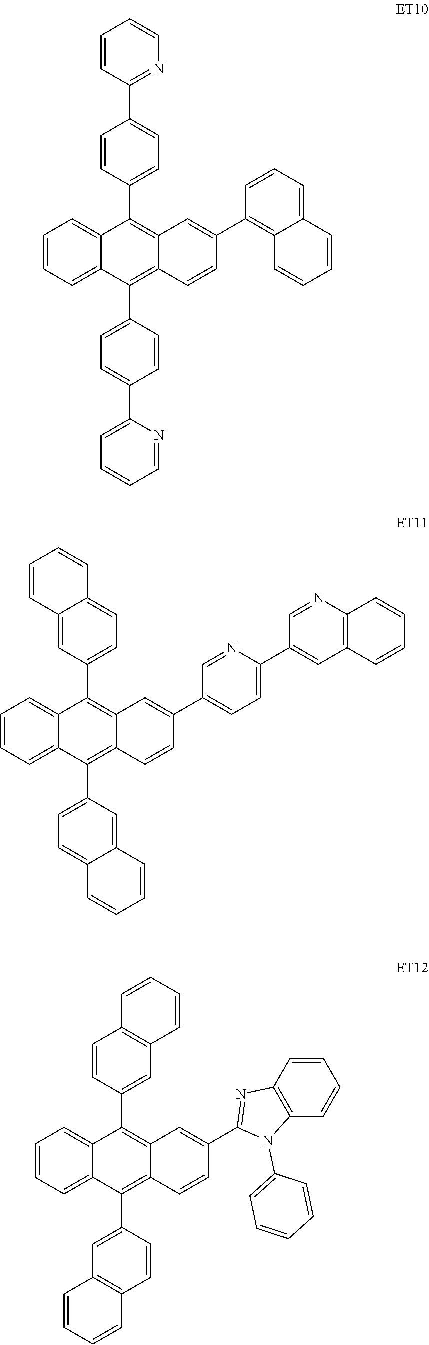 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

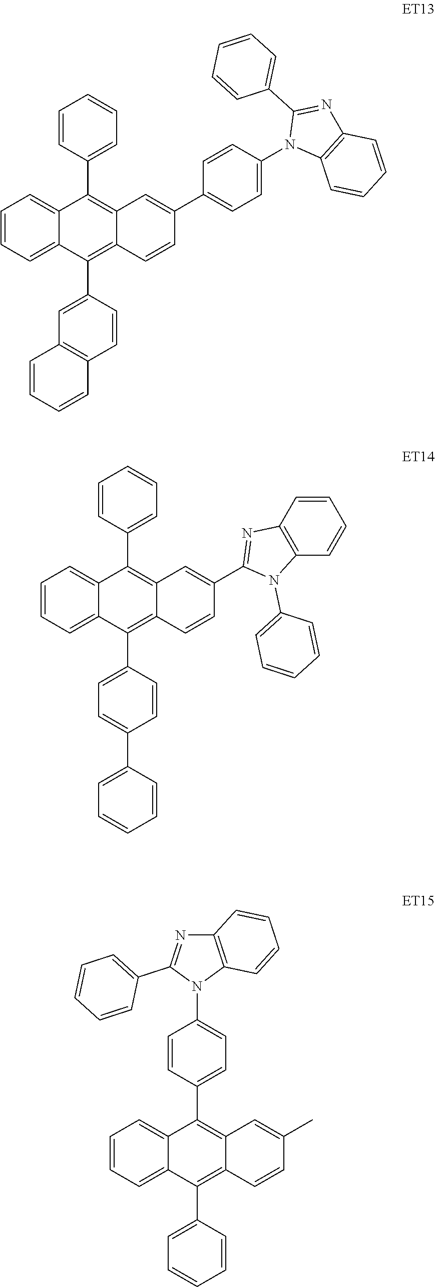 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

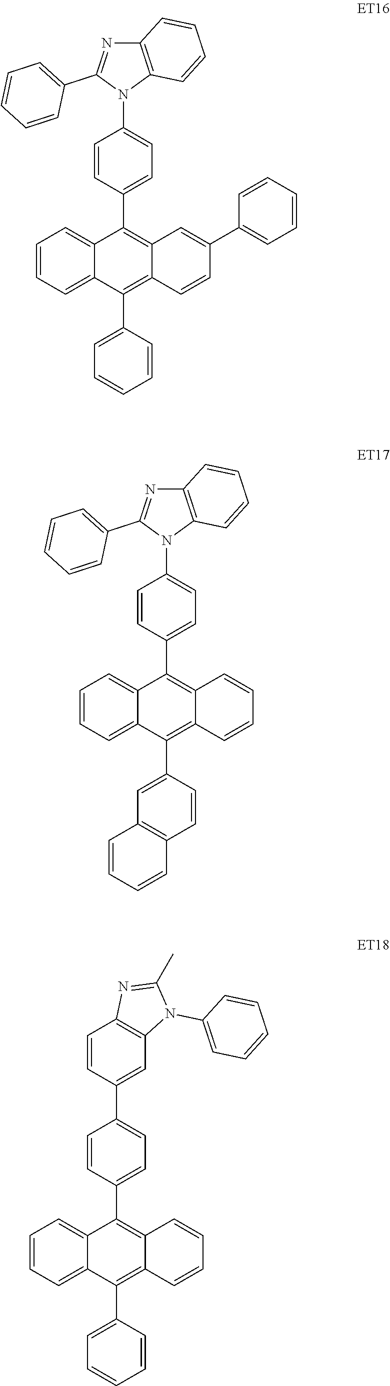 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

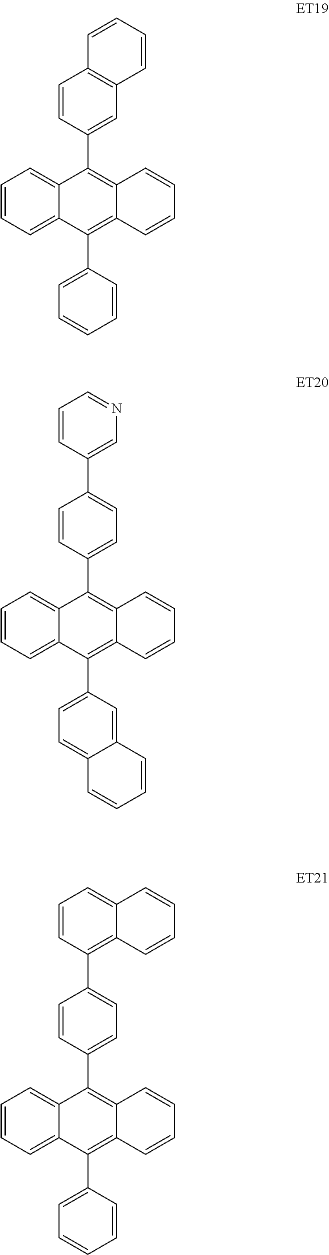

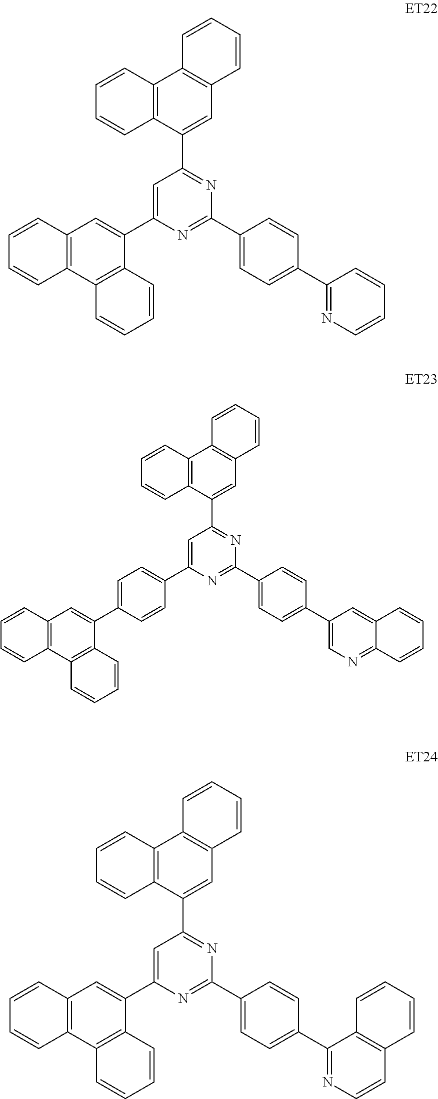 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

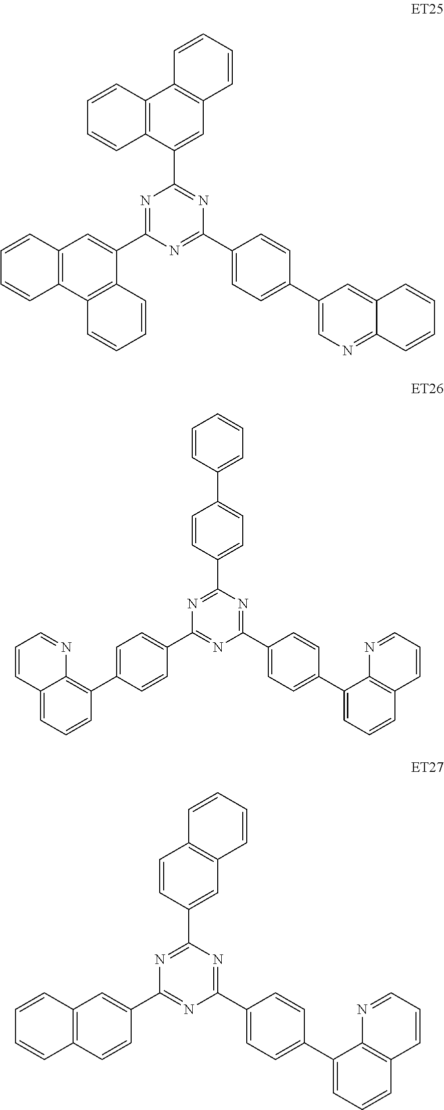 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

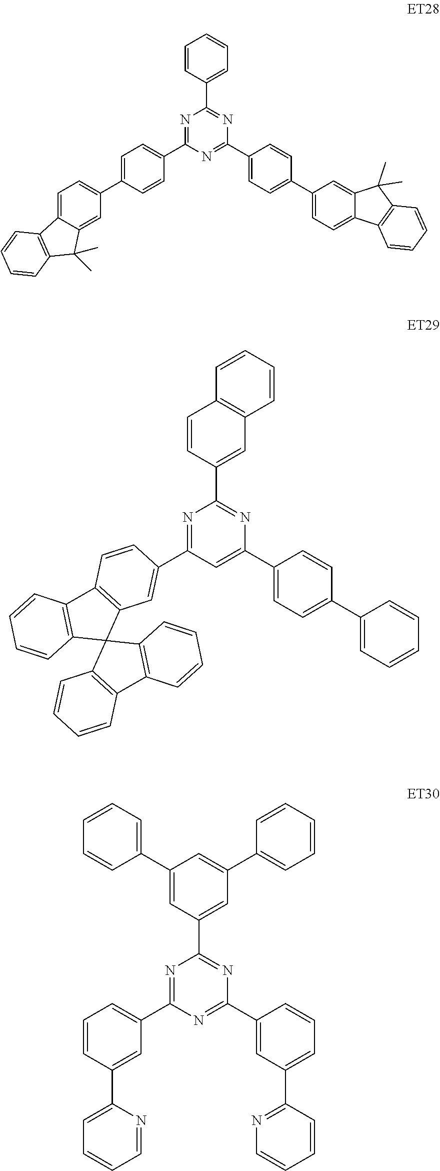 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

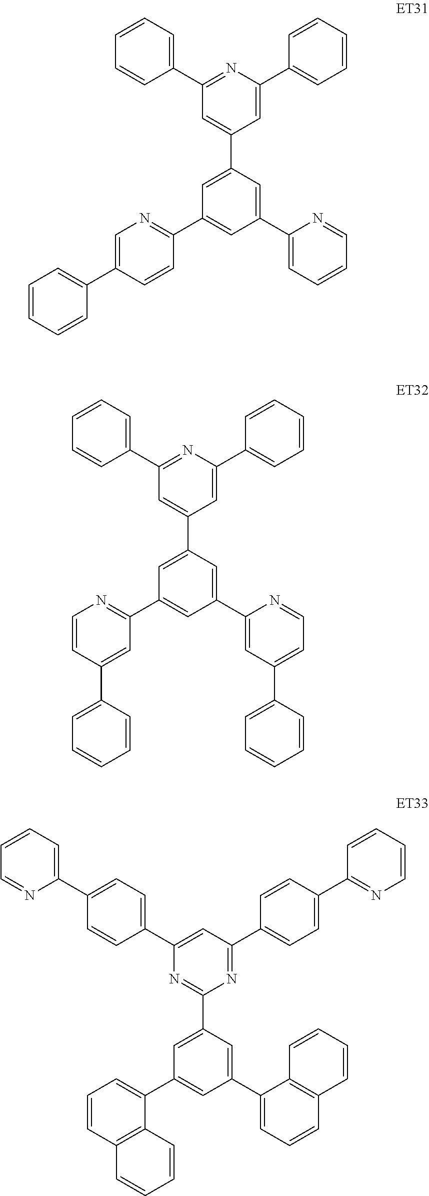 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

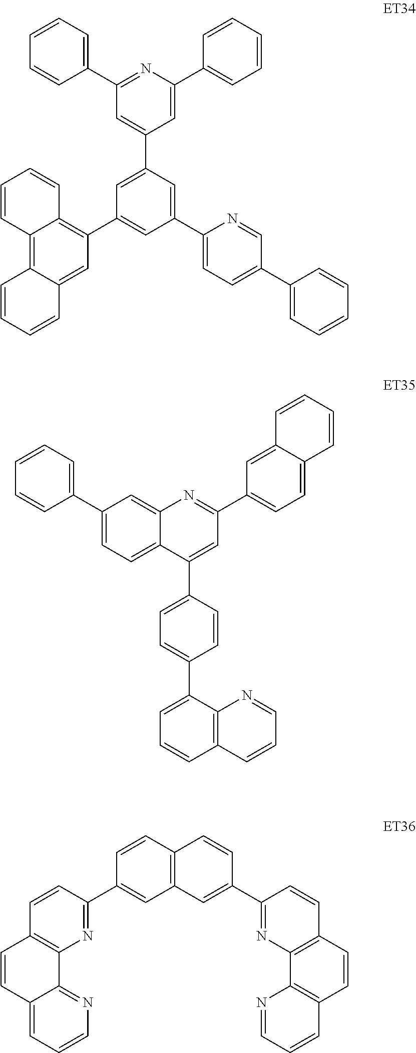 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include a metal halide such as LiF, NaCl, CsF, RbCl, RbI, CuI, and KI; a lanthanide metal such as Yb; or a co-deposited material of a metal halide and a lanthanide metal. For example, the electron transport region ETR may include KJ:Yb, RbJ:Yb, LiF:Yb, etc., as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The insulating organometallic salt may be a material having an energy band gap equal to or greater than about 4 eV. For example, the insulating organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the electron transport region ETR in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL may further be disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may be an epoxy resin, or an acrylate such as methacrylate. However, embodiments are not limited thereto. In an embodiment, the capping layer CPL may include at least one of Compounds P1 to P5:

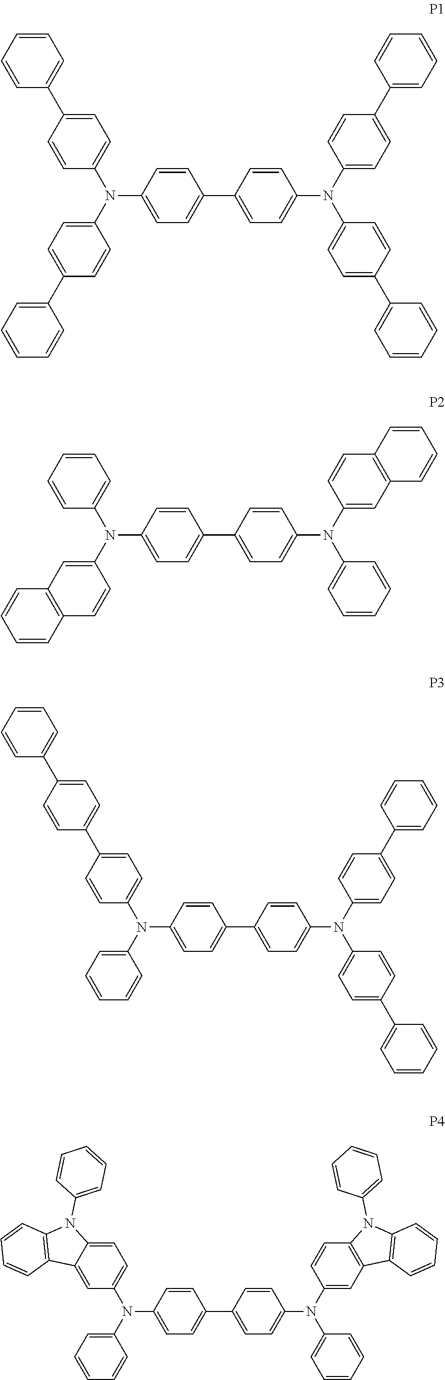 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

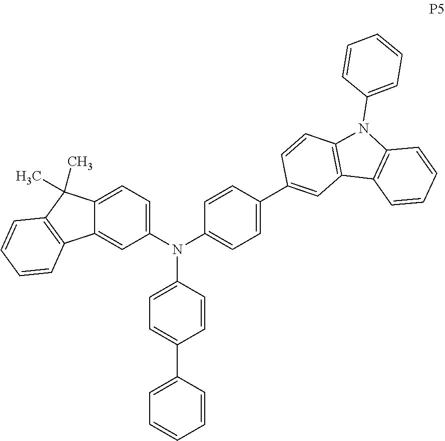 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be equal to or greater than about 1.6. For example, the refractive index of the capping layer CPL may be equal to or greater than about 1.6 with respect to light in a wavelength range of about 550 nm to about 660 nm.

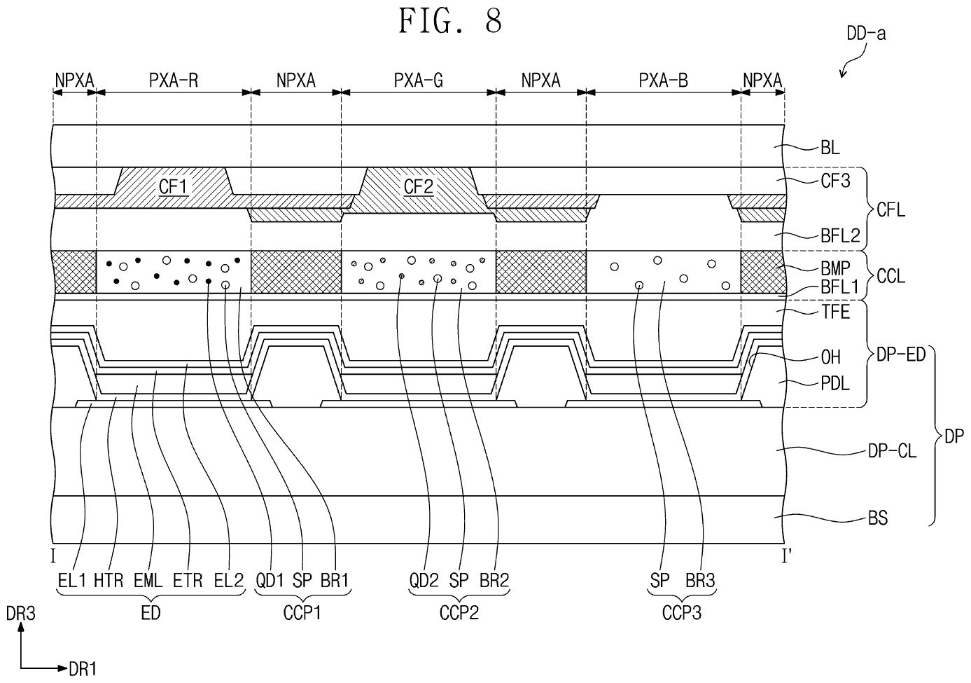

FIGS. 8 to 11 are each a cross-sectional view of a display device according to an embodiment. In the descriptions of the display devices according to embodiments as shown in FIGS. 8 to 11, the features which have been described above with respect to FIGS. 1 to 7c will not be explained again, and the differing features will be described.

Referring to FIG. 8, the display device DD-a according to an embodiment may include a display panel DP including a display device layer DP-ED, a light control layer CCL disposed on the display panel DP, and a color filter layer CFL.

In an embodiment shown in FIG. 8, the display panel DP may include a base layer BS, a circuit layer DP-CL provided on the base layer BS, and the display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 8 may be the same as a structure of a light emitting element according to one of FIGS. 3 to 6 as described above.

In the display device DD-a according to an embodiment, the emission layer EML of the light emitting element ED included may include the polycyclic compound.

Referring to FIG. 8, the emission layer EML may be disposed in an opening OH defined in a pixel defining film PDL. For example, the emission layer EML which is separated by the pixel defining film PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 8, divided patterns BMP may be disposed between the light control parts CCP1, CCP2, and CCP3 which are spaced apart from each other, but embodiments are not limited thereto. In FIG. 8, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light which is the second color light, and the second light control part CCP2 may provide green light, which is the third color light. The third light control part CCP3 may provide blue light by transmitting the blue light which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include a quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2 and CCP3 exposure exposed to moisture/oxygen. The barrier layer BFL1 may cover the light control parts CCP1, CCP2, and CCP3. A barrier layer BFL2 may be provided between the light control parts CCP1, CCP2, and CCP3 and filters CF1, CF2, and CF3.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently include an organic film. The barrier layers BFL1 and BFL2 may each be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not shown in the drawings, the color filter layer CFL may further include a light shielding part (not shown). The light shielding part (not shown) may be a black matrix. The light shielding part (not shown) may include an organic light shielding material or an inorganic light shielding material, each including a black pigment or dye. The light shielding part (not shown) may prevent light leakage, and may separate adjacent filters CF1, CF2, and CF3.

The first to third filters CF1, CF2, and CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

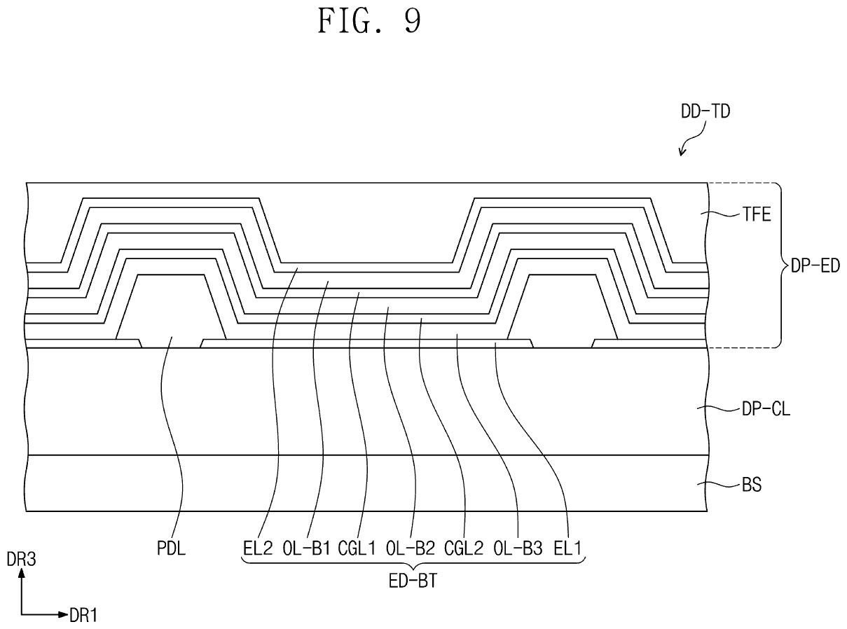

FIG. 9 is a schematic cross-sectional view of a portion of a display device according to an embodiment. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 8) and a hole transport region HTR (FIG. 8) and an electron transport region ETR (FIG. 8) disposed with the emission layer EML located therebetween.

For example, the light emitting element ED-BT included in the display device DD-TD may be a light emitting element having a tandem structure and including multiple emission layers EML.

In an embodiment illustrated in FIG. 9, light emitted from each of the light emitting structures OL-B1, OL-B2, and OL-B3 may be blue light. However, embodiments are not limited thereto, and the light emitted from each of the light emitting structures OL-B1, OL-B2, and OL-B3 may have wavelength ranges that are different from each other. For example, the light emitting element ED-BT that includes light emitting structures OL-B1, OL-B2, and OL-B3, which emit light having wavelength ranges that are different from each other may emit white light.

Charge generation layers CGL1 and CGL2 may each be disposed between adjacent light emitting structures among the light emitting structures OL-B1, OL-B2, and OL-B3. Charge generation layers CGL1 and CGL2 may each independently include a p-type charge generation layer and/or an n-type charge generation layer.

In at least one of the luminous structures OL-B1, OL-B2, and OL-B3 included in the display device DD-TD according to an embodiment, the polycyclic compound may be included. For example, at least one of multiple emission layers included in the light emitting element ED-BT may include the polycyclic compound.

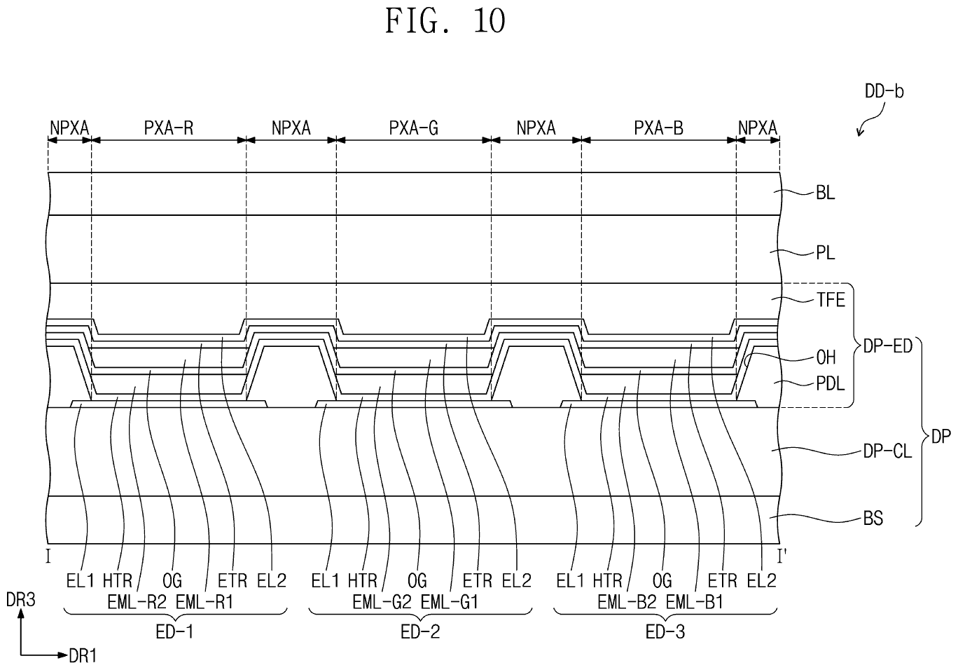

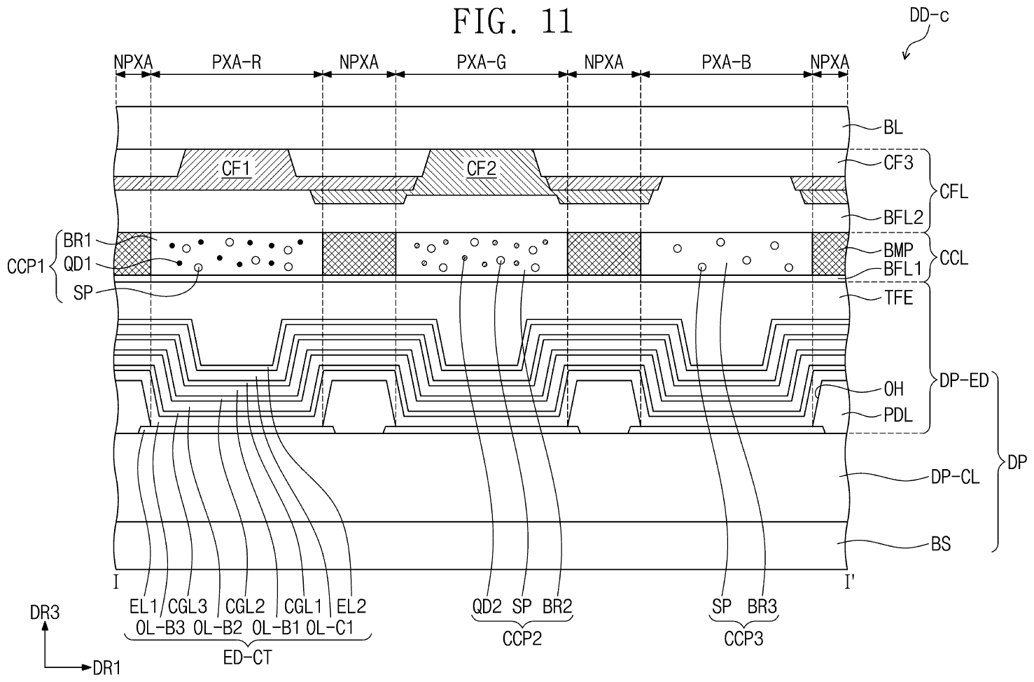

FIG. 10 is a schematic cross-sectional view of a display device according to an embodiment. FIG. 11 is a schematic cross-sectional view of a display device according to an embodiment.

Referring to FIG. 10, the display device DD-b according to an embodiment may include light emitting elements ED-1, ED-2, and ED-3 in which two emission layers are stacked. In comparison to the display device DD shown in FIG. 2, the embodiment shown in FIG. 10 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R₂. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R₂, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be provided by being patterned in the openings OH defined in the pixel defining film PDL.

The first red emission layer EML-R1, the first green emission layer EML-G1, and the first blue emission layer EML-B1 may be each disposed between the emission auxiliary part OG and the electron transport region ETR. The second red emission layer EML-R₂, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R₂, the emission auxiliary part OG, the first red emission layer EML-R1, the electron transport region ETR, and the second electrode EL2, which are stacked in that order. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

At least one emission layer included in the display device DD-b according to an embodiment, shown in FIG. 10, may include the polycyclic compound according to an embodiment. For example, at least one of the first blue emission layer EML-B1 and the second blue emission layer EML-B2 may include the polycyclic compound according to an embodiment.

In contrast to FIGS. 9 and 10, FIG. 11 shows that a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. Light emitting structures OL-C1, OL-B1, OL-B2, and OL-B3 are stacked successively, and the charge generation layer CGL1 is disposed between light emitting structures OL-B1 and OL-C1, the charge generation layer CGL2 is disposed between light emitting structures OL-B1 and OL-B2, and the charge generation layer CGL3 is disposed between light emitting structures OL-B2 and OL-B3. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures among the first to fourth light emitting structures OL-B1, OL-B2, OL-B3, and OL-C1 may each include a p-type charge generation layer and/or an n-type charge generation layer.

In the display device DD-c, at least one of the luminous structures OL-B1, OL-B2, OL-B3, and OL-C1 may each independently include the polycyclic compound according to an embodiment. For example, in an embodiment, at least one of the first to third luminous structures OL-B1, OL-B2, and OL-B3 may each independently include the polycyclic compound.

The light emitting element ED according to an embodiment may include the polycyclic compound represented by Formula 1 in at least one functional layer disposed between the first electrode EL1 and the second electrode EL2, and may exhibit excellent emission efficiency and improved lifetime characteristics. For example, the emission layer EML of the light emitting element ED may include the polycyclic compound, and the light emitting element may exhibit long-life characteristics.

In an embodiment, the electronic apparatus may include a display device including light emitting elements and a control part that controls the display device. The electronic apparatus may be a device that is activated according to an electrical signal. The electronic apparatus may include display devices of various embodiments. For example, the electronic apparatus may include not only large-sized electronic apparatuses such as a television set, a monitor, or an outdoor billboard but also include small-electronic apparatus and medium-sized electronic apparatus such as a personal computer, a laptop computer, a personal digital terminal, a display device for a vehicle, a game console, a portable electronic device, or a camera.

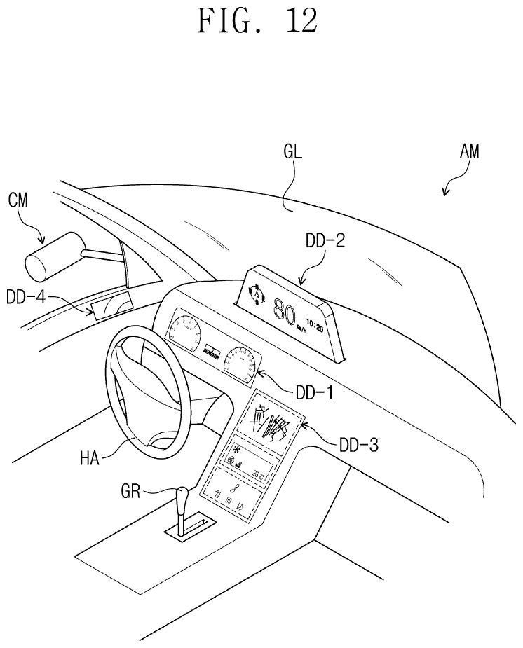

FIG. 12 is a schematic perspective view of an interior of a vehicle AM including first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c as described with reference to FIGS. 1, 2, and 8 to 11.

FIG. 12 is a schematic perspective view of an interior of a vehicle AM including first to fourth display devices DD-1, DD-2, DD-3, and DD-4 in various transportation means such as bicycles, motorcycles, trains, ships, and airplanes. In an embodiment, at least one of the first to fourth display devices DD-1, DD-2, DD-3, and DD-4 having a structure according to one of display devices DD, DD-TD, DD-a, DD-b, and DD-c may be employed in a personal computer, a laptop computer, a personal digital terminal, a game console, a portable electronic device, a television, a monitor, an outdoor billboard, or the like. However, these are merely presented as examples, and thus may be employed in other electronic apparatuses.

At least one of the first to fourth display devices DD-1, DD-2, DD-3, and DD-4 may each independently include a light emitting element ED according to as described in reference to FIGS. 3 to 6.

Referring to FIG. 12, the vehicle AM may include a steering wheel HA and a gearshift GR for driving the vehicle AM. The vehicle AM may include a front window GL that is disposed so as to face the driver.

The first display device DD-1 may be disposed in a first region that overlaps the steering wheel HA. For example, the first display device DD-1 may be a digital cluster which displays the first information of the vehicle AM. The first information may include a first scale which indicates a driving speed of the vehicle AM, a second scale which indicates an engine speed (for example, as revolutions per minute (RPM)), a fuel gauge, etc. The first scale and a second scale may each be displayed as a digital image.

The second display device DD-2 may be disposed in a second region facing the driver's seat and overlapping the front window GL. The driver's seat may be a seat where the steering wheel HA is disposed. For example, the second display device DD-2 may be a head up display (HUD) that displays second information of the vehicle AM. The second display device DD-2 may be optically transparent. The second information may include digital numbers that indicate a driving speed and may further include information such as the current time. Although not shown in the drawings, in an embodiment, the second information of the second display device DD-2 may be projected to the front window GL to be displayed.

The third display device DD-3 may be disposed in a third region adjacent to the gearshift GR. For example, the third display device DD-3 may be a center information display (CID) for a vehicle that displays third information, and the third display device DD-3 may be disposed between the driver's seat and the passenger seat. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display device DD-4 may be spaced apart from the steering wheel HA and the gearshift GR, and may be disposed in a fourth region adjacent to a side of the vehicle AM. For example, the fourth display device DD-4 may be a digital side-view mirror that displays fourth information. The fourth display device DD-4 may display an image outside the vehicle AM that is taken by a camera module CM disposed outside the vehicle AM. The fourth information may include an image outside of the vehicle AM.

The first to fourth information as described above are only presented as examples, and the first to fourth display devices DD-1, DD-2, DD-3, and DD-4 may further display information about the interior and exterior of the vehicle AM. The first to fourth information may include information that is different from each other. However, embodiments are not limited thereto, and a part of the first to fourth information may include the same information as one another.

Hereinafter, a polycyclic compound according to an embodiment and a light emitting element according to an embodiment will be described with reference to the Examples and the Comparative Examples. The Examples described below are only provided as illustrations to assist in understanding the disclosure, and the scope thereof is not limited thereto.

### EXAMPLES

### 1. Synthesis of Polycyclic Compounds

A synthesis method of the polycyclic compound according to an embodiment will be explained by illustrating the synthesis methods of Compounds 4, 10, and 23. The synthesis methods of the polycyclic compounds as explained below are provided only as examples, and the synthesis methods of the polycyclic compound according to an embodiment is not limited to the Examples below.

### (1) Synthesis of Compound 4

Compound 4 according to an embodiment may be synthesized, for example, by Reaction 1.

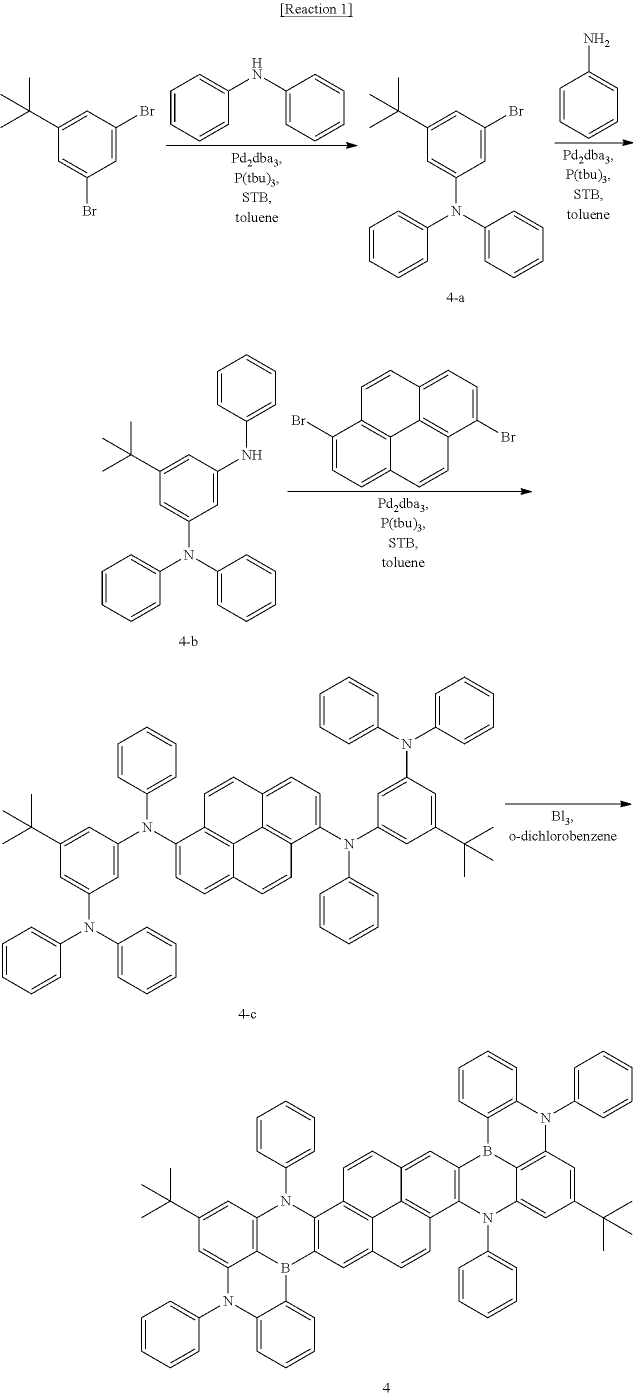

### 1) Synthesis of Intermediate Compound 4-a

Under an argon atmosphere, to a 2 L flask, 1,3-dibromo-5-(tert-butyl)benzene (24 g, 38 mmol), diphenylamine (13 g, 76 mmol), pd₂dba₃ (1.0 g, 1.1 mmol), tris-tert-butyl phosphine (P(tbu)₃, 1.1 mL, 2.2 mmol), and sodium tert-butoxide (STB, 11 g, 114 mmol) were added and dissolved in 400 mL of toluene. The reaction solution was stirred at about 100° C. for about 12 hours. After cooling, water (1 L) and ethyl acetate (300 mL) were added, and extraction was performed. Organic layers were collected, dried over MgSO₄ and filtered. The solvent of the filtrate solution was removed under a reduced pressure, and the solid thus obtained was purified and separated by column chromatography using silica gel and using CH₂Cl₂ and hexane as developing solvents to obtain Intermediate Compound 4-a (white solid, 24 g, yield 81%).

ESI-LCMS: [M]⁺: C₂₂H₂₂BrN. 379.0911.

### 2) Synthesis of Intermediate Compound 4-b

Under an argon atmosphere, to a 2 L flask, Intermediate Compound 4-a (24 g, 38 mmol), aniline (13 g, 76 mmol), pd₂dba₃ (1.0 g, 1.1 mmol), tris-tert-butyl phosphine (P(tbu)₃, 1.1 mL, 2.2 mmol), and sodium tert-butoxide (11 g, 114 mmol) were added and dissolved in 400 mL of toluene. The reaction solution was stirred at about 100° C. for about 12 hours. After cooling, water (1 L) and ethyl acetate (300 mL) were added, and extraction was performed. Organic layers were collected, dried over MgSO₄ and filtered. The solvent of the filtrate solution was removed under a reduced pressure, and the solid thus obtained was purified and separated by column chromatography using silica gel and using CH₂Cl₂ and hexane as developing solvents to obtain Intermediate Compound 4-b (white solid, 24 g, yield 81%).

ESI-LCMS: [M]⁺: C₂₈H₂₈N₂. 392.2387.

### 3) Synthesis of Intermediate Compound 4-c

Under an argon atmosphere, to a 2 L flask, Intermediate Compound 4-b (24 g, 30 mmol), 1,6-dibromopyrene (10 g, 30 mmol), pd₂dba₃ (0.8 g, 0.9 mmol), tris-tert-butyl phosphine (0.8 mL, 1.8 mmol), and sodium tert-butoxide (8.6 g, 90 mmol) were added and dissolved in 300 mL of toluene. The reaction solution was stirred at about 100° C. for about 12 hours. After cooling, water (1 L) and ethyl acetate (300 mL) were added, and extraction was performed. Organic layers were collected, dried over MgSO₄ and filtered. The solvent of the filtrate solution was removed under a reduced pressure, and the solid thus obtained was purified and separated by column chromatography using silica gel and using CH₂Cl₂ and hexane as developing solvents to obtain Intermediate Compound 4-c (white solid, 18 g, yield 62%).

ESI-LCMS: [M]⁺: C₇₂H₆₂N₄. 982.5053.

### 4) Synthesis of Compound 4

Under an argon atmosphere, to a 1 L flask, Intermediate Compound 4-c (8 g, 5.7 mmol) was added and dissolved in 200 mL of o-dichlorobenzene, and BI₃ (1.5 equiv.) was added thereto. The reaction solution was stirred at about 140° C. for about 12 hours. After cooling, triethylamine was added to quench the reaction, the solvent was removed under a reduced pressure, and the solid thus obtained was purified and separated by column chromatography using silica gel and using CH₂Cl₂ and hexane as developing solvents to obtain Compound 4 (yellow solid, 1.6 g, yield 21%).

ESI-LCMS: [M]⁺: C₇₂H₅₆B₂N₄. 998.4712.

NMR-¹H: 8.57 (s, 2H), 8.38 (d, 2H), 7.94 (d, 2H), 7.88 (m, 8H), 7.35 (m, 10H), 7.24 (m, 4H), 7.08 (d, 8H), 6.15 (s, 4H), 1.77 (s, 18H).

### (2) Synthesis of Compound 10

Compound 10 according to an embodiment may be synthesized, for example, by Reaction 2.

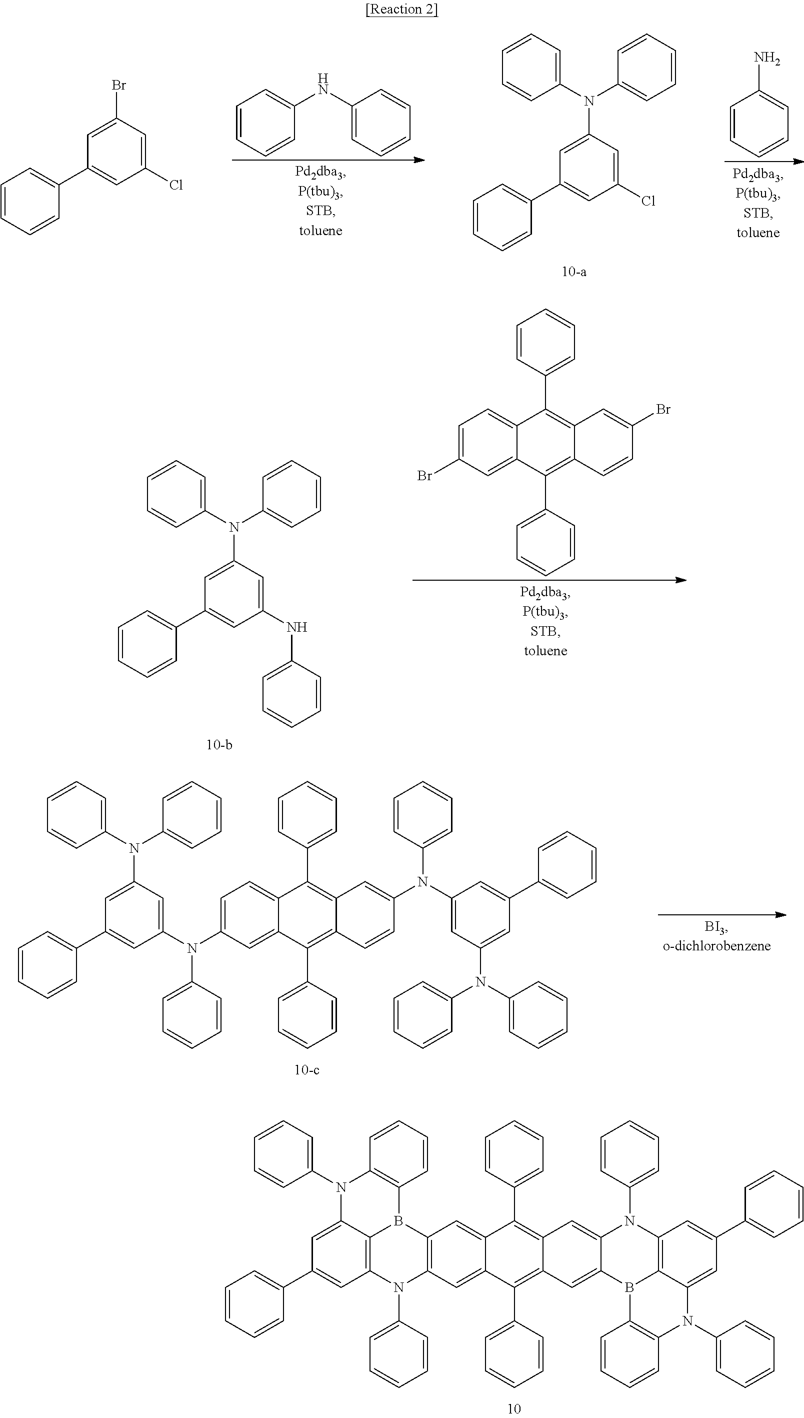

### 1) Synthesis of Intermediate Compound 10-a

Intermediate Compound 10-a was obtained by using the same method as the synthesis method of Intermediate Compound 4-a except for using 3-bromo-5-chloro-1,1′-biphenyl instead of 1,3-dibromo-5-(tert-butyl)benzene as a starting material.

### 2) Synthesis of Intermediate Compound 10-b

Intermediate Compound 10-b was obtained by using the same method as the synthesis method of Intermediate Compound 4-b except for using Intermediate Compound 10-a instead of Intermediate Compound 4-a as a starting material.

### 3) Synthesis of Intermediate Compound 10-c

Intermediate Compound 10-c was obtained by using the same method as the synthetic method of Intermediate Compound 4-c except for using Intermediate Compound 10-b instead of Intermediate Compound 4-b and using 2,6-dibromo-9,10-diphenylanthracene instead of 1,6-dibromopyrene as starting materials.

### 4) Synthesis of Compound 10

Under an argon atmosphere, to a 1 L flask, Intermediate Compound 10-c (5 g, 4.3 mmol) was added and dissolved in 100 mL of o-dichlorobenzene, and BI₃ (1.5 equiv.) was added thereto. The reaction solution was stirred at about 150° C. for about 24 hours. After cooling, triethylamine was added to quench the reaction, the solvent was removed under a reduced pressure, and the solid thus obtained was purified and separated by column chromatography using silica gel and using CH₂Cl₂ and hexane as developing solvents to obtain Compound 10 (yellow solid, 1.5 g, yield 29%).

ESI-LCMS: [M]⁺: C₈₆H₅₆B₂N₄ m/z: 1166.47.

NMR-1H: 8.78 (s, 2H), 8.39 (d, 2H), 8.03 (d, 4H), 7.84 (m, 4H), 7.75 (m, 4H), 7.63 (m, 10H), 7.43 (d, 8H), 7.35 (m, 16H), 7.08 (s, 2H), 6.84 (s, 4H).

### (3) Synthesis of Compound 23

Compound 23 according to an embodiment may be synthesized, for example, by Reaction 3.

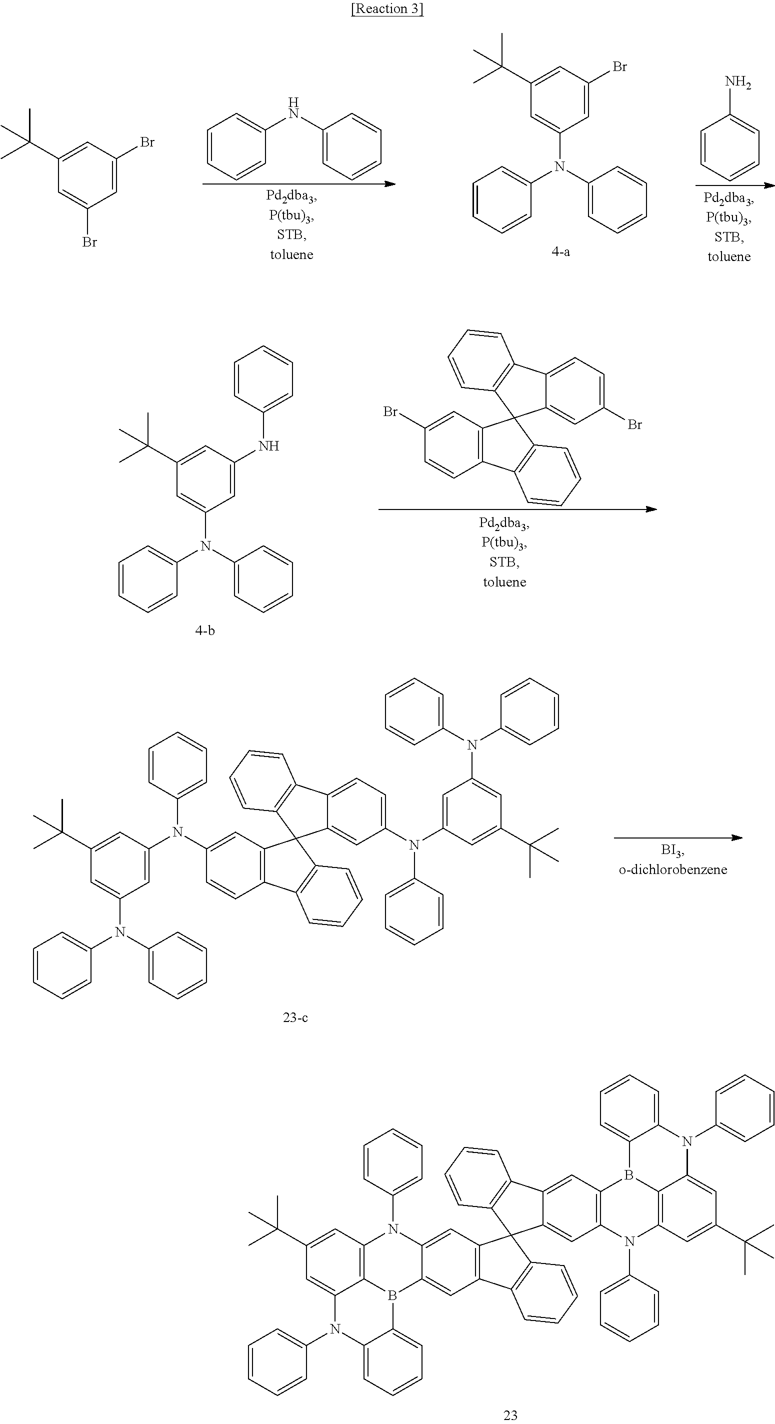

### 1) Synthesis of Intermediate Compound 23-c

Intermediate Compound 23-c was obtained by using the same method as the synthesis method of Intermediate Compound 4-c except for using 2,2′-dibromo-9,9′-spirobi[fluorene] instead of 1,6-dibromopyrene as a starting material.

### 2) Synthesis of Compound 23

Under an argon atmosphere, to a 1 L flask, Intermediate Compound 23-c (5 g, 4.3 mmol) was added and dissolved in 100 mL of o-dichlorobenzene, and BI₃ (1.5 equiv.) was added thereto. The reaction solution was stirred at about 150° C. for about 24 hours. After cooling, triethylamine was added to quench the reaction, the solvent was removed under a reduced pressure, and the solid thus obtained was purified and separated by column chromatography using silica gel and using CH₂Cl₂ and hexane as developing solvents to obtain Compound 23 (yellow solid, 1.5 g, yield 29%).

ESI-LCMS: [M]⁺: C₈₁H₆₂B₂N₄ m/z: 1112.52.

NMR-1H: 8.44 (s, 2H), 8.23 (d, 2H), 7.77 (d, 4H), 7.65 (m, 4H), 7.57 (m, 12H), 7.38 (m, 10H), 7.24 (m, 2H), 7.08 (d, 4H), 6.43 (s, 4H), 1.68 (s, 18H).

### 2. Manufacture and Evaluation of Light Emitting Elements

Light emitting elements of embodiments, including the polycyclic compounds of embodiment in emission layers were manufactured by a method. Light emitting elements of Example 1 to Example 3 were manufactured using Compounds 4, 10 and 23, which are the above-described Example Compounds, as the dopant materials of emission layers. Comparative Example 1 to Comparative Example 3 correspond to light emitting elements manufactured using Compound A to Compound C as the dopant materials of emission layers.

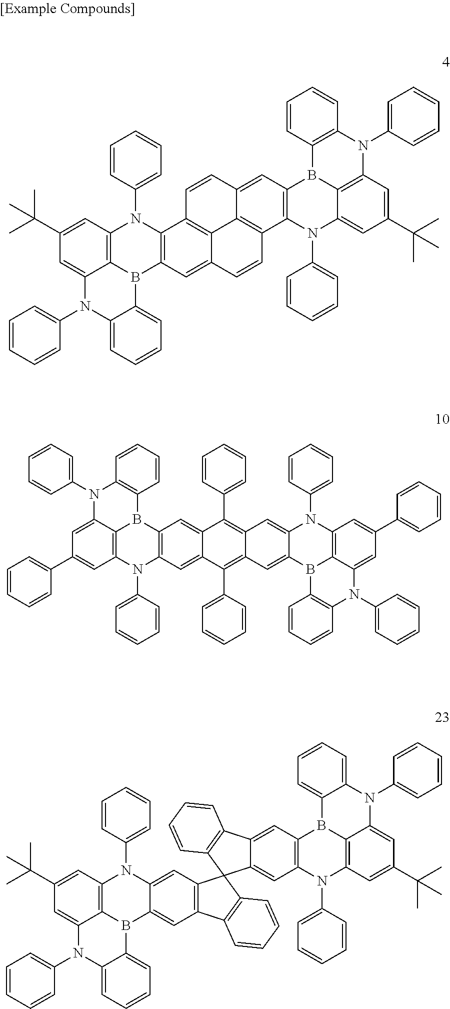 [SMILES: CC(C)(C)c1cc2c3c(c1)N(c1ccccc1)c1c(cc4ccc5c6c(cc7ccc1c4c75)B1c4ccccc4N(c4ccccc4)c4cc(C(C)(C)C)cc(c41)N6c1ccccc1)B3c1ccccc1N2c1ccccc1 ; c1ccc(-c2cc3c4c(c2)N(c2ccccc2)c2cc5c(-c6ccccc6)c6cc7c(cc6c(-c6ccccc6)c5cc2B4c2ccccc2N3c2ccccc2)N(c2ccccc2)c2cc(-c3ccccc3)cc3c2B7c2ccccc2N3c2ccccc2)cc1 ; CC(C)(C)c1cc2c3c(c1)N(c1ccccc1)c1cc4c(cc1B3c1ccccc1N2c1ccccc1)-c1ccccc1C41c2ccccc2-c2cc3c(cc21)N(c1ccccc1)c1cc(C(C)(C)C)cc2c1B3c1ccccc1N2c1ccccc1]

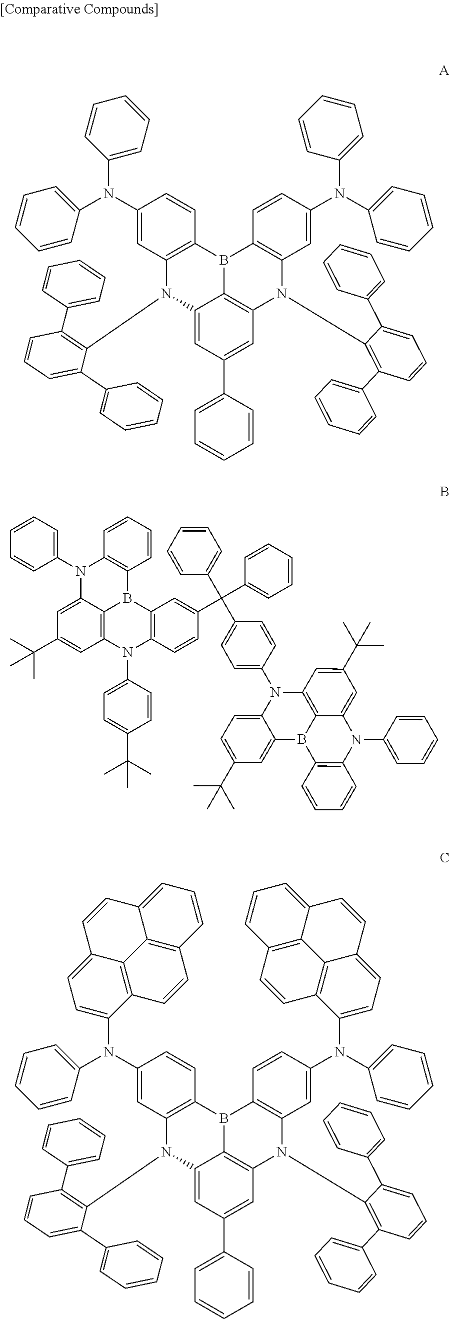

### 1) Manufacture of Light Emitting Element

For the manufacture of the light emitting elements of the Examples and Comparative Examples, as an anode, a glass substrate on which an ITO electrode of 15 Ω/cm² (1200 Å) was formed (a product of Corning Co.) was cut into a size of 50 mm×50 mm×0.7 mm, washed by ultrasonic waves using isopropyl alcohol and pure water for about 5 minutes each, cleansed by exposing to ultraviolet for about 30 minutes and exposing to ozone, and installed on a vacuum deposition apparatus.

On the anode, NPD was deposited to form a hole injection layer having a thickness of about 300 Å, and on the hole injection layer, H-1-19 was deposited to form a hole transport layer having a thickness of about 200 Å. On the hole transport layer, CzSi was deposited to form a buffer layer having a thickness of about 100 Å.

After that, a host mixture of the second compound and the third compound by about 1:1, the fourth compound, and the Example Compound or Comparative Compound were co-deposited in a weight ratio of about 85:14:1 to form an emission layer having a thickness of about 200 Å. On the emission layer, TSPO1 was deposited to form an electron transport layer having a thickness of about 200 Å, and on the electron transport layer, TPBi was deposited to form a buffer layer having a thickness of about 300 Å. On the buffer layer, Yb was deposited to form an electron injection layer having a thickness of about 10 Å, and MgAg was deposited to form a Yb/MgAg cathode having a thickness of about 100 Å. On the cathode, Compound P4 was deposited to form a capping layer having a thickness of about 700 Å to manufacture a light emitting element.

All layers were formed by a vacuum deposition method. The second compound used HT35 of the compounds in Compound Group 2, the third compound used ETH66 of the compounds in Compound Group 3, and the fourth compound used AD-38 of the compounds in Compound Group 4.

The compounds used for the manufacture of the light emitting elements of the Examples and Comparative Examples are shown. The materials were used for the manufacture of the light emitting elements after purifying by sublimation commercial products.

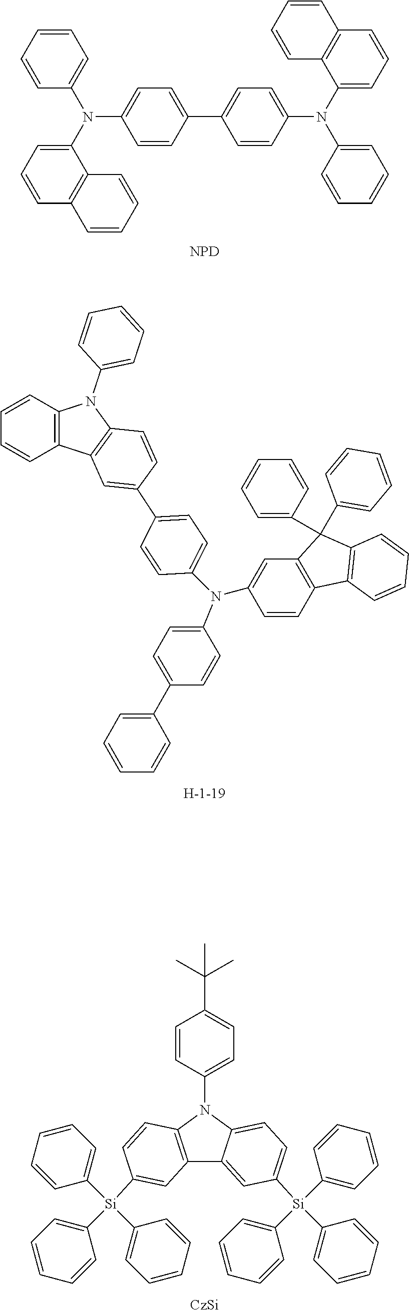

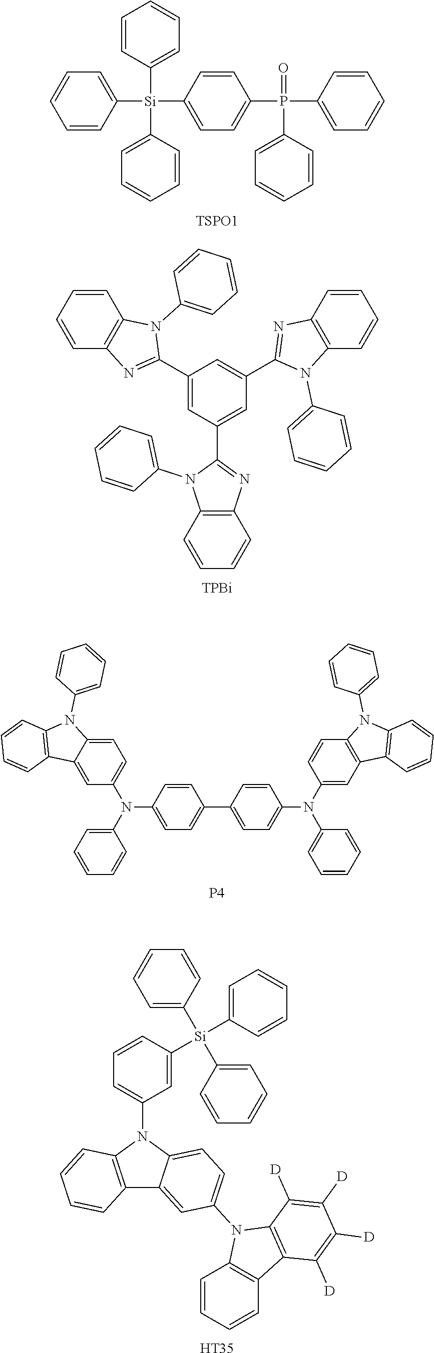

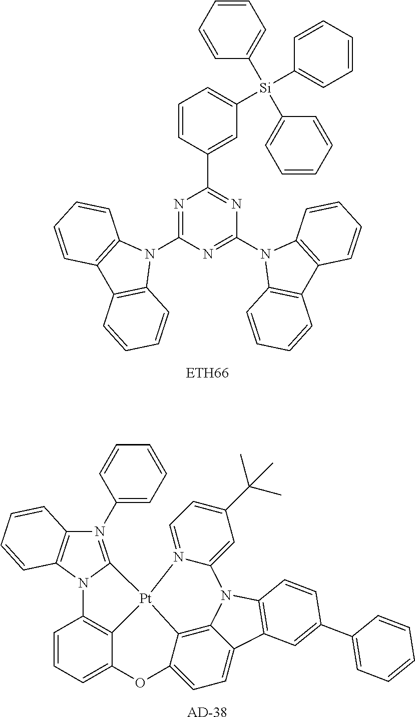

### 2) Evaluation of Physical Properties of Example Compounds and Comparative Compounds

In Table 1, the physical properties of Compound 4, Compound 10, and Compound 23, which are the Example Compounds, and Compounds A to C, which are the Comparative Compounds, were evaluated and shown.

In Table 1, the lowest unoccupied molecular orbital (LUMO) energy level, the highest occupied molecular orbital (HOMO) energy level, the lowest excitation singlet energy level (S1), the lowest excitation triplet energy level (T1), and a difference (S1-T1, hereinafter, ΔE_{ST1}) between the lowest excitation singlet energy level (S1) and the lowest excitation triplet energy level (T1) of the Example Compounds and the Comparative Compounds are shown. In Table 1, the photoluminescence quantum yield (PLQY), the maximum absorption wavelength (λ_{Abs}), the maximum emission wavelength (λₑₘᵢ), the Stokes-shift (difference between λ_{Abs} and λₑₘᵢ), and the full width at quarter maximum (FWQM) of the Example Compounds and Comparative Compounds were measured and shown. λₑₘᵢ is the maximum emission wavelength of the Example Compounds and Comparative Compounds in a solution state.

TABLE 1

| | | HOMO | LUMO | | | | | | | | |
|---|---|---|---|---|---|---|---|---|---|---|---|
| | | energy | energy | | | | | | | | |
| | | level | level | S1 | T1 | ΔE_{ST} | PLQY | λ_{Abs} | λₑₘᵢ | Stokes- | FWQM |
| | Dopant | (eV) | (eV) | (eV) | (eV) | (eV) | (%) | (nm) | (nm) | shift | (sol.) |
| Example 1 | Compound 4 | −5.45 | −2.36 | 2.70 | 2.01 | 0.69 | 90.1 | 449 | 458 | 9 | 36 |
| Example 2 | Compound 10 | −5.23 | −2.32 | 2.71 | 1.56 | 1.15 | 88.1 | 449 | 459 | 10 | 34 |
| Example 3 | Compound 23 | −5.20 | −2.34 | 2.69 | 1.60 | 1.09 | 89.6 | 453 | 462 | 9 | 32 |
| Comparative | Compound A | −5.47 | −2.41 | 2.68 | 2.53 | 0.15 | 84.9 | 449 | 462 | 13 | 35 |
| Example 1 | | | | | | | | | | | |
| Comparative | Compound B | −5.12 | −2.31 | 2.72 | 2.37 | 0.35 | 86.8 | 447 | 456 | 9 | 42 |
| Example 2 | | | | | | | | | | | |
| Comparative | Compound C | −5.43 | −2.32 | 2.71 | 1.96 | 0.75 | 86.1 | 446 | 458 | 12 | 28 |
| Example 3 | | | | | | | | | | | |

### 3) Evaluation of Properties of Light Emitting Elements

In Table 2, the evaluation results on the light emitting elements of Example 1 to Example 3, and Comparative Example 1 to Comparative Example 3 are shown. The evaluation of the properties of the light emitting elements was conducted using a luminance orientation characteristic measuring device.

In Table 2, the driving voltages, emission efficiency, emission wavelengths, lifetime ratios, color coordinates (CIE) and quantum efficiency (Q.E.) of the light emitting elements according to the Examples and Comparative Examples were measured and shown.

In Table 2, the driving voltage (V) and the emission efficiency (cd/A) at a current density of about 10 mA/cm² on the light emitting elements were measured. For evaluating the lifetime of the light emitting elements, time consumed from an initial value to 5% luminance deterioration when continuously driven at the maximum emission wavelength (λₘₐₓ), the quantum efficiency (Q.E.), and 10 mA/cm², was evaluated. Particularly, the lifetime (T95) was obtained by measuring time consumed for reducing an initial luminance of 100% to 95%.

TABLE 2

| | | | | Driving | Emission | Emission | | | |
|---|---|---|---|---|---|---|---|---|---|
| | Host | | | voltage | efficiency | wavelength | Lifetime | CIE | Q.E. |
| | (HT/ET) | Sensitizer | Dopant | (V) | (cd/A) | (nm) | (T95) | (x, y) | (%) |
| Example 1 | HT35/ETH66 | AD-38 | Example | 4.1 | 14.8 | 461 | 250 | 0.135, | 30.1 |
| | | | Compound 4 | | | | | 0.053 | |
| Example 2 | HT35/ETH66 | AD-38 | Example | 4.0 | 14.5 | 460 | 237 | 0.135, | 29.9 |
| | | | Compound 10 | | | | | 0.051 | |
| Example 3 | HT35/ETH66 | AD-38 | Example | 4.2 | 14.6 | 461 | 180 | 0.136, | 30.0 |
| | | | Compound 23 | | | | | 0.055 | |
| Comparative | HT35/ETH66 | AD-38 | Comparative | 4.6 | 16.5 | 462 | 30 | 0.137, | 36.4 |
| Example 1 | | | Compound A | | | | | 0.052 | |
| Comparative | HT35/ETH66 | AD-38 | Comparative | 4.8 | 16.6 | 463 | 20 | 0.135, | 35.2 |
| Example 2 | | | Compound B | | | | | 0.055 | |
| Comparative | HT35/ETH66 | AD-38 | Comparative | 4.8 | 14.2 | 462 | 50 | 0.135, | 29.7 |
| Example 3 | | | Compound C | | | | | 0.057 | |

Referring to Table 2, it can be confirmed that the light emitting elements of the Examples used the polycyclic compound according to embodiments as light-emitting materials, and showed lower driving voltages, and improved emission efficiency and/or lifetime characteristics compared to the Comparative Examples.

In more detail, the light emitting elements of the Examples showed lower driving voltages by about 0.5 V or more and improved lifetime characteristics in contrast to the light emitting elements of Comparative Example 1 to Comparative Example 3.

The polycyclic compounds used in the light emitting elements of the Examples introduce polycyclic aromatic hydrocarbons (PAHs) in the core part, and may reduce a second lowest triplet energy level (T2) as well as the lowest triplet energy level (T1). Accordingly, the light emitting elements of the Examples, including the polycyclic compounds showed somewhat low emission efficiency in contrast to Comparative Example 1 and Comparative Example 2, but showed improved lifetime characteristics by about 10 times. From such results, it can be found that the polycyclic compound shows excellent effects as a light-emitting material.

The light emitting element according to an embodiment includes the polycyclic compound according to an embodiment in an emission layer and may show low driving voltage characteristics and long-life characteristics.

The polycyclic compound according to an embodiment includes an organic compound having a low value of the lowest triplet energy level in a core part, and includes a fused structure of a first fused ring and a second fused ring in the core part, and may contribute to the reduction of the driving voltage and the increase of the lifetime of a light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element, comprising:
a first electrode;
a second electrode disposed on the first electrode; and
an emission layer disposed between the first electrode and the second electrode, wherein
the emission layer comprises a first compound represented by Formula 1: 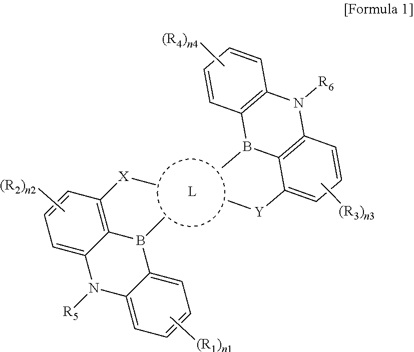
wherein in Formula 1,
L is a substituted or unsubstituted polycyclic aromatic hydrocarbon group of 12 to 25 ring-forming carbon atoms,
X and Y are each independently N(R₇), O, S, or Se,
R₁ to R₄ are each independently a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted alkoxy group of 1 to 60 carbon atoms, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms,
R₅ to R₇ are each independently a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms,
n1 and n4 are each independently an integer from 0 to 4, and
n2 and n3 are each independently an integer from 0 to 3.

2. The light emitting element of claim 1, wherein the first compound is represented by one of Formula 2-1 to Formula 2-5: 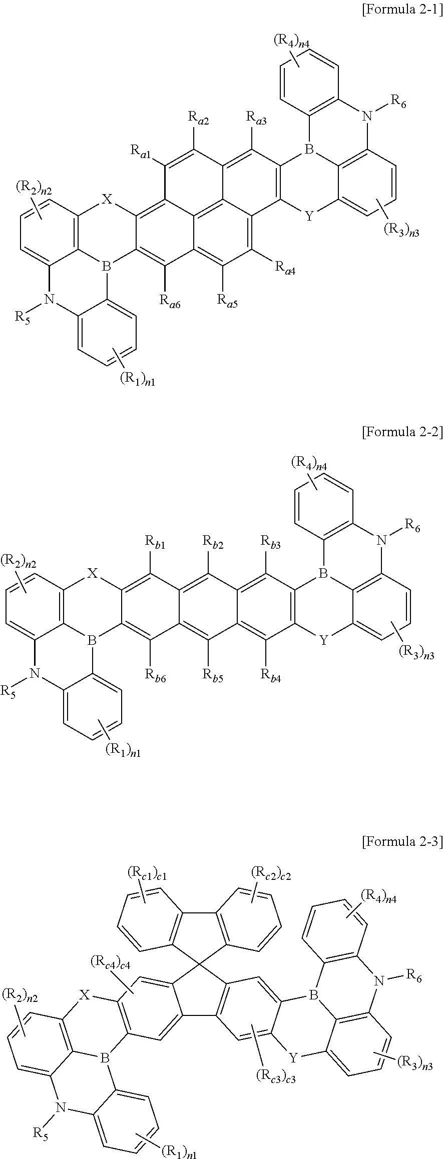 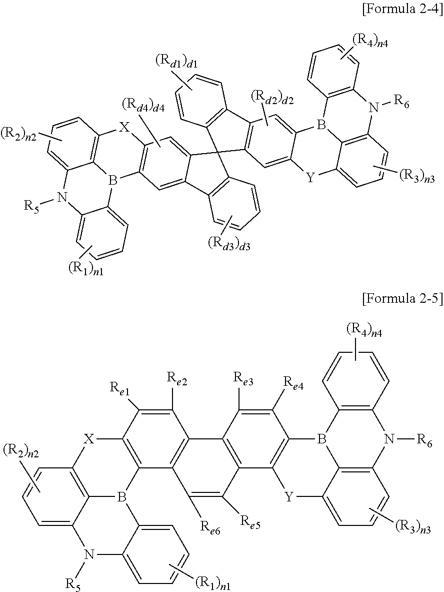
wherein in Formula 2-1 to Formula 2-5,
Rₐ₁ to Rₐ₆, R_{b1} to R_{b6}, R_{c1} to R_{c4}, R_{d1} to R_{d4}, and Rₑ₁ to Rₑ₆ are each independently a hydrogen atom, a deuterium atom, or a substituted or unsubstituted aryl group of 6 to 15 ring-forming carbon atoms,
c1, c2, d1, and d3 are each independently an integer from 0 to 4,
c3, c4, d2, and d4 are each independently an integer from 0 to 2, and
X, Y, R₁ to R₆, and n1 to n4 are the same as defined in Formula 1.

3. The light emitting element of claim 2, wherein the first compound is represented by Formula 2-1A: 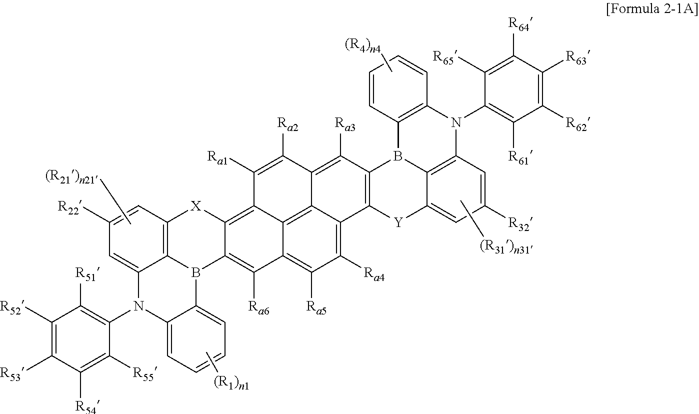
wherein in Formula 2-1A,
R₂₁′ and R₃₁′ are each independently a hydrogen atom or a deuterium atom,
R₂₂′ and R₃₂′ are each independently a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms,
R₅₁′ to R₅₅′ and R₆₁′ to R₆₅′ are each independently a hydrogen atom, a deuterium atom, a substituted or unsubstituted alkyl group of 1 to 10 carbon atoms, or a substituted or unsubstituted aryl group of 6 to 10 ring-forming carbon atoms,
n21′ and n31′ are each independently an integer from 0 to 2, and
R₁, R₄, Rₐ₁ to Rₐ₆, n1, n4, X, and Y are the same as defined in Formula 1 and Formula 2-1.

4. The light emitting element of claim 2, wherein the first compound is represented by Formula 2-2A: 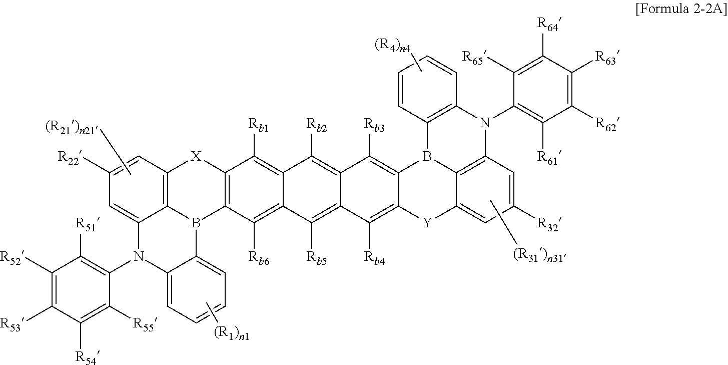
wherein in Formula 2-2A,
R₂₁′ and R₃₁′ are each independently a hydrogen atom or a deuterium atom,
R₂₂′ and R₃₂′ are each independently a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms,
R₅₁′ to R₅₅′ and R₆₁′ to R₆₅′ are each independently a hydrogen atom, a deuterium atom, a substituted or unsubstituted alkyl group of 1 to 10 carbon atoms, or a substituted or unsubstituted aryl group of 6 to 10 ring-forming carbon atoms,
n21′ and n31′ are each independently an integer from 0 to 2, and
R₁, R₄, R_{b1} to R_{b6}, n1, n4, X, and Y are the same as defined in Formula 1 and Formula 2-2.

5. The light emitting element of claim 1, wherein L has a lowest triplet state energy level (T1) in a range of about 1.5 eV to about 2.4 eV.

6. The light emitting element of claim 1, wherein the first compound is represented by Formula 3: 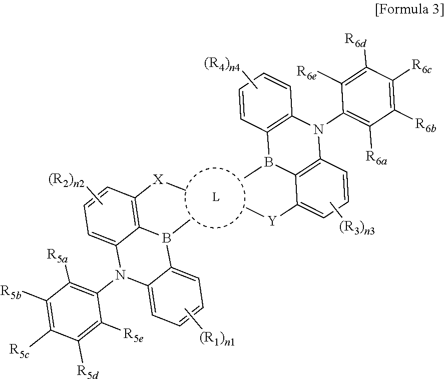
wherein in Formula 3,
R₅ₐ to R₅ₑ and R₆ₐ to R₆ₑ are each independently a hydrogen atom, a deuterium atom, a substituted or unsubstituted alkyl group of 1 to 10 carbon atoms, or a substituted or unsubstituted aryl group of 6 to 10 ring-forming carbon atoms, and
R₁ to R₄, n1 to n4, L, X, and Y are the same as defined in Formula 1.

7. The light emitting element of claim 1, wherein the first compound is represented by Formula 4: 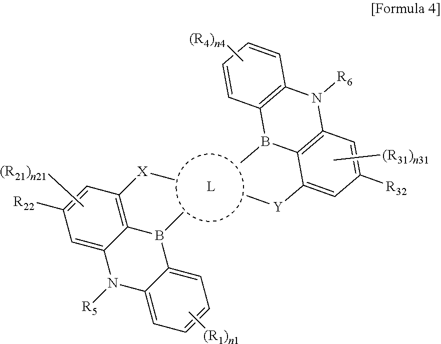
wherein in Formula 4,
R₂₁ and R₃₁ are each independently a hydrogen atom or a deuterium atom,
R₂₂ and R₃₂ are each independently a hydrogen atom, a deuterium atom, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms,
n21 and n31 are each independently an integer from 0 to 2, and
R₁, R₄ to R₆, n1, n4, L, X, and Y are the same as defined in Formula 1.

8. The light emitting element of claim 1, wherein the first compound is represented by one of Formula 5-1 to Formula 5-4: 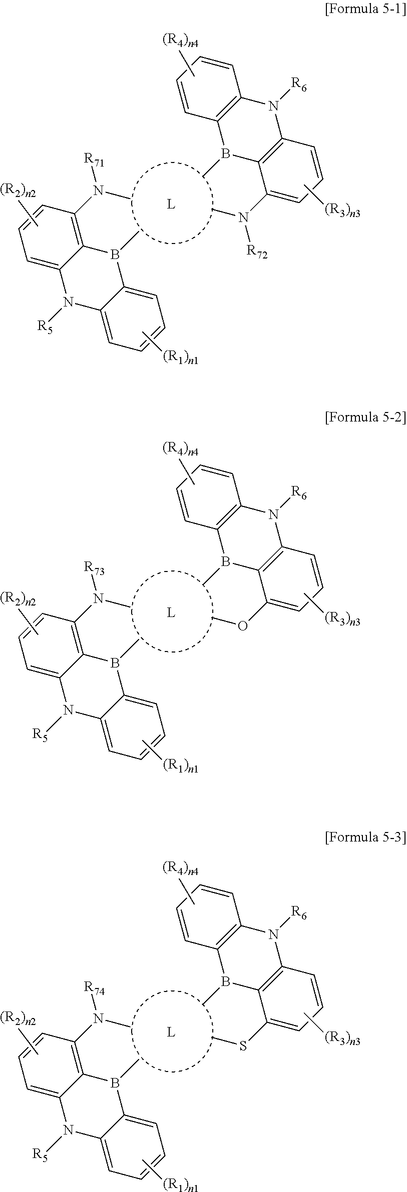 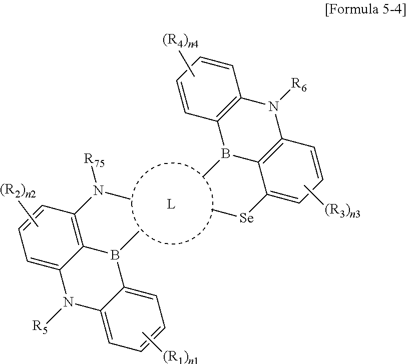
wherein in Formula 5-1 to Formula 5-4,
R₇₁ to R₇₅ are each independently a substituted or unsubstituted aryl group of 6 to 20 ring-forming carbon atoms or a substituted or unsubstituted heteroaryl group of 2 to 20 ring-forming carbon atoms, and
R₁ to R₆, n1 to n4, and L are the same as defined in Formula 1.

9. The light emitting element of claim 1, wherein in Formula 1, at least one of L and R₁ to R₇ is each independently a deuterium atom, or a substituent comprising a deuterium atom.

10. The light emitting element of claim 1, wherein the emission layer further comprises at least one of a second compound represented by Formula HT-1, a third compound represented by Formula ET-1, and a fourth compound represented by Formula S-1: 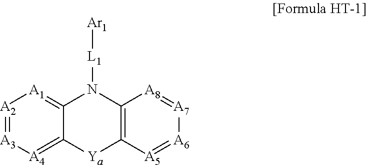
wherein in Formula HT-1,
A₁ to A₈ are each independently N or C(R₁),
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, C(Rₓ₂)(Rₓ₃), or Si(Rₓ₄)(Rₓ₅),
Ar is a substituted or unsubstituted aryl group of 6 to 30 ring-forming carbon atoms or a substituted or unsubstituted heteroaryl group of 2 to 30 ring-forming carbon atoms, and
Rₓ₁ to Rₓ₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 ring-forming carbon atoms, a substituted or unsubstituted aryl group of 6 to 60 ring-forming carbon atoms, or a substituted or unsubstituted heteroaryl group of 2 to 60 ring-forming carbon atoms, or bonded to an adjacent group to form a ring; 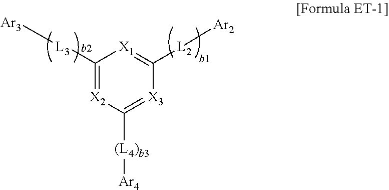
wherein in Formula ET-1,
at least one of X₁ to X₃ is each N,
the remainder of X₁ to X₃ are each independently C(Rₓ₆),
Rₓ₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group of 2 to 30 ring-forming carbon atoms; 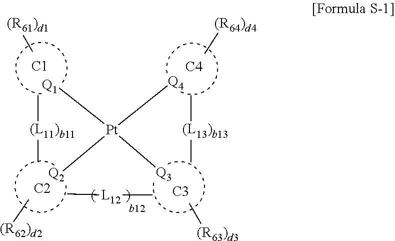
wherein in Formula S-1,
Q₁ to Q₄ are each independently C or N,
C1 to C4 are each independently a substituted or unsubstituted hydrocarbon ring of 5 to 30 ring-forming carbon atoms or a substituted or unsubstituted heterocycle of 2 to 30 ring-forming carbon atoms,
L₁₁ to L₁₃ are each independently a direct linkage, 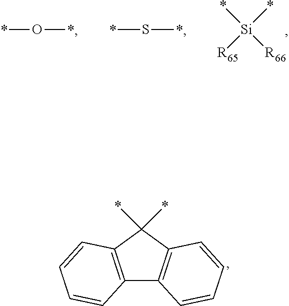
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 ring-forming carbon atoms, a substituted or unsubstituted aryl group of 6 to 60 ring-forming carbon atoms, or a substituted or unsubstituted heteroaryl group of 2 to 60 ring-forming carbon atoms, or bonded to an adjacent group to form a ring, and
d1 to d4 are each independently an integer from 0 to 4.

11. The light emitting element of claim 10, wherein the emission layer comprises the first compound, the second compound, and the third compound.

12. The light emitting element of claim 10, wherein the emission layer comprises the first compound, the second compound, the third compound, and the fourth compound.

13. The light emitting element of claim 1, wherein the first compound comprises at least one compound selected from Compound Group 1: 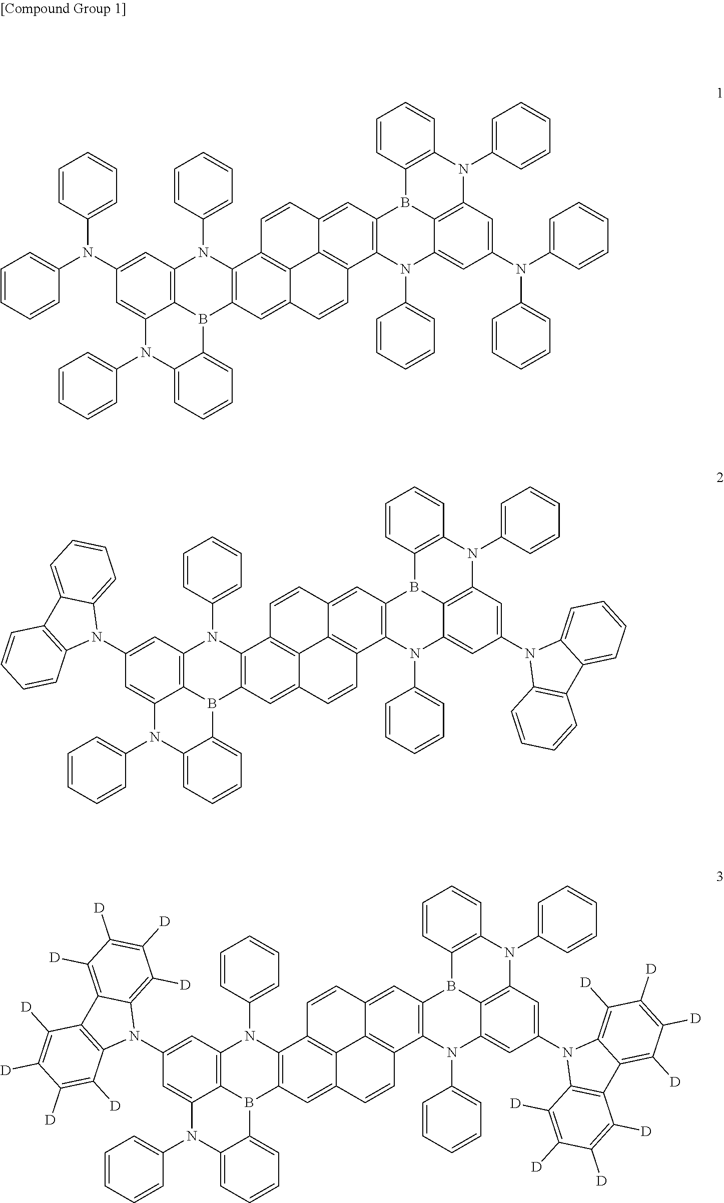 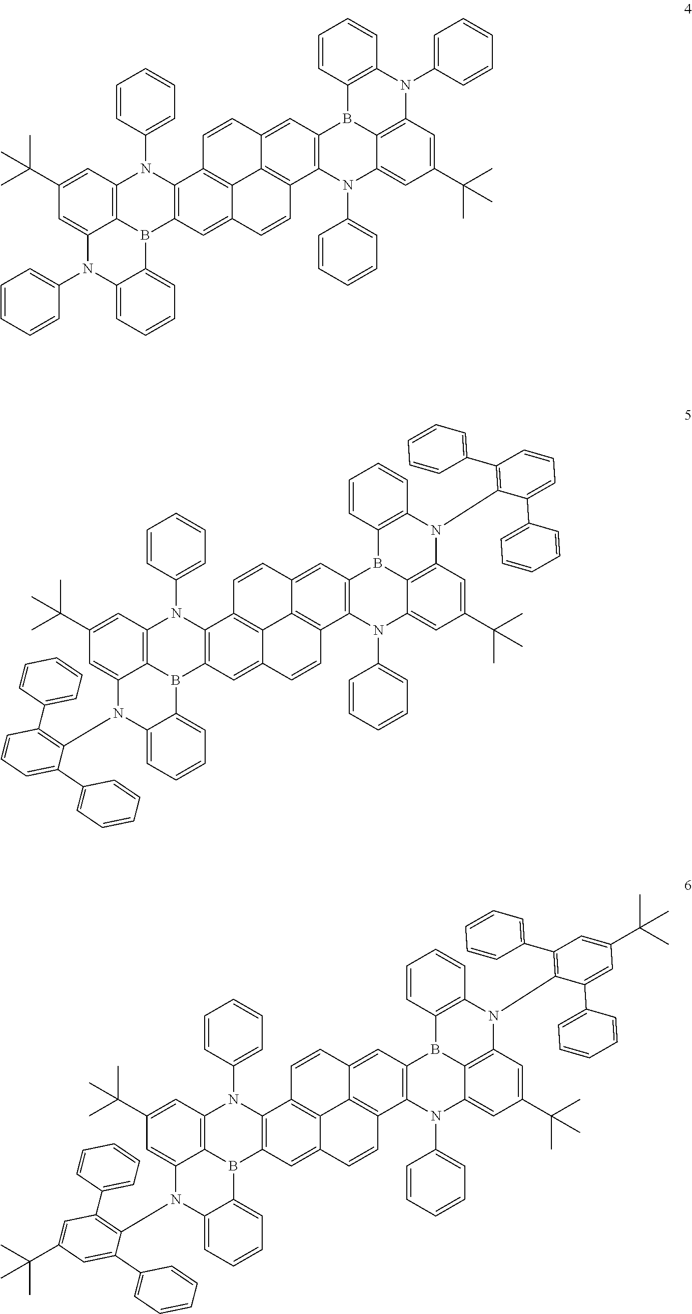 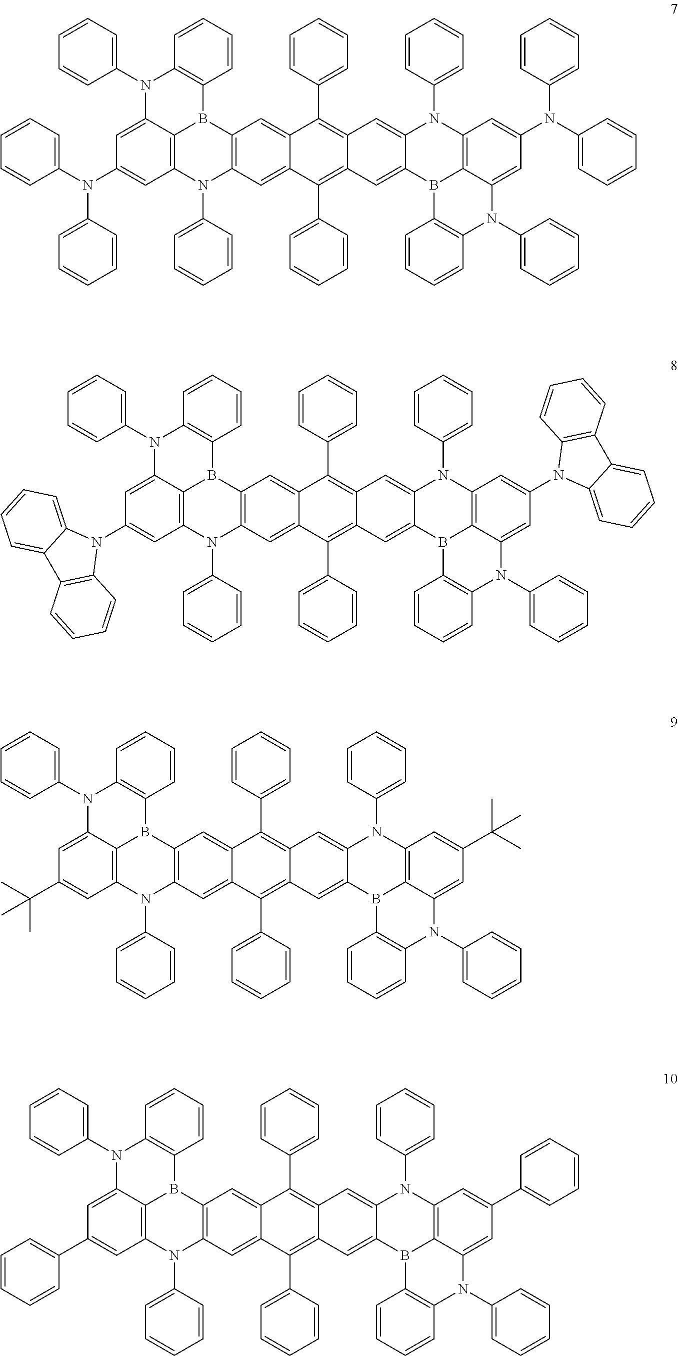 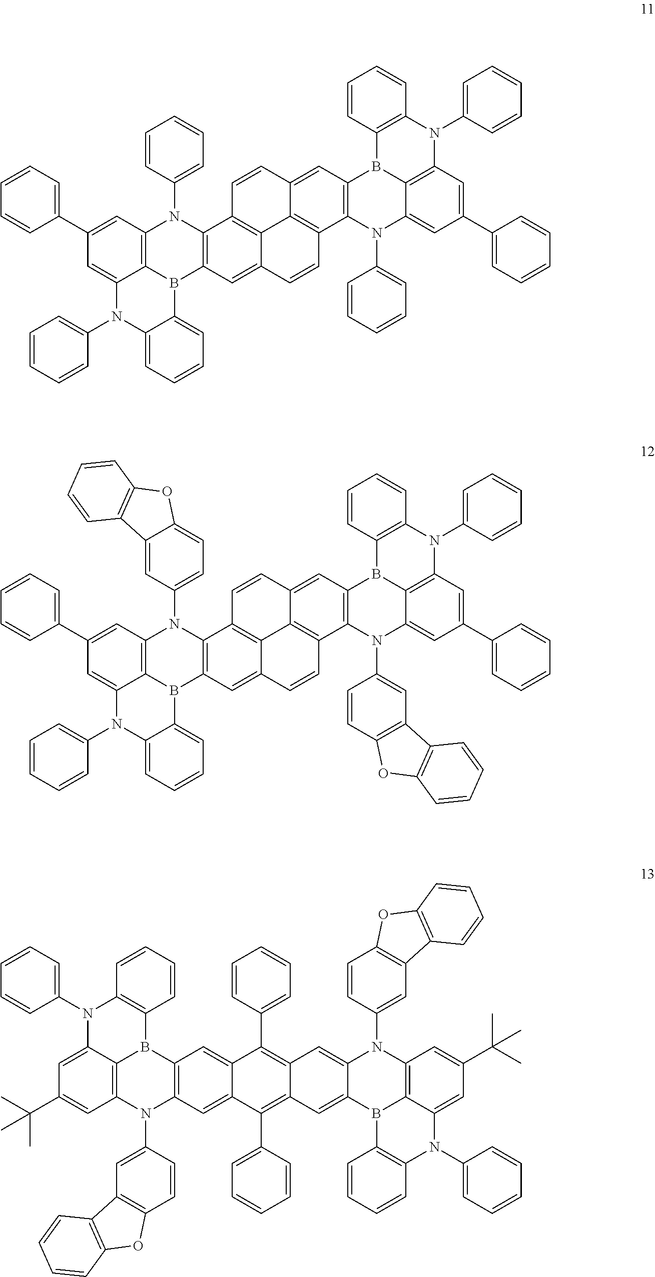 [SMILES: c1ccc(-c2cc3c4c(c2)N(c2ccccc2)c2c(cc5ccc6c7c(cc8ccc2c5c86)B2c5ccccc5N(c5ccccc5)c5cc(-c6ccccc6)cc(c52)N7c2ccccc2)B4c2ccccc2N3c2ccccc2)cc1 ; c1ccc(-c2cc3c4c(c2)N(c2ccc5oc6ccccc6c5c2)c2c(cc5ccc6c7c(cc8ccc2c5c86)B2c5ccccc5N(c5ccccc5)c5cc(-c6ccccc6)cc(c52)N7c2ccc5oc6ccccc6c5c2)B4c2ccccc2N3c2ccccc2)cc1 ; CC(C)(C)c1cc2c3c(c1)N(c1ccc4oc5ccccc5c4c1)c1cc4c(-c5ccccc5)c5cc6c(cc5c(-c5ccccc5)c4cc1B3c1ccccc1N2c1ccccc1)N(c1ccc2oc3ccccc3c2c1)c1cc(C(C)(C)C)cc2c1B6c1ccccc1N2c1ccccc1] 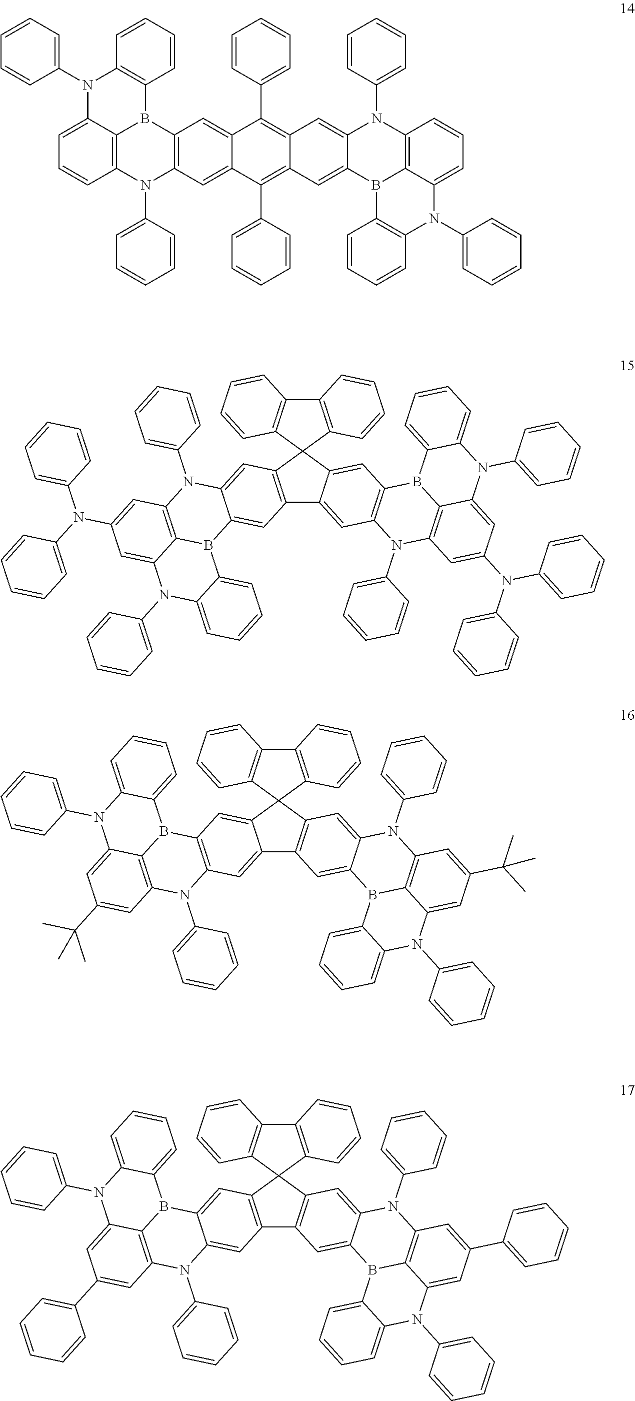 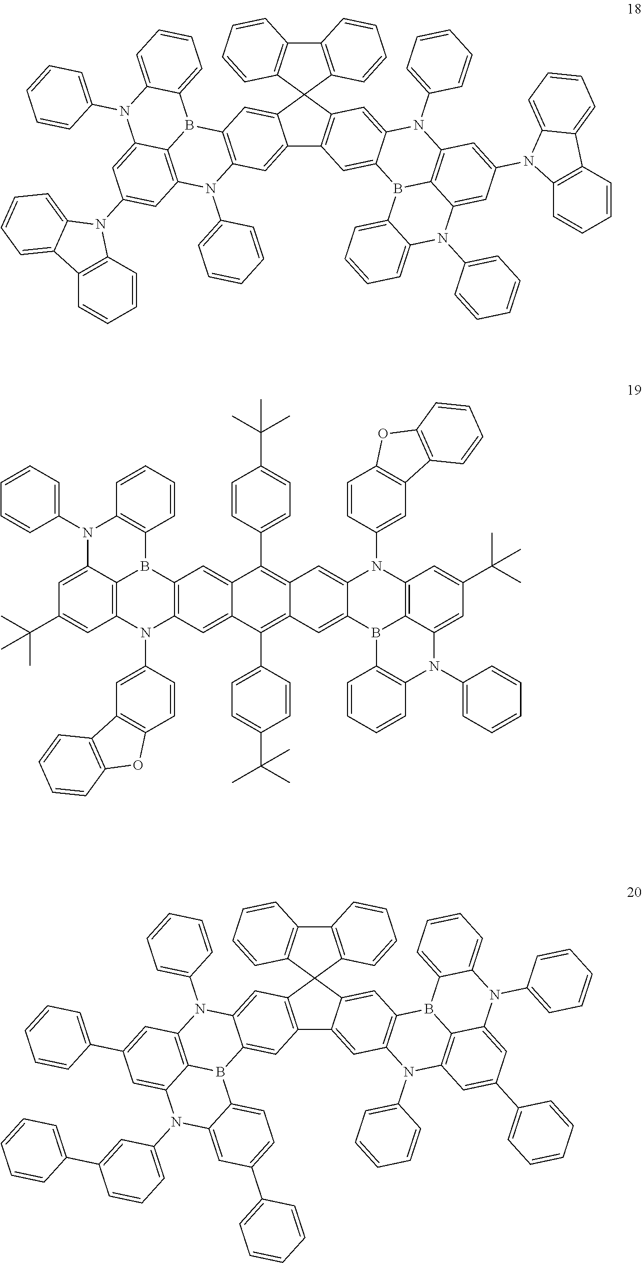 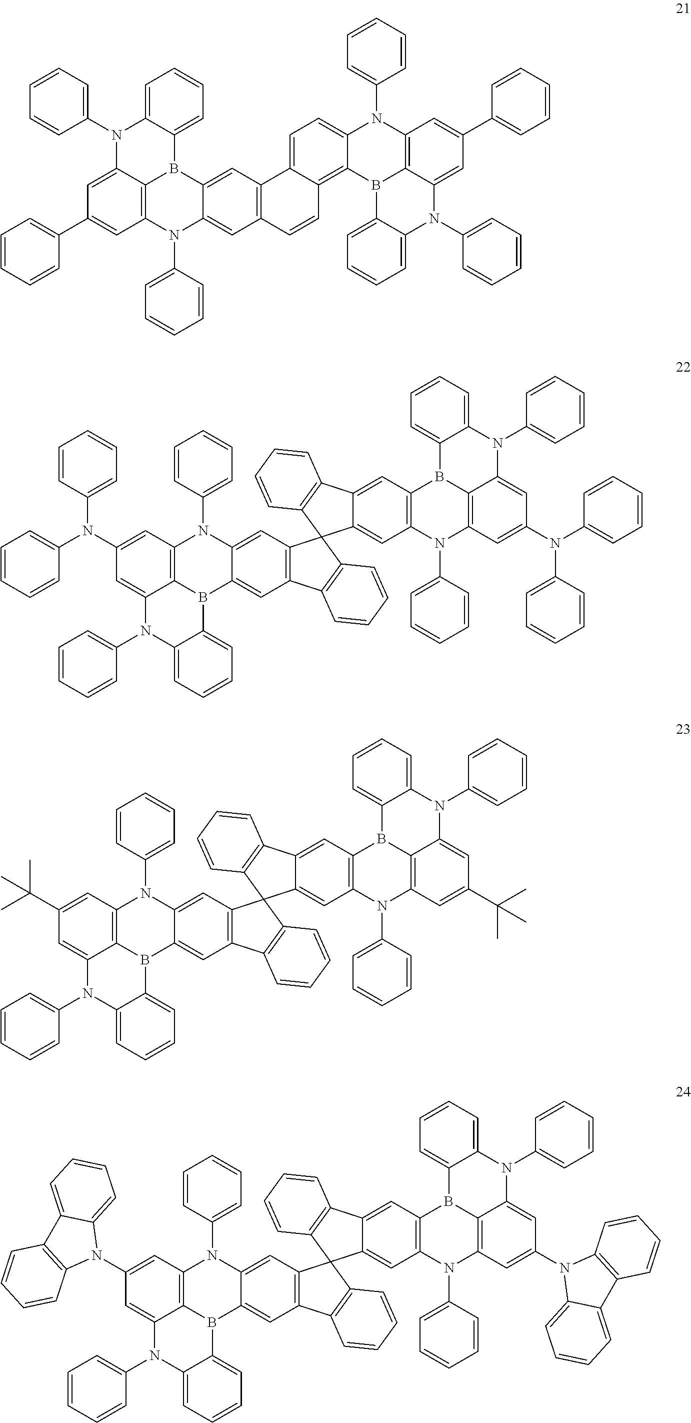 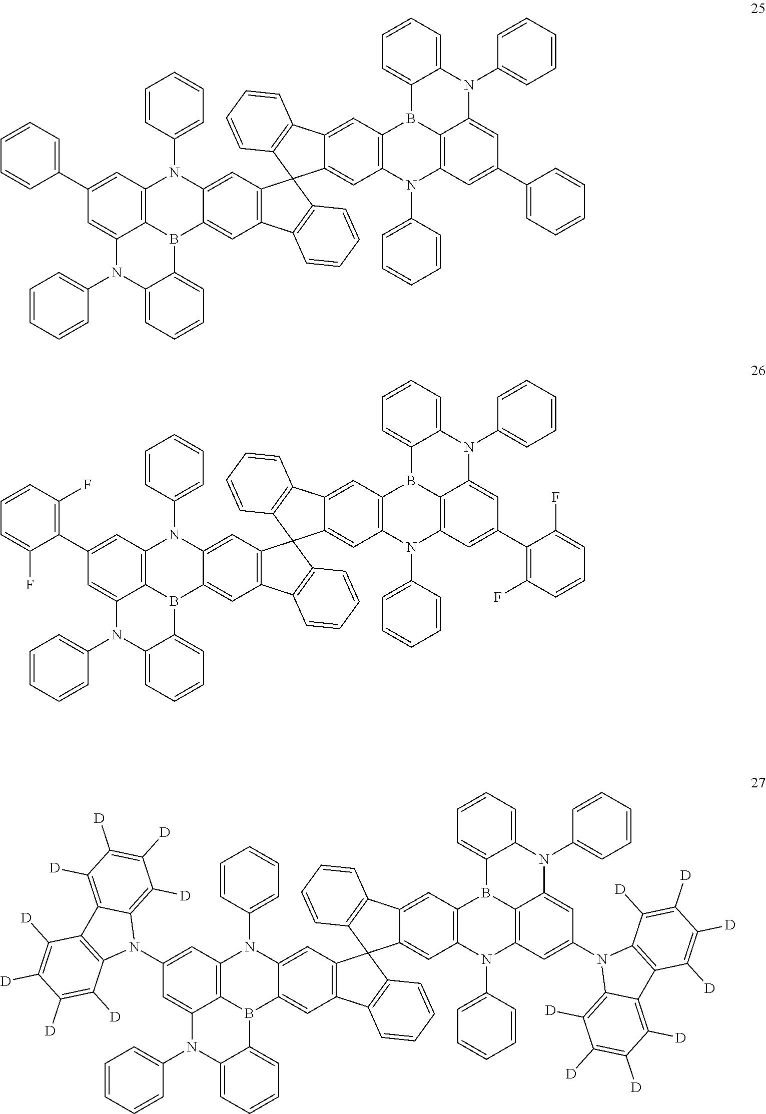 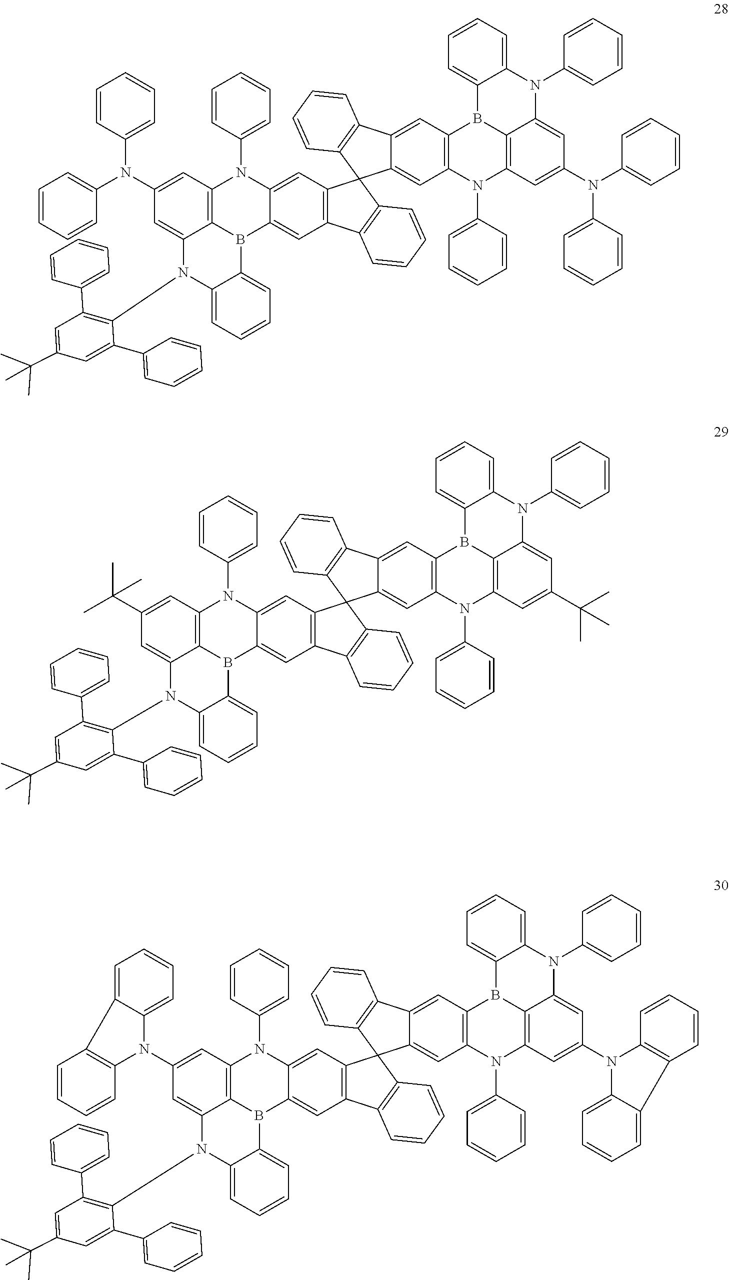 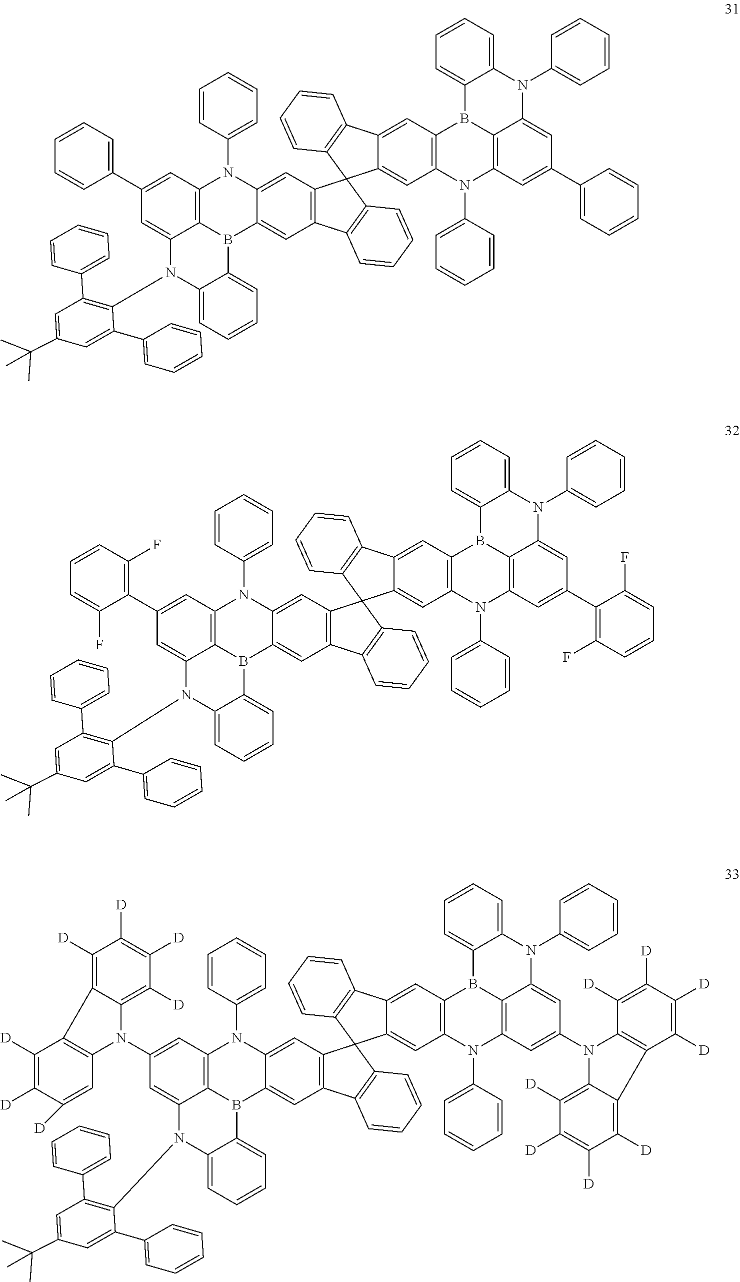 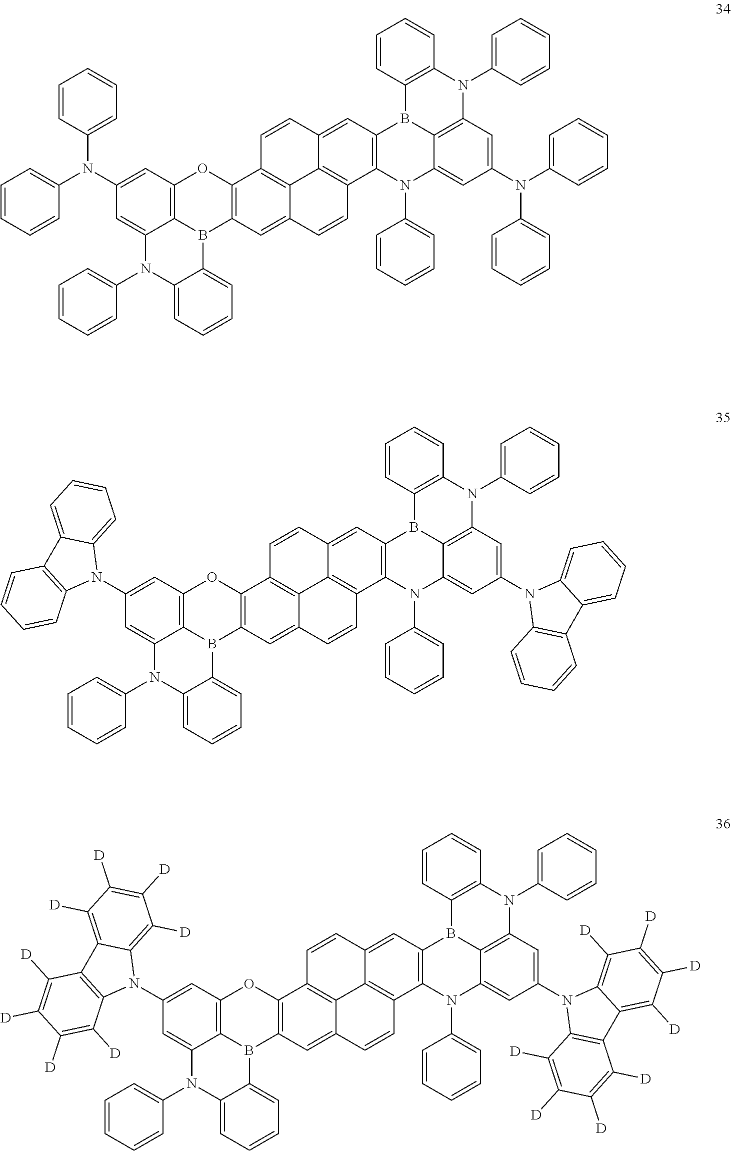 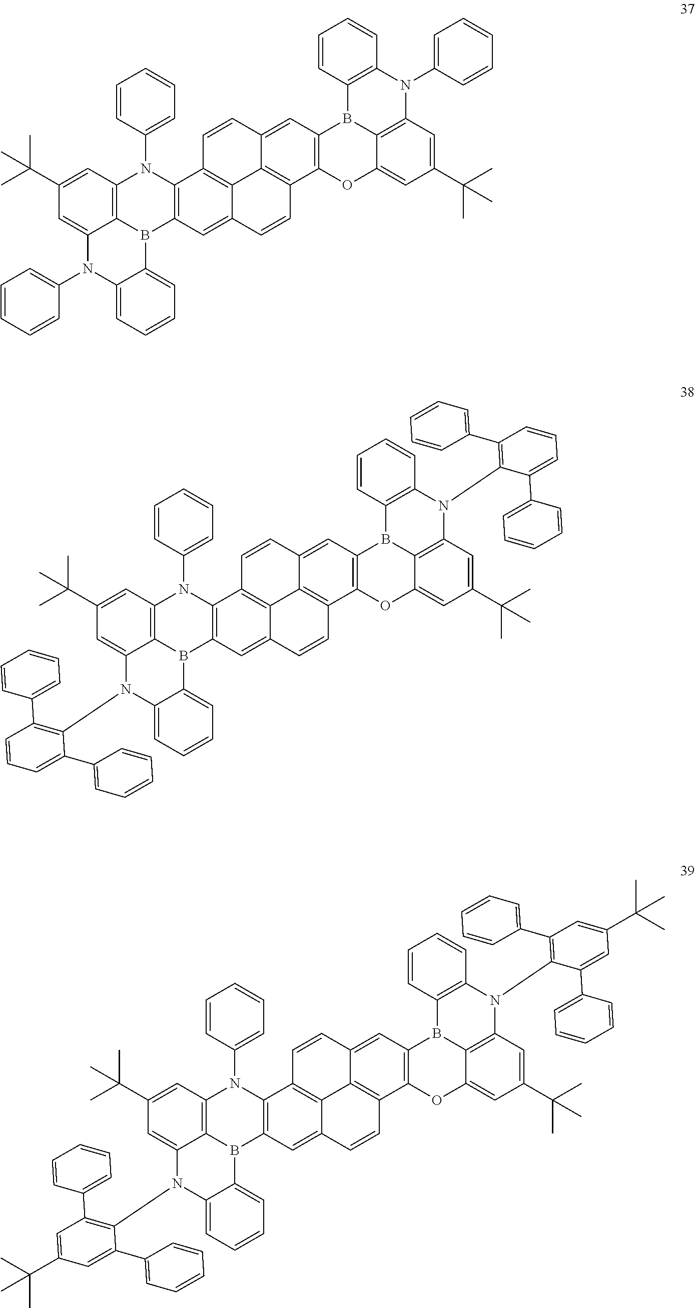 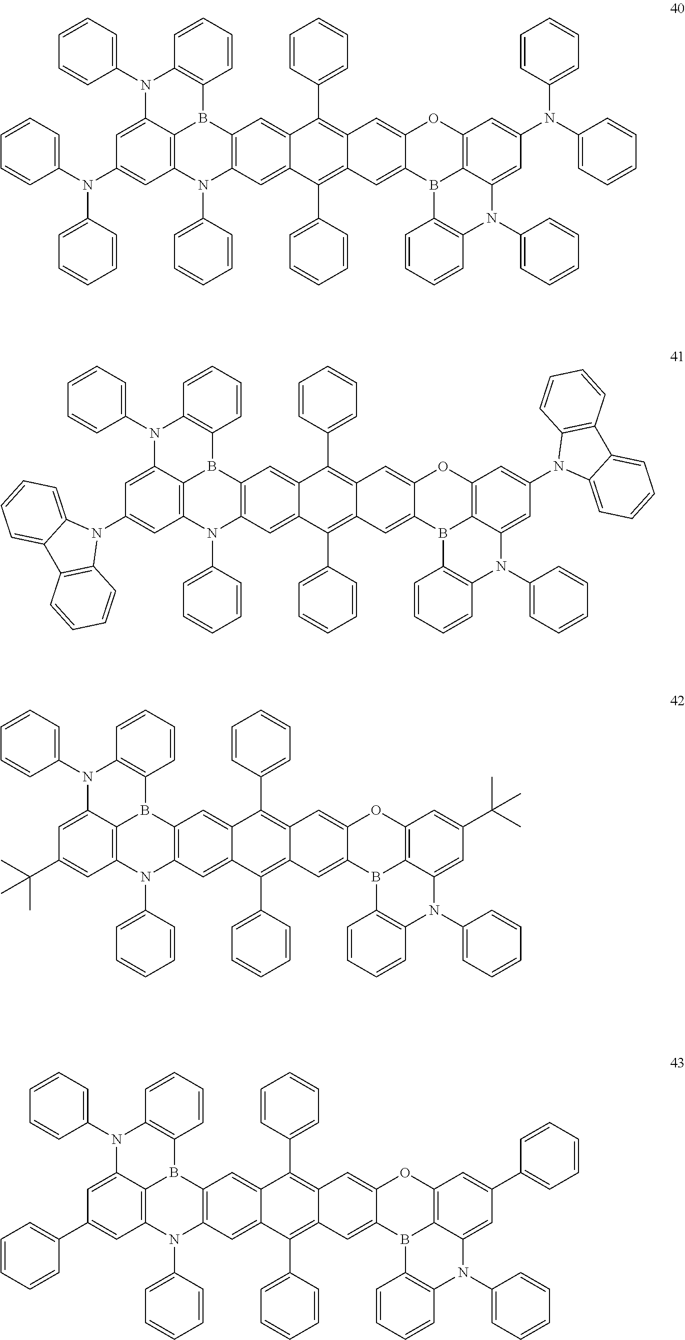 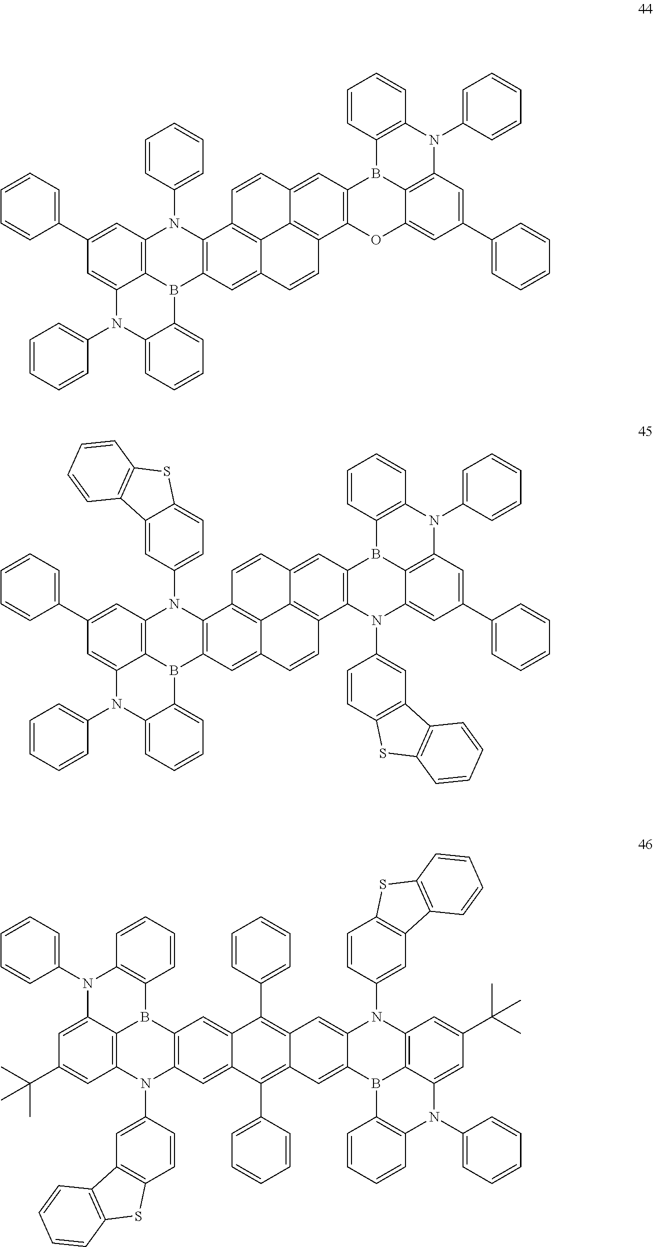 [SMILES: c1ccc(-c2cc3c4c(c2)N(c2ccccc2)c2ccccc2B4c2cc4ccc5c6c(cc7ccc(c2O3)c4c75)B2c3ccccc3N(c3ccccc3)c3cc(-c4ccccc4)cc(c32)N6c2ccccc2)cc1 ; c1ccc(-c2cc3c4c(c2)N(c2ccc5sc6ccccc6c5c2)c2c(cc5ccc6c7c(cc8ccc2c5c86)B2c5ccccc5N(c5ccccc5)c5cc(-c6ccccc6)cc(c52)N7c2ccc5sc6ccccc6c5c2)B4c2ccccc2N3c2ccccc2)cc1 ; CC(C)(C)c1cc2c3c(c1)N(c1ccc4sc5ccccc5c4c1)c1cc4c(-c5ccccc5)c5cc6c(cc5c(-c5ccccc5)c4cc1B3c1ccccc1N2c1ccccc1)N(c1ccc2sc3ccccc3c2c1)c1cc(C(C)(C)C)cc2c1B6c1ccccc1N2c1ccccc1] 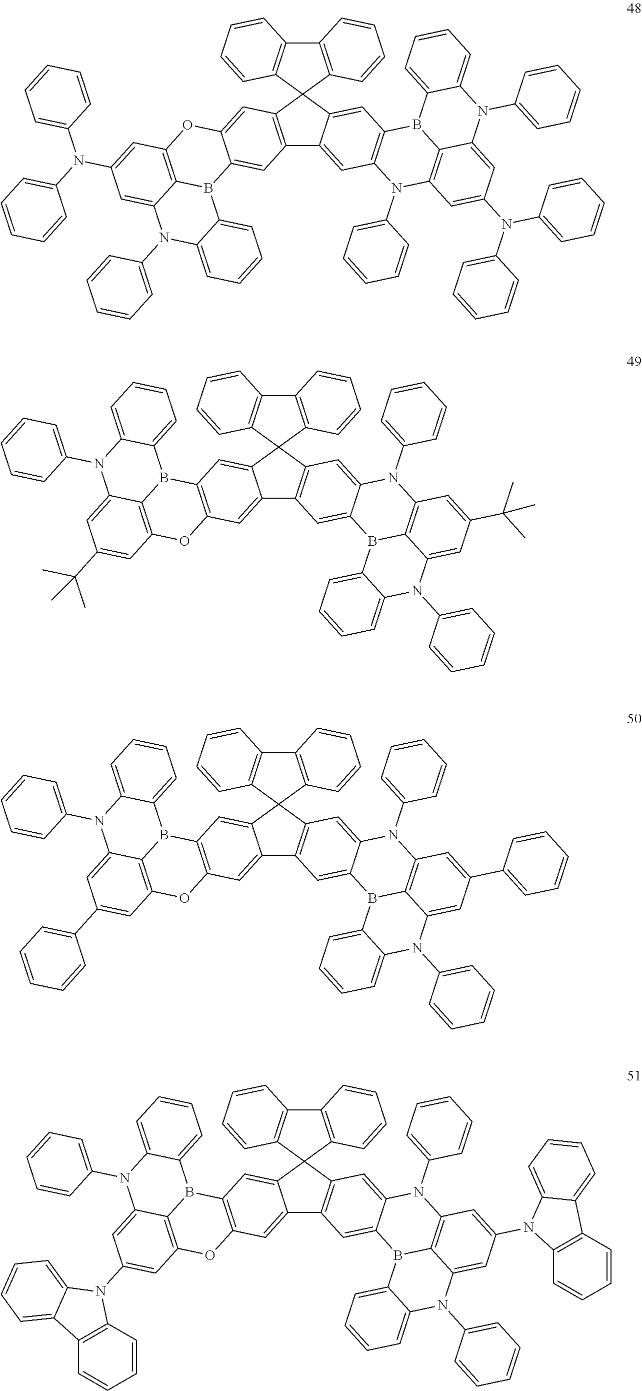 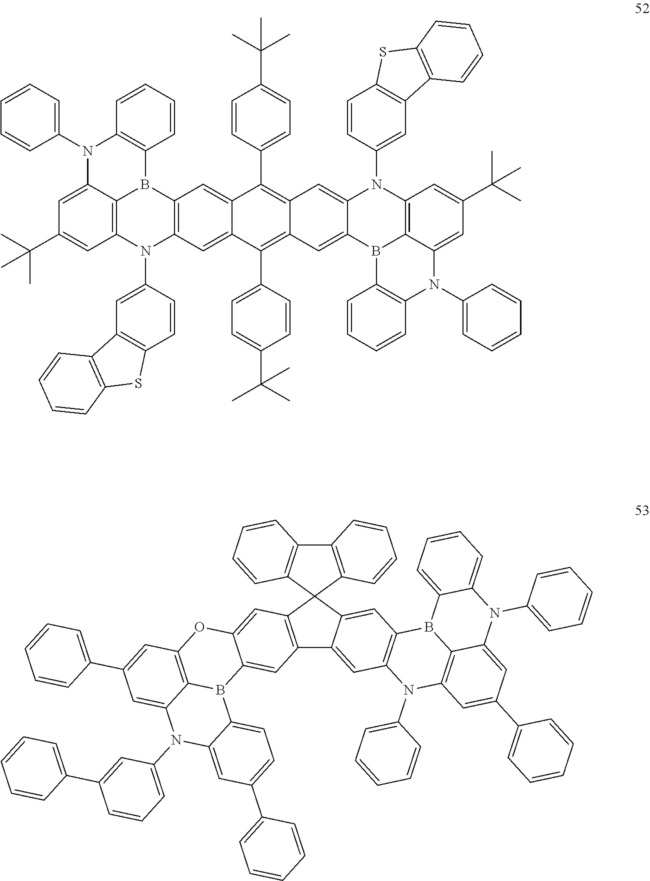 [SMILES: CC(C)(C)c1ccc(-c2c3cc4c(cc3c(-c3ccc(C(C)(C)C)cc3)c3cc5c(cc23)N(c2ccc3sc6ccccc6c3c2)c2cc(C(C)(C)C)cc3c2B5c2ccccc2N3c2ccccc2)N(c2ccc3sc5ccccc5c3c2)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5Oc5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1] 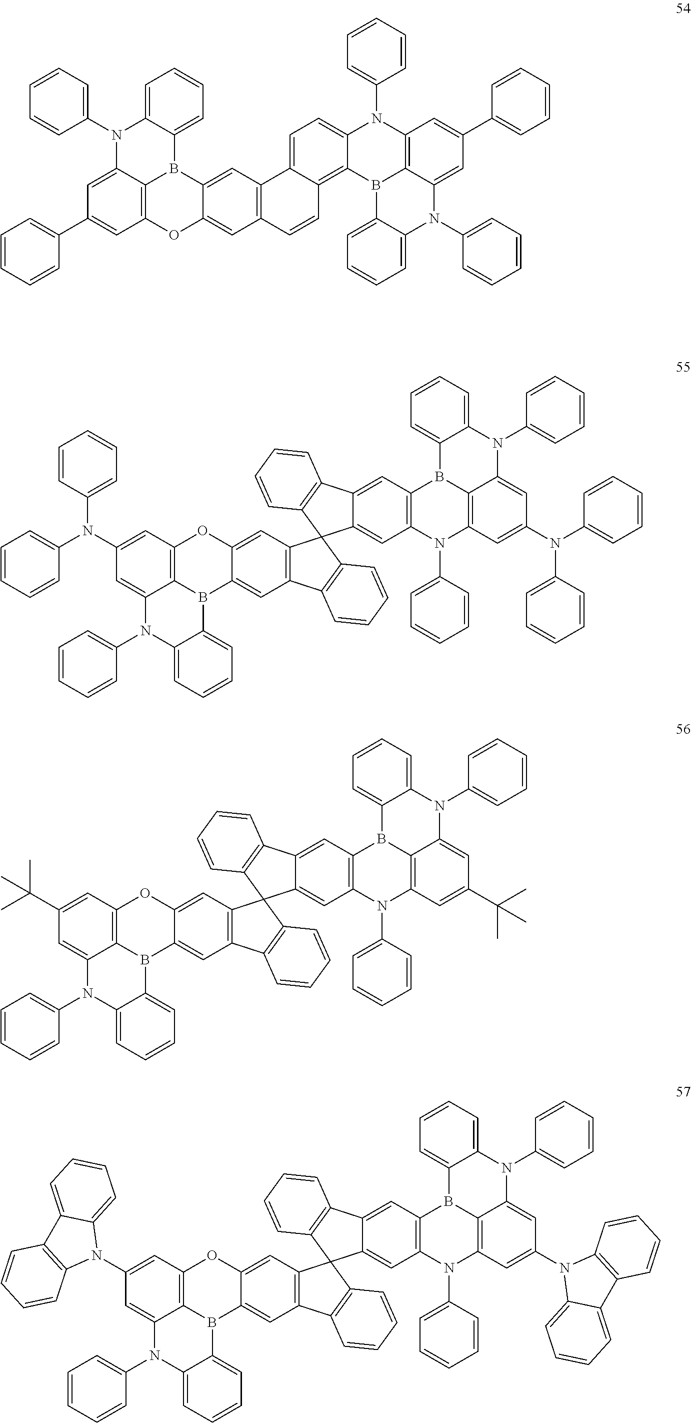 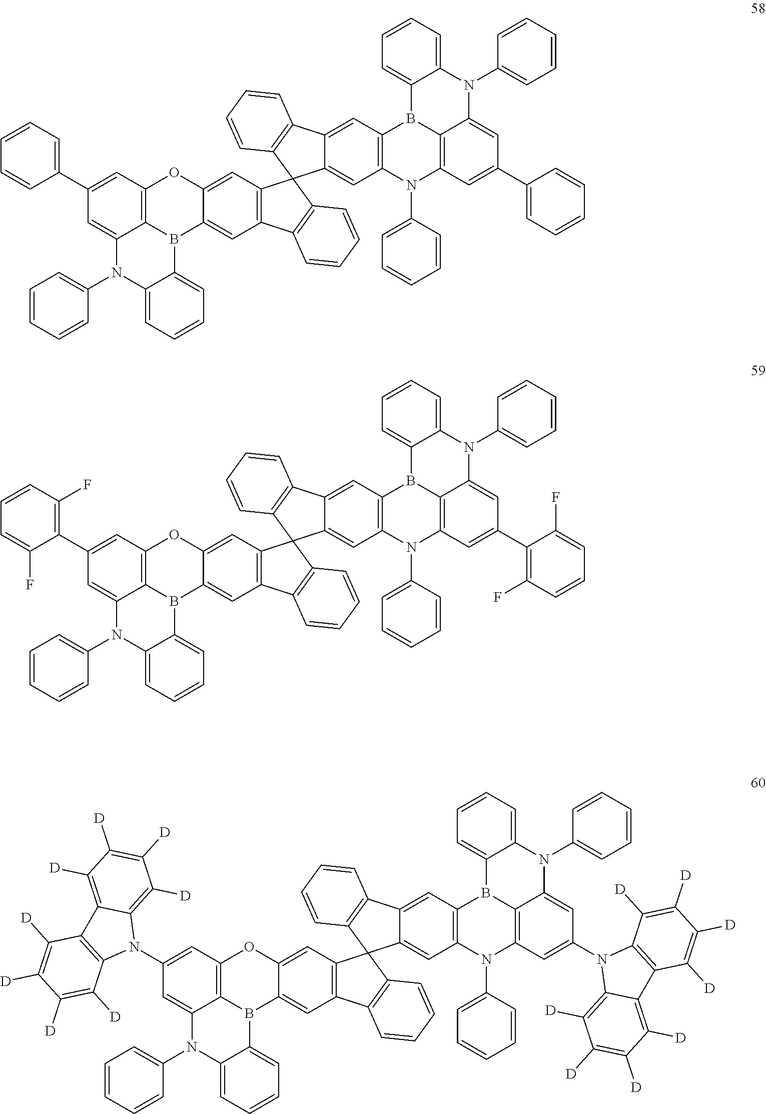 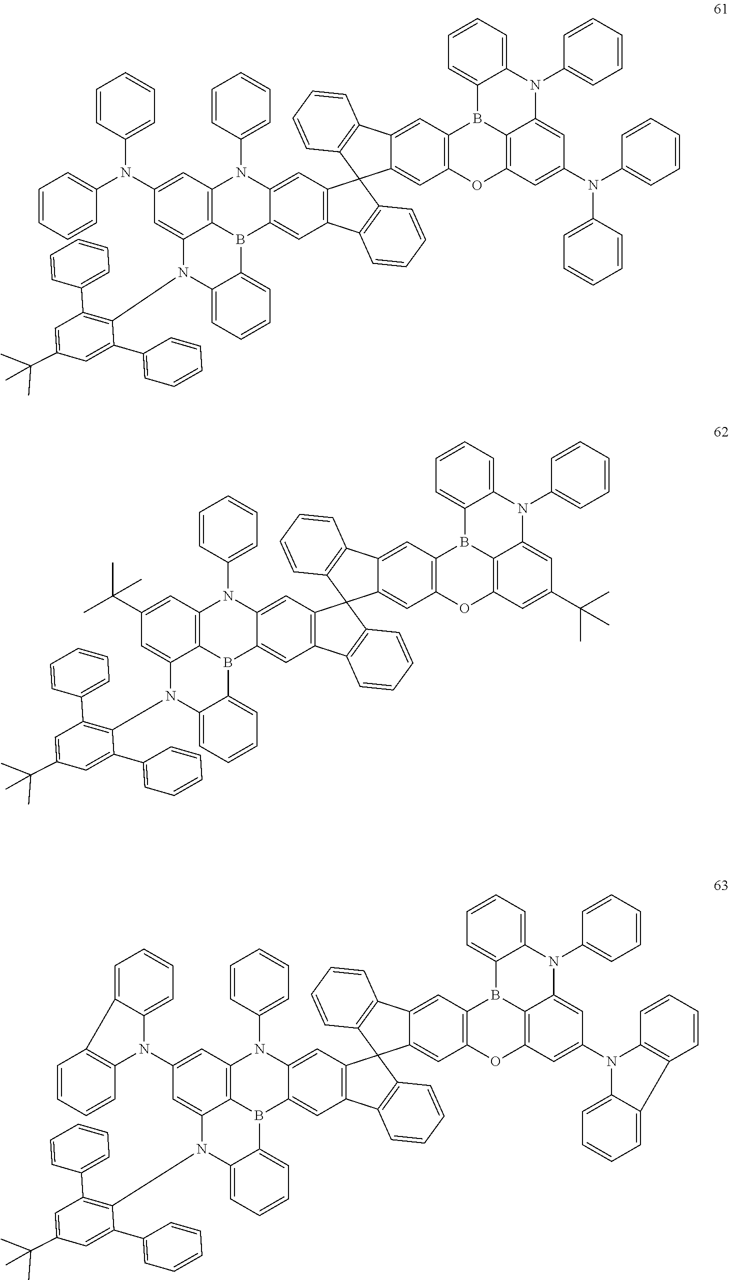 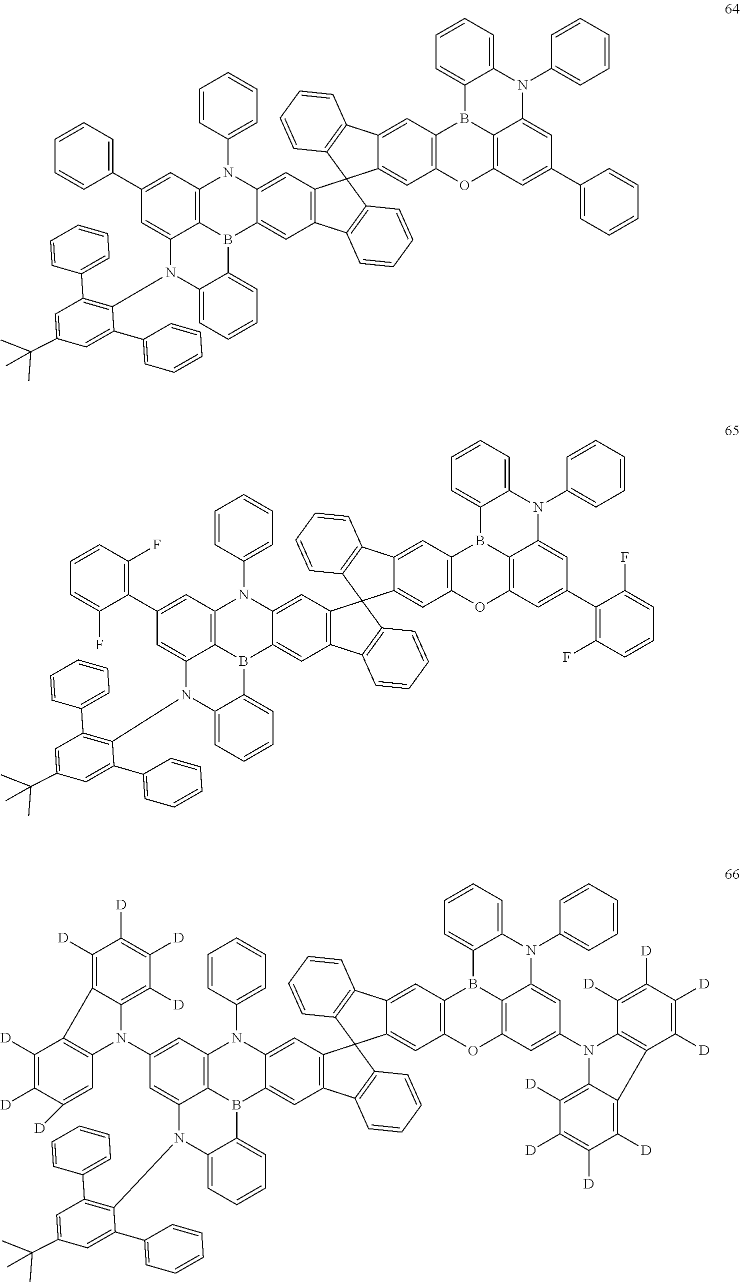 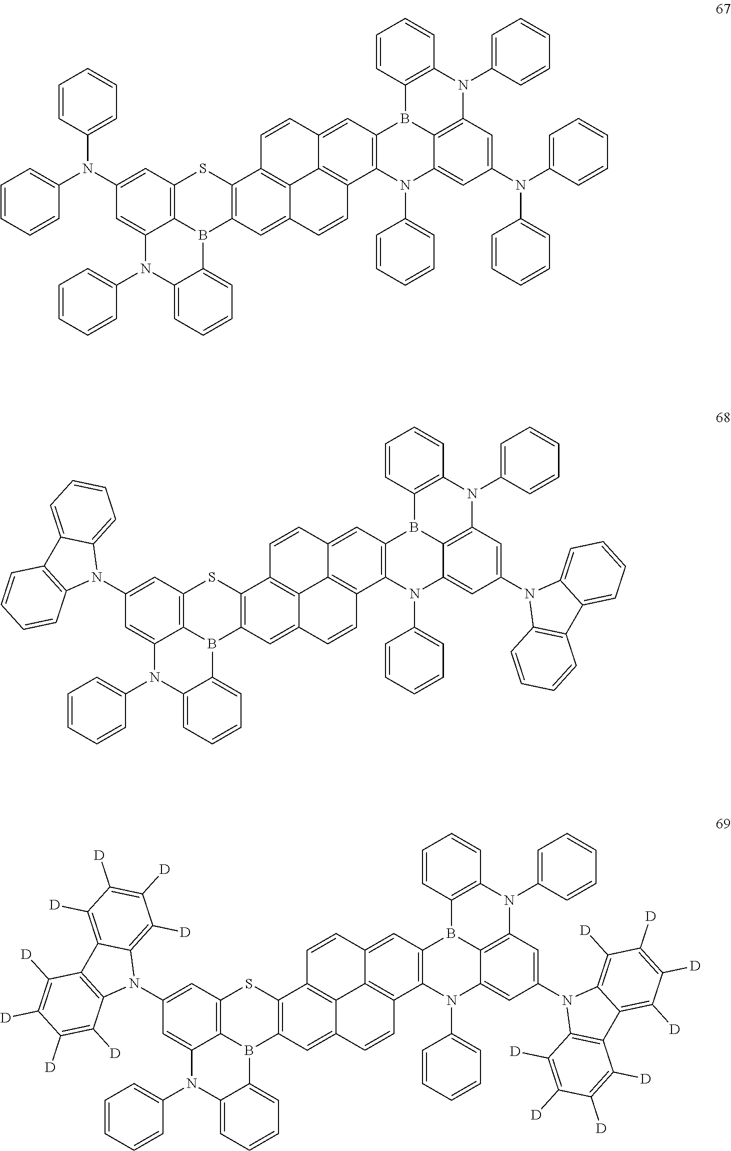 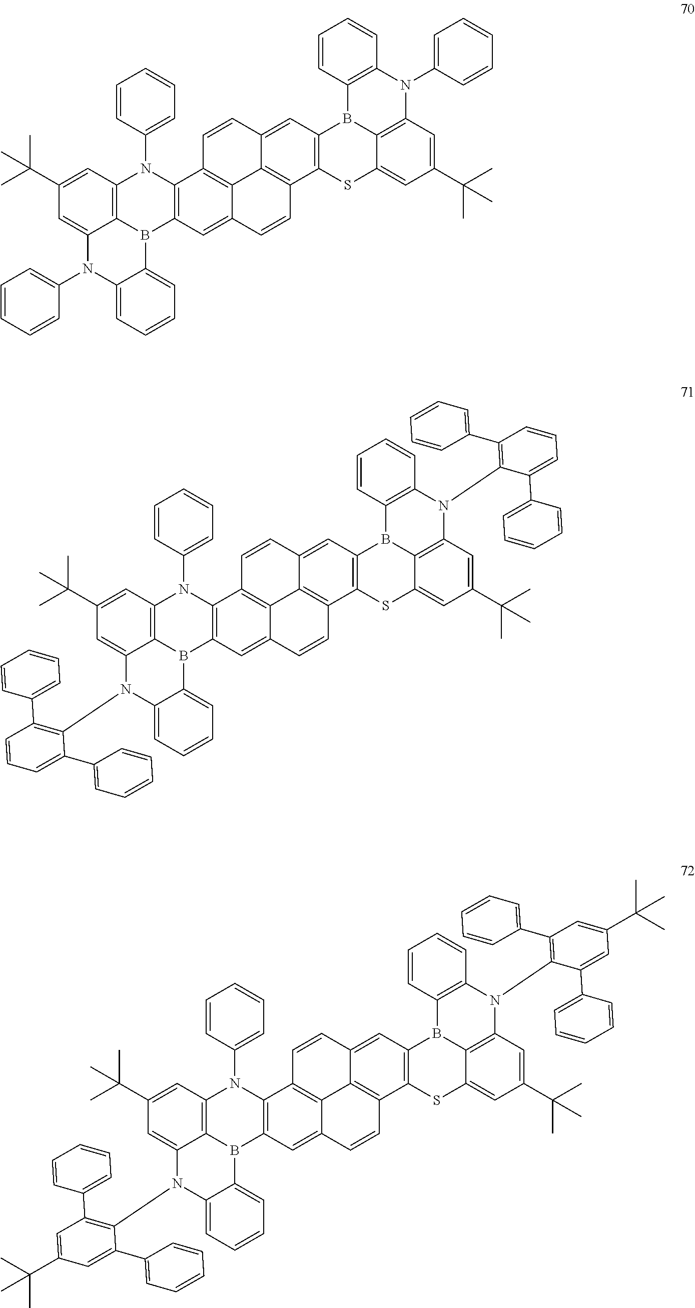 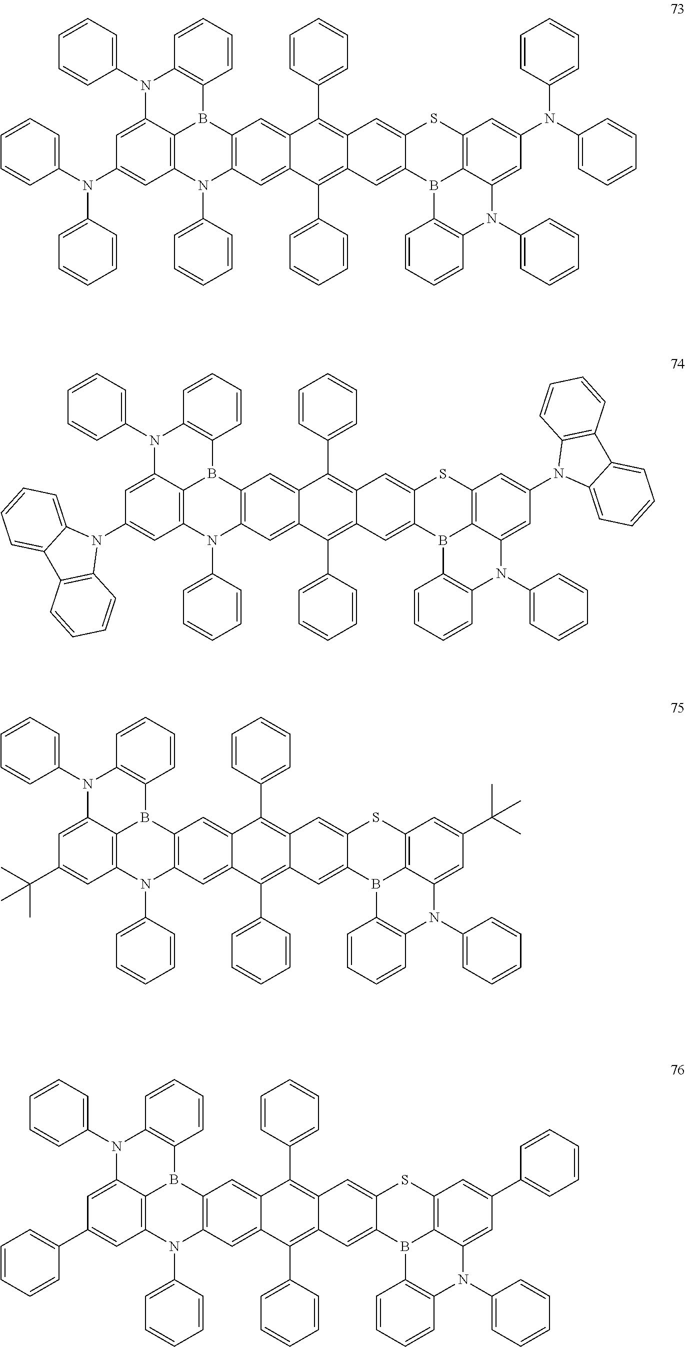 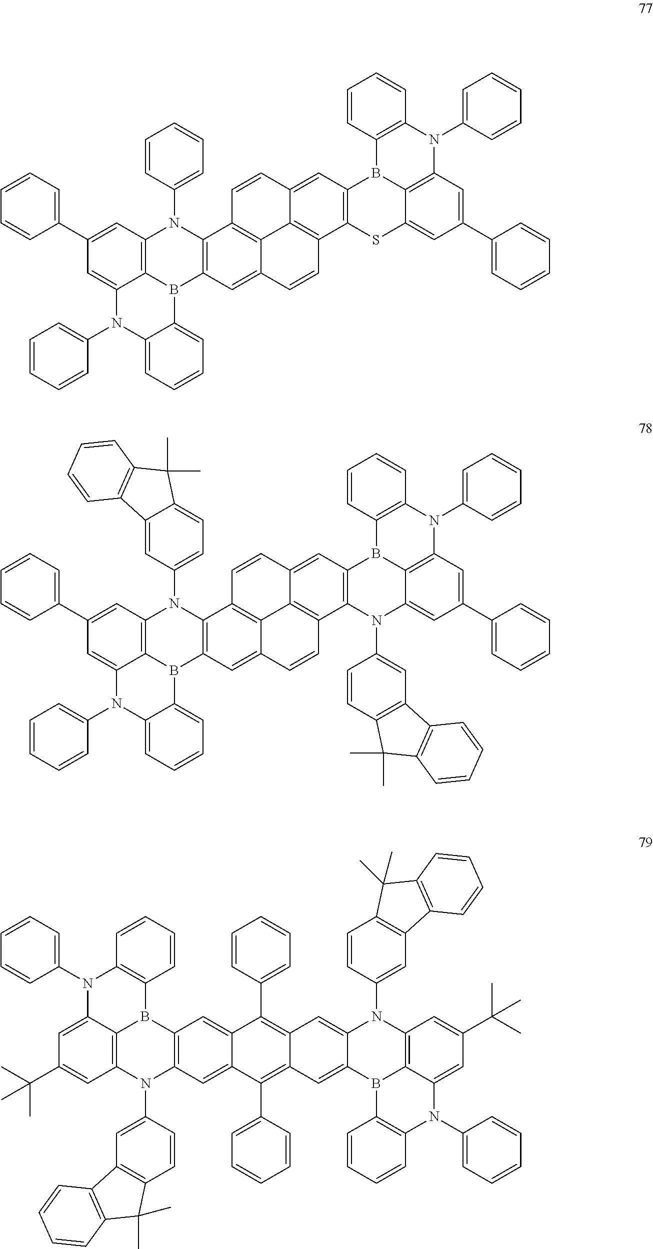 [SMILES: c1ccc(-c2cc3c4c(c2)N(c2ccccc2)c2ccccc2B4c2cc4ccc5c6c(cc7ccc(c2S3)c4c75)B2c3ccccc3N(c3ccccc3)c3cc(-c4ccccc4)cc(c32)N6c2ccccc2)cc1 ; CC1(C)c2ccccc2-c2cc(N3c4cc(-c5ccccc5)cc5c4B(c4ccccc4N5c4ccccc4)c4cc5ccc6c7c(cc8ccc(c43)c5c86)B3c4ccccc4N(c4ccccc4)c4cc(-c5ccccc5)cc(c43)N7c3ccc4c(c3)-c3ccccc3C4(C)C)ccc21 ; CC(C)(C)c1cc2c3c(c1)N(c1ccc4c(c1)-c1ccccc1C4(C)C)c1cc4c(-c5ccccc5)c5cc6c(cc5c(-c5ccccc5)c4cc1B3c1ccccc1N2c1ccccc1)N(c1ccc2c(c1)-c1ccccc1C2(C)C)c1cc(C(C)(C)C)cc2c1B6c1ccccc1N2c1ccccc1] 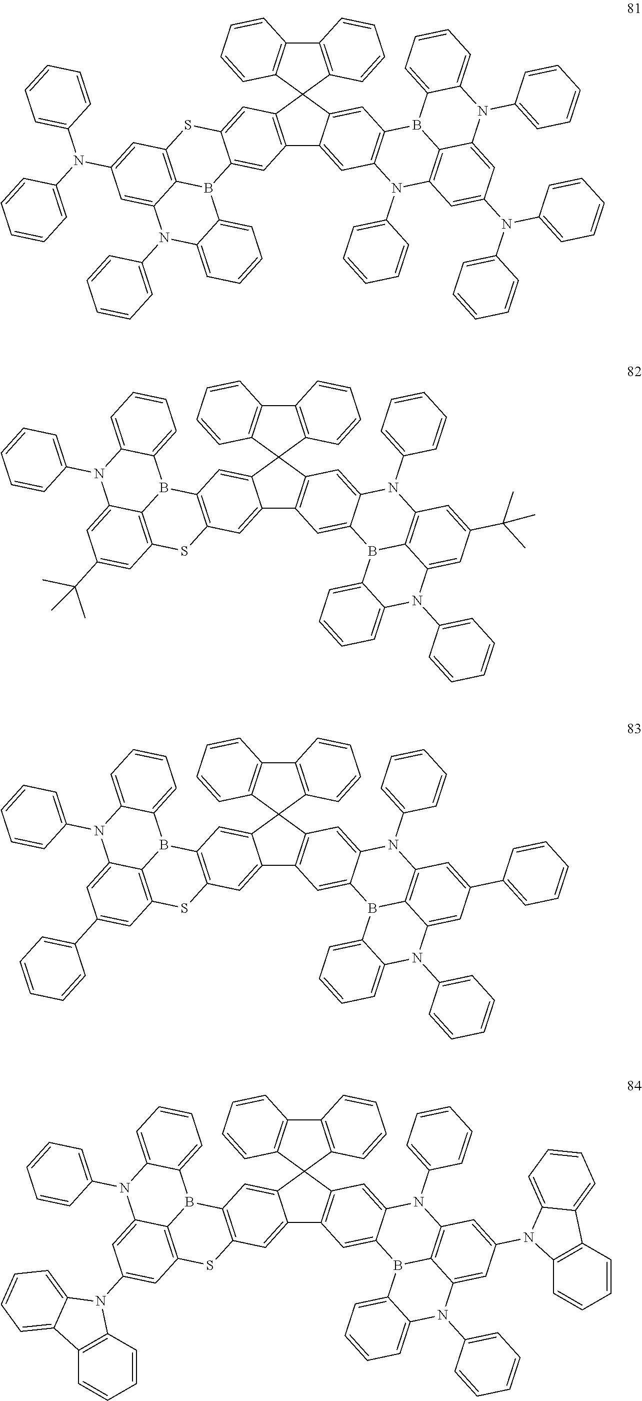 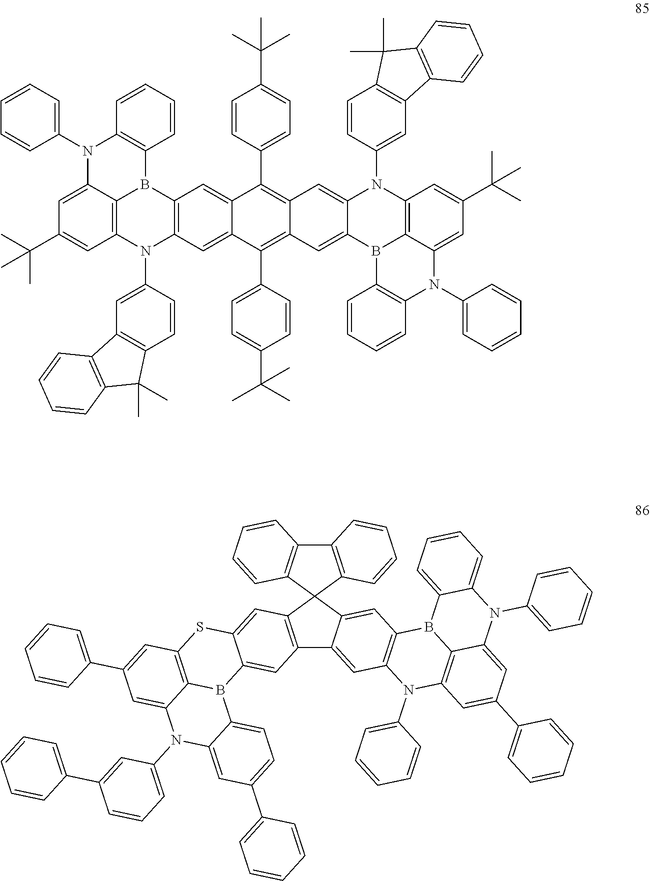 [SMILES: CC(C)(C)c1ccc(-c2c3cc4c(cc3c(-c3ccc(C(C)(C)C)cc3)c3cc5c(cc23)N(c2ccc3c(c2)-c2ccccc2C3(C)C)c2cc(C(C)(C)C)cc3c2B5c2ccccc2N3c2ccccc2)N(c2ccc3c(c2)-c2ccccc2C3(C)C)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5Sc5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1] 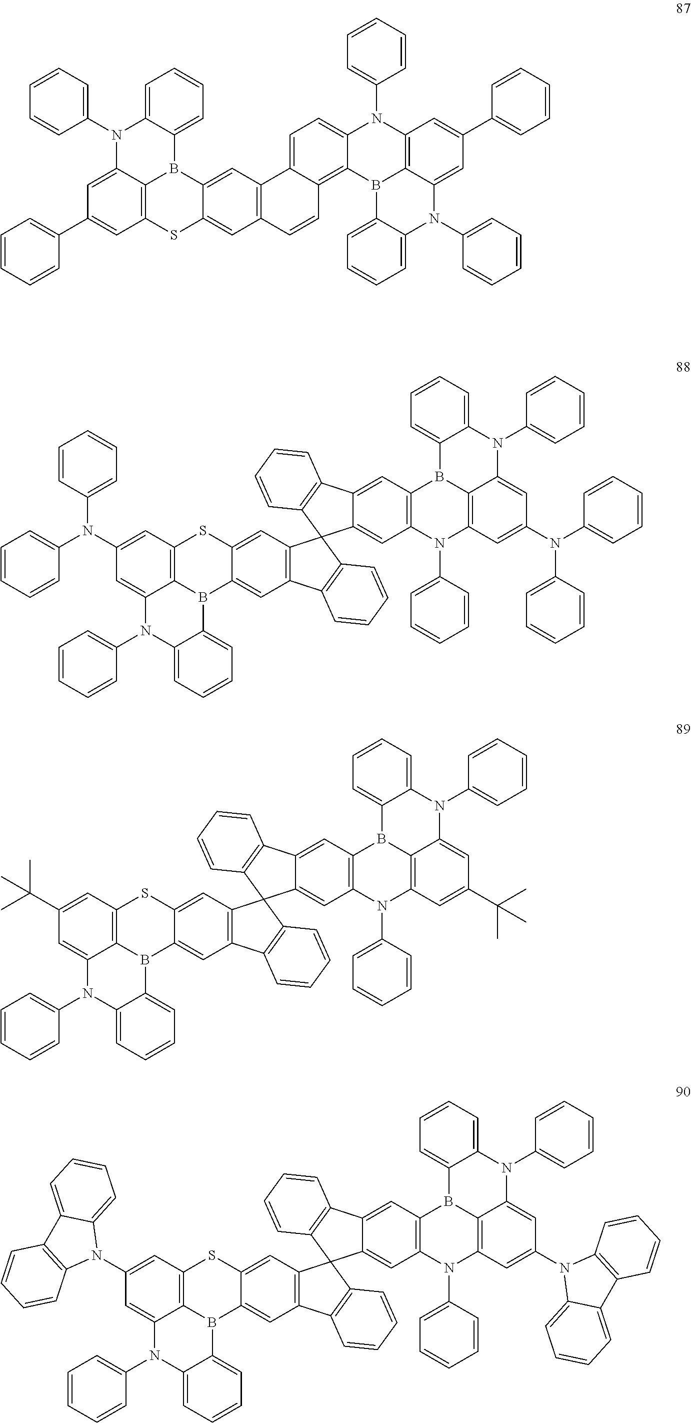 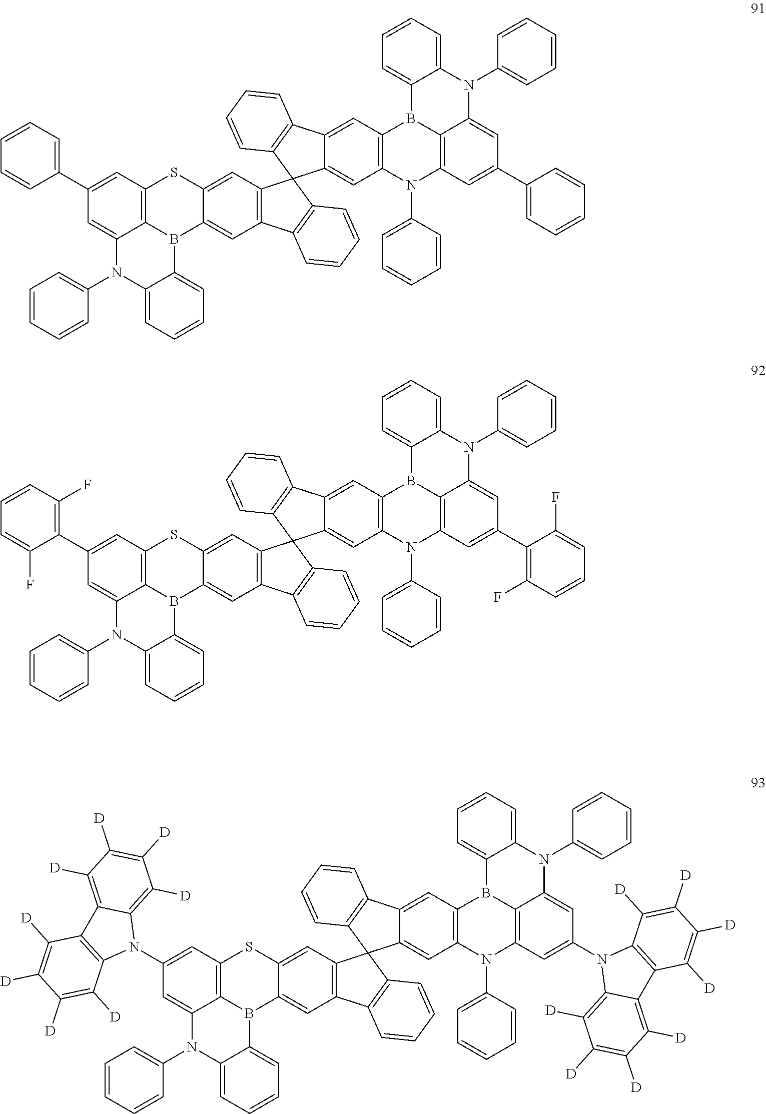 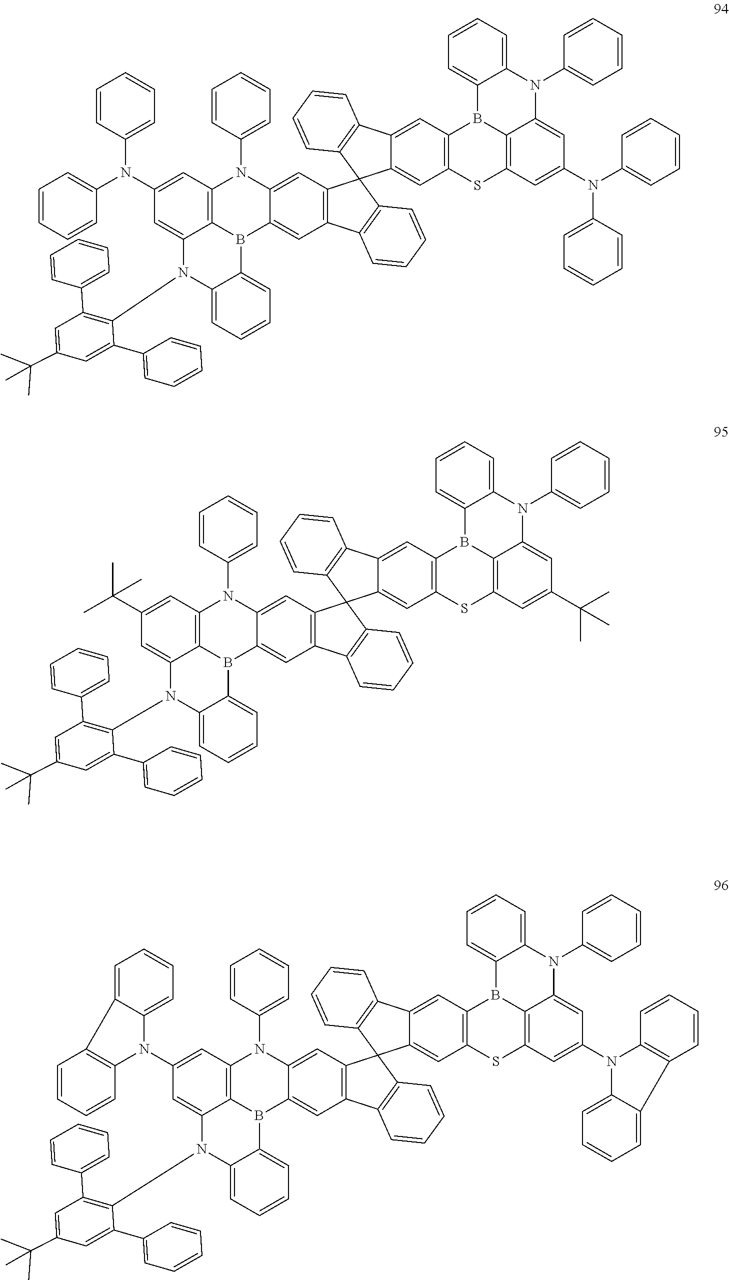 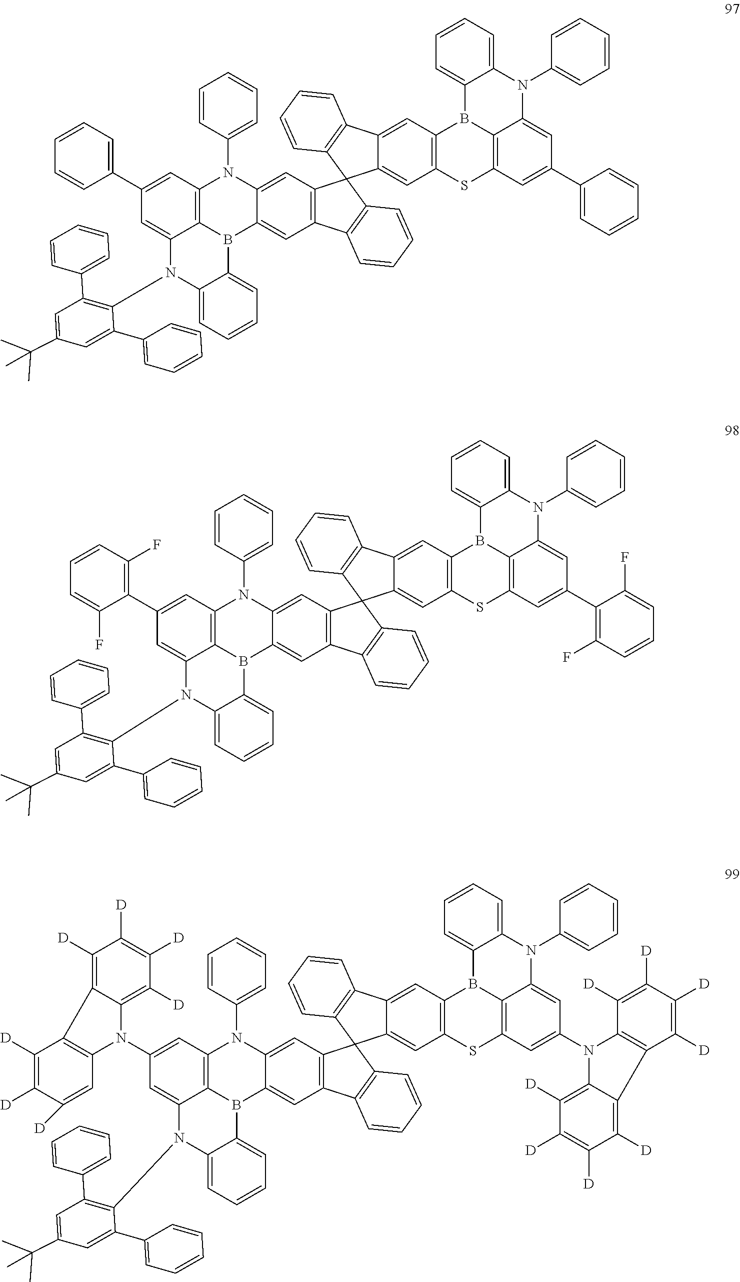
wherein in Compound Group 1,
D indicates a deuterium atom.

14. A polycyclic compound represented by Formula 1: 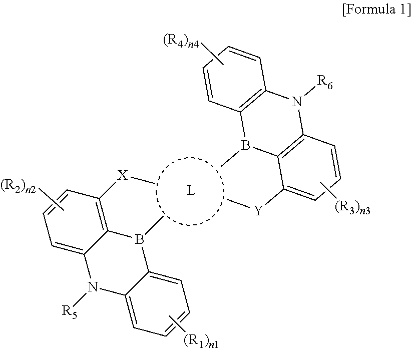
wherein in Formula 1,
L is a substituted or unsubstituted polycyclic aromatic hydrocarbon group of 12 to 25 ring-forming carbon atoms,
X and Y are each independently N(R₇), O, S, or Se,
R₁ to R₄ are each independently a hydrogen atom, a deuterium atom, a halogen atom, a cyano group, a nitro group, a substituted or unsubstituted silyl group, a substituted or unsubstituted amine group, a substituted or unsubstituted alkyl group of 1 to 60 carbon atoms, a substituted or unsubstituted alkoxy group of 1 to 60 carbon atoms, a substituted or unsubstituted cycloalkyl group of 3 to 60 ring-forming carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms,
R₅ to R₇ are each independently a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms,
n1 and n4 are each independently an integer from 0 to 4, and
n2 and n3 are each independently an integer from 0 to 3.

15. The polycyclic compound of claim 14, wherein L is a substituted or unsubstituted pyrenyl group, a substituted or unsubstituted anthracenyl group, a substituted or unsubstituted phenanthryl group, or a substituted or unsubstituted fluorenyl group.

16. The polycyclic compound of claim 15, wherein the polycyclic compound represented by Formula 1 is represented by one of Formula 2-1 to Formula 2-5: 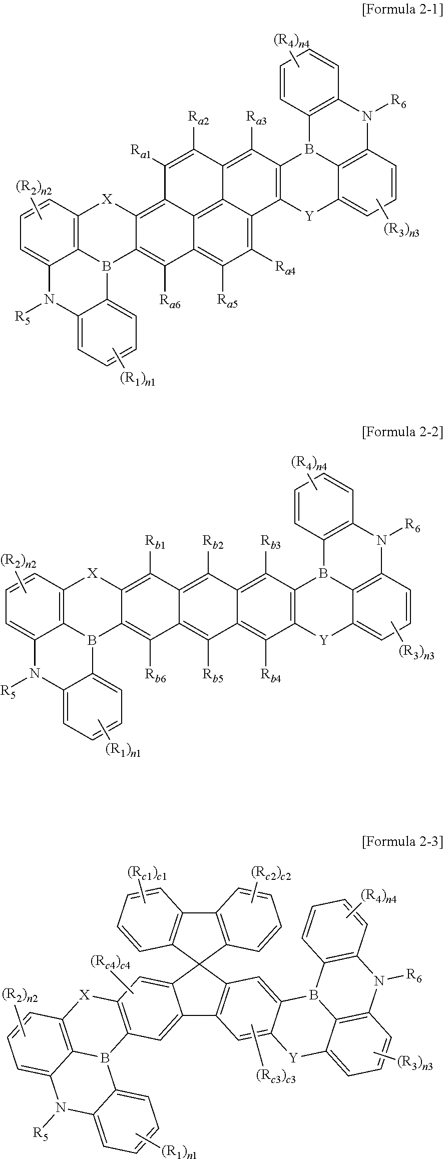 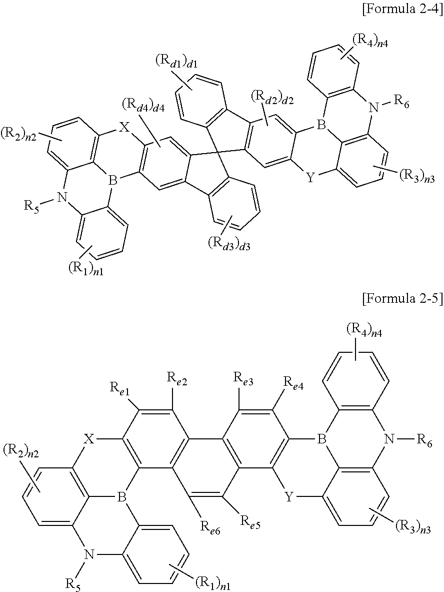
wherein in Formula 2-1 to Formula 2-5,
Rₐ₁ to Rₐ₆, R_{b1} to R_{b6}, R_{c1} to R_{c4}, R_{d1} to R_{d4}, and Rₑ₁ to Rₑ₆ are each independently a hydrogen atom, a deuterium atom, or a substituted or unsubstituted aryl group of 6 to 15 ring-forming carbon atoms,
c1, c2, d1, and d3 are each independently an integer from 0 to 4,
c3, c4, d2, and d4 are each independently an integer from 0 to 2, and
X, Y, R₁ to R₆, and n1 to n4 are the same as defined in Formula 1.

17. The polycyclic compound of claim 16, wherein the polycyclic compound represented by Formula 2-1 is represented by Formula 2-1A: 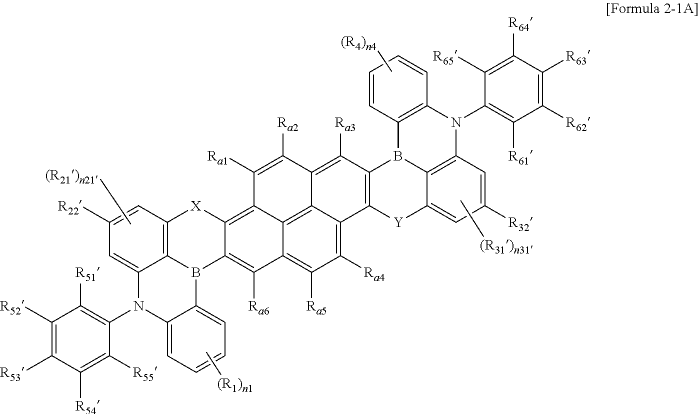
wherein in Formula 2-1A,
R₂₁′ and R₃₁′ are each independently a hydrogen atom or a deuterium atom,
R₂₂′ and R₃₂′ are each independently a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms,
R₅₁′ to R₅₅′ and R₆₁′ to R₆₅′ are each independently a hydrogen atom, a deuterium atom, a substituted or unsubstituted alkyl group of 1 to 10 carbon atoms, or a substituted or unsubstituted aryl group of 6 to 10 ring-forming carbon atoms,
n21′ and n31′ are each independently an integer from 0 to 2, and
R₁, R₄, Rₐ₁ to Rₐ₆, n1, n4, X, and Y are the same as defined in Formula 1 and Formula 2-1.

18. The polycyclic compound of claim 16, wherein the polycyclic compound represented by Formula 2-2 is represented by Formula 2-2A: 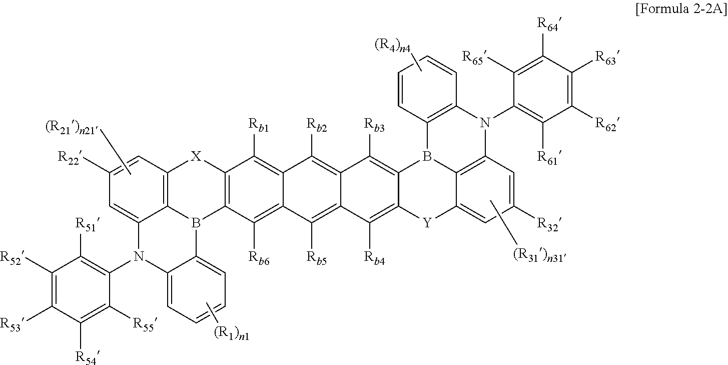
wherein in Formula 2-2A,
R₂₁′ and R₃₁′ are each independently a hydrogen atom or a deuterium atom,
R₂₂′ and R₃₂′ are each independently a hydrogen atom, a deuterium atom, a substituted or unsubstituted amine group, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms,
R₅₁′ to R₅₅′ and R₆₁′ to R₆₅′ are each independently a hydrogen atom, a deuterium atom, a substituted or unsubstituted alkyl group of 1 to 10 carbon atoms, or a substituted or unsubstituted aryl group of 6 to 10 ring-forming carbon atoms,
n21′ and n31′ are each independently an integer from 0 to 2, and
R₁, R₄, R_{b1} to R_{b6}, n1, n4, X, and Y are the same as defined in Formula 1 and Formula 2-2.

19. The polycyclic compound of claim 14, wherein the polycyclic compound represented by Formula 1 is represented by Formula 3: 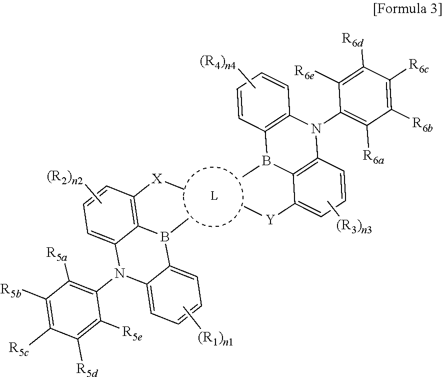
wherein in Formula 3,
R₅ₐ to R₅ₑ and R₆ₐ to R₆ₑ are each independently a hydrogen atom, a deuterium atom, a substituted or unsubstituted alkyl group of 1 to 10 carbon atoms, or a substituted or unsubstituted aryl group of 6 to 10 ring-forming carbon atoms, and
R₁ to R₄, n1 to n4, L, X, and Y are the same as defined in Formula 1.

20. The polycyclic compound of claim 14, wherein the polycyclic compound represented by Formula 1 is represented by Formula 4: 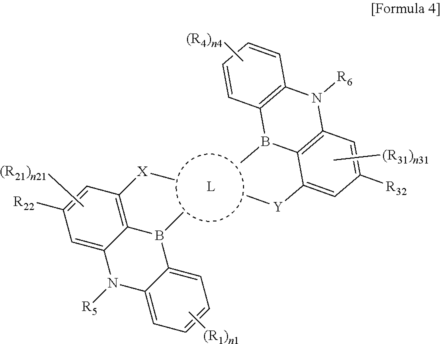
wherein in Formula 4,
R₂₁ and R₃₁ are each independently a hydrogen atom, or a deuterium atom,
R₂₂ and R₃₂ are each independently a hydrogen atom, a deuterium atom, a substituted or unsubstituted alkyl group of 1 to 10 carbon atoms, a substituted or unsubstituted aryl group of 6 to 15 ring-forming carbon atoms, or a substituted or unsubstituted heteroaryl group of 2 to 15 ring-forming carbon atoms,
n21 and n31 are each independently an integer from 0 to 2, and
R₁, R₄ to R₆, n1, n4, L, X, and Y are the same as defined in Formula 1.

21. The polycyclic compound of claim 14, wherein the polycyclic compound represented by Formula 1 is represented by one of Formula 5-1 to Formula 5-4: 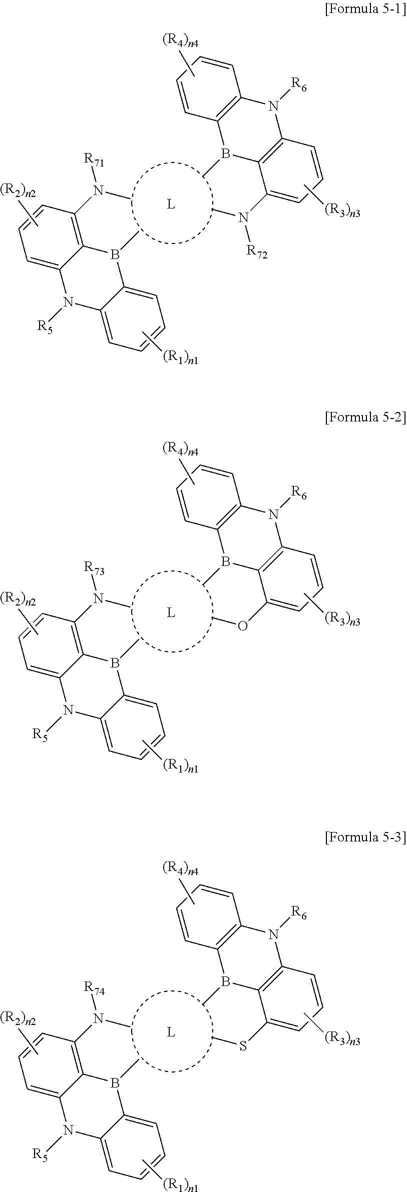 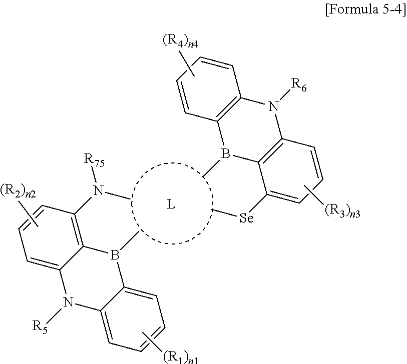
wherein in Formula 5-1 to Formula 5-4,
R₇₁ to R₇₅ are each independently a substituted or unsubstituted aryl group of 6 to 20 ring-forming carbon atoms or a substituted or unsubstituted heteroaryl group of 2 to 20 ring-forming carbon atoms, and
R₁ to R₆, n1 to n4, and L are the same as defined in Formula 1.

22. The polycyclic compound of claim 14, wherein at least one of X and Y is each independently N(R₇).

23. The polycyclic compound of claim 14, wherein the polycyclic compound represented by Formula 1 is selected from Compound Group 1: 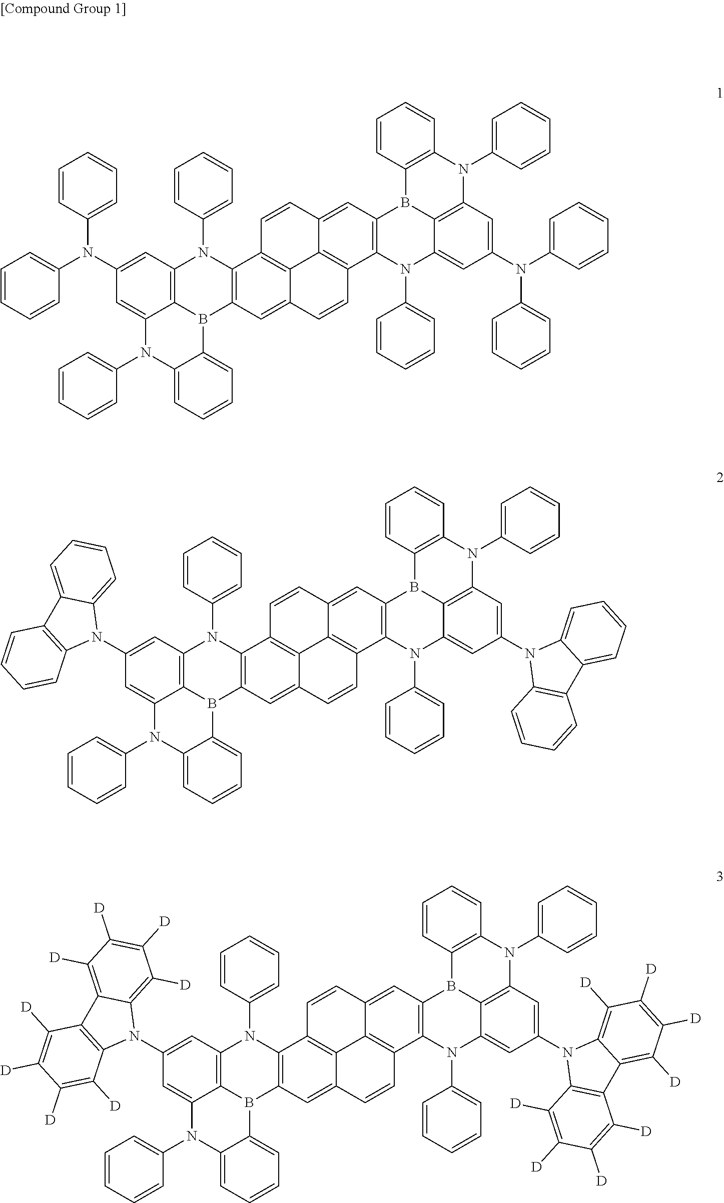 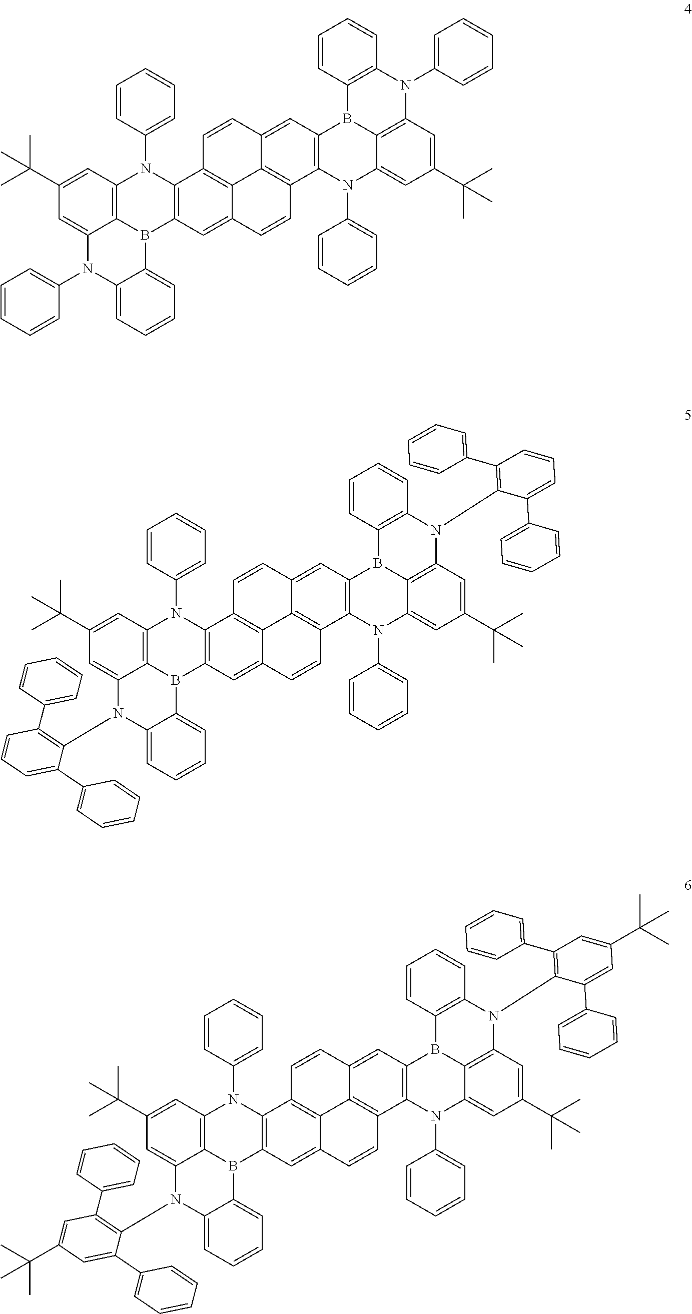 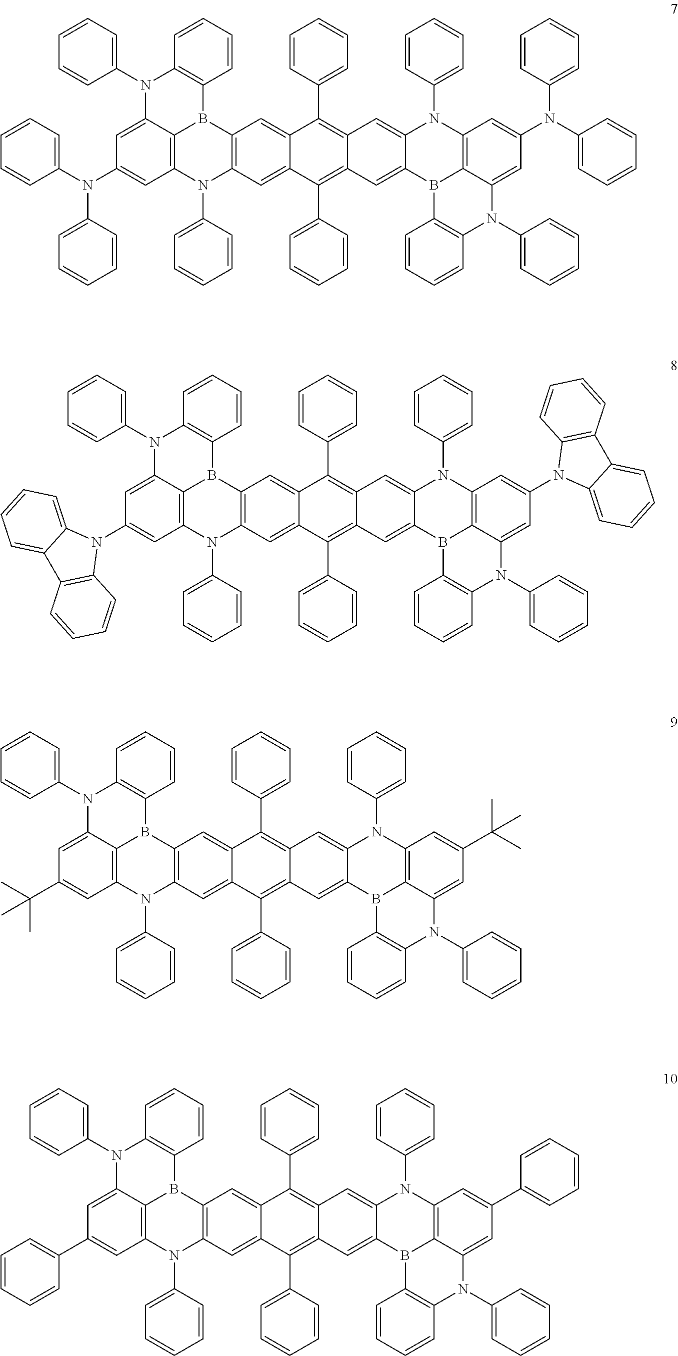 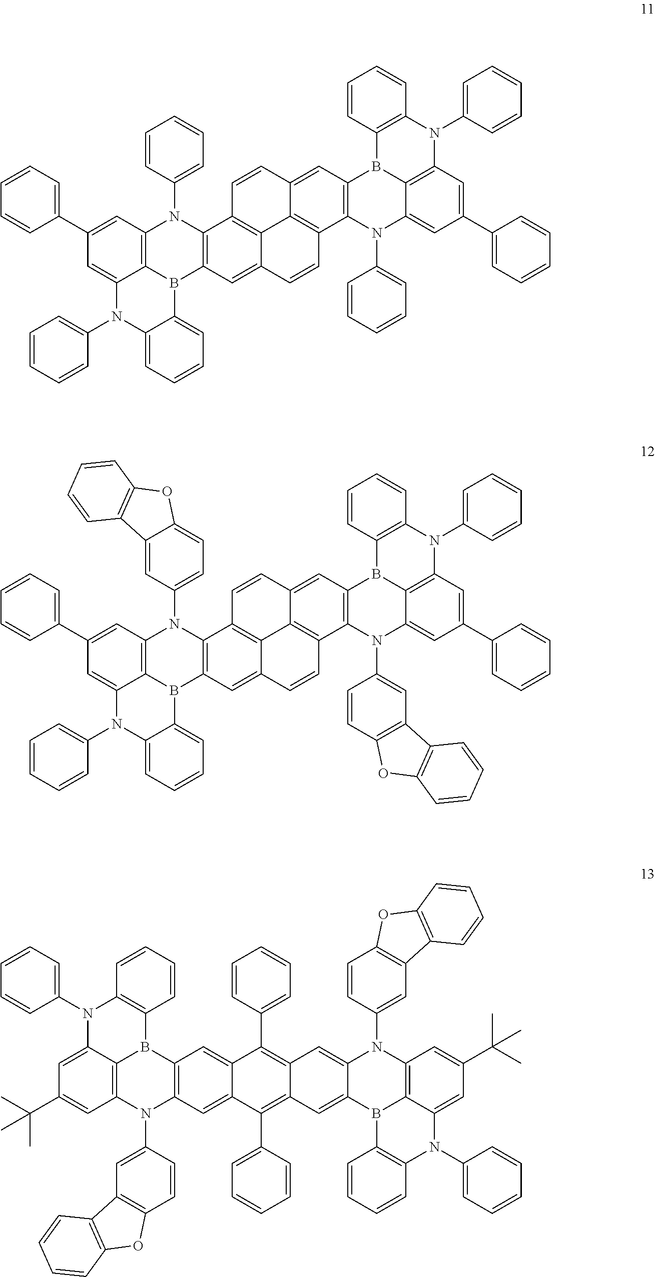 [SMILES: c1ccc(-c2cc3c4c(c2)N(c2ccccc2)c2c(cc5ccc6c7c(cc8ccc2c5c86)B2c5ccccc5N(c5ccccc5)c5cc(-c6ccccc6)cc(c52)N7c2ccccc2)B4c2ccccc2N3c2ccccc2)cc1 ; c1ccc(-c2cc3c4c(c2)N(c2ccc5oc6ccccc6c5c2)c2c(cc5ccc6c7c(cc8ccc2c5c86)B2c5ccccc5N(c5ccccc5)c5cc(-c6ccccc6)cc(c52)N7c2ccc5oc6ccccc6c5c2)B4c2ccccc2N3c2ccccc2)cc1 ; CC(C)(C)c1cc2c3c(c1)N(c1ccc4oc5ccccc5c4c1)c1cc4c(-c5ccccc5)c5cc6c(cc5c(-c5ccccc5)c4cc1B3c1ccccc1N2c1ccccc1)N(c1ccc2oc3ccccc3c2c1)c1cc(C(C)(C)C)cc2c1B6c1ccccc1N2c1ccccc1] 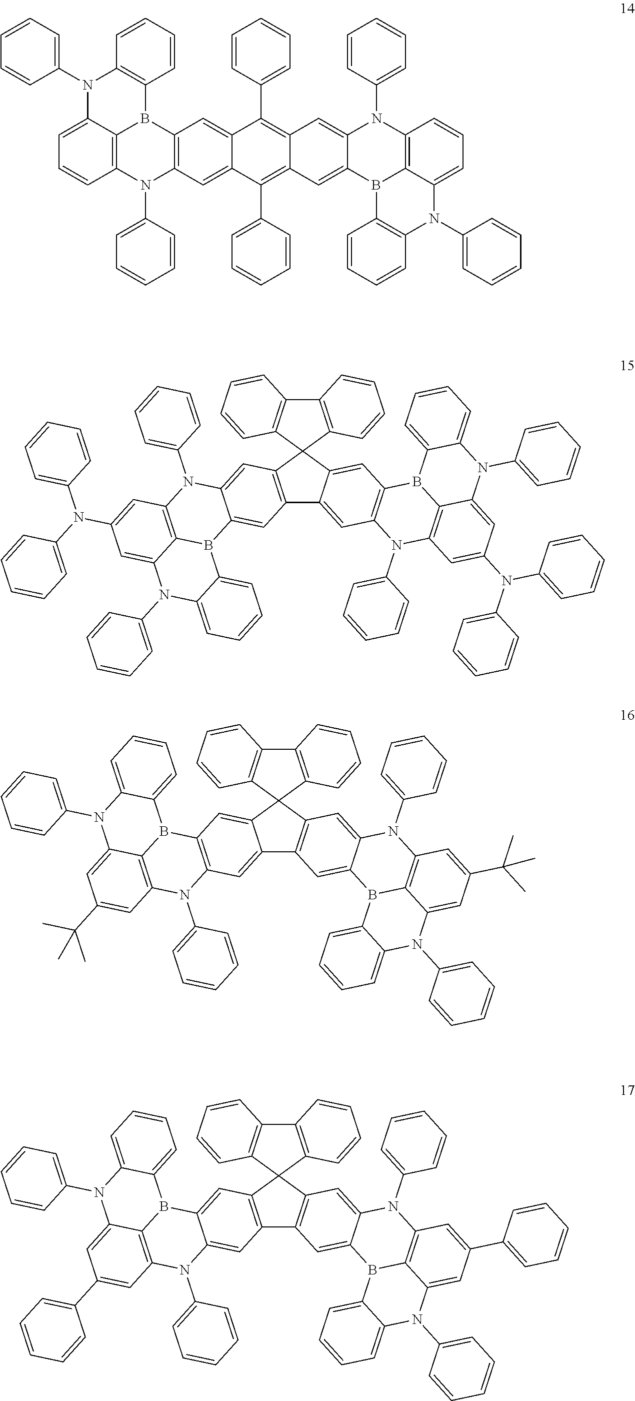 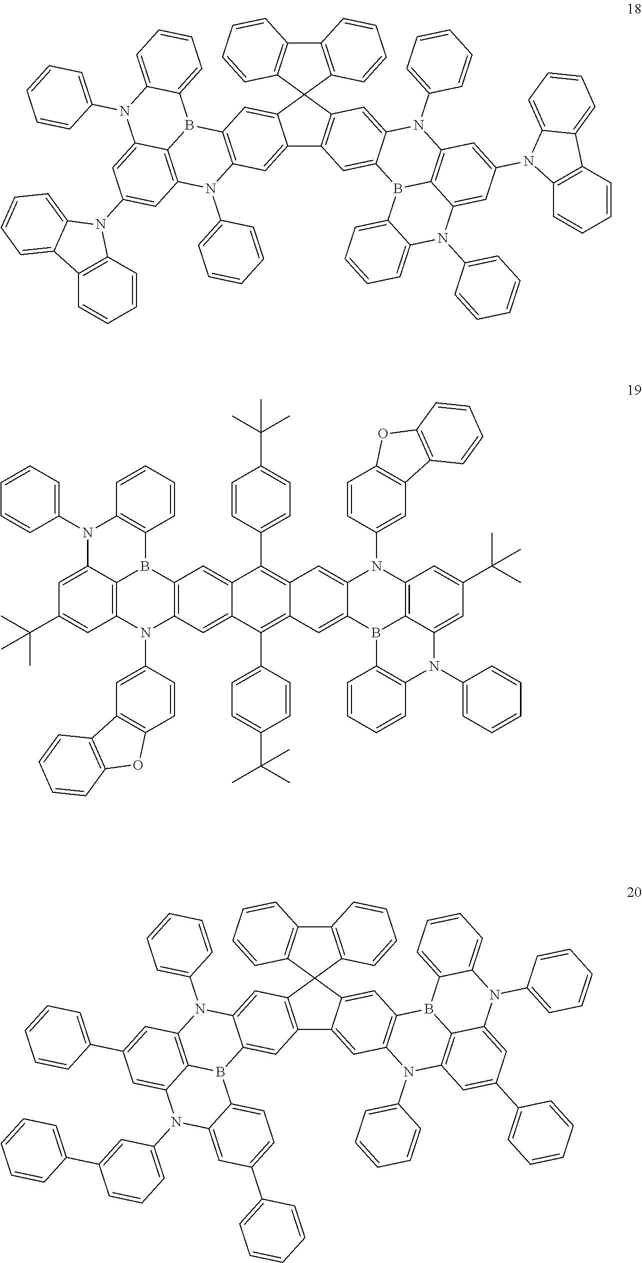 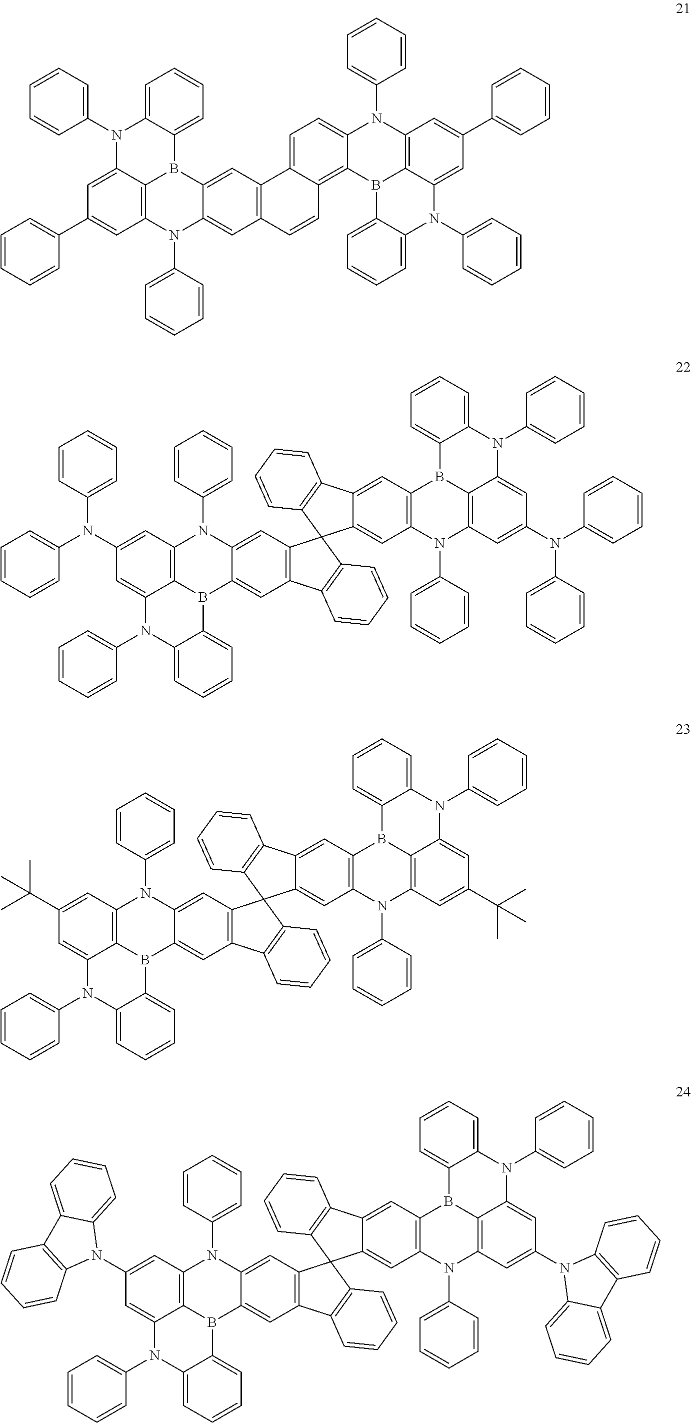 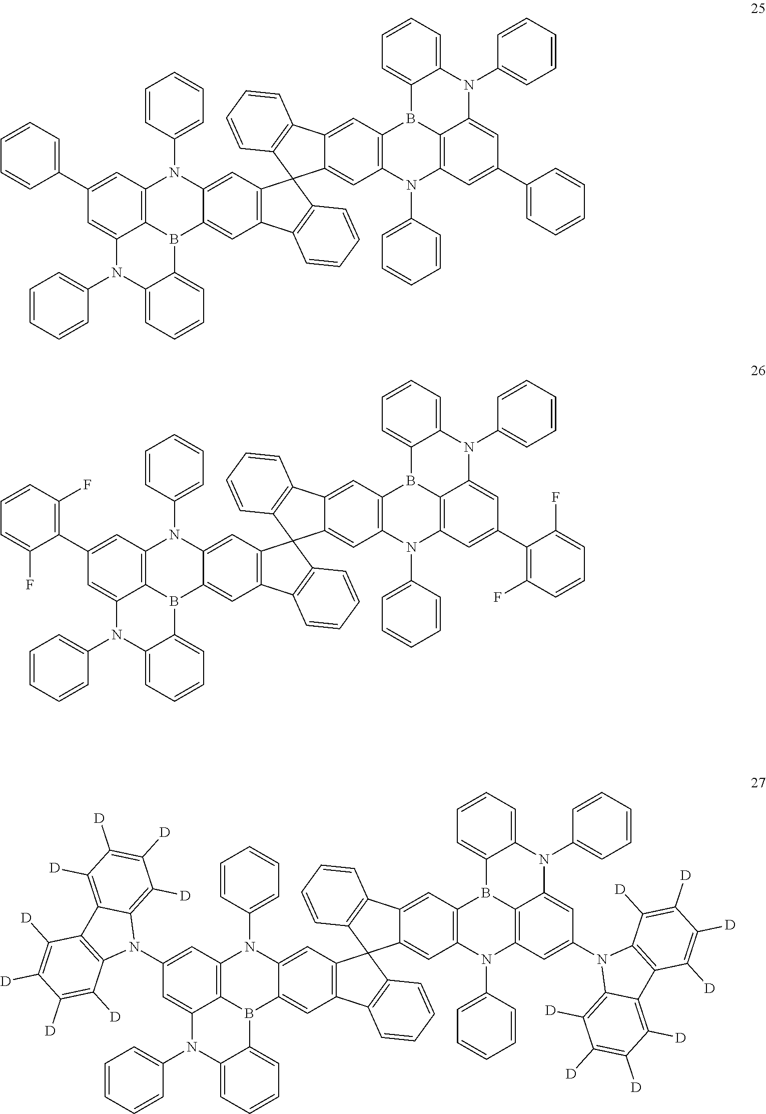 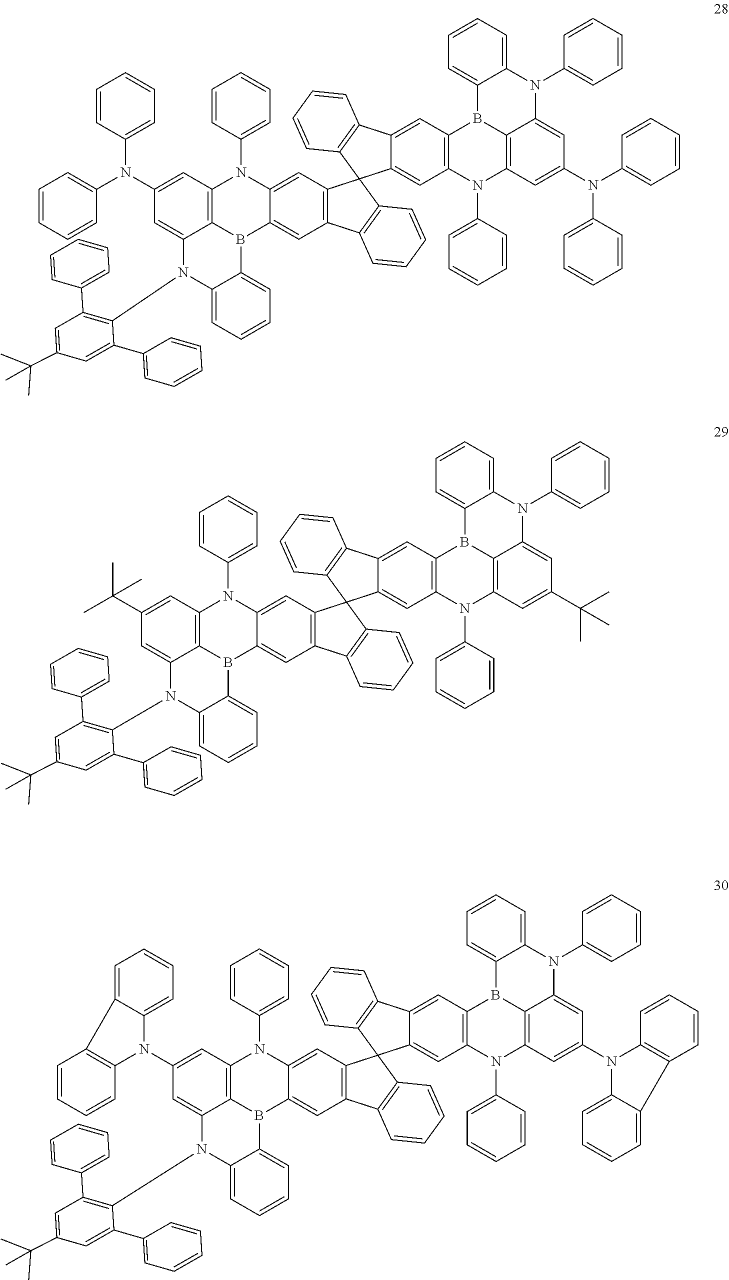 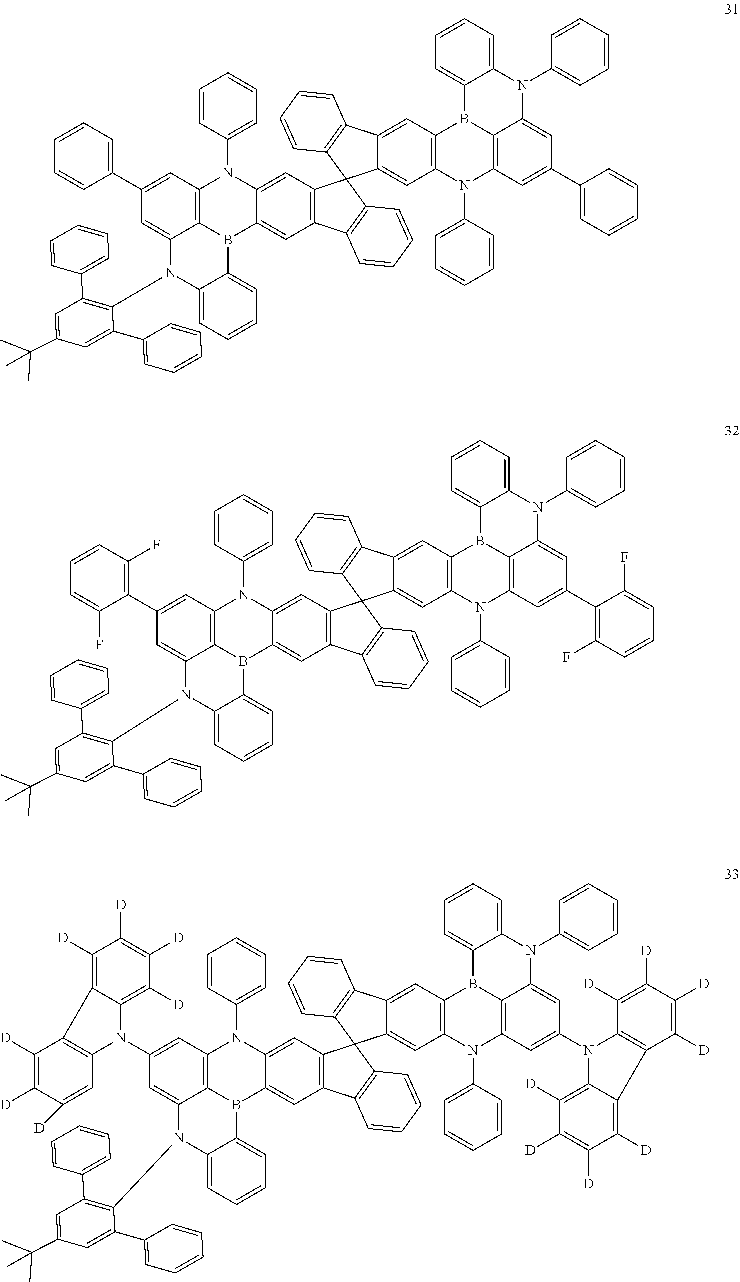 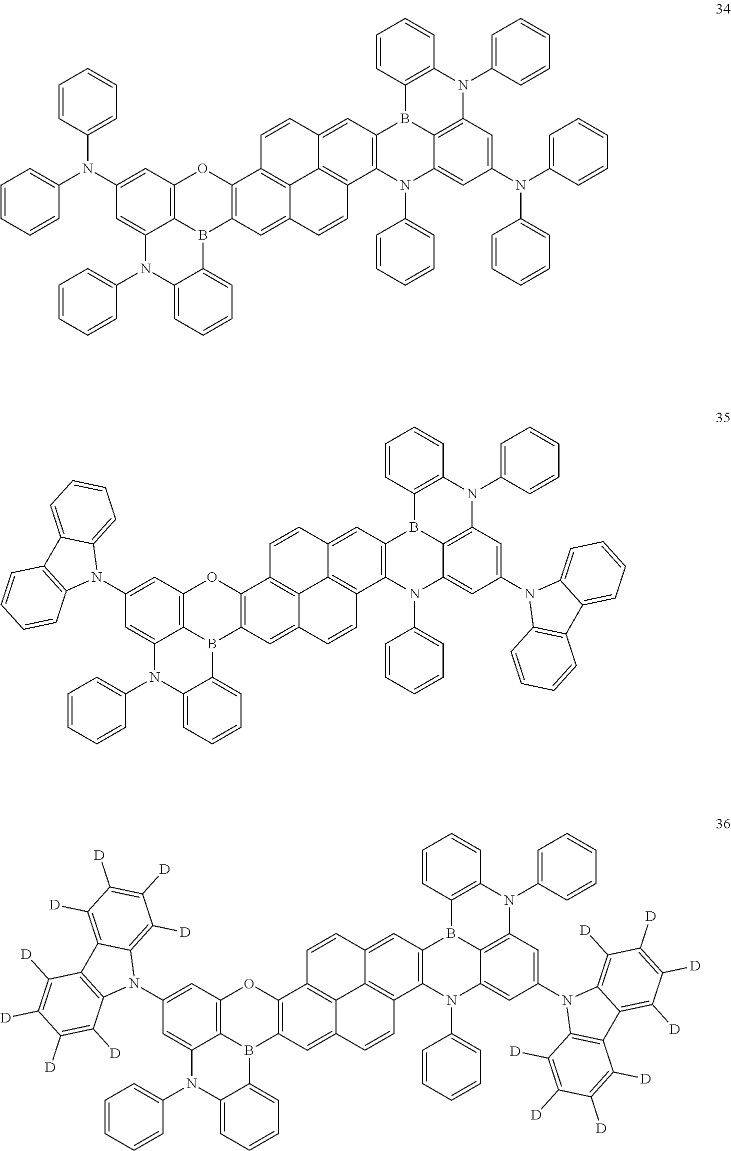 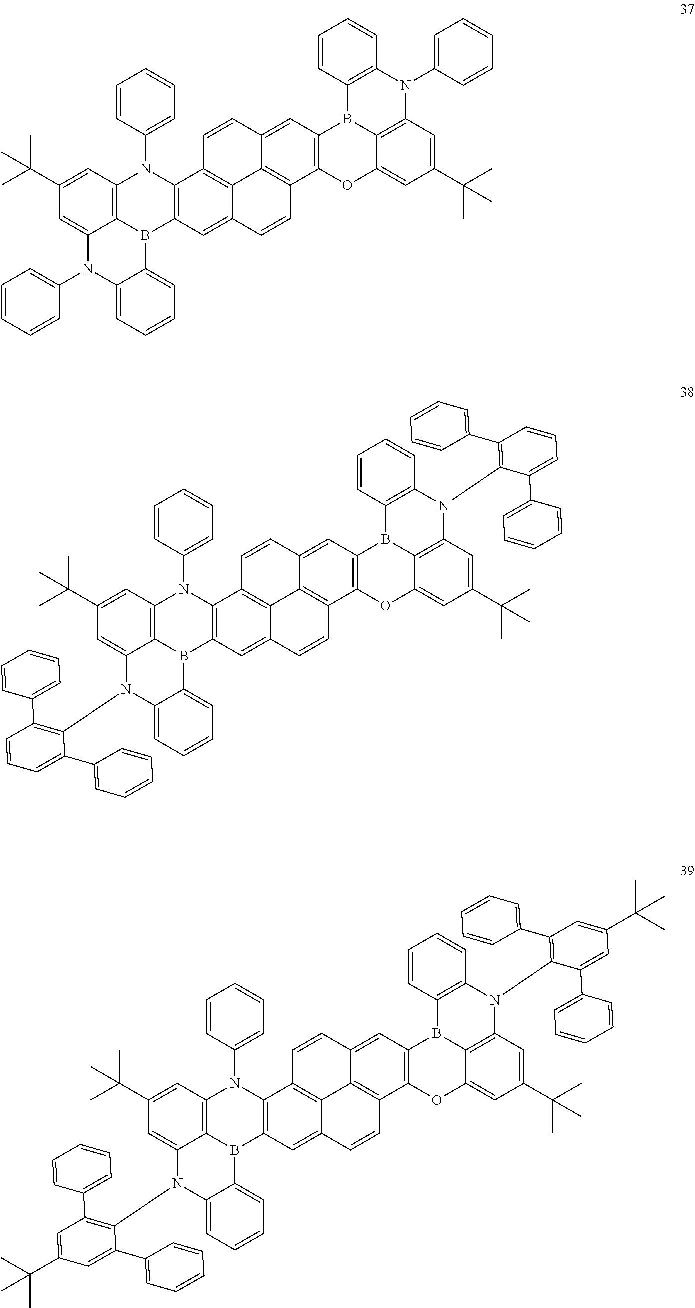 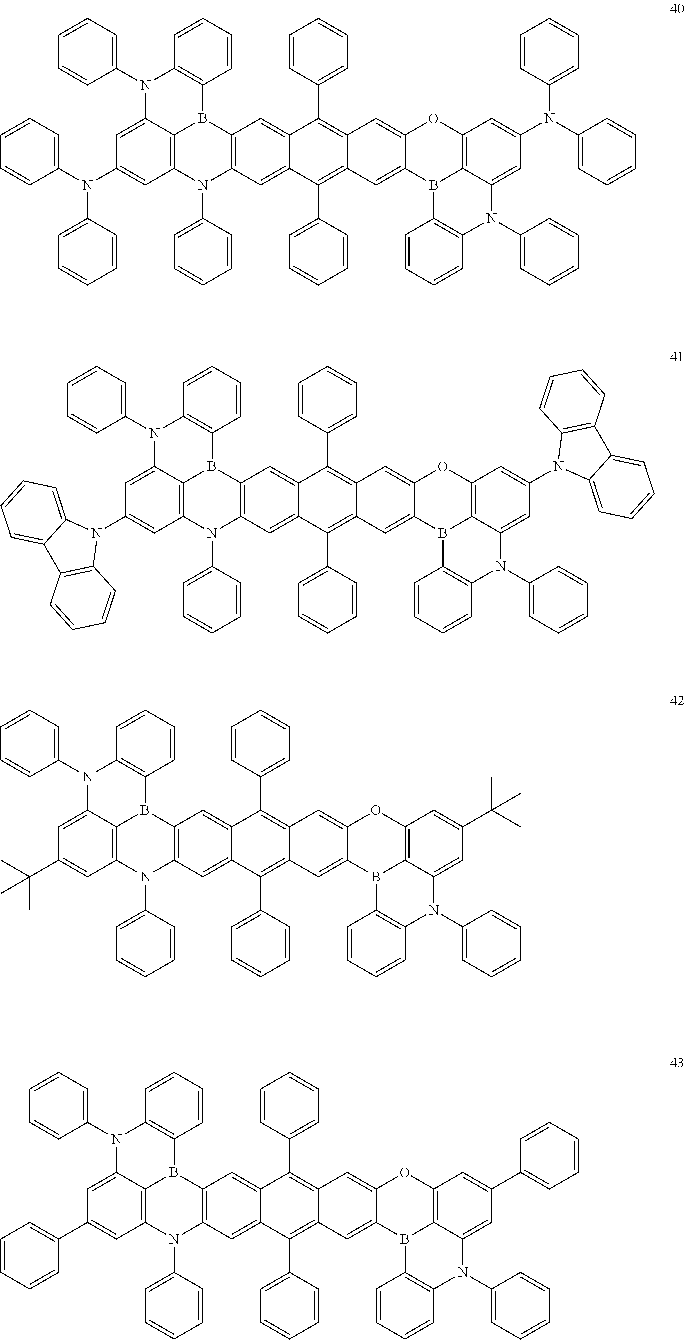 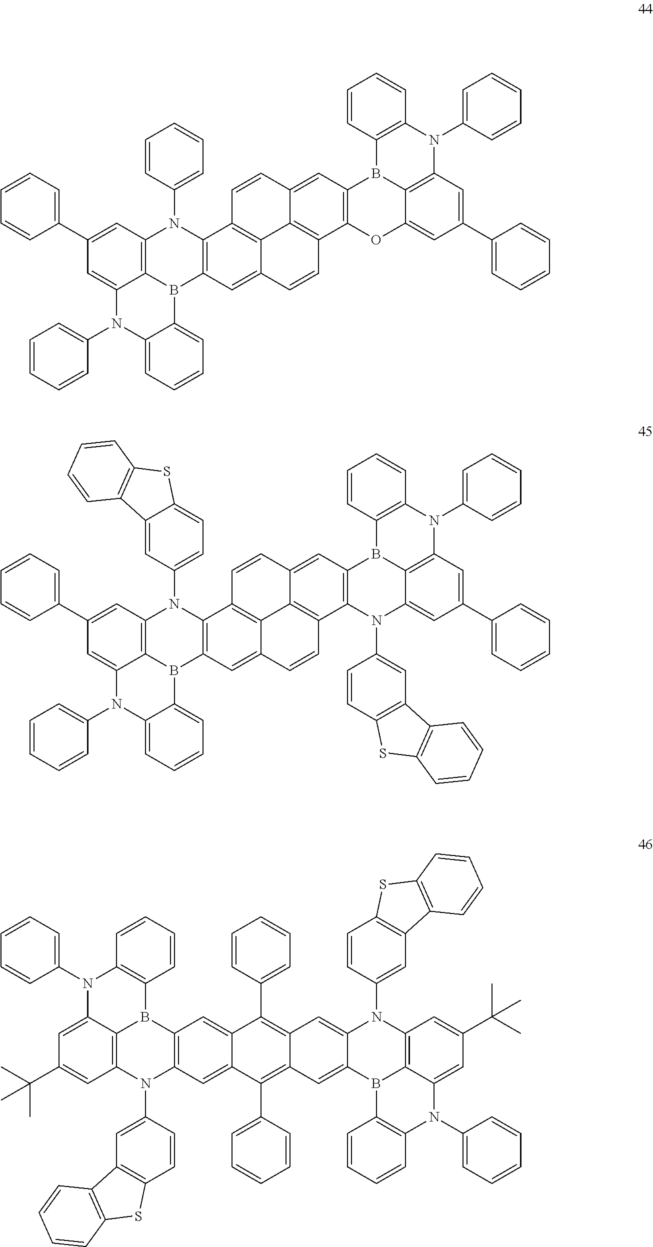 [SMILES: c1ccc(-c2cc3c4c(c2)N(c2ccccc2)c2ccccc2B4c2cc4ccc5c6c(cc7ccc(c2O3)c4c75)B2c3ccccc3N(c3ccccc3)c3cc(-c4ccccc4)cc(c32)N6c2ccccc2)cc1 ; c1ccc(-c2cc3c4c(c2)N(c2ccc5sc6ccccc6c5c2)c2c(cc5ccc6c7c(cc8ccc2c5c86)B2c5ccccc5N(c5ccccc5)c5cc(-c6ccccc6)cc(c52)N7c2ccc5sc6ccccc6c5c2)B4c2ccccc2N3c2ccccc2)cc1 ; CC(C)(C)c1cc2c3c(c1)N(c1ccc4sc5ccccc5c4c1)c1cc4c(-c5ccccc5)c5cc6c(cc5c(-c5ccccc5)c4cc1B3c1ccccc1N2c1ccccc1)N(c1ccc2sc3ccccc3c2c1)c1cc(C(C)(C)C)cc2c1B6c1ccccc1N2c1ccccc1] 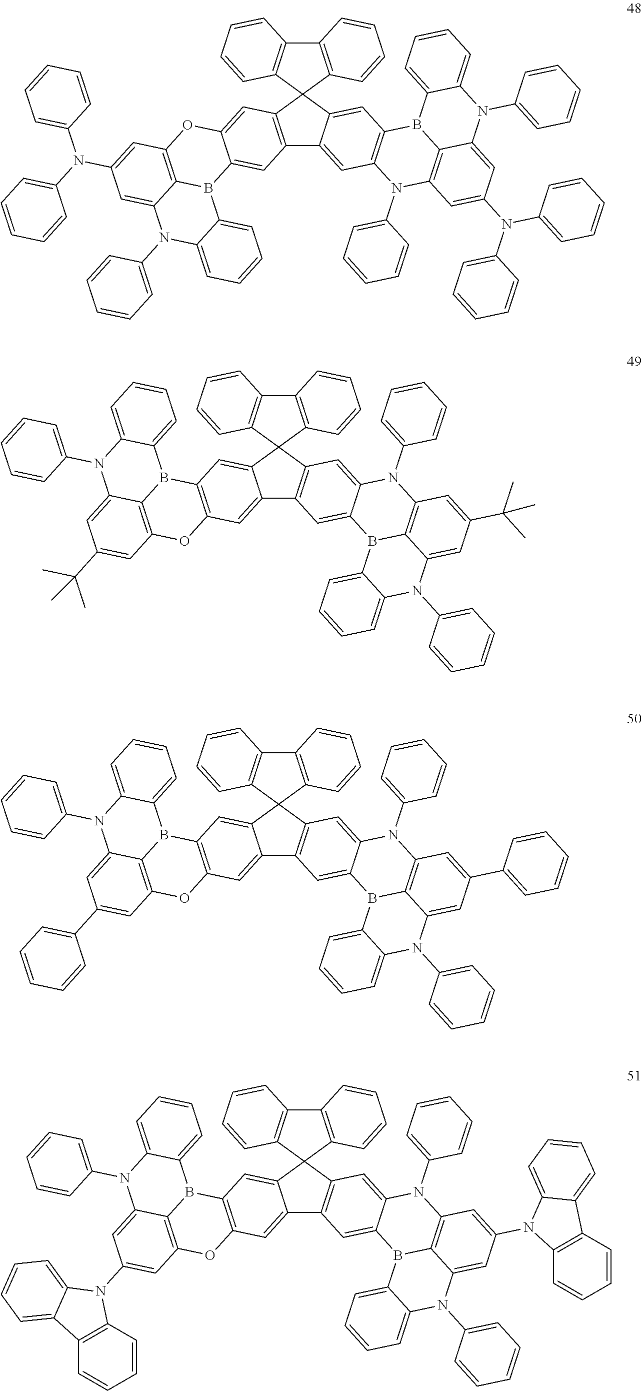 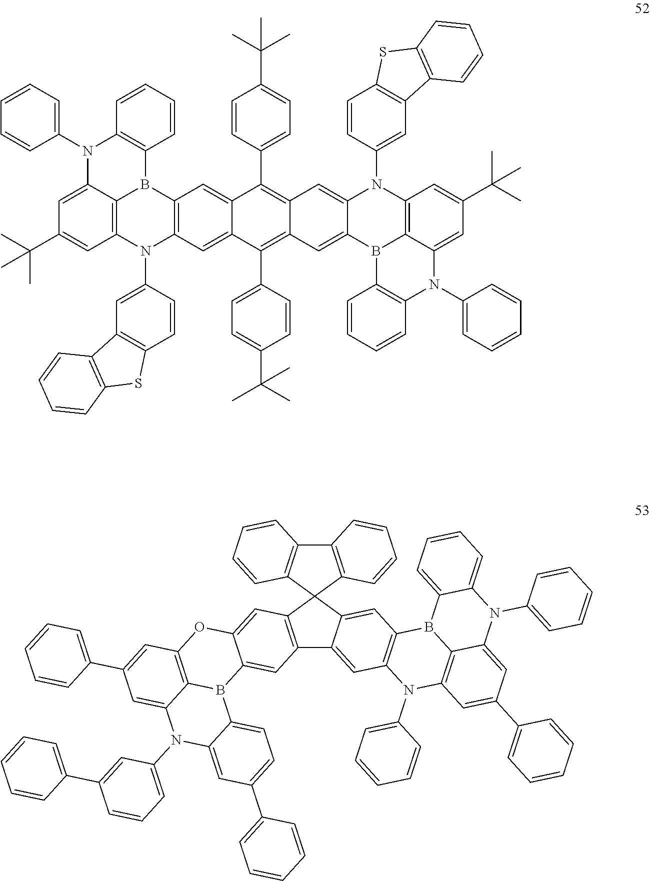 [SMILES: CC(C)(C)c1ccc(-c2c3cc4c(cc3c(-c3ccc(C(C)(C)C)cc3)c3cc5c(cc23)N(c2ccc3sc6ccccc6c3c2)c2cc(C(C)(C)C)cc3c2B5c2ccccc2N3c2ccccc2)N(c2ccc3sc5ccccc5c3c2)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5Oc5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1] 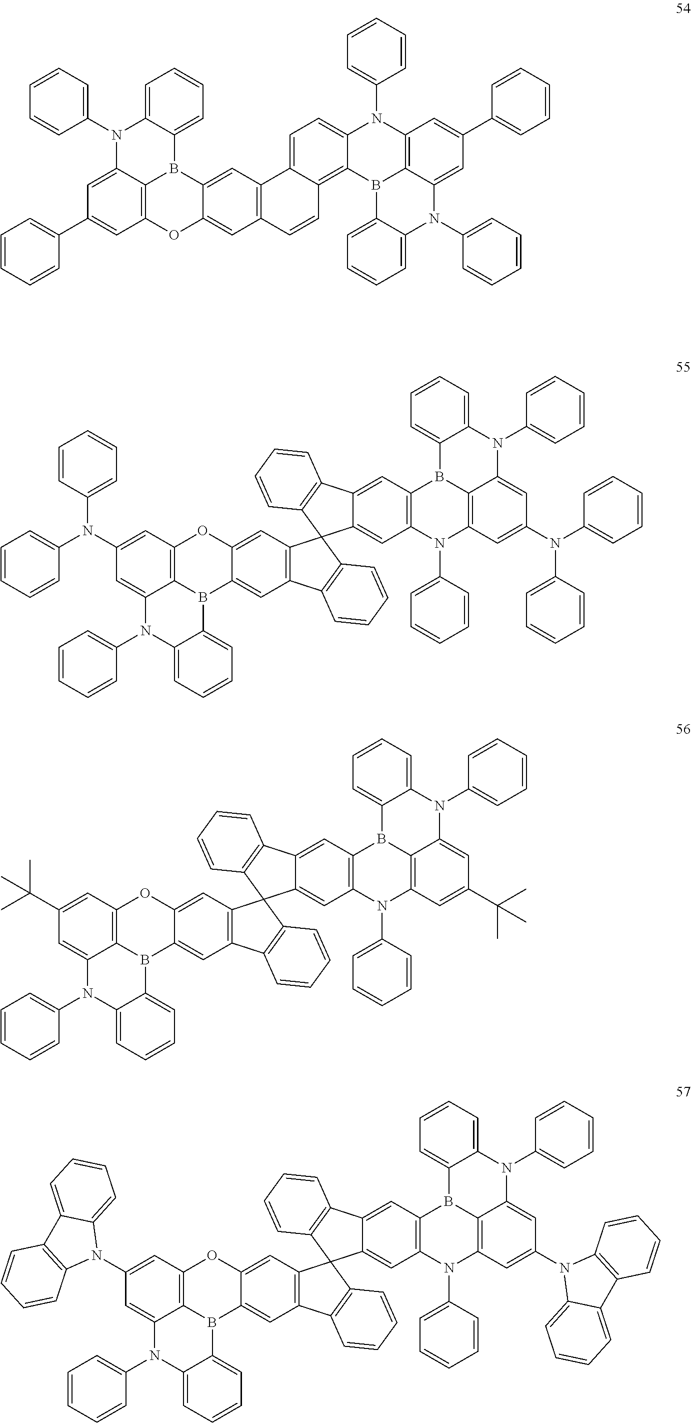 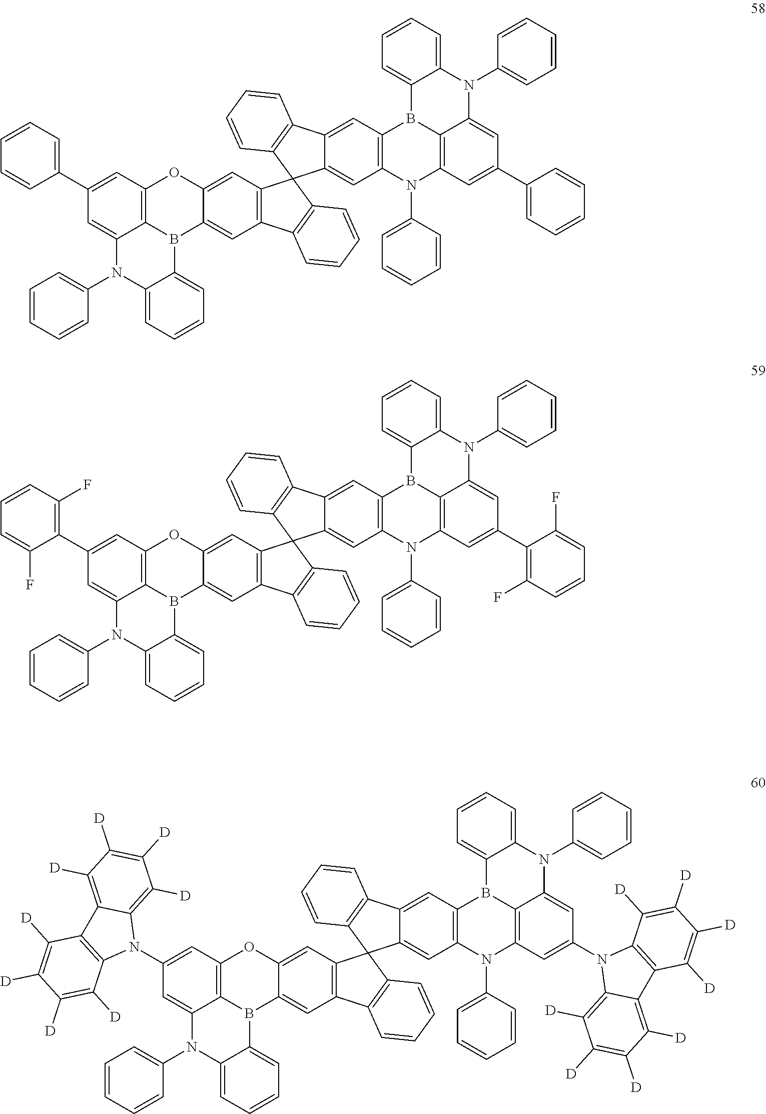 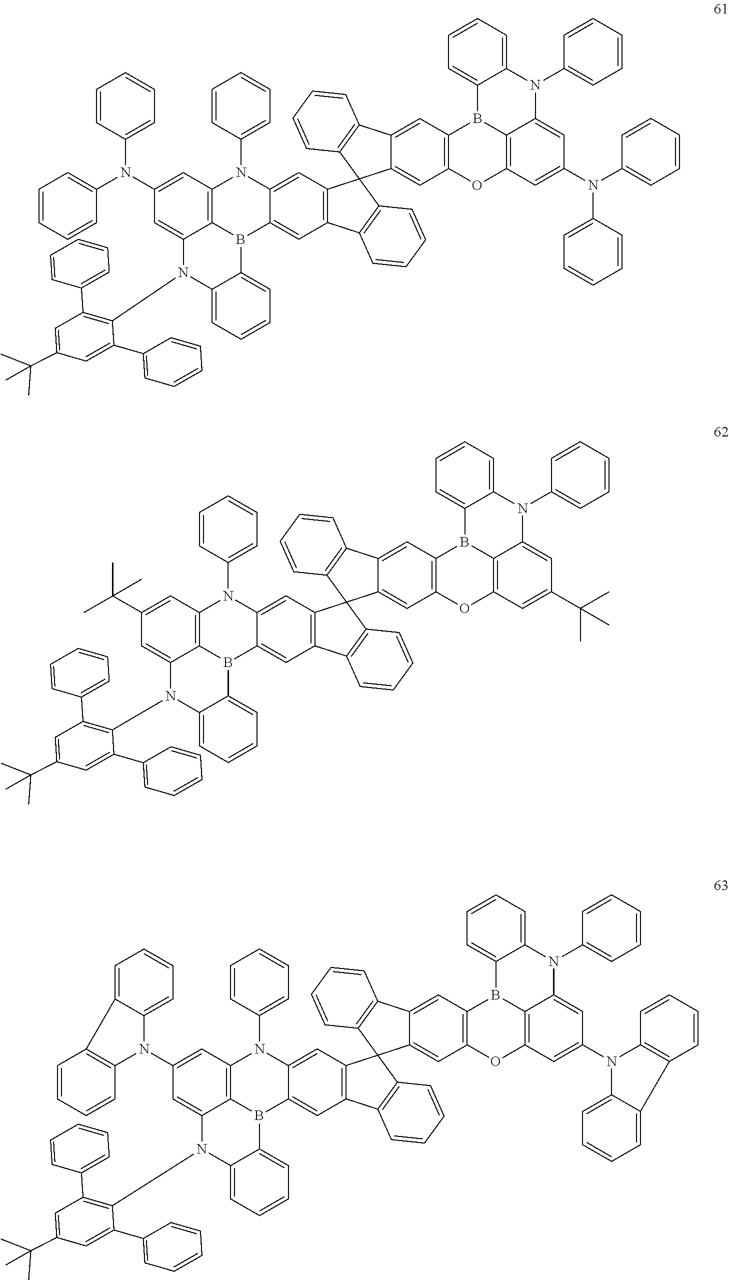 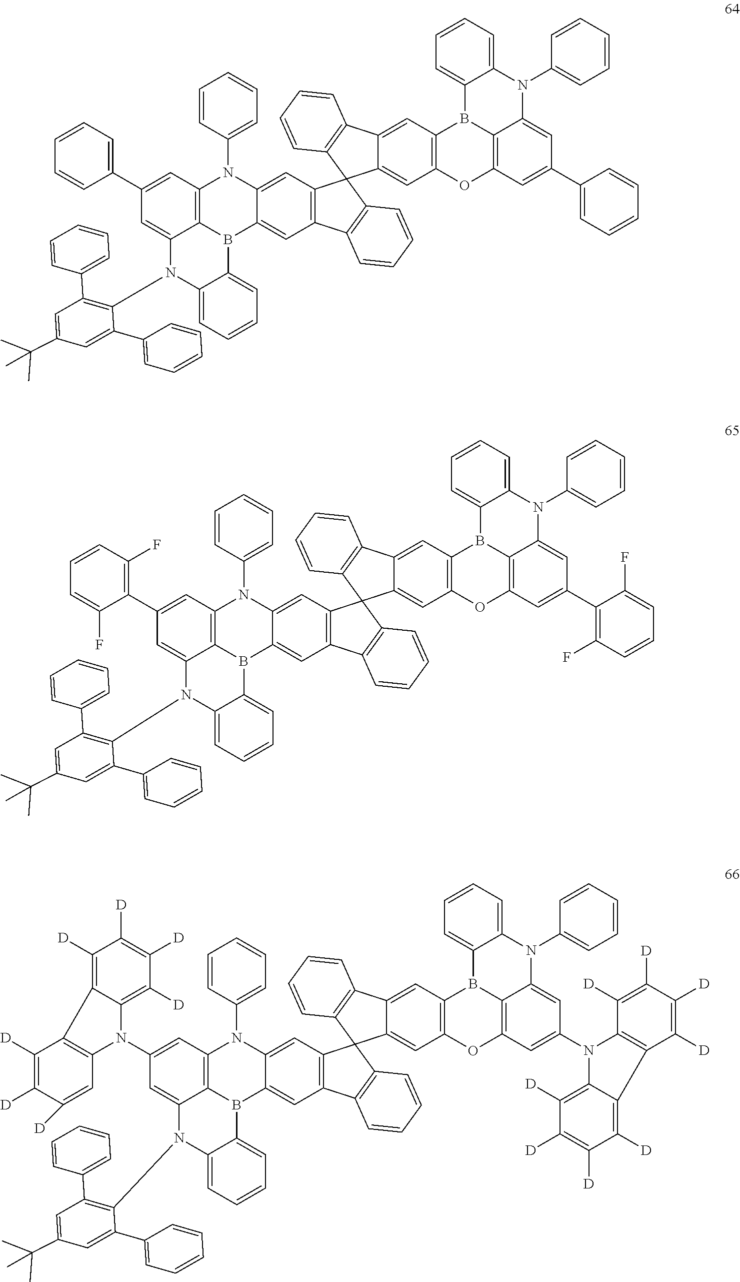 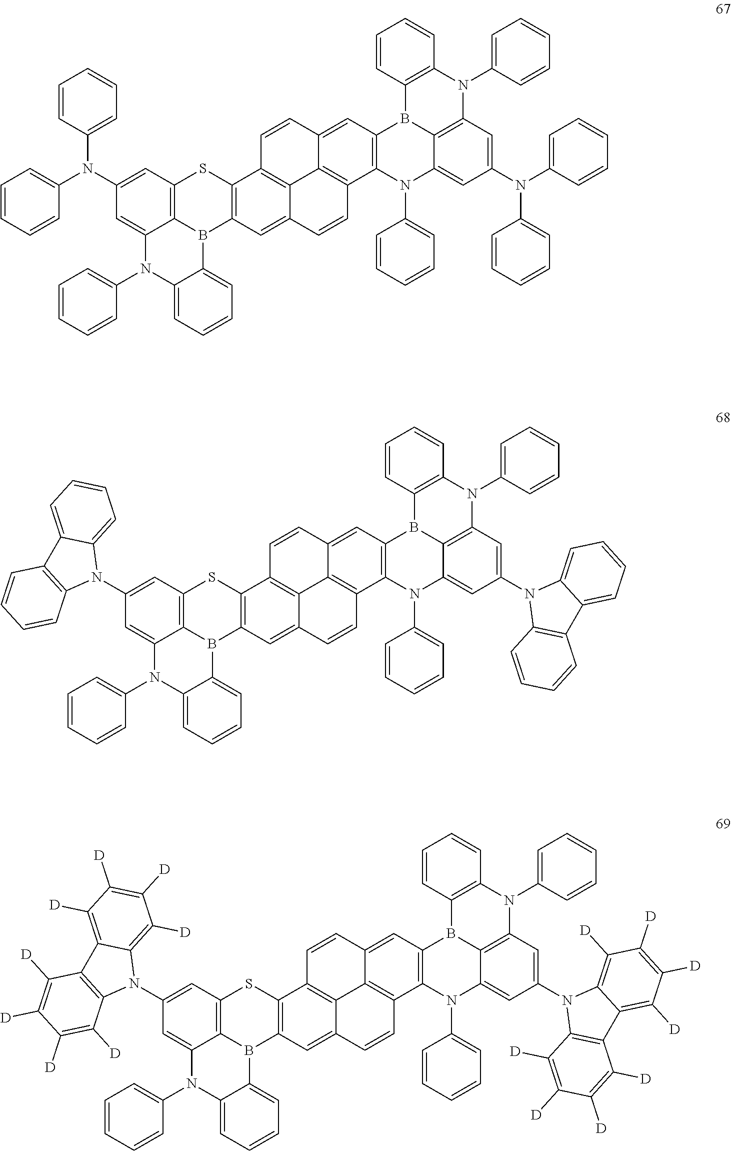 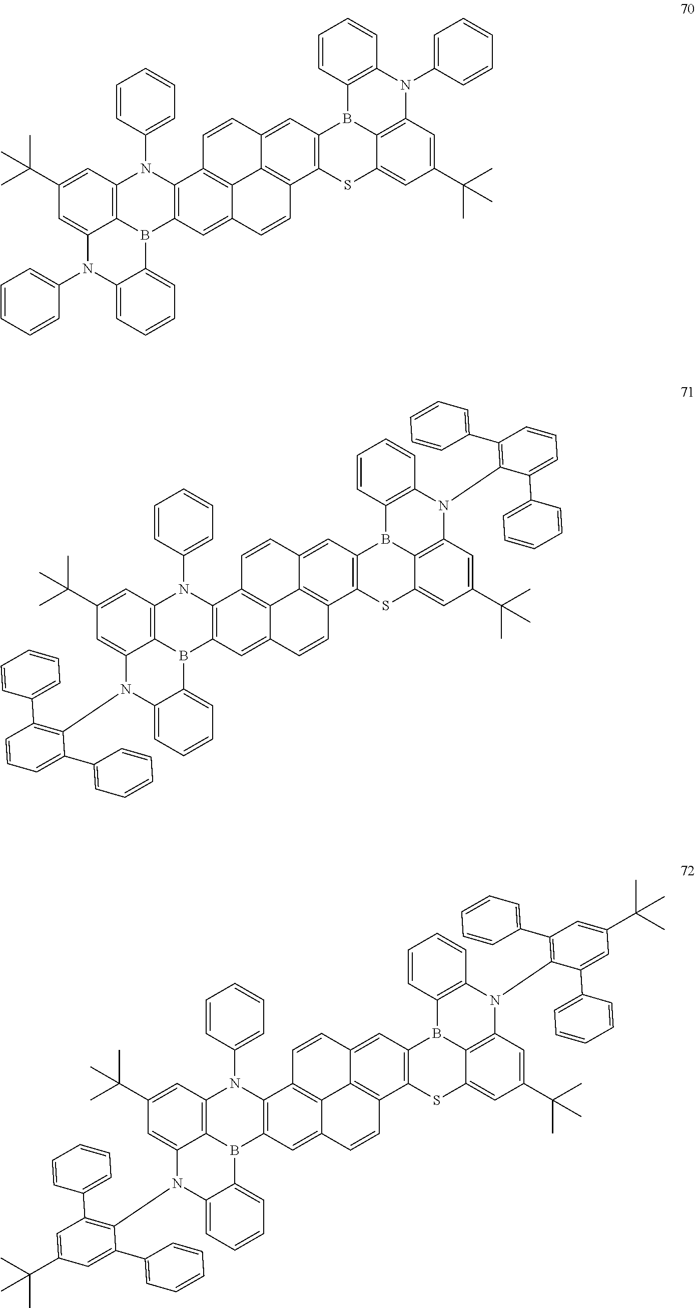 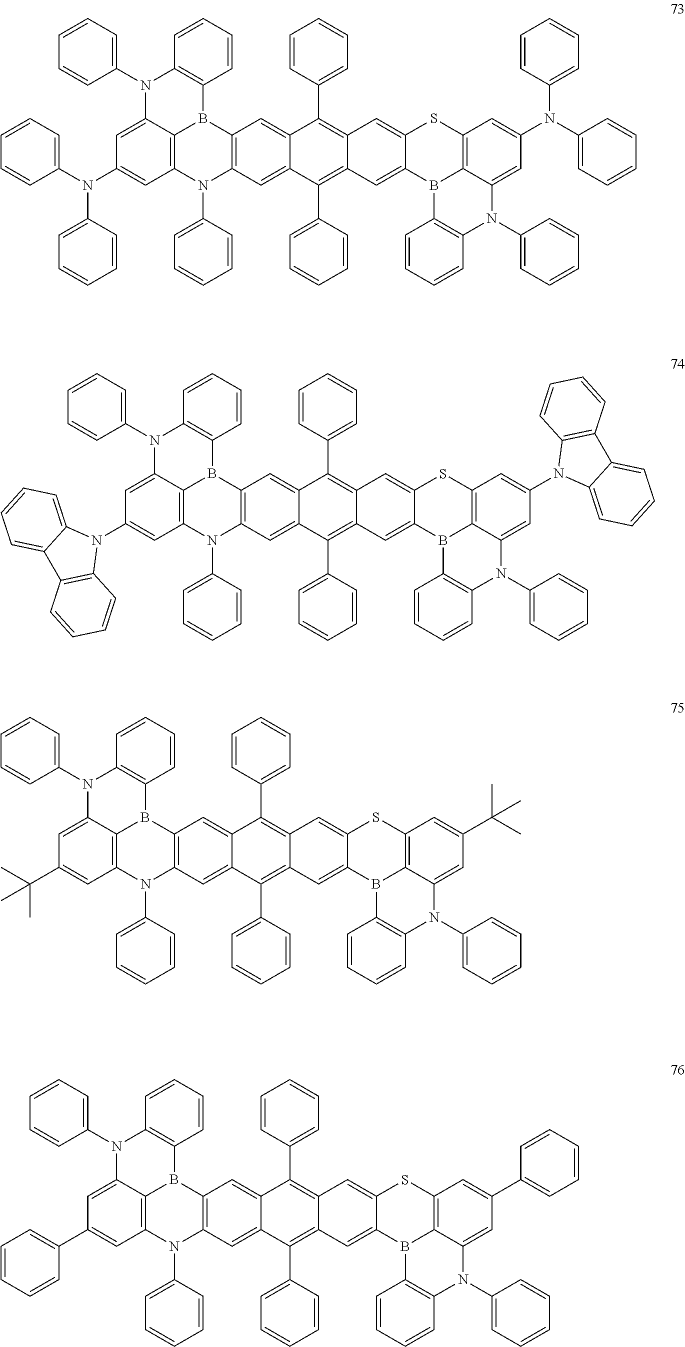 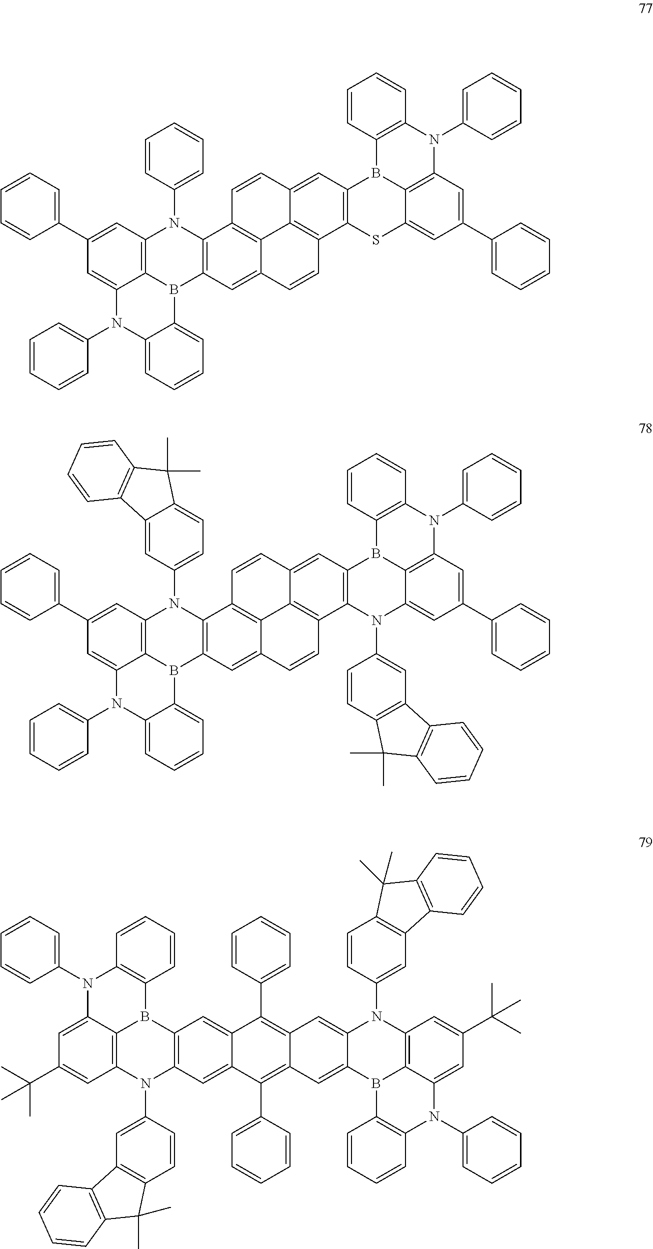 [SMILES: c1ccc(-c2cc3c4c(c2)N(c2ccccc2)c2ccccc2B4c2cc4ccc5c6c(cc7ccc(c2S3)c4c75)B2c3ccccc3N(c3ccccc3)c3cc(-c4ccccc4)cc(c32)N6c2ccccc2)cc1 ; CC1(C)c2ccccc2-c2cc(N3c4cc(-c5ccccc5)cc5c4B(c4ccccc4N5c4ccccc4)c4cc5ccc6c7c(cc8ccc(c43)c5c86)B3c4ccccc4N(c4ccccc4)c4cc(-c5ccccc5)cc(c43)N7c3ccc4c(c3)-c3ccccc3C4(C)C)ccc21 ; CC(C)(C)c1cc2c3c(c1)N(c1ccc4c(c1)-c1ccccc1C4(C)C)c1cc4c(-c5ccccc5)c5cc6c(cc5c(-c5ccccc5)c4cc1B3c1ccccc1N2c1ccccc1)N(c1ccc2c(c1)-c1ccccc1C2(C)C)c1cc(C(C)(C)C)cc2c1B6c1ccccc1N2c1ccccc1] 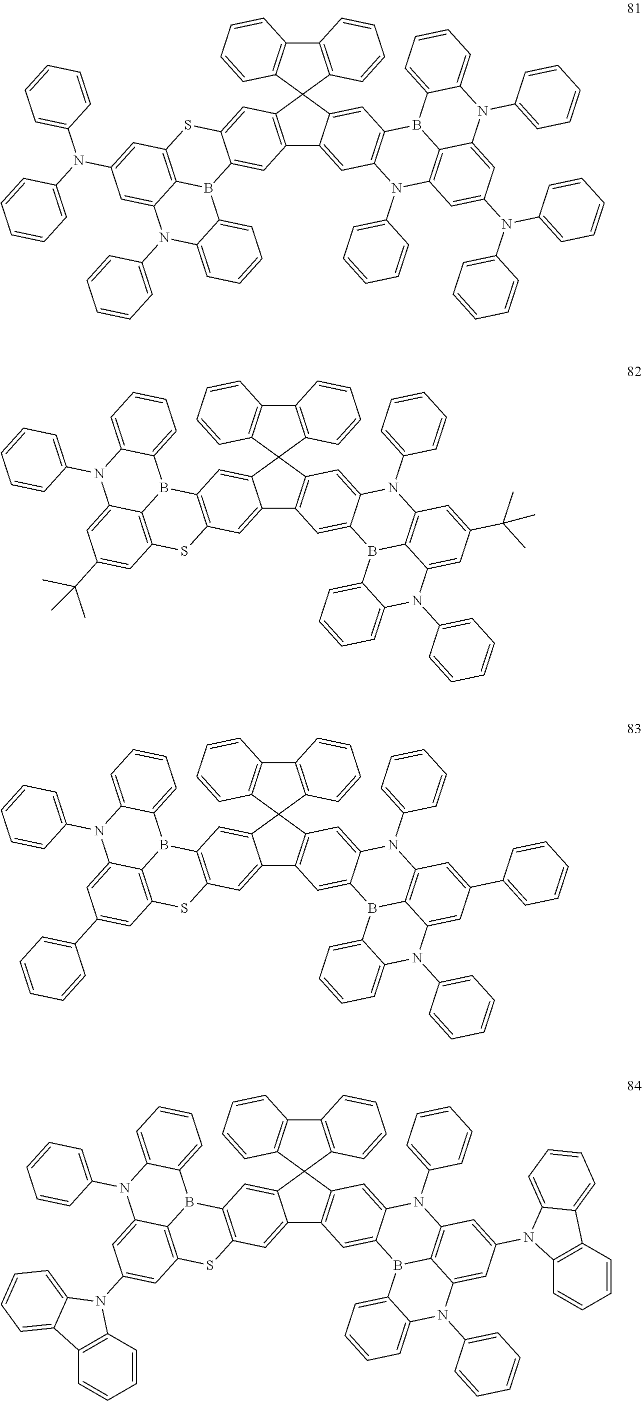 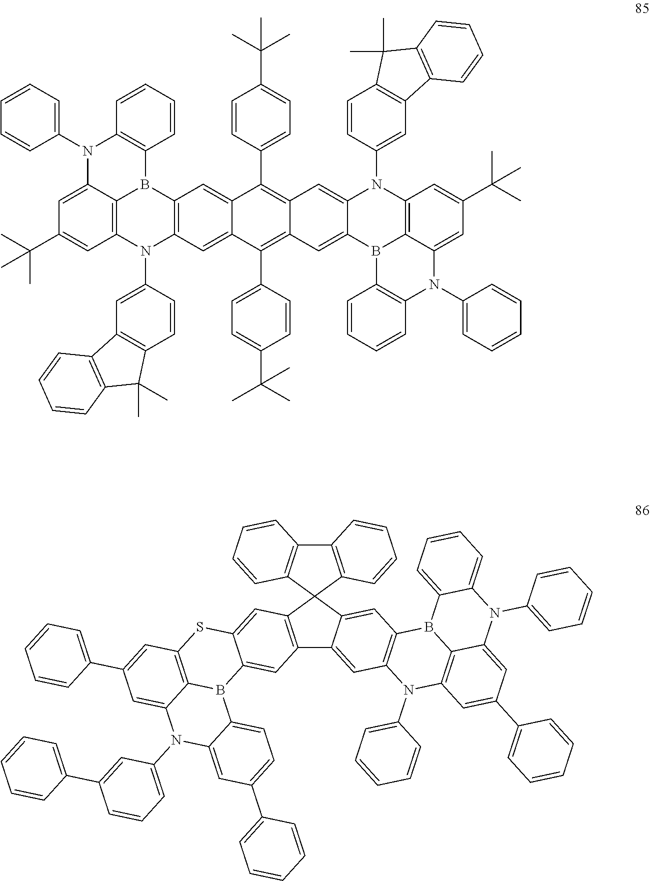 [SMILES: CC(C)(C)c1ccc(-c2c3cc4c(cc3c(-c3ccc(C(C)(C)C)cc3)c3cc5c(cc23)N(c2ccc3c(c2)-c2ccccc2C3(C)C)c2cc(C(C)(C)C)cc3c2B5c2ccccc2N3c2ccccc2)N(c2ccc3c(c2)-c2ccccc2C3(C)C)c2cc(C(C)(C)C)cc3c2B4c2ccccc2N3c2ccccc2)cc1 ; c1ccc(-c2cccc(N3c4cc(-c5ccccc5)ccc4B4c5cc6c(cc5Sc5cc(-c7ccccc7)cc3c54)C3(c4ccccc4-c4ccccc43)c3cc4c(cc3-6)N(c3ccccc3)c3cc(-c5ccccc5)cc5c3B4c3ccccc3N5c3ccccc3)c2)cc1] 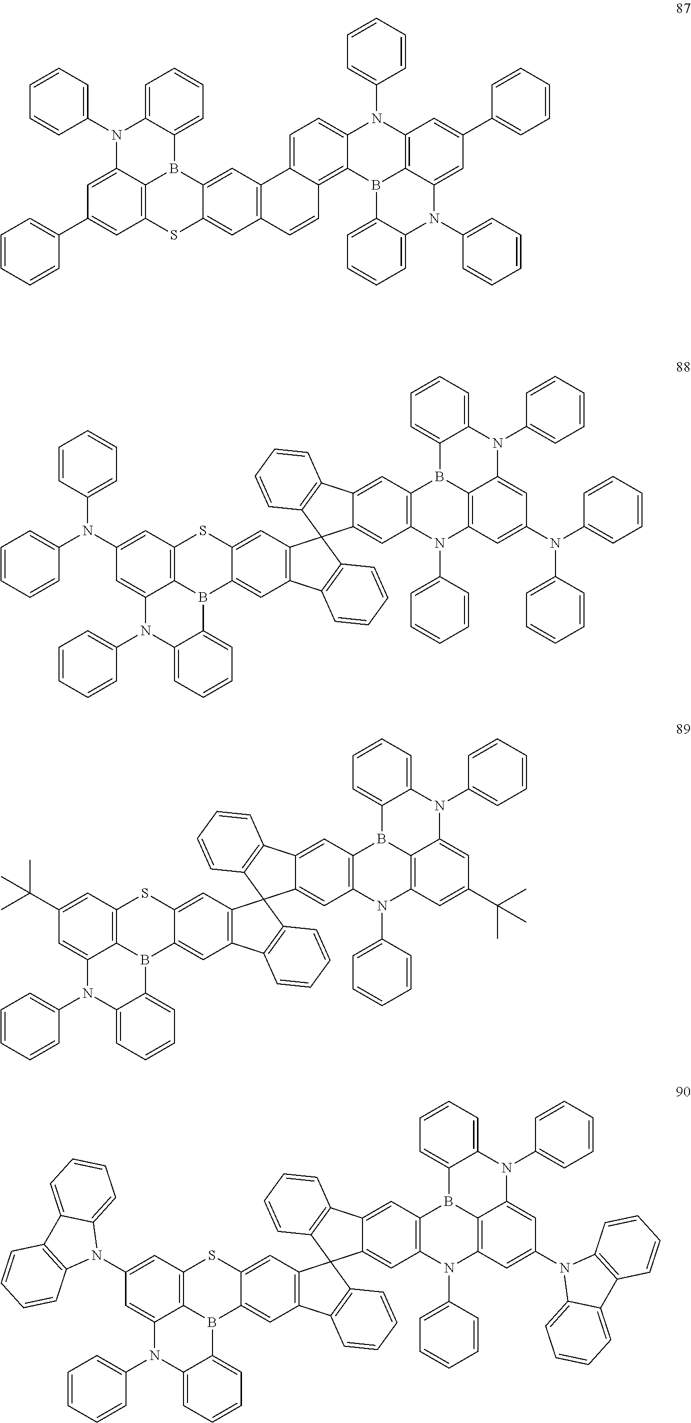 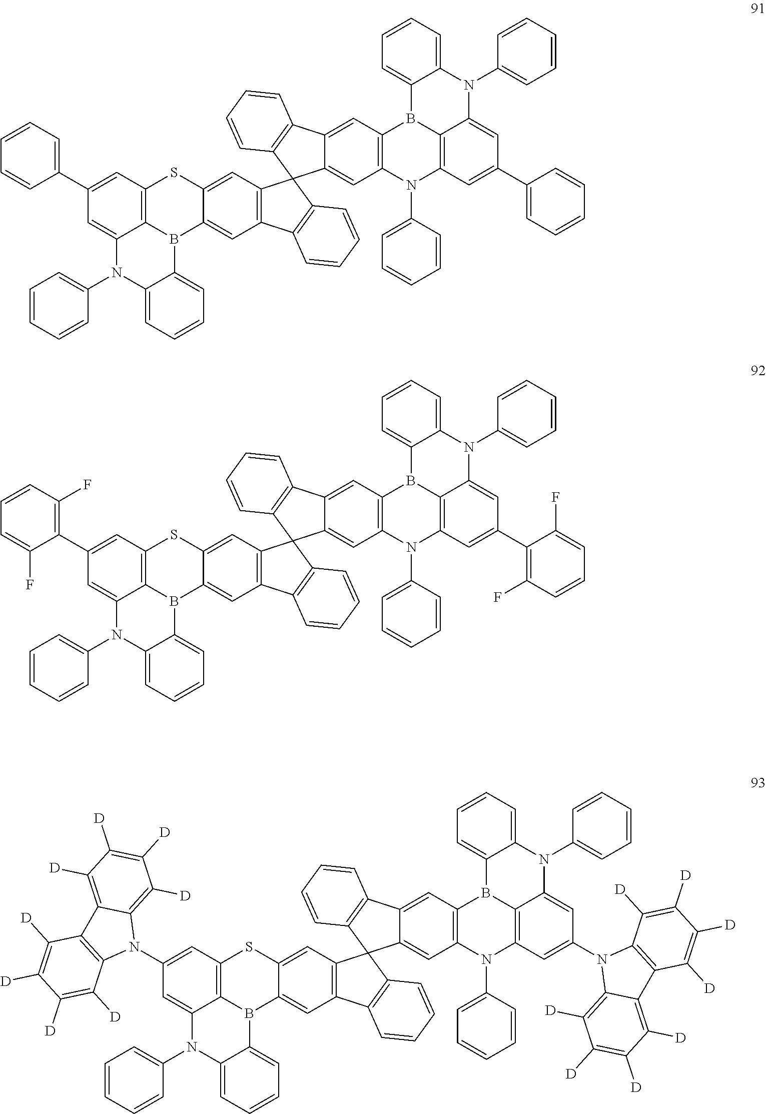 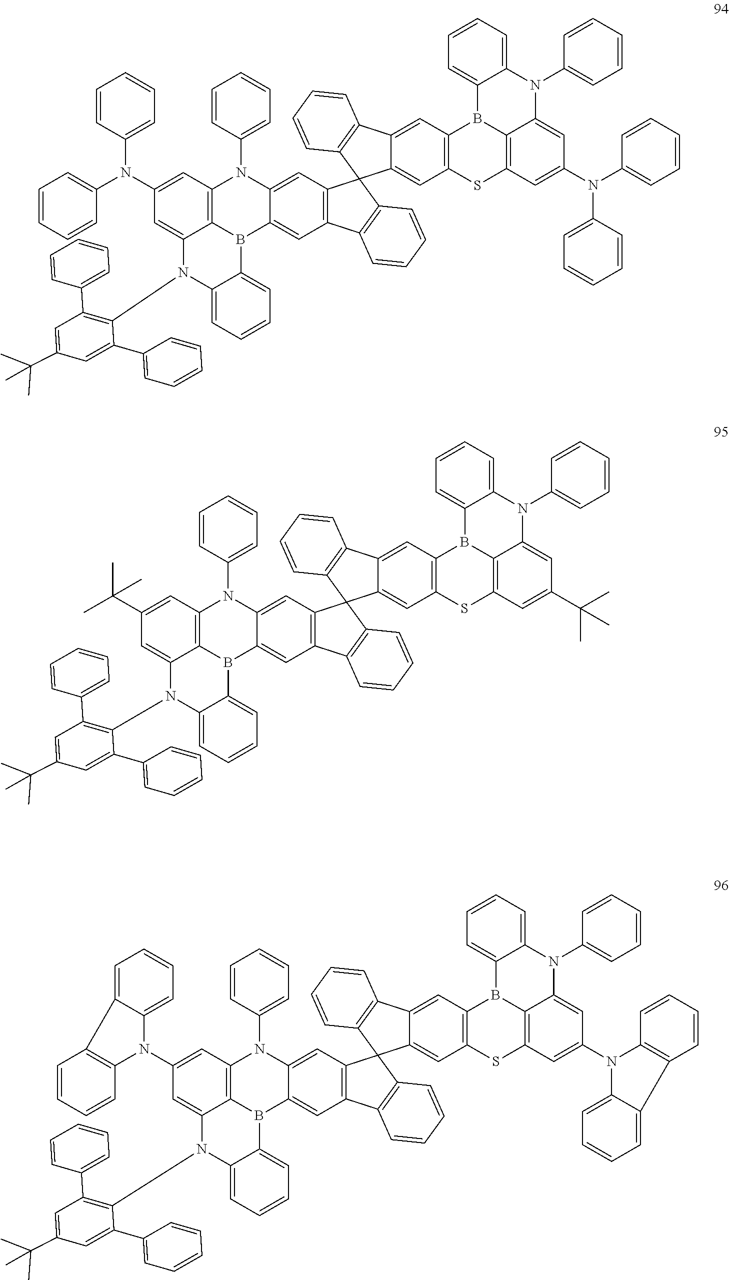 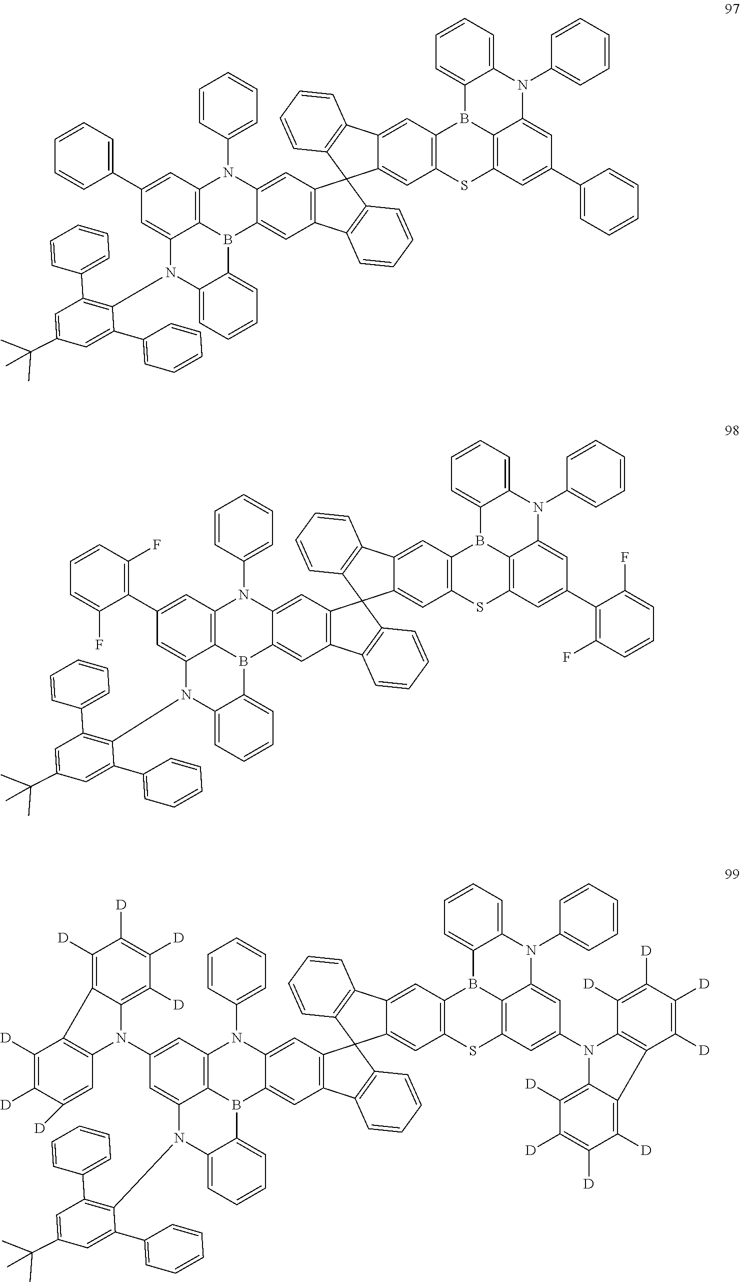
wherein in Compound Group 1,
D indicates a deuterium atom.

24. The polycyclic compound of claim 14, wherein in the polycyclic compound represented by Formula 1, a difference between a lowest singlet energy level and a second lowest triplet energy level is greater than a difference between the second lowest triplet energy level and a lowest triplet energy level.
